(19) United States
(12) Patent Application Publication
(10) Pub. No.: US 2023/0006143 A1
(43) Pub. Date: Jan. 5, 2023

(54) MIXTURE OF TWO HOST MATERIALS, AND ORGANIC ELECTROLUMINESCENT DEVICE COMPRISING SAME

(71) Applicant: Merck Patent GmbH, Darmstadt (DE)

(72) Inventors: Amir Hossain PARHAM, Frankfurt am Main (DE); Jonas Valentin KROEBER, Frankfurt am Main (DE); Jens ENGELHART, Darmstadt (DE); Christian EHRENREICH, Darmstadt (DE); Christian EICKHOFF, Mannheim (DE)

(21) Appl. No.: 17/761,223

(22) PCT Filed: Sep. 15, 2020
(86) PCT No.: PCT/EP2020/075689

§ 371 Date: Mar. 17, 2022

(30) Foreign Application Priority Data
Sep. 19, 2019 (EP) 19198370.9

(51) Int. Cl. H01L 51/00; C09K 11/02; C09K 11/06; H01L 51/56

(52) U.S. Cl. CPC H01L 51/0067; C09K 11/02; C09K 11/06; H01L 51/0072; H01L 51/0085; H01L 51/0073; H01L 51/0074; H01L 51/56; C09K 2211/185; C09K 2211/1029; C09K 2211/1033; C09K 2211/1007; H01L 51/5016

(57) ABSTRACT

The present invention relates to an organic electroluminescent device containing a mixture which comprises an electron-transporting host material and a hole-transporting host material, to a formulation comprising a mixture of the host materials and to a mixture comprising the host materials. The electron-transporting host material corresponds to a compound of the formula (1) from the class of compounds containing two triazine units. The hole-transporting host material corresponds to a compound of the formula (2) from the class of the biscarbazoles or derivatives thereof.

The present invention relates to an organic electroluminescent device containing a mixture which comprises an electron-transporting host material and a hole-transporting host material, and to a formulation comprising a mixture of the host materials and a mixture comprising the host materials. The electron-transporting host material corresponds to a compound of the formula (1), as described below, from the class of compounds containing two triazine units. The hole-transporting host material corresponds to a compound of the formula (2), as described below, from the class of the biscarbazoles or derivatives thereof.

The structure of organic electroluminescent devices (e.g. OLEDs—organic light-emitting diodes, or OLECs—organic light-emitting electrochemical cells) in which organic semiconductors are employed as functional materials has been known for some time. The emitting materials employed here, besides fluorescent emitters, are increasingly organometallic complexes, which exhibit phosphorescence instead of fluorescence. For quantum-mechanical reasons, an up to four-fold increased energy and power efficiency is possible using organometallic compounds as phosphorescence emitters. In general, however, there is still a need for improvement, in particular with respect to efficiency, operating voltage and lifetime, in the case of OLEDs, in particular also in the case of OLEDs which exhibit triplet emission (phosphorescence).

The properties of organic electroluminescent devices are not determined only by the emitters employed. In particular, the other materials used, such as host and matrix materials, hole-blocking materials, electron-transport materials, hole-transport materials and electron- or exciton-blocking materials, are also of particular importance here, and of these in particular the host or matrix materials. Improvements in these materials can result in significant improvements in electroluminescent devices.

Host materials for use in organic electronic devices are well known to the person skilled in the art. In the prior art, the term matrix material is frequently also used if a host material for phosphorescent emitters is meant. This use of the term also applies for the present invention. In the meantime, a multiplicity of host materials has been developed, both for fluorescent electronic devices and for phosphorescent electronic devices.

Another way of improving the performance data of electronic devices, in particular of organic electroluminescent devices, consists in using combinations of two or more materials, in particular host materials or matrix materials.

U.S. Pat. No. 6,392,250 B1 discloses the use of a mixture consisting of an electron-transport material, a hole-transport material and a fluorescent emitter in the emission layer of an OLED. With the aid of this mixture, it was possible to improve the lifetime of the OLED compared with the prior art.

U.S. Pat. No. 6,803,720 B1 discloses the use of a mixture comprising a phosphorescent emitter and a hole-transport material and an electron-transport material in the emission layer of an OLED. Both the hole-transport material and the electron-transport material here are small organic molecules.

KR20100131745 describes specifically connected bistriazine compounds and the use thereof as host material in an organic electroluminescent device. Also described are devices containing these bistriazine compounds in the light-emitting layer together with indolocarbazole compounds as further host material.

WO2012048779 discloses inks for use in organic electroluminescent devices, comprising a carbazole compound, an electron-transport compound, a triplet emitter compound and at least one solvent, where the electron-transport compound includes a ketone compound or a triazine compound, which may also be a specifically connected triazine compound, and where the carbazole compound contains at least two carbazole groups which are connected to one another via their N atoms.

US20140299192 discloses specifically connected bistriazine compounds and the use thereof in an organic electroluminescent device, in particular as electron-transport material.

JP2015106658 also describes, inter alia, a dibenzofuran compound which is substituted in the 2 and 8 position by 4,6-diphenyl-1,3,5-triazin-2-ylphenyl, and the use thereof as host material in an organic electroluminescent device together with a further host material.

WO2015169412 describes compounds containing two triazine units which can be used as host material in an organic electroluminescent device together with a further host material.

US2016329502 discloses organic electroluminescent devices containing a light-emitting layer comprising three components, a first host material, a compound according to the invention as second host material and an emitter, where the compounds according to the invention could contain two triazine units.

US20170054087 describes specific triazine derivatives and the use thereof as host material together with other host materials in a light-emitting electronic device.

WO2017178311 describes specific dibenzofuran compounds or dibenzothiophene compounds which may carry two triazine substituents, and the use thereof in an organic electroluminescent device, where these compounds can also be employed as host material. It is furthermore described that compounds of this type can be combined with further host materials. Table 1 describes, for example, the structure of an organic light-emitting diode (E11) which comprises two host materials in the light-emitting layer, where 7,7-dimethyl-5-phenyl-2-(9-phenylcarbazol-3-yl)indeno[2,1-b]-carbazole is used as second host material.

CN108250189 describes specific dibenzofuran compounds or dibenzothiophene compounds which may carry two triazine substituents, and the use thereof as host material in an organic electroluminescent device.

US2019013490 describes specific dibenzofuran compounds or dibenzothiophene compounds and the use thereof as host material in combination with further host materials.

WO19017730 describes specific dibenzofuran compounds or dibenzothiophene compounds and the use thereof as host material.

WO19122899 describes specific bistriazine compounds and the use thereof as host material in a light-emitting layer together with a light-emitting material.

However, there is still a need for improvement on use of these materials or on use of mixtures of the materials, in particular in relation to efficiency, operating voltage and/or lifetime of the organic electroluminescent device.

The object of the present invention is therefore the provision of a combination of host materials which are suitable for use in an organic electroluminescent device, in particular in a fluorescent or phosphorescent OLED, and lead to good device properties, in particular with respect to an improved lifetime, and the provision of the corresponding electroluminescent device.

It has now been found that the combination of at least one compound of the formula (1) as first host material and at least one hole-transporting compound of the formula (2) as second host material in a light-emitting layer of an organic electroluminescent device achieves this object and overcomes the disadvantages from the prior art. The use of a material combination of this type for the production of the light-emitting layer in an organic electroluminescent device leads to very good properties of these devices, in particular with respect to the lifetime, in particular with the same or improved efficiency and/or operating voltage. The advantages are also evident, in particular, in the presence of a light-emitting component in the emission layer, in particular on combination with emitters of the formula (3), at concentrations between 2 and 15% by weight.

The present invention therefore relates firstly to an organic electroluminescent device comprising an anode, a cathode and at least one organic layer, comprising at least one light-emitting layer, where the at least one light-emitting layer comprises at least one compound of the formula (1) as host material 1 and at least one compound of the formula (2) as host material 2,

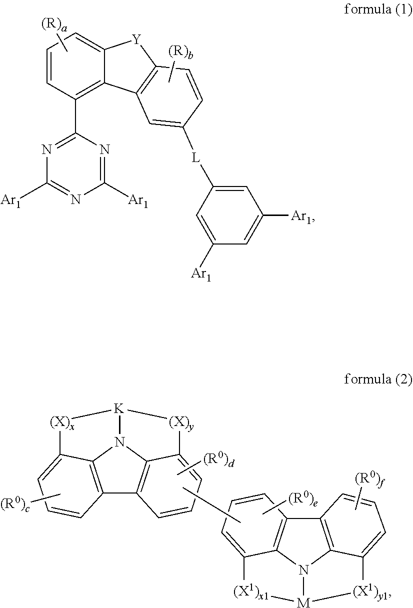

where the following applies to the symbols and indices used:
Y is selected from O, S, C(CH₃)₂, C(phenyl)₂ or

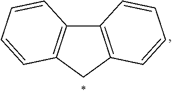 [SMILES: c1ccc2c(c1)Cc1ccccc1-2]

where * marks the C atom that is bonded to the remainder of the formula (1);
L is selected from one of the divalent linkers L-1 to L-26,

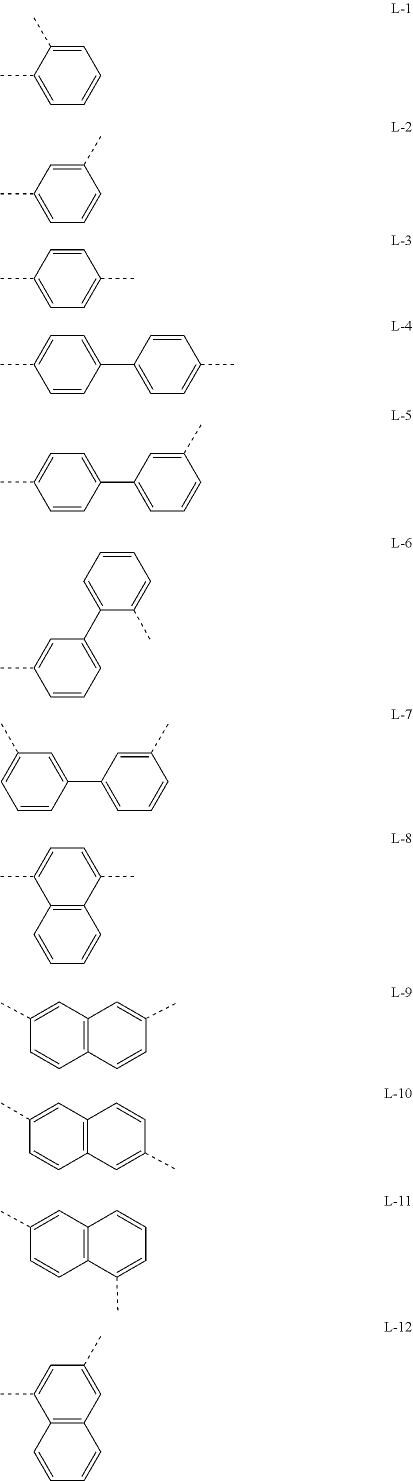

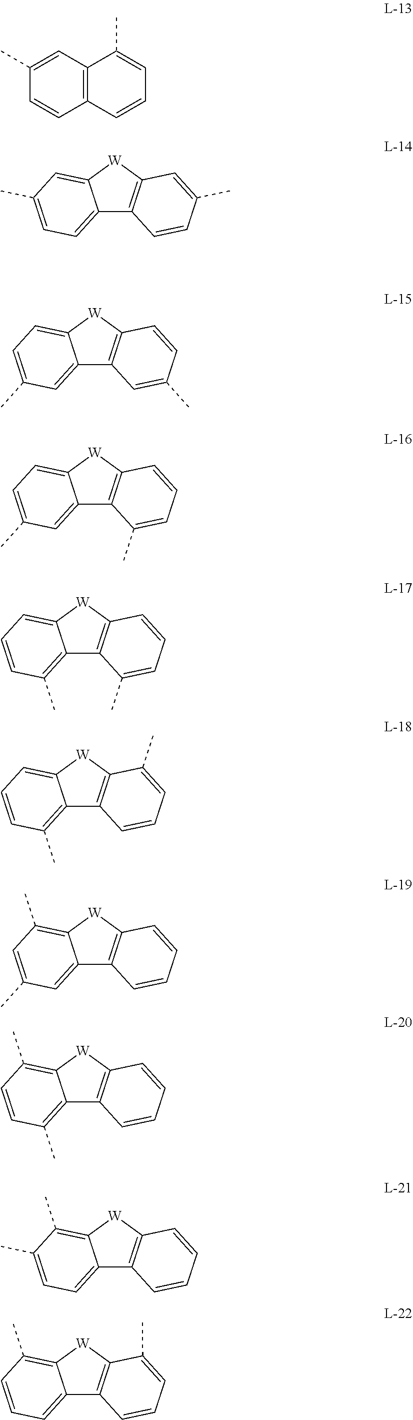

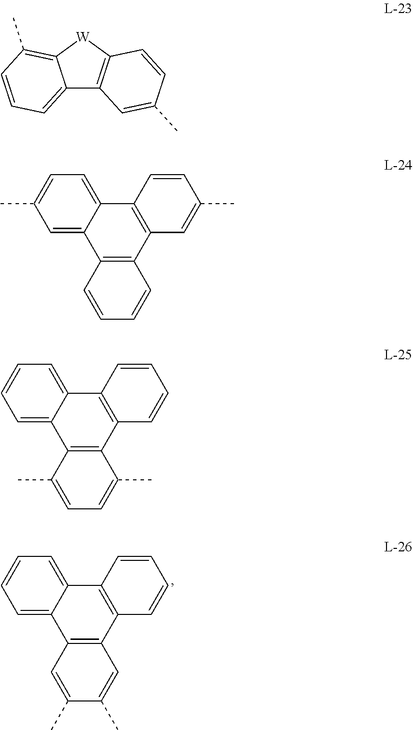

where the linkers L-1 to L-26 may also be substituted by one or more substituents R;
W is O, S or C(CH₃)₂; preferably O or S;
a is 0 or 1;
b is 0 or 1;
R is selected on each occurrence, identically or differently, from the group consisting of CN, a straight-chain alkyl, alkoxy or thioalkyl group having 1 to 20 C atoms or a branched or cyclic alkyl, alkoxy or thioalkyl group having 3 to 20 C atoms, an aromatic or heteroaromatic ring system having 5 to 40 aromatic ring atoms, an aryloxy or heteroaryloxy group having 5 to 40 aromatic ring atoms, or an aralkyl or heteroaralkyl group having 5 to 40 aromatic ring atoms;
Ar₁ is on each occurrence, in each case independently of one another, an aryl or heteroaryl group having 5 to 40 aromatic ring atoms, which may be substituted by one or more radicals R;
K, M are in each case, independently of one another, an aromatic ring system having 6 to 40 aromatic ring atoms, which is unsubstituted or partially or fully deuterated or monosubstituted by R*, if x and y denote 0 and if x₁ and y1 denote 0, or
K, M in each case, independently of one another, together with X or X¹, form a heteroaromatic ring systems having 14 to 40 ring atoms as soon as the value of x, x1, y and/or y1 denotes 1;
x, x1 are in each case, independently on each occurrence, 0 or 1;
y, y1 are in each case, independently on each occurrence, 0 or 1;
X and X¹ are in each case, independently of one another on each occurrence, a bond or C(R#)₂;
R⁰ is on each occurrence, independently of one another, an unsubstituted or partially or fully deuterated aromatic ring system having 6 to 18 C atoms;
R* is dibenzofuranyl or dibenzothiophenyl;
R# is on each occurrence, independently of one another, a straight-chain or branched alkyl group having 1 to 4 C atoms and
c, d, e and f are, independently of one another, 0 or 1.

The invention furthermore encompasses a process for the production of the organic electroluminescent devices and mixtures comprising at least one compound of the formula (1) and at least one compound of the formula (2), specific material combinations, and formulations which comprise mixtures or material combinations of this type. The present invention likewise relates to the corresponding preferred embodiments, as described below. The surprising and advantageous effects are achieved by specific selection of the compounds of the formula (1) and the compounds of the formula (2).

The organic electroluminescent device according to the invention is, for example, an organic light-emitting transistor (OLET), an organic field-quench device (OFQD), an organic light-emitting electrochemical cell (OLEC, LEC, LEEC), an organic laser diode (0-laser) or an organic light-emitting diode (OLED). The organic electroluminescent device according to the invention is, in particular, an organic light-emitting diode or an organic light-emitting electrochemical cell. The device according to the invention is particularly preferably an OLED.

The organic layer of the device according to the invention which comprises the light-emitting layer comprising the material combination of at least one compound of the formula (1) and at least one compound of the formula (2), as described above or described below, preferably comprises, besides this light-emitting layer (EML), a hole-injection layer (HIL), a hole-transport layer (HTL), an electron-transport layer (ETL), an electron-injection layer (EIL) and/or a hole-blocking layer (HBL). The device according to the invention may also comprise a plurality of layers from this group selected from EML, HIL, HTL, ETL, EIL and HBL.

However, the device may also comprise inorganic materials or also layers built up entirely from inorganic materials.

It is preferred for the light-emitting layer comprising at least one compound of the formula (1) and at least one compound of the formula (2) to be a phosphorescent layer which is characterised in that, in addition to the host-material combination of compounds of the formula (1) and formula (2), as described above, it comprises at least one phosphorescent emitter. A suitable choice of emitters and preferred emitters are described below.

An aryl group in the sense of this invention contains 6 to 40 aromatic ring atoms, preferably C atoms. A heteroaryl group in the sense of this invention contains 5 to 40 aromatic ring atoms, where the ring atoms include C atoms and at least one heteroatom, with the proviso that the sum of C atoms and heteroatoms is at least 5. The heteroatoms are preferably selected from N, O and/or S. An aryl group or heteroaryl group here is taken to mean either a simple aromatic ring, i.e. phenyl, derived from benzene, or a simple heteroaromatic ring, for example derived from pyridine, pyrimidine or thiophene, or a condensed aryl or heteroaryl group, for example derived from naphthalene, anthracene, phenanthrene, quinoline or isoquinoline. An aryl group having 6 to 18 C atoms is therefore preferably phenyl, naphthyl, phenanthryl or triphenylenyl, where the bonding of the aryl group as substituent is not restricted. The aryl or heteroaryl group in the sense of this invention may carry one or more radicals R, where the substituent R is described below.

An aromatic ring system in the sense of this invention contains 6 to 40 C atoms in the ring system. The aromatic ring system also includes aryl groups, as described above.

An aromatic ring system having 6 to 18 C atoms is preferably selected from phenyl, biphenyl, naphthyl, phenanthryl and triphenylenyl.

A heteroaromatic ring system in the sense of this invention contains 5 to 40 ring atoms and at least one heteroatom. A preferred heteroaromatic ring system has 10 to 40 ring atoms and at least one heteroatom. The heteroaromatic ring system also includes heteroaryl groups, as described above. The heteroatoms in the heteroaromatic ring system are preferably selected from N, O and/or S.

For the purposes of this invention, an aromatic or heteroaromatic ring system is taken to mean a system which does not necessarily contain only aryl or heteroaryl groups, but in which, in addition, several aryl or heteroaryl groups may be interrupted by a non-aromatic unit (preferably less than 10% of the atoms other than H), such as, for example, a C, N or O atom or a carbonyl group. Thus, for example, systems such as 9,9′-spirobifluorene, 9,9-diarylfluorene, triarylamine, diaryl ether, stilbene, etc. are intended to be taken to be aromatic or heteroaromatic ring systems in the sense of this invention, as are systems in which two or more aryl groups are interrupted, for example, by a linear or cyclic alkyl group or by a silyl group. Systems in which two or more aryl or heteroaryl groups are bonded directly to one another, such as, for example, biphenyl, terphenyl, quaterphenyl or bipyridine, are likewise covered by the definition of the aromatic or heteroaromatic ring system.

An aromatic or heteroaromatic ring system having 5-40 ring atoms, which may be linked via any desired positions on the aromatic or heteroaromatic rings, is taken to mean, for example, groups derived from benzene, naphthalene, anthracene, benzanthracene, phenanthrene, benzophenanthrene, pyrene, chrysene, perylene, fluoranthene, benzofluoranthene, naphthacene, pentacene, benzopyrene, biphenyl, biphenylene, terphenyl, terphenylene, fluorene, spirobifluorene, dihydrophenanthrene, dihydropyrene, tetrahydropyrene, cis- or trans-indenofluorene, cis- or trans-monobenzoindenofluorene, cis- or trans-dibenzoindenofluorene, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, indolocarbazole, indenocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

The abbreviation Ar₁ is on each occurrence, in each case independently of one another, an aryl or heteroaryl group having 5 to 40 aromatic ring atoms, which may be substituted by one or more radicals R, where the radical R has a meaning as described above or below.

A cyclic alkyl, alkoxy or thioalkyl group in the sense of this invention is taken to mean a monocyclic, bicyclic or polycyclic group.

For the purposes of the present invention, a straight-chain, branched or cyclic C₁- to C₂₀-alkyl group is taken to mean, for example, the radicals methyl, ethyl, n-propyl, i-propyl, cyclopropyl, n-butyl, i-butyl, s-butyl, t-butyl, cyclobutyl, 2-methylbutyl, n-pentyl, s-pentyl, t-pentyl, 2-pentyl, neopentyl, cyclopentyl, n-hexyl, s-hexyl, t-hexyl, 2-hexyl, 3-hexyl, neohexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2,2,2]octyl, 2-bicyclo[2,2,2]octyl, 2-(2,6-dimethyl)octyl, 3-(3,7-dimethyl)octyl, adamantyl, trifluoromethyl, pentafluoroethyl, 2,2,2-trifluoroethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyl-n-hexadec-1-yl, 1,1-diethyl-n-octadec-1-yl, 1-(n-propyl)cyclohex-1-yl, 1-(n-butyl)cyclohex-1-yl, 1-(n-hexyl)cyclohex-1-yl, 1-(n-octyl)cyclohex-1-yl- and 1-(n-decyl)cyclohex-1-yl.

A straight-chain or branched C₁- to C₂₀-alkoxy group is taken to mean, for example, methoxy, trifluoromethoxy, ethoxy, n-propoxy, i-propoxy, n-butoxy, i-butoxy, s-butoxy, t-butoxy or 2-methylbutoxy.

A straight-chain C₁- to C₂₀-thioalkyl group is taken to mean, for example, S-alkyl groups, for example thiomethyl, 1-thioethyl, 1-thio-i-propyl, 1-thio-n-propoyl, 1-thio-i-butyl, 1-thio-n-butyl or 1-thio-t-butyl.

An aryloxy or heteroaryloxy group having 5 to 40 aromatic ring atoms denotes O-aryl or O-heteroaryl and means that the aryl or heteroaryl group is bonded via an oxygen atom, where the aryl or heteroaryl group has a meaning as described above.

An aralkyl or heteroaralkyl group having 5 to 40 aromatic ring atoms means that an alkyl group, as described above, is substituted by an aryl group or heteroaryl group, where the aryl or heteroaryl group has a meaning as described above.

A phosphorescent emitter in the sense of the present invention is a compound which exhibits luminescence from an excited state having higher spin multiplicity, i.e. a spin state >1, in particular from an excited triplet state. For the purposes of this application, all luminescent complexes with transition metals or lanthanides are intended to be regarded as phosphorescent emitters. A more precise definition is given below.

If the host materials of the light-emitting layer comprising at least one compound of the formula (1), as described above or preferably described below, and at least one compound of the formula (2), as described above or described below, is employed for a phosphorescent emitter, it is preferred if its triplet energy is not significantly less than the triplet energy of the phosphorescent emitter. The following preferably applies to the triplet level: T₁(emitter)−T₁(matrix)≤0.2 eV, particularly preferably <0.15 eV, very particularly preferably <0.1 eV, where T₁(matrix) is the triplet level of the matrix material in the emission layer, where this condition applies to each of the two matrix materials, and T₁(emitter) is the triplet level of the phosphorescent emitter. If the emission layer contains more than two matrix materials, the above-mentioned relationship preferably also applies to each further matrix material.

Host material 1 and its preferred embodiments present in the device according to the invention are described below. The preferred embodiments of the host material 1 of the formula (1) also apply to the mixture and/or formulation according to the invention.

In compounds of the formula (1), Y is selected from O, S, C(CH₃)₂, C(phenyl)₂ or

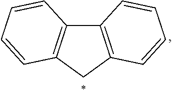 [SMILES: c1ccc2c(c1)Cc1ccccc1-2]

where*marks the C atom that is bonded to the remainder of the formula (1).
Y is preferably selected from O, S and C(CH₃)₂.
Y is particularly preferably selected from O and S.

In a very particularly preferred embodiment of the host material of the formula (1), Y stands for O.

Accordingly, the invention furthermore relates to the organic electroluminescent device, as described above, where Y in host material 1 stands for O.

In compounds of the formula (1), a stands for 0 or 1, preferably for 0.

In compounds of the formula (1), b stands for 0 or 1, preferably for 0.

R in compounds of the formula (1) is selected on each occurrence, identically or differently, from the group consisting of CN, a straight-chain alkyl, alkoxy or thioalkyl group having 1 to 20 C atoms or a branched or cyclic alkyl, alkoxy or thioalkyl group having 3 to 20 C atoms, an aromatic or heteroaromatic ring system having 5 to 40 aromatic ring atoms, an aryloxy or heteroaryloxy group having 5 to 40 aromatic ring atoms, or an aralkyl or heteroaralkyl group having 5 to 40 aromatic ring atoms. The substituent R preferably stands on each occurrence, independently of one another, for CN or an aryl group having 6 to 40 C atoms. R is on each occurrence, independently of one another, particularly preferably phenyl.

In compounds of the formula (1), as described or preferably described above, Ar₁ preferably stands on each occurrence, independently of one another, for an aryl group having 6 to 40 aromatic ring atoms, dibenzofuranyl or dibenzothiophenyl. In compounds of the formula (1), as described or preferably described above, Ar₁ in each case, independently of one another, particularly preferably stands for phenyl, triphenylenyl, biphenyl, fluorenyl, naphthyl or dibenzofuranyl, where the bonding to the remainder of the formula (1) can take place via any desired position of the aryl group, of the dibenzofuranyl or of the dibenzothiophenyl. For example, a dibenzofuran is preferably bonded to the remainder of the formula (1) via position 1, 3 or 7. A fluorene, for example, is preferably bonded to the remainder of the formula (1) via position 8. A preferred biphenyl is 1,3-biphenyl. Particularly preferably, at least one Ar₁ stands for phenyl and the other aromatic substituent Ar₁ stands for an aryl group having 6 to 40 aromatic ring atoms, dibenzofuranyl or dibenzothiophenyl. Very particularly preferably, both groups Ar₁ are identical. Very particularly preferably, both groups Ar₁ stand for phenyl. Preferably, both groups Ar₁ stand for dibenzofuranyl, where the bonding to the triazine is in each case independent.

In compounds of the formula (1), L is selected from the group of linkers L-1 to L-26, where linkers L-1 to L-26 may also be substituted by one or more substituents R. Linkers L-1 to L-26 are preferably unsubstituted or carry one substituent R. Linkers L-1 to L-26 are particularly preferably unsubstituted.

The substituent R in linkers L-1 to L-26 is selected on each occurrence, identically or differently, from the group consisting of CN, a straight-chain alkyl, alkoxy or thioalkyl group having 1 to 20 C atoms or a branched or cyclic alkyl, alkoxy or thioalkyl group having 3 to 20 C atoms, an aromatic or heteroaromatic ring system having 5 to 40 aromatic ring atoms, an aryloxy or heteroaryloxy group having 5 to 40 aromatic ring atoms, or an aralkyl or heteroaralkyl group having 5 to 40 aromatic ring atoms. In linkers L-1 to L-26, the substituent R preferably stands on each occurrence, independently of one another, for CN or an aryl group having 6 to 40 C atoms. In linkers L-1 to L-26, the substituent R particularly preferably stands on each occurrence, independently of one another, for CN or phenyl.

Host materials of the formula (1) with linkers L-1 to L-26, as described or preferably described above, are preferably combined with host materials of the formula (2) in which at least one value x, x1, y or y1 denotes 1, preferably represented by compounds of the formula (2b) or (2c), as described below. Host materials of the formula (1) with linkers L-1 to L-26, as described or preferably described above, are preferably combined with host materials of the formula (2) in which precisely one value x, x1, y or y1 denotes 1, preferably represented by compounds of the formula (2b), as described below.

Host materials of the formula (1) with linkers L-14 to L-23, as described above, where W denotes O, S or C(CH₃)₂ and where W is preferably O or S, are preferably combined with host materials of the formula (2) in which at least one value x, x1, y or y1 denotes 1, preferably represented by compounds of the formula (2b) or (2c), as described below. Host materials of the formula (1) with linkers L-14 to L-23, as described or preferably described above, are preferably combined with host materials of the formula (2) in which precisely one value x, x1, y or y1 denotes 1, preferably represented by compounds of the formula (2b), as described below.

In compounds of the formula (1), as described or preferably described above, L is preferably selected from linkers L-1 to L-13 and L-24 to L-26, as described above.

Host materials of the formula (1) with linkers L-1 to L-13 and L-24 to L-26 are preferably combined with host materials of the formula (2), as described below, in which x and x1 on each occurrence independently denote 0 or 1 and y and y1 on each occurrence independently denote 0 or 1, preferably represented by compounds of the formula (2a), (2b) or (2c), as described below.

It is furthermore preferred if the linker L in the host materials of the formula (1) is selected from linkers L-2, L-3, L-4, L-24, L-25 and L-26.

In compounds of the formula (1), as described or preferably described above, L is, in an alternative embodiment, preferably selected from linkers L-2, L-3, L-4, L-16, L-18, L-20, L-24, L-25 and L-26, as described above, where W denotes O, S or C(CH₃)₂ and where W is preferably O or S.

Accordingly, the invention furthermore relates to an organic electroluminescent device, as described or preferably described above, where the linker L in host material 1 is selected from linkers L-1 to L-13 and L-24 to L-26.

Accordingly, the invention furthermore relates to an organic electroluminescent device, as described or preferably described above, where the linker L in host material 1 is selected from linkers L-2, L-3, L-4, L-16, L-18, L-20, L-24, L-25 and L-26 and W denotes O, S or C(CH₃)₂. W is preferably O or S.

Examples of suitable host materials of the formula (1) which are selected in accordance with the invention, and are preferably used in combination with at least one compound of the formula (2) in the electroluminescent device according to the invention, are the structures given below in Table 1.

TABLE 1

| | |
|---|---|
| 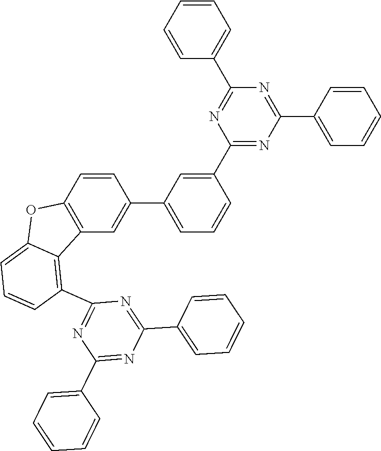 [SMILES: c1ccc(-c2nc(-c3ccccc3)nc(-c3cccc(-c4ccc5oc6cccc(-c7nc(-c8ccccc8)nc(-c8ccccc8)n7)c6c5c4)c3)n2)cc1] | 1 |
| 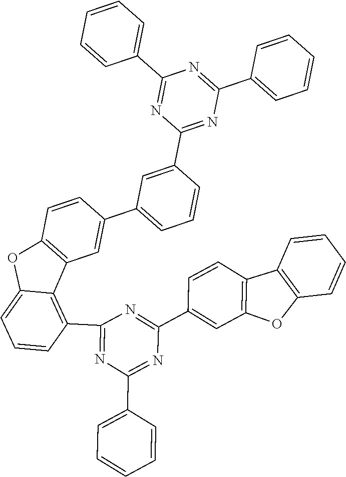 [SMILES: c1ccc(-c2nc(-c3ccccc3)nc(-c3cccc(-c4ccc5oc6cccc(-c7nc(-c8ccccc8)nc(-c8ccc9c(c8)oc8ccccc89)n7)c6c5c4)c3)n2)cc1] | 2 |
| 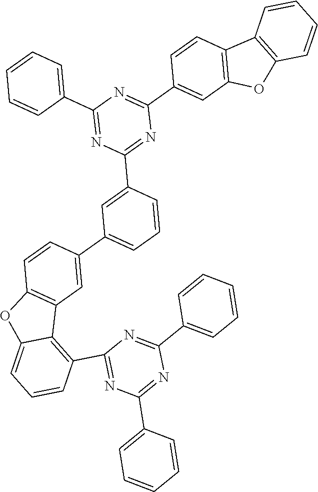 [SMILES: c1ccc(-c2nc(-c3cccc(-c4ccc5oc6cccc(-c7nc(-c8ccccc8)nc(-c8ccccc8)n7)c6c5c4)c3)nc(-c3ccc4c(c3)oc3ccccc34)n2)cc1] | 3 |
| 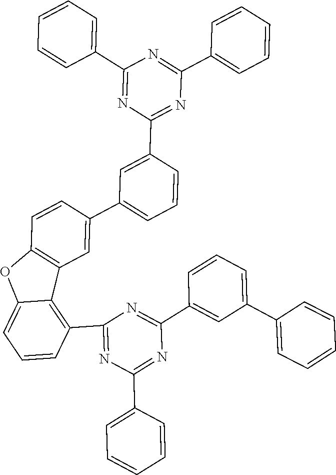 [SMILES: c1ccc(-c2cccc(-c3nc(-c4ccccc4)nc(-c4cccc5oc6ccc(-c7cccc(-c8nc(-c9ccccc9)nc(-c9ccccc9)n8)c7)cc6c45)n3)c2)cc1] | |
| 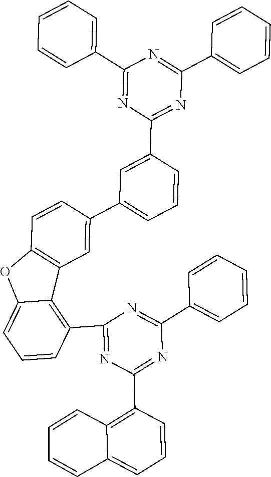 [SMILES: c1ccc(-c2nc(-c3ccccc3)nc(-c3cccc(-c4ccc5oc6cccc(-c7nc(-c8ccccc8)nc(-c8cccc9ccccc89)n7)c6c5c4)c3)n2)cc1] | |
| 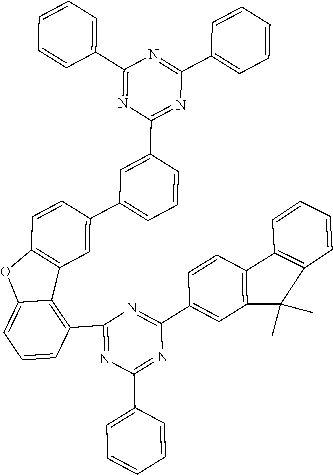 [SMILES: CC1(C)c2ccccc2-c2ccc(-c3nc(-c4ccccc4)nc(-c4cccc5oc6ccc(-c7cccc(-c8nc(-c9ccccc9)nc(-c9ccccc9)n8)c7)cc6c45)n3)cc21] | |
| 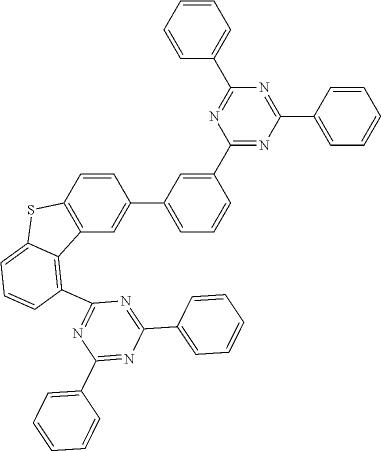 [SMILES: c1ccc(-c2nc(-c3ccccc3)nc(-c3cccc(-c4ccc5sc6cccc(-c7nc(-c8ccccc8)nc(-c8ccccc8)n7)c6c5c4)c3)n2)cc1] | 4 |
| 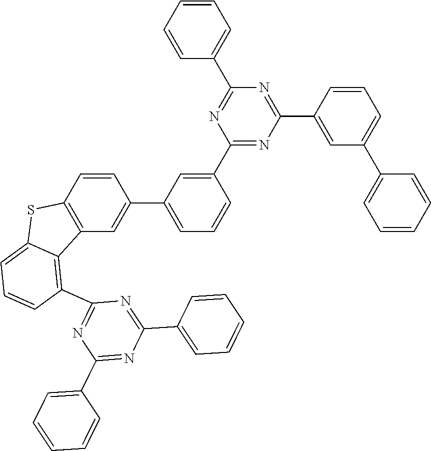 [SMILES: c1ccc(-c2cccc(-c3nc(-c4ccccc4)nc(-c4cccc(-c5ccc6sc7cccc(-c8nc(-c9ccccc9)nc(-c9ccccc9)n8)c7c6c5)c4)n3)c2)cc1] | |
| 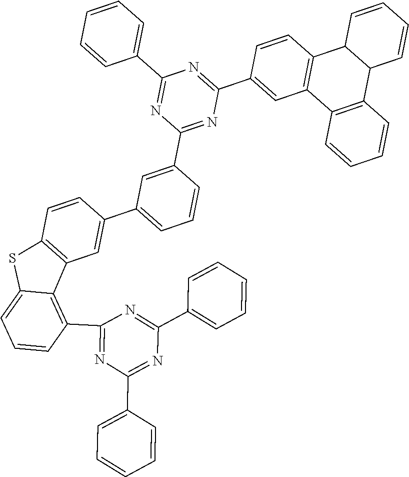 [SMILES: C1=CC2c3ccccc3-c3cc(-c4nc(-c5ccccc5)nc(-c5cccc(-c6ccc7sc8cccc(-c9nc(-c%10ccccc%10)nc(-c%10ccccc%10)n9)c8c7c6)c5)n4)ccc3C2C=C1] | |
| 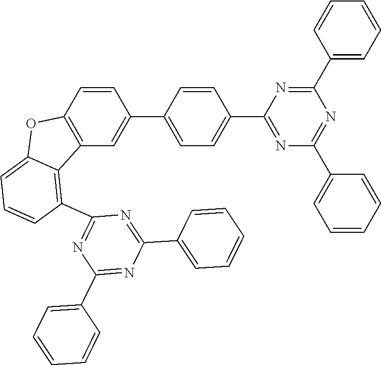 [SMILES: c1ccc(-c2nc(-c3ccccc3)nc(-c3ccc(-c4ccc5oc6cccc(-c7nc(-c8ccccc8)nc(-c8ccccc8)n7)c6c5c4)cc3)n2)cc1] | 5 |
| 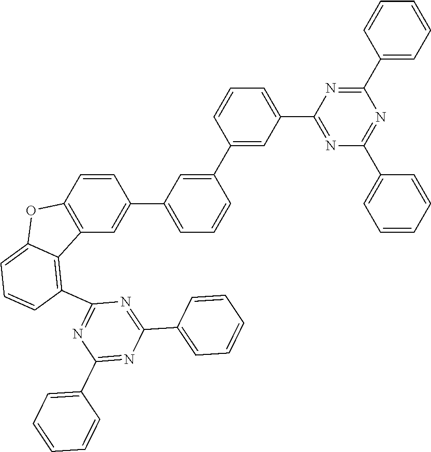 [SMILES: c1ccc(-c2nc(-c3ccccc3)nc(-c3cccc(-c4cccc(-c5ccc6oc7cccc(-c8nc(-c9ccccc9)nc(-c9ccccc9)n8)c7c6c5)c4)c3)n2)cc1] | 6 |
| 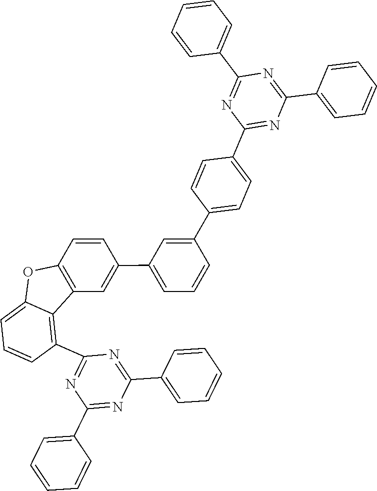 [SMILES: c1ccc(-c2nc(-c3ccccc3)nc(-c3ccc(-c4cccc(-c5ccc6oc7cccc(-c8nc(-c9ccccc9)nc(-c9ccccc9)n8)c7c6c5)c4)cc3)n2)cc1] | |
| 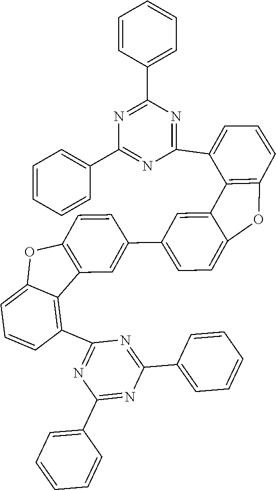 [SMILES: c1ccc(-c2nc(-c3ccccc3)nc(-c3cccc4oc5ccc(-c6ccc7oc8cccc(-c9nc(-c%10ccccc%10)nc(-c%10ccccc%10)n9)c8c7c6)cc5c34)n2)cc1] | 7 |
| 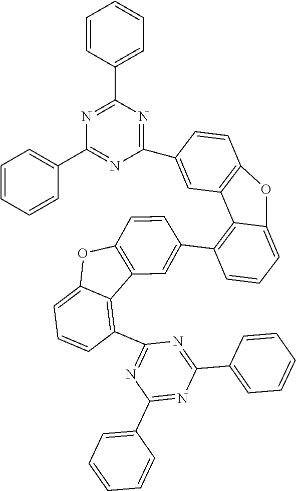 [SMILES: c1ccc(-c2nc(-c3ccccc3)nc(-c3ccc4oc5cccc(-c6ccc7oc8cccc(-c9nc(-c%10ccccc%10)nc(-c%10ccccc%10)n9)c8c7c6)c5c4c3)n2)cc1] | |
| 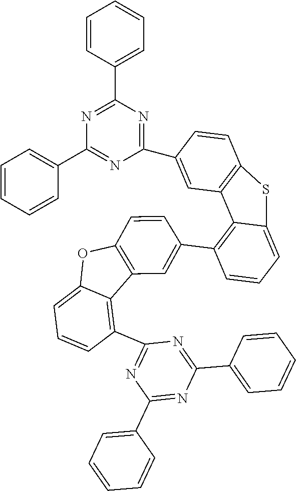 [SMILES: c1ccc(-c2nc(-c3ccccc3)nc(-c3ccc4sc5cccc(-c6ccc7oc8cccc(-c9nc(-c%10ccccc%10)nc(-c%10ccccc%10)n9)c8c7c6)c5c4c3)n2)cc1] | 8 |
| 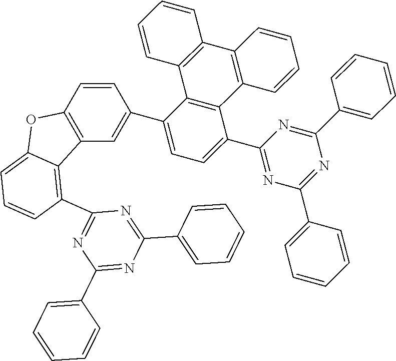 [SMILES: c1ccc(-c2nc(-c3ccccc3)nc(-c3cccc4oc5ccc(-c6ccc(-c7nc(-c8ccccc8)nc(-c8ccccc8)n7)c7c8ccccc8c8ccccc8c67)cc5c34)n2)cc1] | |
| 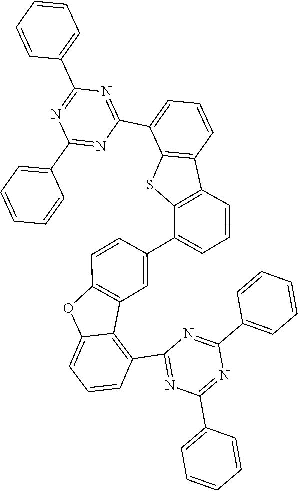 [SMILES: c1ccc(-c2nc(-c3ccccc3)nc(-c3cccc4c3sc3c(-c5ccc6oc7cccc(-c8nc(-c9ccccc9)nc(-c9ccccc9)n8)c7c6c5)cccc34)n2)cc1] | |
| 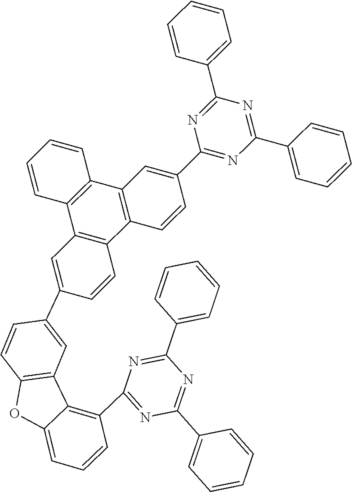 [SMILES: c1ccc(-c2nc(-c3ccccc3)nc(-c3ccc4c5ccc(-c6ccc7oc8cccc(-c9nc(-c%10ccccc%10)nc(-c%10ccccc%10)n9)c8c7c6)cc5c5ccccc5c4c3)n2)cc1] | |
| 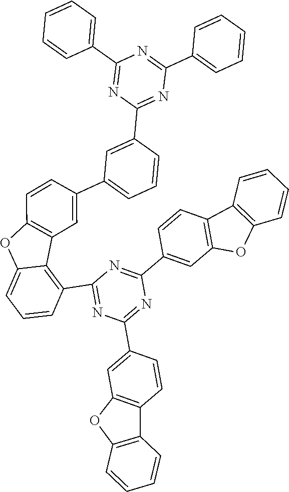 [SMILES: c1ccc(-c2nc(-c3ccccc3)nc(-c3cccc(-c4ccc5oc6cccc(-c7nc(-c8ccc9c(c8)oc8ccccc89)nc(-c8ccc9c(c8)oc8ccccc89)n7)c6c5c4)c3)n2)cc1] | 9 |
| 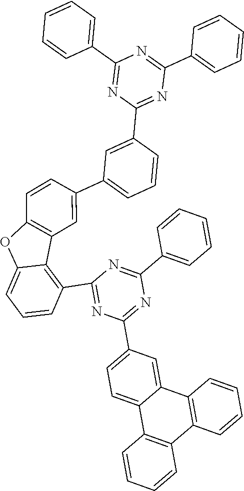 [SMILES: c1ccc(-c2nc(-c3ccccc3)nc(-c3cccc(-c4ccc5oc6cccc(-c7nc(-c8ccccc8)nc(-c8ccc9c%10ccccc%10c%10ccccc%10c9c8)n7)c6c5c4)c3)n2)cc1] | |
| 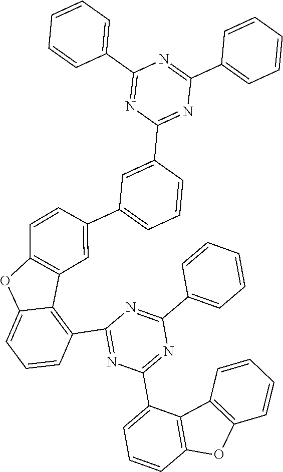 [SMILES: c1ccc(-c2nc(-c3ccccc3)nc(-c3cccc(-c4ccc5oc6cccc(-c7nc(-c8ccccc8)nc(-c8cccc9oc%10ccccc%10c89)n7)c6c5c4)c3)n2)cc1] | |
| 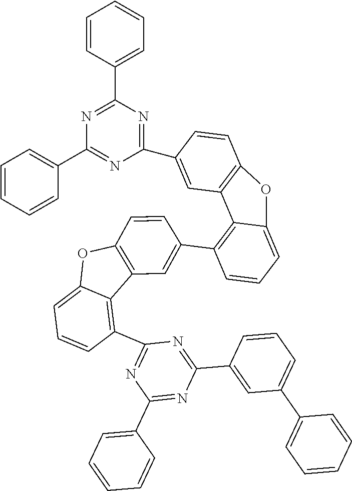 [SMILES: c1ccc(-c2cccc(-c3nc(-c4ccccc4)nc(-c4cccc5oc6ccc(-c7cccc8oc9ccc(-c%10nc(-c%11ccccc%11)nc(-c%11ccccc%11)n%10)cc9c78)cc6c45)n3)c2)cc1] | |
| 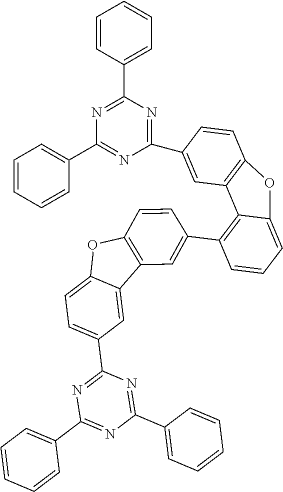 [SMILES: c1ccc(-c2nc(-c3ccccc3)nc(-c3ccc4oc5ccc(-c6cccc7oc8ccc(-c9nc(-c%10ccccc%10)nc(-c%10ccccc%10)n9)cc8c67)cc5c4c3)n2)cc1] | |
| 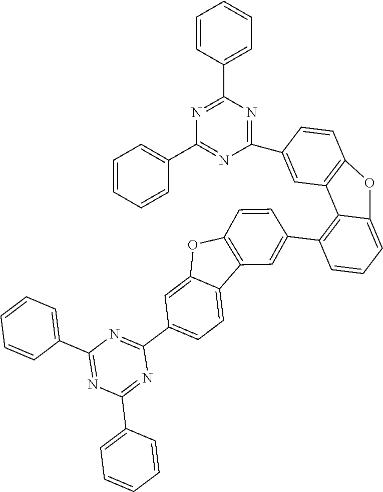 [SMILES: c1ccc(-c2nc(-c3ccccc3)nc(-c3ccc4c(c3)oc3ccc(-c5cccc6oc7ccc(-c8nc(-c9ccccc9)nc(-c9ccccc9)n8)cc7c56)cc34)n2)cc1] | |
| 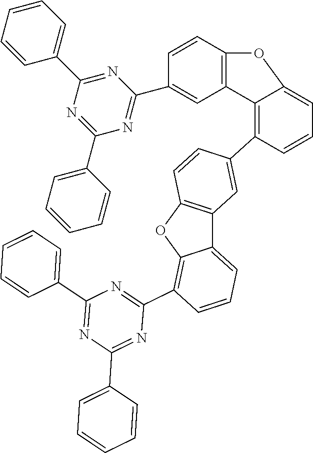 [SMILES: c1ccc(-c2nc(-c3ccccc3)nc(-c3ccc4oc5cccc(-c6ccc7oc8c(-c9nc(-c%10ccccc%10)nc(-c%10ccccc%10)n9)cccc8c7c6)c5c4c3)n2)cc1] | |
| 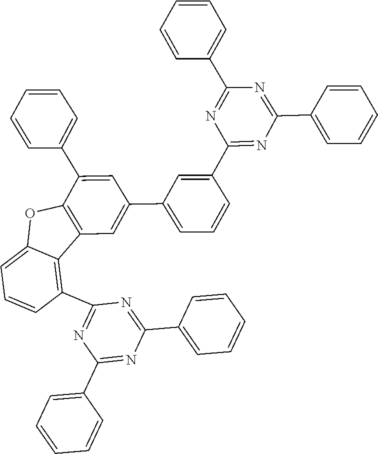 [SMILES: c1ccc(-c2nc(-c3ccccc3)nc(-c3cccc(-c4cc(-c5ccccc5)c5oc6cccc(-c7nc(-c8ccccc8)nc(-c8ccccc8)n7)c6c5c4)c3)n2)cc1] | |
| 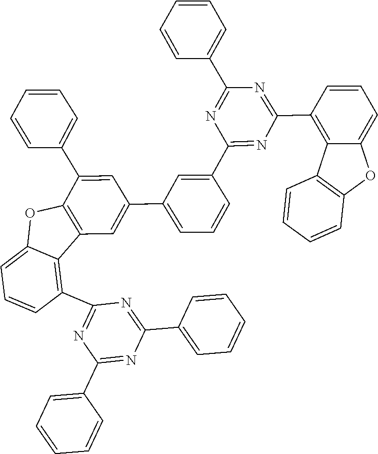 [SMILES: c1ccc(-c2nc(-c3cccc(-c4cc(-c5ccccc5)c5oc6cccc(-c7nc(-c8ccccc8)nc(-c8ccccc8)n7)c6c5c4)c3)nc(-c3cccc4oc5ccccc5c34)n2)cc1] | |
| 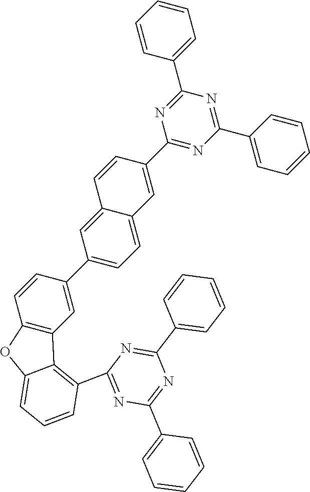 [SMILES: c1ccc(-c2nc(-c3ccccc3)nc(-c3ccc4cc(-c5ccc6oc7cccc(-c8nc(-c9ccccc9)nc(-c9ccccc9)n8)c7c6c5)ccc4c3)n2)cc1] | |
| 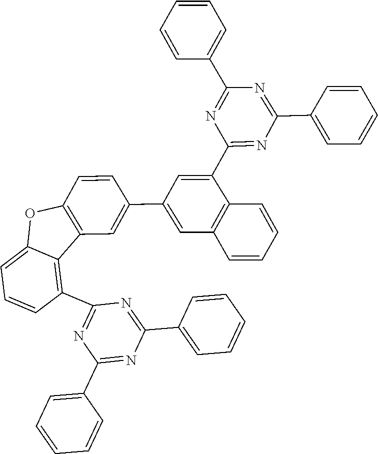 [SMILES: c1ccc(-c2nc(-c3ccccc3)nc(-c3cc(-c4ccc5oc6cccc(-c7nc(-c8ccccc8)nc(-c8ccccc8)n7)c6c5c4)cc4ccccc34)n2)cc1] | |
| 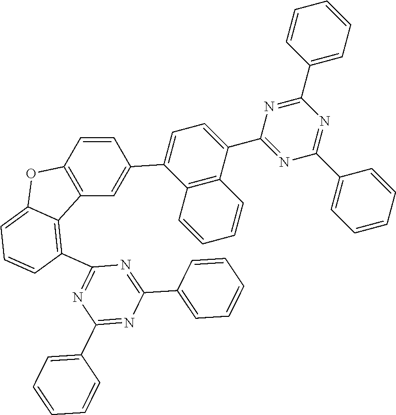 [SMILES: c1ccc(-c2nc(-c3ccccc3)nc(-c3ccc(-c4ccc5oc6cccc(-c7nc(-c8ccccc8)nc(-c8ccccc8)n7)c6c5c4)c4ccccc34)n2)cc1] | |
| 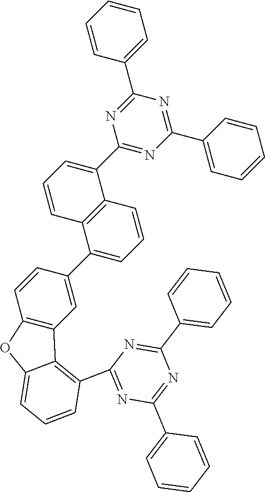 [SMILES: c1ccc(-c2nc(-c3ccccc3)nc(-c3cccc4c(-c5ccc6oc7cccc(-c8nc(-c9ccccc9)nc(-c9ccccc9)n8)c7c6c5)cccc34)n2)cc1] | |
| 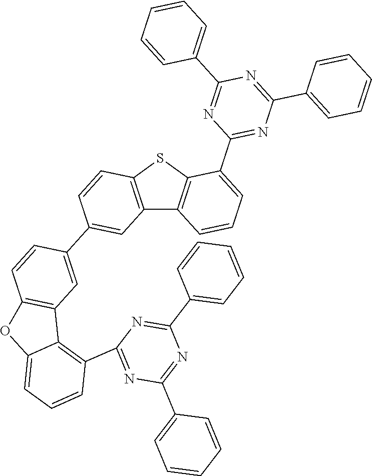 [SMILES: c1ccc(-c2nc(-c3ccccc3)nc(-c3cccc4c3sc3ccc(-c5ccc6oc7cccc(-c8nc(-c9ccccc9)nc(-c9ccccc9)n8)c7c6c5)cc34)n2)cc1] | |
| 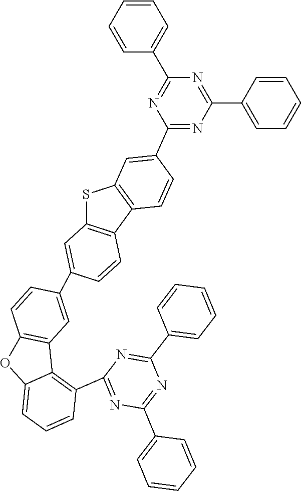 [SMILES: c1ccc(-c2nc(-c3ccccc3)nc(-c3ccc4c(c3)sc3cc(-c5ccc6oc7cccc(-c8nc(-c9ccccc9)nc(-c9ccccc9)n8)c7c6c5)ccc34)n2)cc1] | |
| 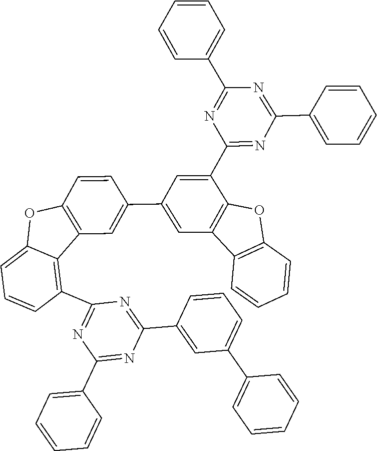 [SMILES: c1ccc(-c2cccc(-c3nc(-c4ccccc4)nc(-c4cccc5oc6ccc(-c7cc(-c8nc(-c9ccccc9)nc(-c9ccccc9)n8)c8oc9ccccc9c8c7)cc6c45)n3)c2)cc1] | |
| 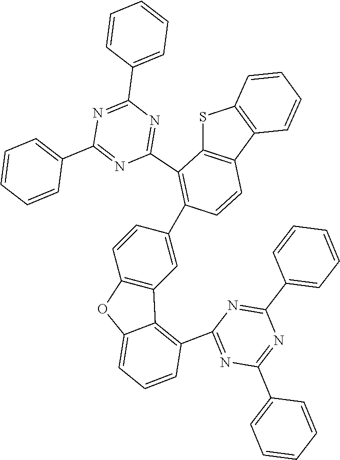 [SMILES: c1ccc(-c2nc(-c3ccccc3)nc(-c3c(-c4ccc5oc6cccc(-c7nc(-c8ccccc8)nc(-c8ccccc8)n7)c6c5c4)ccc4c3sc3ccccc34)n2)cc1] | |
| 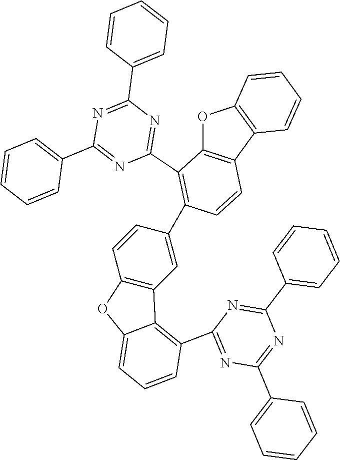 [SMILES: c1ccc(-c2nc(-c3ccccc3)nc(-c3c(-c4ccc5oc6cccc(-c7nc(-c8ccccc8)nc(-c8ccccc8)n7)c6c5c4)ccc4c3oc3ccccc34)n2)cc1] | |
| 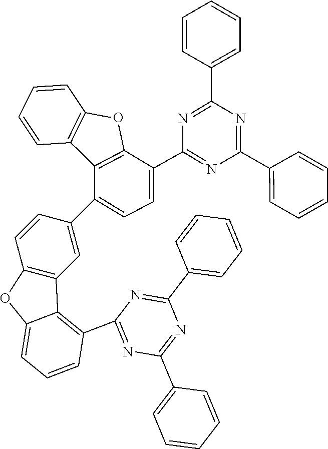 [SMILES: c1ccc(-c2nc(-c3ccccc3)nc(-c3ccc(-c4ccc5oc6cccc(-c7nc(-c8ccccc8)nc(-c8ccccc8)n7)c6c5c4)c4c3oc3ccccc34)n2)cc1] | |
| 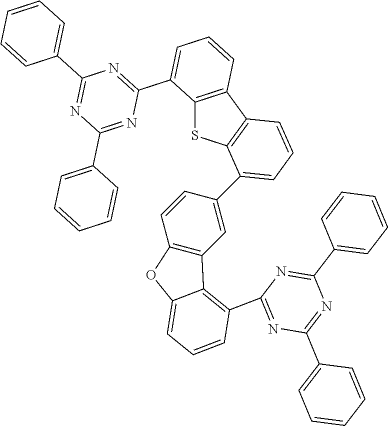 [SMILES: c1ccc(-c2nc(-c3ccccc3)nc(-c3cccc4c3sc3c(-c5ccc6oc7cccc(-c8nc(-c9ccccc9)nc(-c9ccccc9)n8)c7c6c5)cccc34)n2)cc1] | |
| 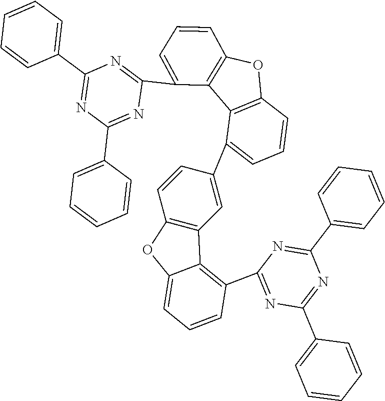 [SMILES: c1ccc(-c2nc(-c3ccccc3)nc(-c3cccc4oc5ccc(-c6cccc7oc8cccc(-c9nc(-c%10ccccc%10)nc(-c%10ccccc%10)n9)c8c67)cc5c34)n2)cc1] | |
| 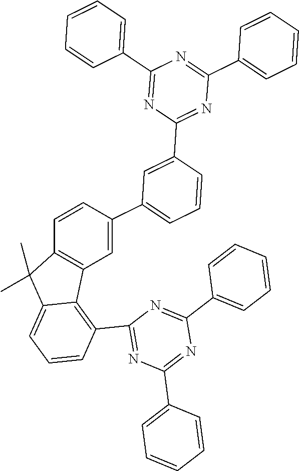 [SMILES: CC1(C)c2ccc(-c3cccc(-c4nc(-c5ccccc5)nc(-c5ccccc5)n4)c3)cc2-c2c(-c3nc(-c4ccccc4)nc(-c4ccccc4)n3)cccc21] | 10 |
| 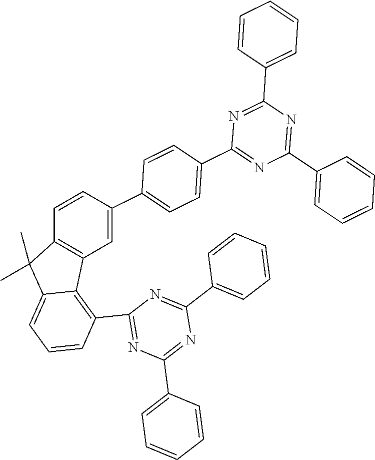 [SMILES: CC1(C)c2ccc(-c3ccc(-c4nc(-c5ccccc5)nc(-c5ccccc5)n4)cc3)cc2-c2c(-c3nc(-c4ccccc4)nc(-c4ccccc4)n3)cccc21] | |
| 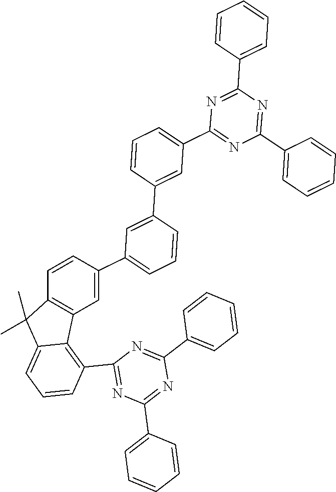 [SMILES: CC1(C)c2ccc(-c3cccc(-c4cccc(-c5nc(-c6ccccc6)nc(-c6ccccc6)n5)c4)c3)cc2-c2c(-c3nc(-c4ccccc4)nc(-c4ccccc4)n3)cccc21] | |
| 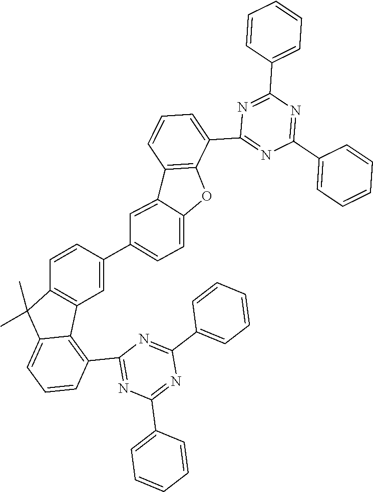 [SMILES: CC1(C)c2ccc(-c3ccc4oc5c(-c6nc(-c7ccccc7)nc(-c7ccccc7)n6)cccc5c4c3)cc2-c2c(-c3nc(-c4ccccc4)nc(-c4ccccc4)n3)cccc21] | |
| 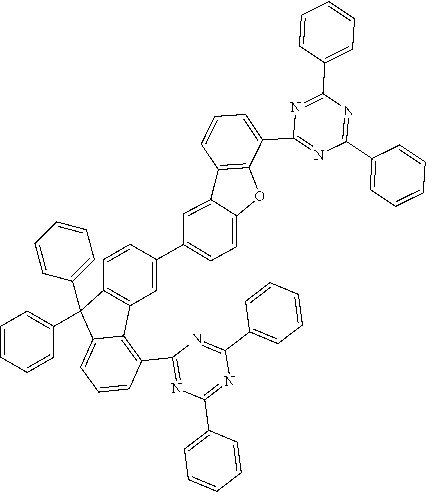 [SMILES: c1ccc(-c2nc(-c3ccccc3)nc(-c3cccc4c3-c3cc(-c5ccc6oc7c(-c8nc(-c9ccccc9)nc(-c9ccccc9)n8)cccc7c6c5)ccc3C4(c3ccccc3)c3ccccc3)n2)cc1] | |
| 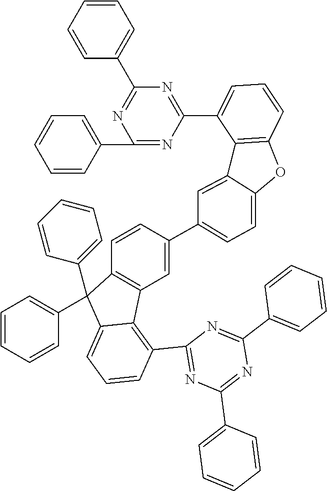 [SMILES: c1ccc(-c2nc(-c3ccccc3)nc(-c3cccc4c3-c3cc(-c5ccc6oc7cccc(-c8nc(-c9ccccc9)nc(-c9ccccc9)n8)c7c6c5)ccc3C4(c3ccccc3)c3ccccc3)n2)cc1] | |
| 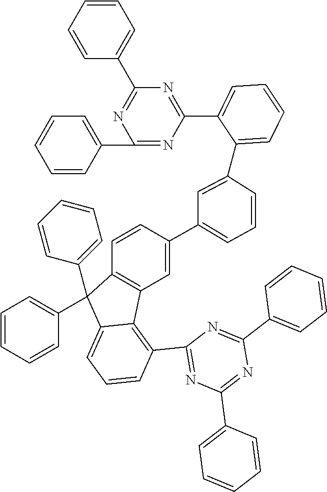 [SMILES: c1ccc(-c2nc(-c3ccccc3)nc(-c3ccccc3-c3cccc(-c4ccc5c(c4)-c4c(-c6nc(-c7ccccc7)nc(-c7ccccc7)n6)cccc4C5(c4ccccc4)c4ccccc4)c3)n2)cc1] | |
| 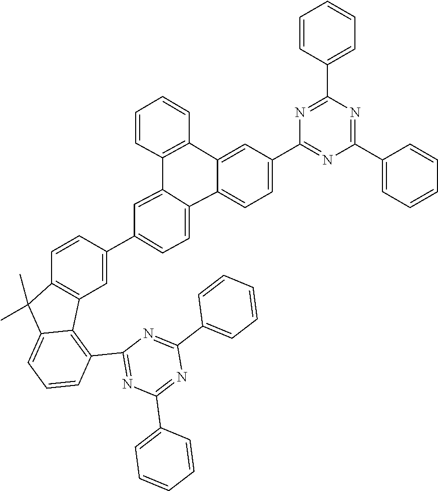 [SMILES: CC1(C)c2ccc(-c3ccc4c5ccc(-c6nc(-c7ccccc7)nc(-c7ccccc7)n6)cc5c5ccccc5c4c3)cc2-c2c(-c3nc(-c4ccccc4)nc(-c4ccccc4)n3)cccc21] | |
| 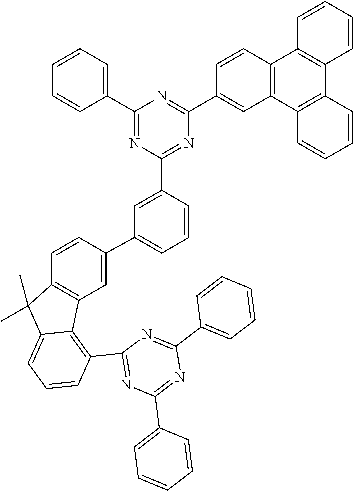 [SMILES: CC1(C)c2ccc(-c3cccc(-c4nc(-c5ccccc5)nc(-c5ccc6c7ccccc7c7ccccc7c6c5)n4)c3)cc2-c2c(-c3nc(-c4ccccc4)nc(-c4ccccc4)n3)cccc21] | |
| 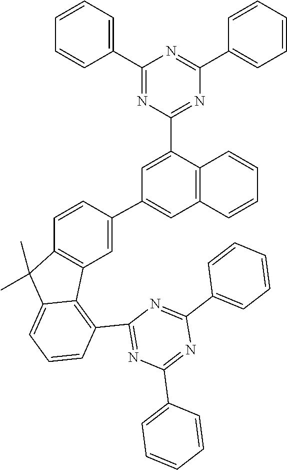 [SMILES: CC1(C)c2ccc(-c3cc(-c4nc(-c5ccccc5)nc(-c5ccccc5)n4)c4ccccc4c3)cc2-c2c(-c3nc(-c4ccccc4)nc(-c4ccccc4)n3)cccc21] | |
| 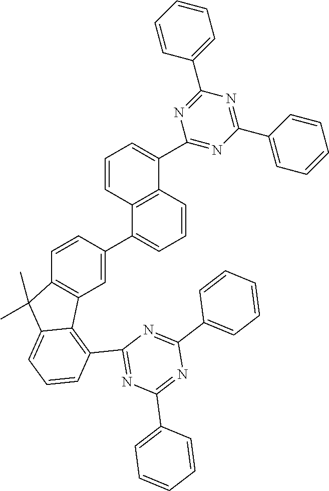 [SMILES: CC1(C)c2ccc(-c3cccc4c(-c5nc(-c6ccccc6)nc(-c6ccccc6)n5)cccc34)cc2-c2c(-c3nc(-c4ccccc4)nc(-c4ccccc4)n3)cccc21] | |
| 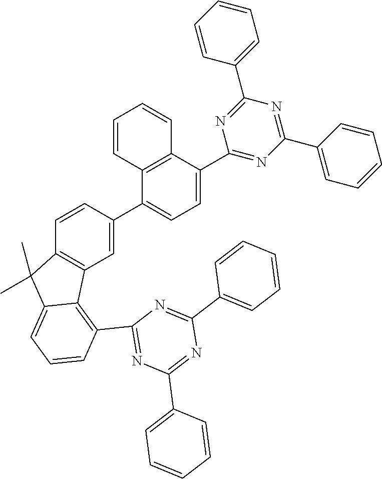 [SMILES: CC1(C)c2ccc(-c3ccc(-c4nc(-c5ccccc5)nc(-c5ccccc5)n4)c4ccccc34)cc2-c2c(-c3nc(-c4ccccc4)nc(-c4ccccc4)n3)cccc21] | |
| 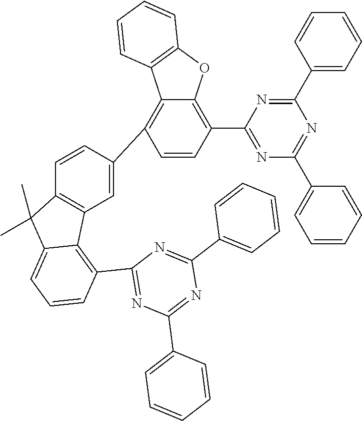 [SMILES: CC1(C)c2ccc(-c3ccc(-c4nc(-c5ccccc5)nc(-c5ccccc5)n4)c4oc5ccccc5c34)cc2-c2c(-c3nc(-c4ccccc4)nc(-c4ccccc4)n3)cccc21] | |
| 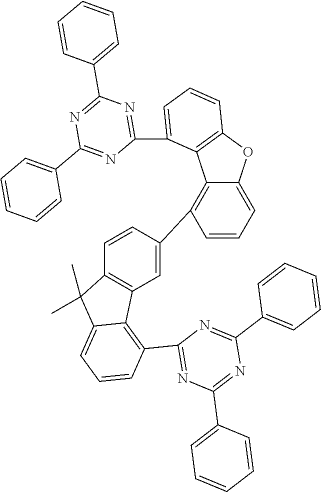 [SMILES: CC1(C)c2ccc(-c3cccc4oc5cccc(-c6nc(-c7ccccc7)nc(-c7ccccc7)n6)c5c34)cc2-c2c(-c3nc(-c4ccccc4)nc(-c4ccccc4)n3)cccc21] | |
| 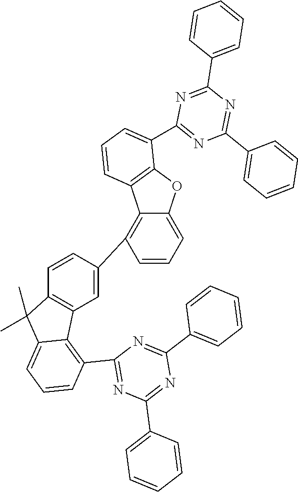 [SMILES: CC1(C)c2ccc(-c3cccc4oc5c(-c6nc(-c7ccccc7)nc(-c7ccccc7)n6)cccc5c34)cc2-c2c(-c3nc(-c4ccccc4)nc(-c4ccccc4)n3)cccc21] | |
| 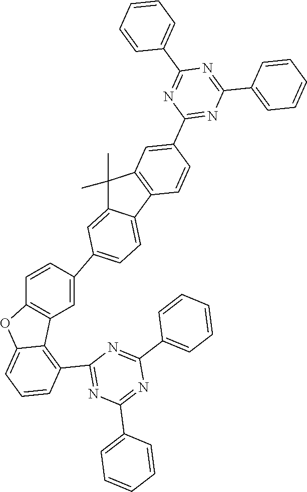 [SMILES: CC1(C)c2cc(-c3ccc4oc5cccc(-c6nc(-c7ccccc7)nc(-c7ccccc7)n6)c5c4c3)ccc2-c2ccc(-c3nc(-c4ccccc4)nc(-c4ccccc4)n3)cc21] | |
| 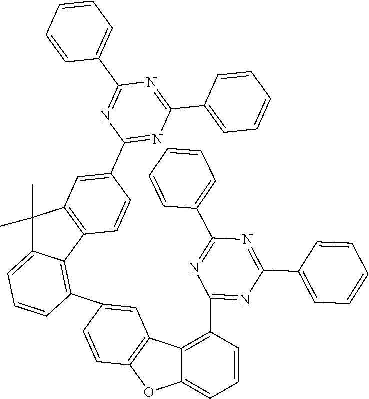 [SMILES: CC1(C)c2cc(-c3nc(-c4ccccc4)nc(-c4ccccc4)n3)ccc2-c2c(-c3ccc4oc5cccc(-c6nc(-c7ccccc7)nc(-c7ccccc7)n6)c5c4c3)cccc21] | |

Particularly suitable compounds of the formula (1), which are preferably used in combination with at least one compound of the formula (2) in the electroluminescent device according to the invention, are compounds 1 to 11 and 29 to 44:

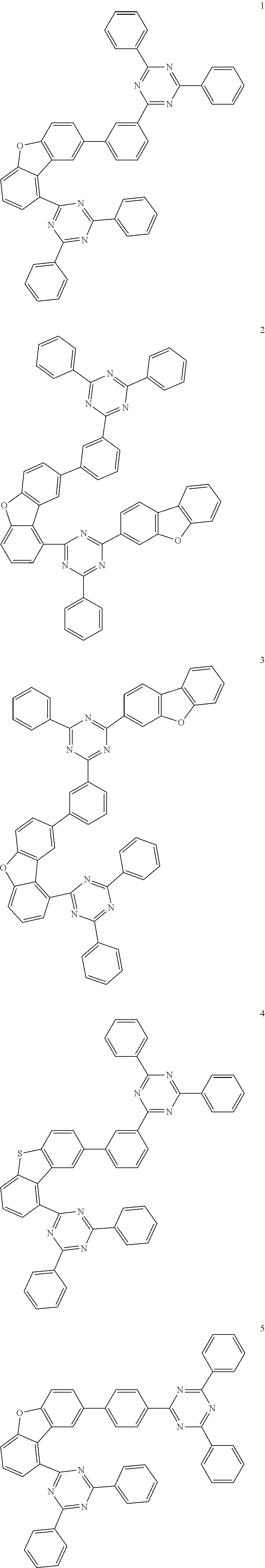

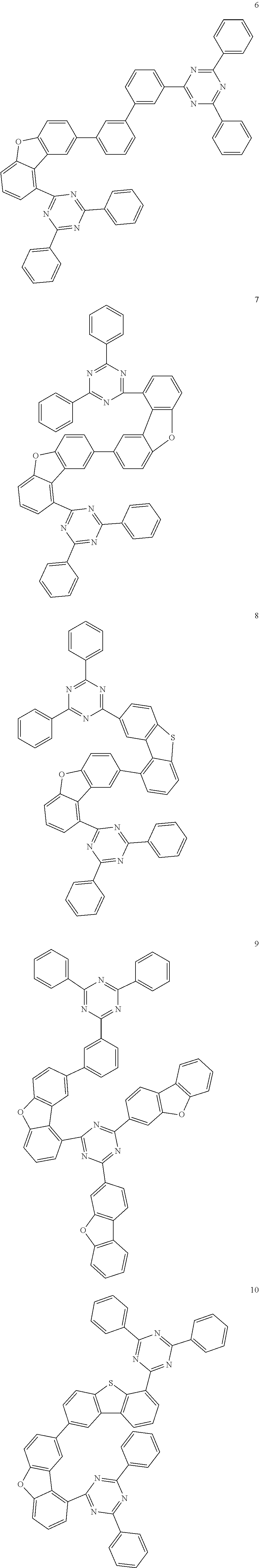

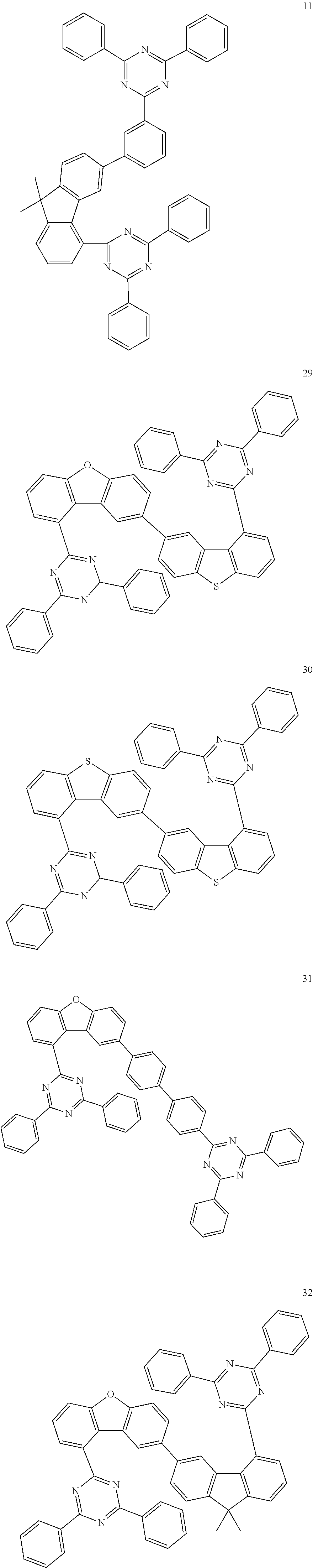

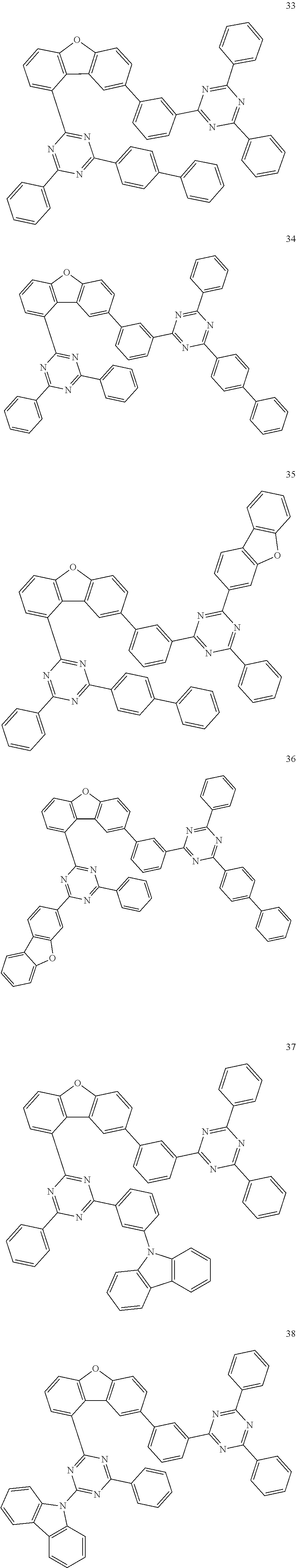

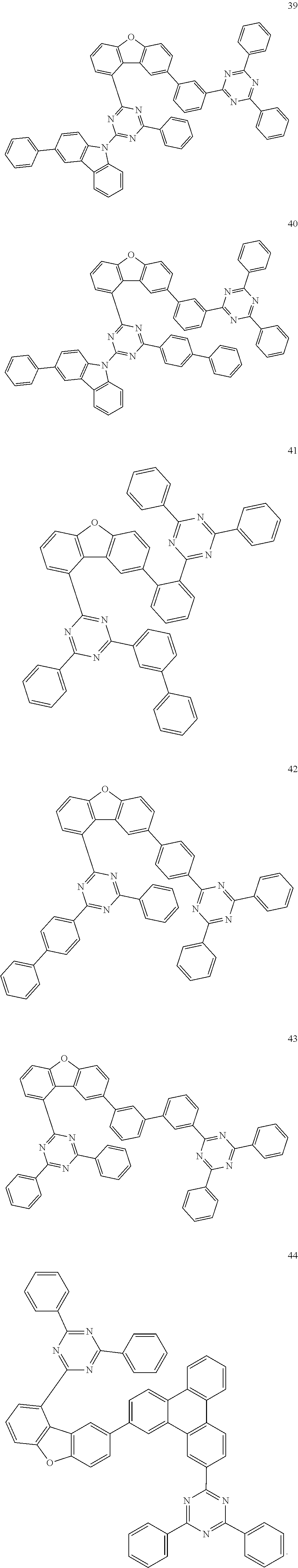

The preparation of the compounds of the formula (1) or the preferred compounds from Table 1 and of compounds 1 to 11 and 29 to 44 is known to the person skilled in the art. The compounds can be prepared by synthesis steps known to the person skilled in the art, such as, for example, halogenation, preferably bromination, and a subsequent organometallic coupling reaction, for example Suzuki coupling, Heck coupling or Hartwig-Buchwald coupling. The preparation of the compounds of the formula (1) or the preferred compounds from Table 1 and of compounds 1 to 11 and 29 to 44 can be derived, in particular, from WO2017178311, in particular page 46 and the synthesis examples on pages 81 to 106.

The preparation of the compounds of the formula (1) can be carried out in accordance with Scheme 1 below, where Y, R, a, b, Ar₁ and L have one of the meanings indicated or preferably indicated above.

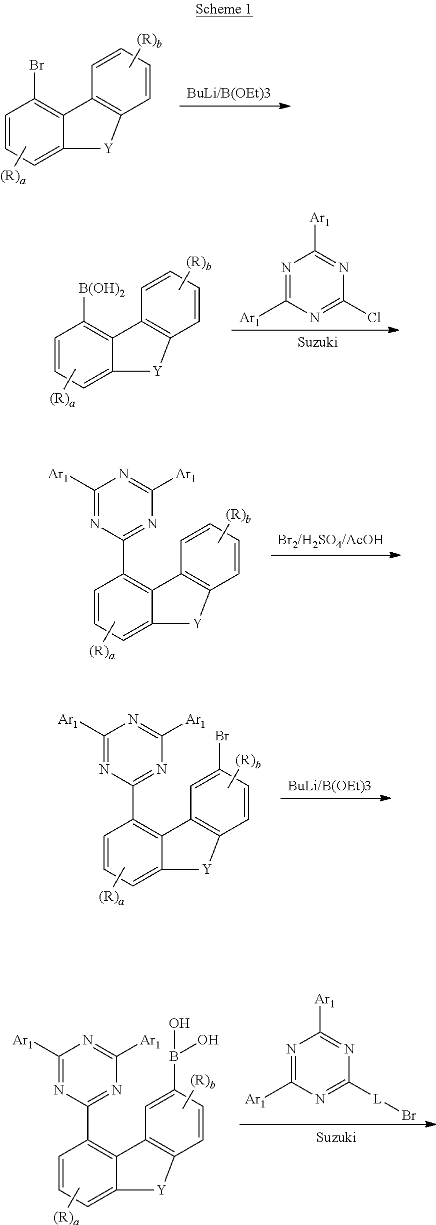

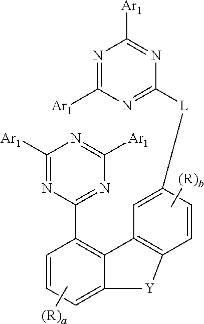

Host material 2 and its preferred embodiments present in the device according to the invention are described below. The preferred embodiments of host material 1 of the formula (1) also apply to the mixture and/or formulation according to the invention.

Host material 2 is at least one compound of the formula (2),

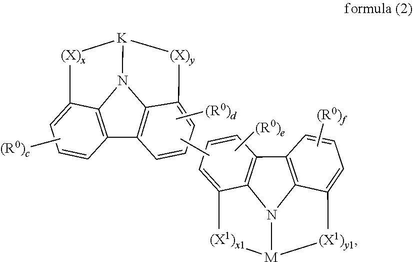

where the following applies to the symbols and indices used:
K, M are in each case, independently of one another, an aromatic ring system having 6 to 40 aromatic ring atoms which is unsubstituted or partially or fully deuterated or monosubstituted by R*, if x and y denote 0 and if x₁ and y₁ denote 0, or
K, M in each case, independently of one another, together with X or X¹, form a heteroaromatic ring system having 14 to 40 ring atoms as soon as the value of x, x1, y and/or y1 denotes 1;
x, x1 are in each case, independently on each occurrence, 0 or 1;
y, y1 are in each case, independently on each occurrence, 0 or 1;
X and X¹ are in each case, independently of one another on each occurrence, a bond or C(R#)₂;
R⁰ is on each occurrence, independently of one another, an unsubstituted or partially or fully deuterated aromatic ring system having 6 to 18 C atoms;
R# is on each occurrence, independently of one another, a straight-chain or branched alkyl group having 1 to 4 C atoms and
c, d, e and f are, independently of one another, 0 or 1.

In an embodiment of the invention, compounds of the formula (2) are selected, as described above, for the device according to the invention, which are used in the light-emitting layer with compounds of the formula (1), as described or preferably described above, or with the compounds from Table 1 or compounds 1 to 11 and 29 to 44.

In a preferred embodiment of the device according to the invention, compounds of the formula (2) in which x, y, x1 and y1 denote 0 are used as host material 2. Compounds of the formula (2) in which x, x1, y and y1 on each occurrence denote 0 can be represented by the following formula (2a),

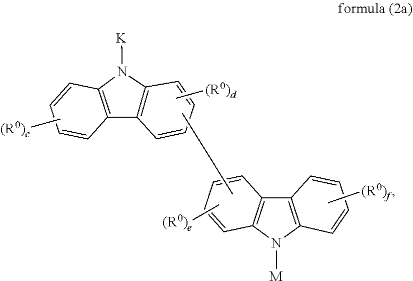

where R⁰, c, d, e and f have a meaning given above or given below and K and M in each case, independently of one another, denote an aromatic ring system having 6 to 40 aromatic ring atoms which is unsubstituted or partially or fully deuterated or monosubstituted by R*.

In preferred compounds of the formula (2a), the sum of the indices c+d+e+f is preferably 0 or 1 and R⁰ has a meaning preferably indicated above or below.

In compounds of the formula (2) or (2a), R⁰ is preferably on each occurrence, independently of one another, an unsubstituted aromatic ring system having 6 to 18 C atoms. R⁰ is preferably on each occurrence, independently of one another, phenyl, 1,3-biphenyl, 1,4-biphenyl, naphthyl or triphenylenyl. R⁰ is particularly preferably on each occurrence, independently of one another, phenyl.

In compounds of the formula (2) or (2a), the indices c, d, e and f are particularly preferably 0.

In compounds of the formula (2) or (2a), K and M are preferably on each occurrence, independently of one another, an aromatic ring system having 6 to 40 aromatic ring atoms which is unsubstituted or partially deuterated or monosubstituted by R*, as described above. K and M in compounds of the formula (2) or (2a) are particularly preferably on each occurrence, independently of one another, phenyl, dibenzofuran-substituted phenyl, dibenzothiophene-substituted phenyl, deuterated phenyl, 1,3-biphenyl, 1,4-biphenyl, terphenyl, partially deuterated terphenyl, quaterphenyl, naphthyl, fluorenyl, 9,9-diphenylfluorenyl, bispirofluorenyl or triphenylenyl.

Accordingly, the invention furthermore relates to an organic electroluminescent device, as described or preferably described above, where the at least one compound of the formula (2) corresponds to a compound of the formula (2a) or a preferred embodiment of the compound of the formula (2a).

In a preferred embodiment of the device according to the invention, compounds of the formula (2) in which x1 and y1 denote 0, x and y denote 0 or 1 and the sum of x and y denotes 1 or 2 are used as host material 2. Compounds of the formula (2) in which x1 and y1 denote 0, x and y denote 0 or 1 and the sum of x and y denotes 1 or 2 can be represented by the following formula (2b),

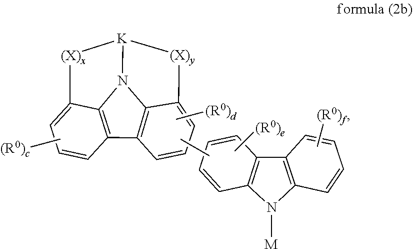

where X, x, y, R⁰, c, d, e and f have a meaning given above or given below, M is an aromatic ring system having 6 to 40 aromatic ring atoms which is unsubstituted or partially or fully deuterated or monosubstituted by R* and K, together with X, forms a heteroaromatic ring system having 14 to 40 ring atoms as soon as the value of x or y denotes 1 or both values x and y denote 1.

In preferred compounds of the formula (2b), the sum of the indices c+d+e+f is preferably 0 or 1 and R⁰ has a meaning indicated or preferably indicated above.

In compounds of the formula (2) or (2b), the indices c, d, e and f are particularly preferably 0.

In compounds of the formula (2) or (2b), K preferably forms a heteroaromatic ring system if the sum of x+y denotes 1 or 2. X in compounds of the formula (2) or (2b) is preferably a direct bond or C(CH₃)₂.

Preferred compounds of the formula (2) or (2b) can be represented by the formulae (2b-1) to (2b-6),

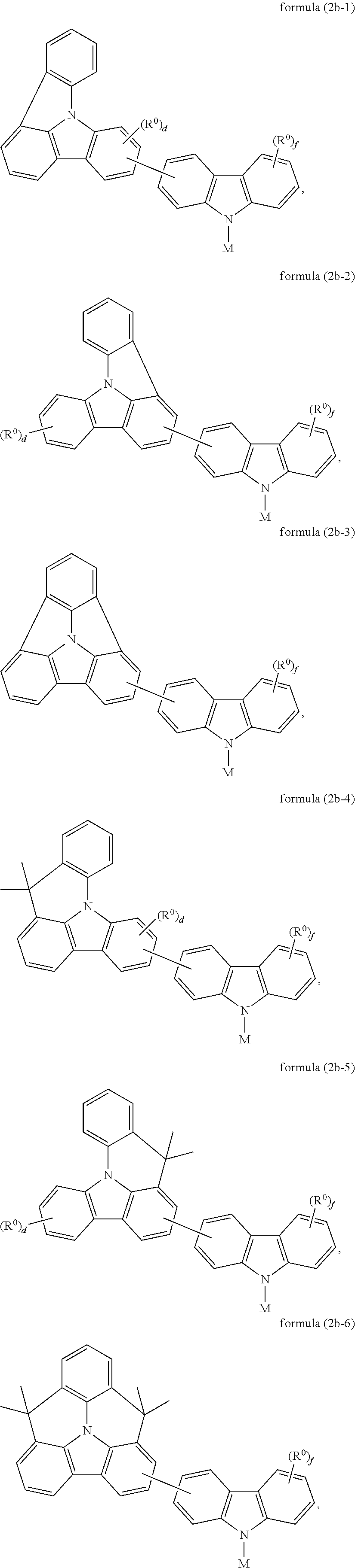

where M, R⁰, c, d, e and f have a meaning given or preferably given above.

In compounds of the formula (2), (2b), (2b-1), (2b-2), (2b-3), (2b-4, (2b-5) or (2b-6), M is preferably an aromatic ring system having 6 to 40 aromatic ring atoms which is unsubstituted or partially deuterated or monosubstituted by R*, as described above. M in compounds of the formula (2), (2b), (2b-1), (2b-2), (2b-3), (2b-4, (2b-5) or (2b-6) is particularly preferably phenyl, dibenzofuran-substituted phenyl, dibenzothiophene-substituted phenyl, deuterated phenyl, 1,3-biphenyl, 1,4-biphenyl, terphenyl, partially deuterated terphenyl, quaterphenyl, naphthyl, fluorenyl, 9,9-diphenyl-fluorenyl, bispirofluorenyl or triphenylenyl.

In compounds of the formula (2b-1), (2b-2), (2b-3), (2b-4, (2b-5) or (2b-6), c, d, e and f are preferably 0.

Accordingly, the invention furthermore relates to an organic electroluminescent device, as described or preferably described above, where the at least one compound of the formula (2) corresponds to a compound of the formula (2b), (2b), (2b-1), (2b-2), (2b-3), (2b-4, (2b-5) or (2b-6) or a preferred embodiment of these compounds.

In a preferred embodiment of the device according to the invention, compounds of the formula (2) in which c and f denote 0 or 1, d and e denote 0 and x, x1, y and y1 on each occurrence, independently of one another, denote 0 or 1, but where the sum of x and y denotes at least 1 and the sum of x1 and y1 denotes at least 1, are used as host material 2. Such compounds of the formula (2) as described above, can preferably be represented by the following formula (2c),

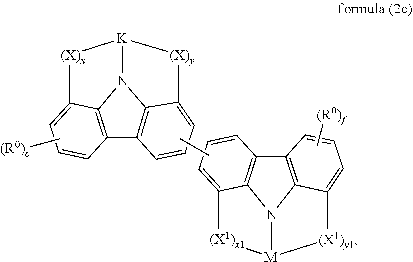

where X and X¹ have a meaning given above or given below,
K and M in each case, independently of one another, together with X or X¹, form a heteroaromatic ring system having 14 to 40 ring atoms,
x, x1, y and/or y1 denote 0 or 1 and the sum of x and y denotes at least 1 and the sum of x1 and y1 denotes at least 1.

In preferred compounds of the formula (2c), the sum of x and y is 1 or 2 and the sum of x1 and y1 is 1. In particularly preferred compounds of the formula (2c), the sum of x and y is 1 and the sum of x1 and y1 is 1.

Accordingly, K and M in compounds of the formula (2) or (2c) preferably form a heteroaromatic ring system. X and X¹ in compounds of the formula (2) or (2c) are preferably a direct bond or C(CH₃)₂.

Preferred compounds of the formula (2) or (2c) can be represented by the formulae (2c-1) to (2c-8),

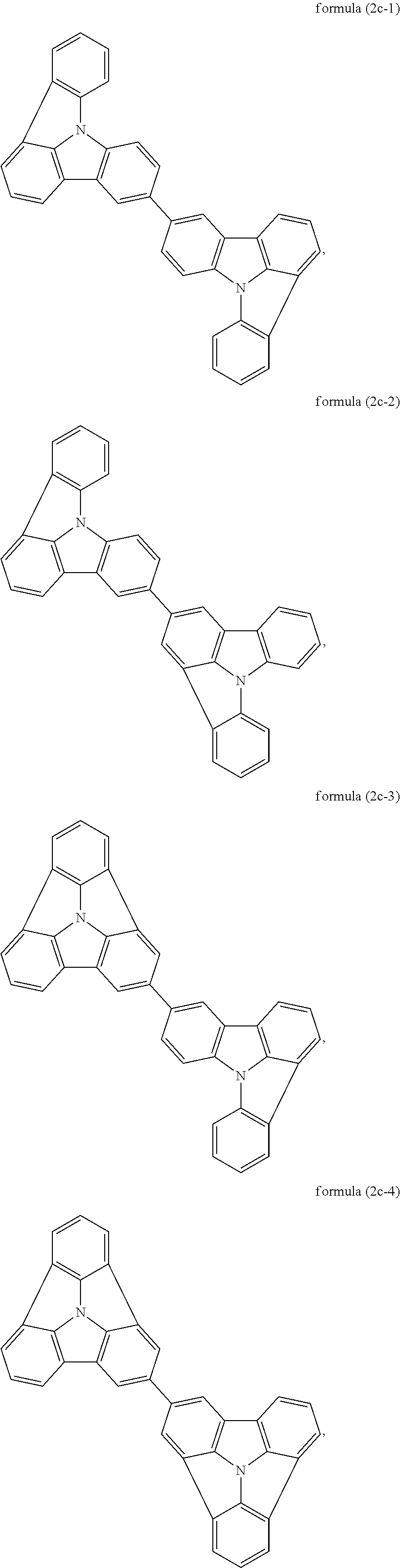 [SMILES: c1ccc2c(c1)c1cccc3c4cc(-c5ccc6c(c5)c5cccc7c8ccccc8n6c75)ccc4n2c13 ; c1ccc2c(c1)c1cccc3c4cc(-c5cc6c7ccccc7n7c8ccccc8c(c5)c67)ccc4n2c13 ; c1ccc2c(c1)c1cccc3c4cc(-c5cc6c7cccc8c9cccc%10c(c5)c6n(c87)c9%10)ccc4n2c13 ; c1cc2c3cccc4c5cc(-c6cc7c8cccc9c%10cccc%11c(c6)c7n(c98)c%10%11)cc6c(c1)c2n(c34)c65]

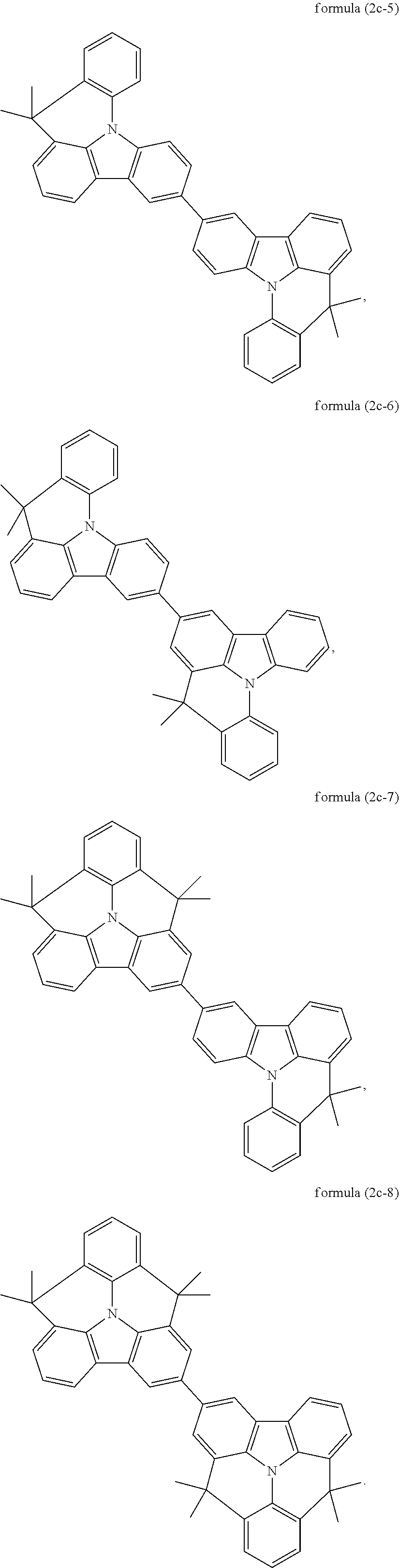

Preferred compounds of the formula (2c) are also compounds 46, 47, 48, 49 and 50, as described below.

Accordingly, the invention furthermore relates to an organic electroluminescent device, as described or preferably described above, where the at least one compound of the formula (2) corresponds to a compound of the formula (2c), (2c-1), (2c-2), (2c-3), (2c-4, (2c-5), (2c-6), (2c-7) or (2c-8).

In a preferred embodiment of the compounds of the formula (2), (2a), (2b), (2b-1), (2b-2), (2b-3), (2b-4, (2b-5) or (2b-6), the carbazole and the bridged carbazole are in each case linked to one another in the 3 position.

In a preferred embodiment of the compounds of the formula (2c), the two bridged carbazoles are in each case linked to one another in the 3 position.

Examples of suitable host materials of the formulae (2), (2a), (2b), (2b-1), (2b-2), (2b-3), (2b-4, (2b-5) and (2c), which are selected in accordance with the invention, and are preferably used in combination with at least one compound of the formula (1) in the electroluminescent device according to the invention, are the structures shown below in Table 2.

TABLE 2

| | |
|---|---|
| 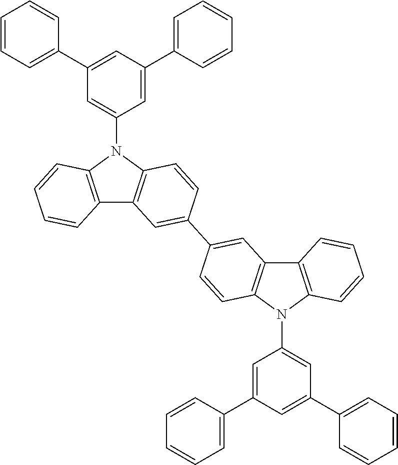 [SMILES: c1ccc(-c2cc(-c3ccccc3)cc(-n3c4ccccc4c4cc(-c5ccc6c(c5)c5ccccc5n6-c5cc(-c6ccccc6)cc(-c6ccccc6)c5)ccc43)c2)cc1] | |
| 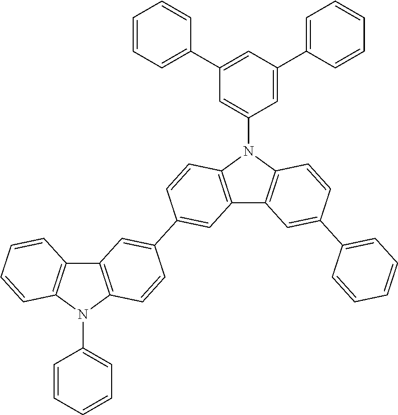 [SMILES: c1ccc(-c2cc(-c3ccccc3)cc(-n3c4ccc(-c5ccccc5)cc4c4cc(-c5ccc6c(c5)c5ccccc5n6-c5ccccc5)ccc43)c2)cc1] | |
| 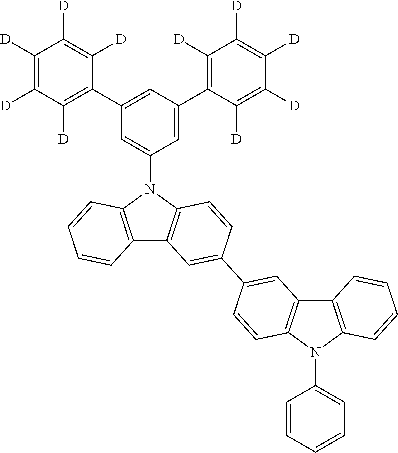 [SMILES: [2H]c1c([2H])c([2H])c(-c2cc(-c3c([2H])c([2H])c([2H])c([2H])c3[2H])cc(-n3c4ccccc4c4cc(-c5ccc6c(c5)c5ccccc5n6-c5ccccc5)ccc43)c2)c([2H])c1[2H]] | |
| 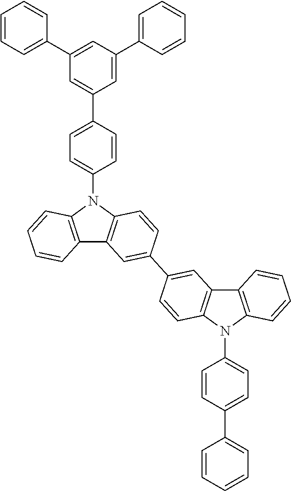 [SMILES: c1ccc(-c2ccc(-n3c4ccccc4c4cc(-c5ccc6c(c5)c5ccccc5n6-c5ccc(-c6cc(-c7ccccc7)cc(-c7ccccc7)c6)cc5)ccc43)cc2)cc1] | |
| 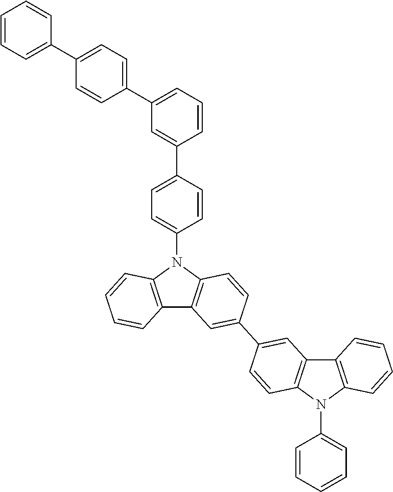 [SMILES: c1ccc(-c2ccc(-c3cccc(-c4ccc(-n5c6ccccc6c6cc(-c7ccc8c(c7)c7ccccc7n8-c7ccccc7)ccc65)cc4)c3)cc2)cc1] | |
| 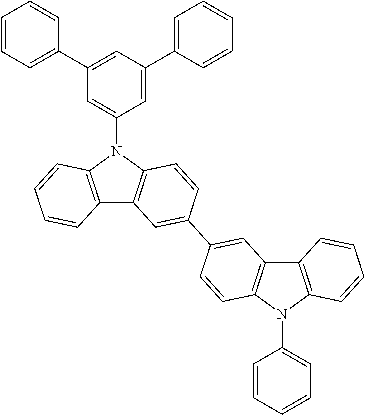 [SMILES: c1ccc(-c2cc(-c3ccccc3)cc(-n3c4ccccc4c4cc(-c5ccc6c(c5)c5ccccc5n6-c5ccccc5)ccc43)c2)cc1] | |
| 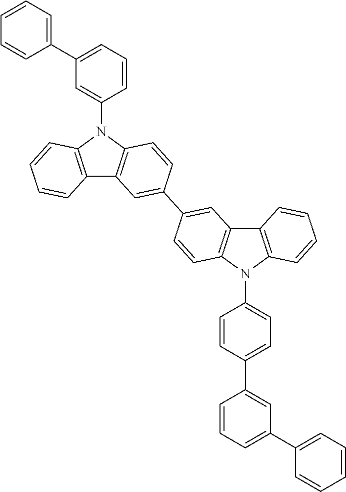 [SMILES: c1ccc(-c2cccc(-c3ccc(-n4c5ccccc5c5cc(-c6ccc7c(c6)c6ccccc6n7-c6cccc(-c7ccccc7)c6)ccc54)cc3)c2)cc1] | |
| 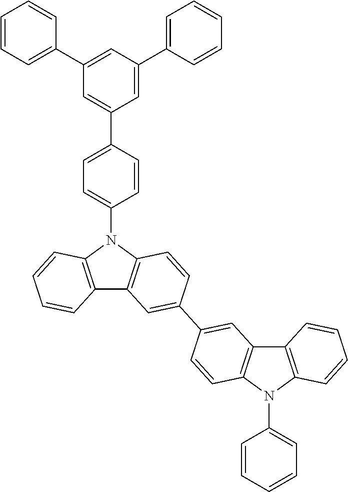 [SMILES: c1ccc(-c2cc(-c3ccccc3)cc(-c3ccc(-n4c5ccccc5c5cc(-c6ccc7c(c6)c6ccccc6n7-c6ccccc6)ccc54)cc3)c2)cc1] | |
| 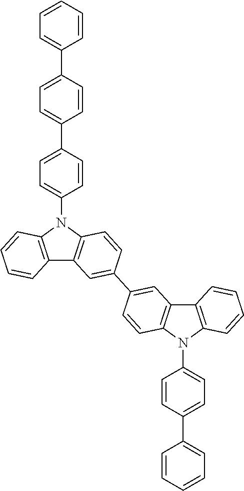 [SMILES: c1ccc(-c2ccc(-c3ccc(-n4c5ccccc5c5cc(-c6ccc7c(c6)c6ccccc6n7-c6ccc(-c7ccccc7)cc6)ccc54)cc3)cc2)cc1] | |
| 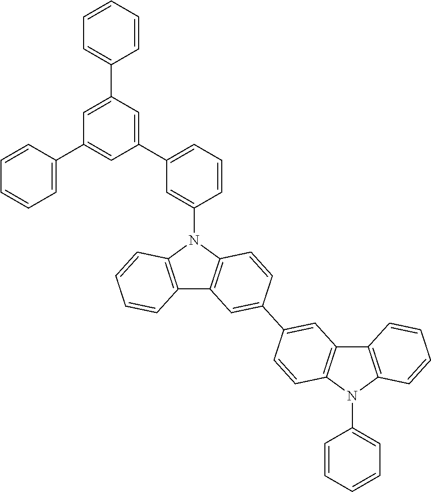 [SMILES: c1ccc(-c2cc(-c3ccccc3)cc(-c3cccc(-n4c5ccccc5c5cc(-c6ccc7c(c6)c6ccccc6n7-c6ccccc6)ccc54)c3)c2)cc1] | |
| 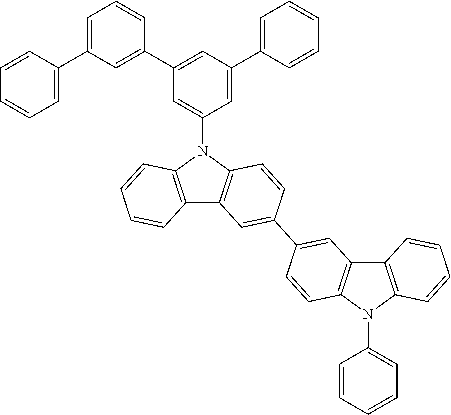 [SMILES: c1ccc(-c2cccc(-c3cc(-c4ccccc4)cc(-n4c5ccccc5c5cc(-c6ccc7c(c6)c6ccccc6n7-c6ccccc6)ccc54)c3)c2)cc1] | |
| 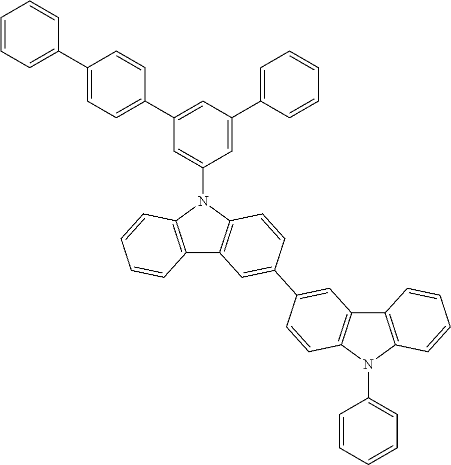 [SMILES: c1ccc(-c2ccc(-c3cc(-c4ccccc4)cc(-n4c5ccccc5c5cc(-c6ccc7c(c6)c6ccccc6n7-c6ccccc6)ccc54)c3)cc2)cc1] | |
| 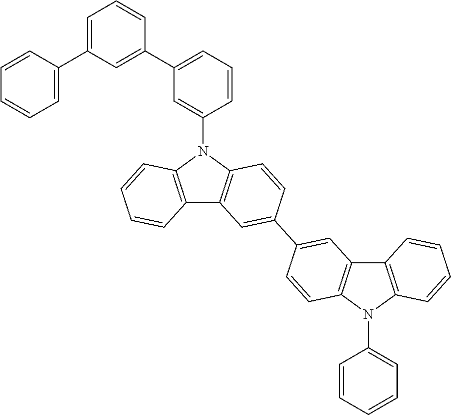 [SMILES: c1ccc(-c2cccc(-c3cccc(-n4c5ccccc5c5cc(-c6ccc7c(c6)c6ccccc6n7-c6ccccc6)ccc54)c3)c2)cc1] | |
| 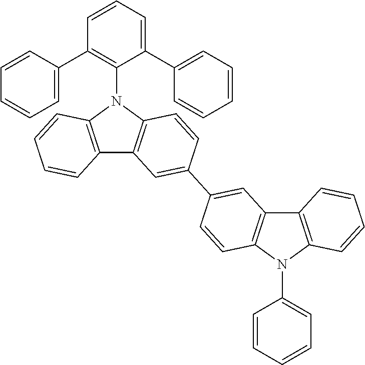 [SMILES: c1ccc(-c2cccc(-c3ccccc3)c2-n2c3ccccc3c3cc(-c4ccc5c(c4)c4ccccc4n5-c4ccccc4)ccc32)cc1] | |
| 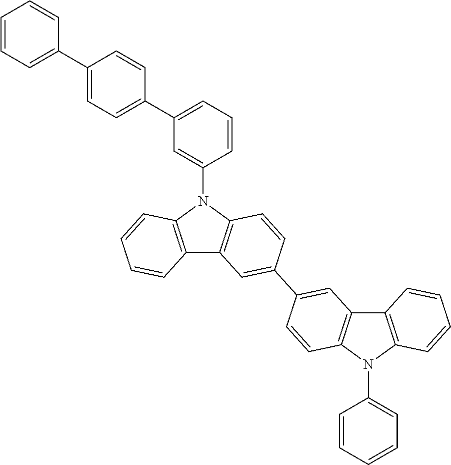 [SMILES: c1ccc(-c2ccc(-c3cccc(-n4c5ccccc5c5cc(-c6ccc7c(c6)c6ccccc6n7-c6ccccc6)ccc54)c3)cc2)cc1] | |
| 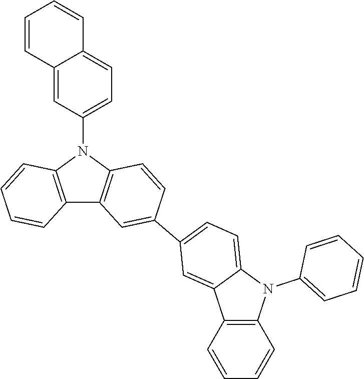 [SMILES: c1ccc(-n2c3ccccc3c3cc(-c4ccc5c(c4)c4ccccc4n5-c4ccc5ccccc5c4)ccc32)cc1] | |
| 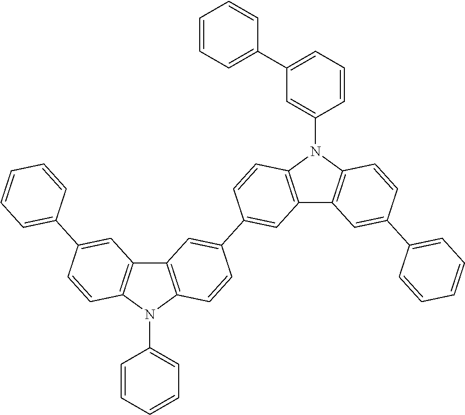 [SMILES: c1ccc(-c2cccc(-n3c4ccc(-c5ccccc5)cc4c4cc(-c5ccc6c(c5)c5cc(-c7ccccc7)ccc5n6-c5ccccc5)ccc43)c2)cc1] | |
| 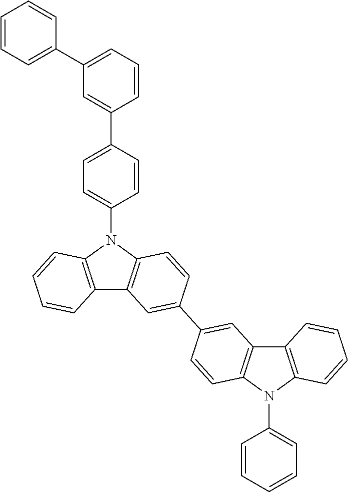 [SMILES: c1ccc(-c2cccc(-c3ccc(-n4c5ccccc5c5cc(-c6ccc7c(c6)c6ccccc6n7-c6ccccc6)ccc54)cc3)c2)cc1] | |
| 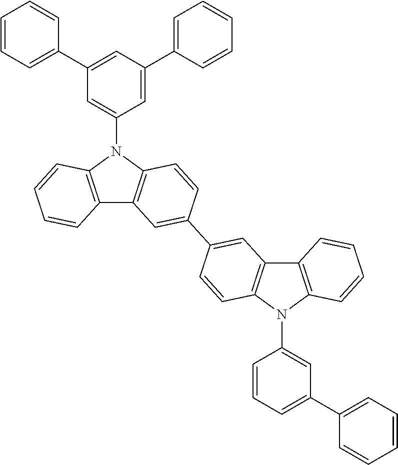 [SMILES: c1ccc(-c2cccc(-n3c4ccccc4c4cc(-c5ccc6c(c5)c5ccccc5n6-c5cc(-c6ccccc6)cc(-c6ccccc6)c5)ccc43)c2)cc1] | |
| 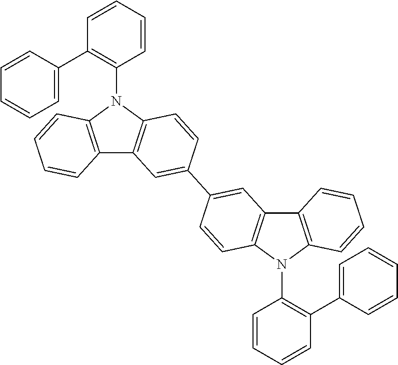 [SMILES: c1ccc(-c2ccccc2-n2c3ccccc3c3cc(-c4ccc5c(c4)c4ccccc4n5-c4ccccc4-c4ccccc4)ccc32)cc1] | |
| 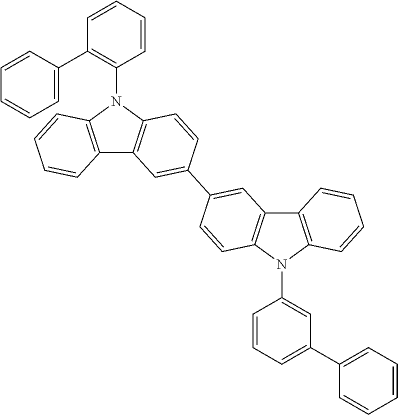 [SMILES: c1ccc(-c2cccc(-n3c4ccccc4c4cc(-c5ccc6c(c5)c5ccccc5n6-c5ccccc5-c5ccccc5)ccc43)c2)cc1] | |
| 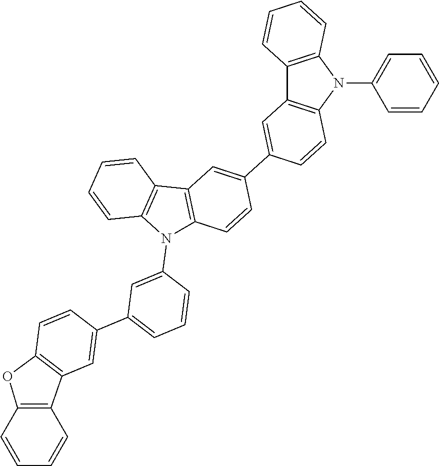 [SMILES: c1ccc(-n2c3ccccc3c3cc(-c4ccc5c(c4)c4ccccc4n5-c4cccc(-c5ccc6oc7ccccc7c6c5)c4)ccc32)cc1] | 24 |
| 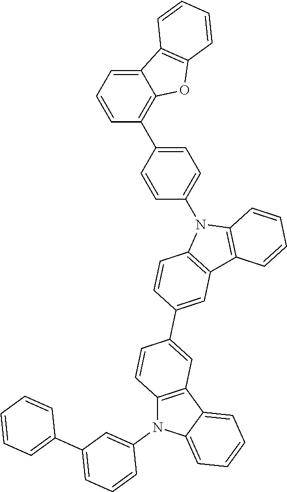 [SMILES: c1ccc(-c2cccc(-n3c4ccccc4c4cc(-c5ccc6c(c5)c5ccccc5n6-c5ccc(-c6cccc7c6oc6ccccc67)cc5)ccc43)c2)cc1] | |
| 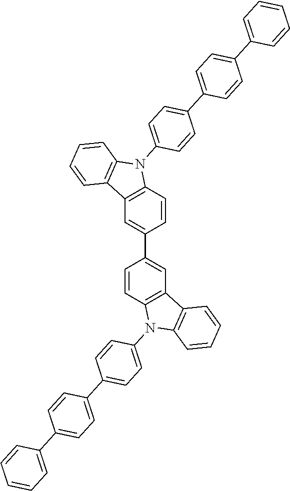 [SMILES: c1ccc(-c2ccc(-c3ccc(-n4c5ccccc5c5cc(-c6ccc7c(c6)c6ccccc6n7-c6ccc(-c7ccc(-c8ccccc8)cc7)cc6)ccc54)cc3)cc2)cc1] | |
| 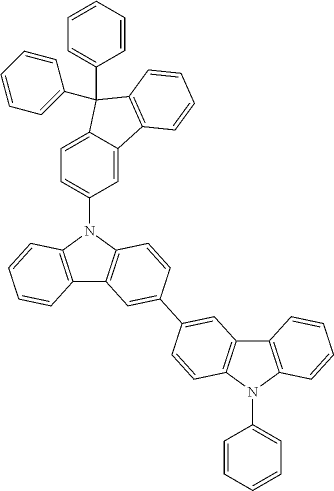 [SMILES: c1ccc(-n2c3ccccc3c3cc(-c4ccc5c(c4)c4ccccc4n5-c4ccc5c(c4)-c4ccccc4C5(c4ccccc4)c4ccccc4)ccc32)cc1] | |
| 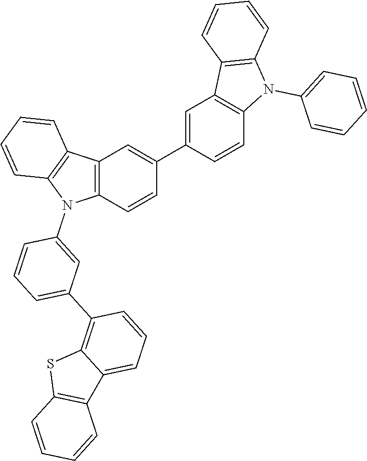 [SMILES: c1ccc(-n2c3ccccc3c3cc(-c4ccc5c(c4)c4ccccc4n5-c4cccc(-c5cccc6c5sc5ccccc56)c4)ccc32)cc1] | |
| 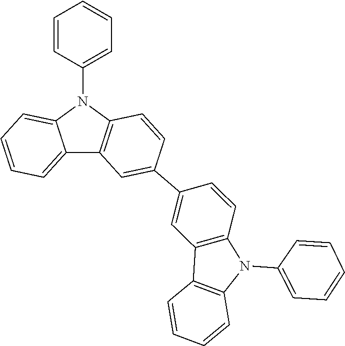 [SMILES: c1ccc(-n2c3ccccc3c3cc(-c4ccc5c(c4)c4ccccc4n5-c4ccccc4)ccc32)cc1] | 23 |
| 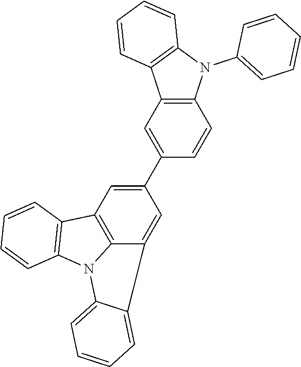 [SMILES: c1ccc(-n2c3ccccc3c3cc(-c4cc5c6ccccc6n6c7ccccc7c(c4)c56)ccc32)cc1] | 25 |
| 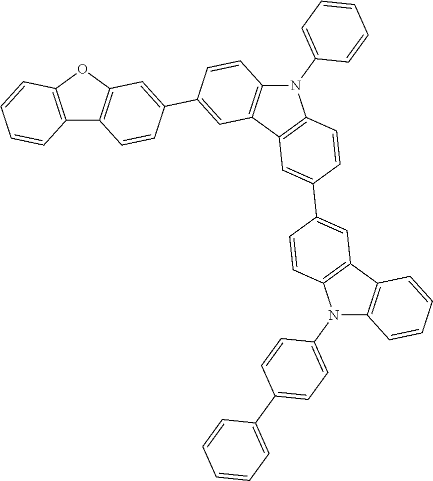 [SMILES: c1ccc(-c2ccc(-n3c4ccccc4c4cc(-c5ccc6c(c5)c5cc(-c7ccc8c(c7)oc7ccccc78)ccc5n6-c5ccccc5)ccc43)cc2)cc1] | |
| 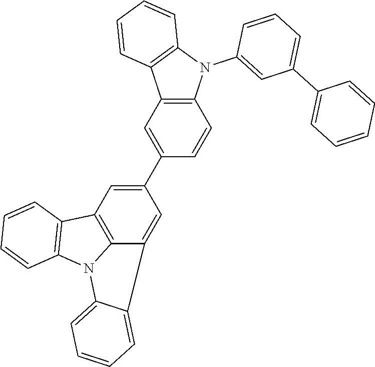 [SMILES: c1ccc(-c2cccc(-n3c4ccccc4c4cc(-c5cc6c7ccccc7n7c8ccccc8c(c5)c67)ccc43)c2)cc1] | 26 |
| 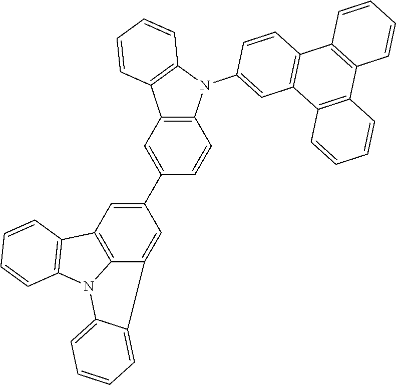 [SMILES: c1ccc2c(c1)c1ccccc1c1cc(-n3c4ccccc4c4cc(-c5cc6c7ccccc7n7c8ccccc8c(c5)c67)ccc43)ccc21] | 27 |
| 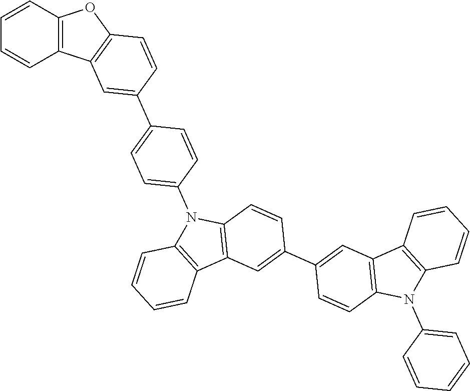 [SMILES: c1ccc(-n2c3ccccc3c3cc(-c4ccc5c(c4)c4ccccc4n5-c4ccc(-c5ccc6oc7ccccc7c6c5)cc4)ccc32)cc1] | |
| 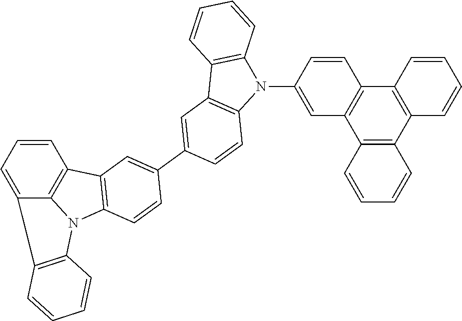 [SMILES: c1ccc2c(c1)c1ccccc1c1cc(-n3c4ccccc4c4cc(-c5ccc6c(c5)c5cccc7c8ccccc8n6c75)ccc43)ccc21] | |
| 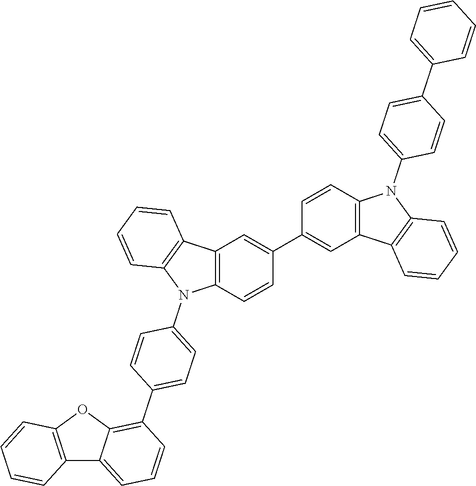 [SMILES: c1ccc(-c2ccc(-n3c4ccccc4c4cc(-c5ccc6c(c5)c5ccccc5n6-c5ccc(-c6cccc7c6oc6ccccc67)cc5)ccc43)cc2)cc1] | |
| 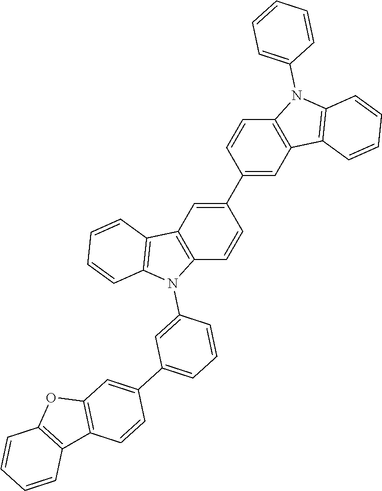 [SMILES: c1ccc(-n2c3ccccc3c3cc(-c4ccc5c(c4)c4ccccc4n5-c4cccc(-c5ccc6c(c5)oc5ccccc56)c4)ccc32)cc1] | |
| 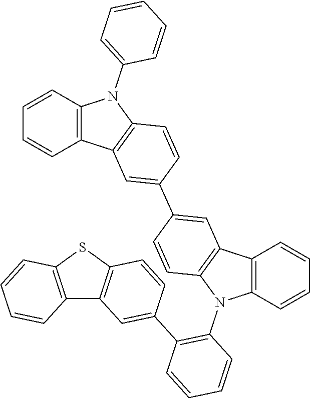 [SMILES: c1ccc(-n2c3ccccc3c3cc(-c4ccc5c(c4)c4ccccc4n5-c4ccccc4-c4ccc5sc6ccccc6c5c4)ccc32)cc1] | |
| 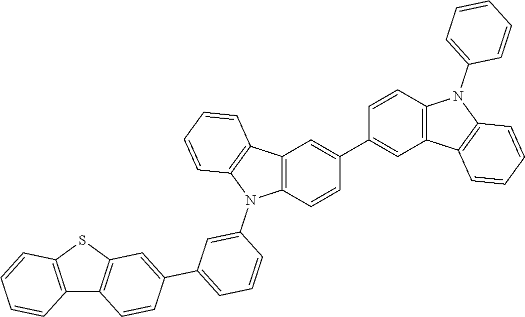 [SMILES: c1ccc(-n2c3ccccc3c3cc(-c4ccc5c(c4)c4ccccc4n5-c4cccc(-c5ccc6c(c5)sc5ccccc56)c4)ccc32)cc1] | |
| 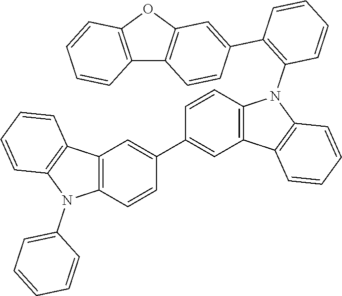 [SMILES: c1ccc(-n2c3ccccc3c3cc(-c4ccc5c(c4)c4ccccc4n5-c4ccccc4-c4ccc5c(c4)oc4ccccc45)ccc32)cc1] | |
| 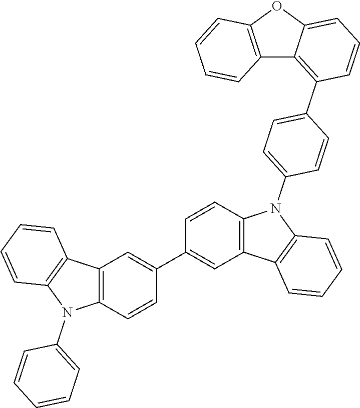 [SMILES: c1ccc(-n2c3ccccc3c3cc(-c4ccc5c(c4)c4ccccc4n5-c4ccc(-c5cccc6oc7ccccc7c56)cc4)ccc32)cc1] | |
| 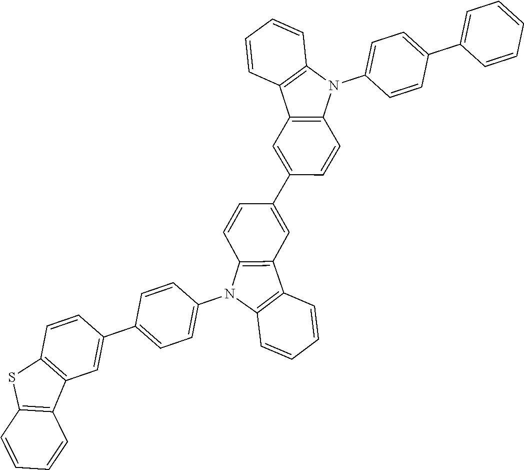 [SMILES: c1ccc(-c2ccc(-n3c4ccccc4c4cc(-c5ccc6c(c5)c5ccccc5n6-c5ccc(-c6ccc7sc8ccccc8c7c6)cc5)ccc43)cc2)cc1] | |
| 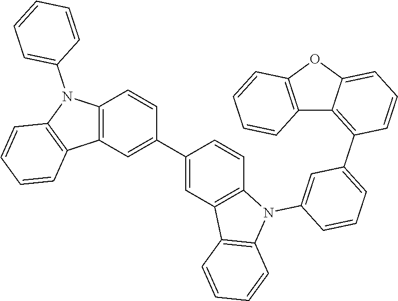 [SMILES: c1ccc(-n2c3ccccc3c3cc(-c4ccc5c(c4)c4ccccc4n5-c4cccc(-c5cccc6oc7ccccc7c56)c4)ccc32)cc1] | |
| 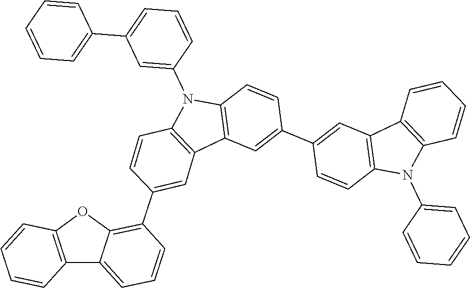 [SMILES: c1ccc(-c2cccc(-n3c4ccc(-c5ccc6c(c5)c5ccccc5n6-c5ccccc5)cc4c4cc(-c5cccc6c5oc5ccccc56)ccc43)c2)cc1] | |
| 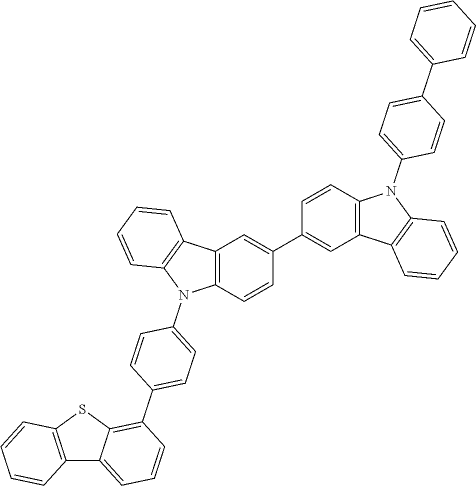 [SMILES: c1ccc(-c2ccc(-n3c4ccccc4c4cc(-c5ccc6c(c5)c5ccccc5n6-c5ccc(-c6cccc7c6sc6ccccc67)cc5)ccc43)cc2)cc1] | |
| 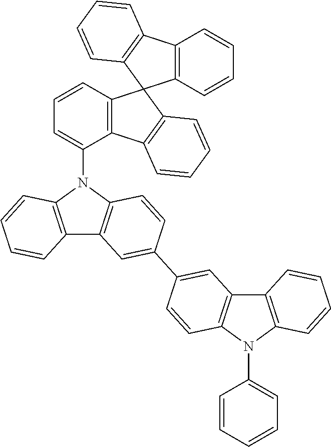 [SMILES: c1ccc(-n2c3ccccc3c3cc(-c4ccc5c(c4)c4ccccc4n5-c4cccc5c4-c4ccccc4C54c5ccccc5-c5ccccc54)ccc32)cc1] | |
| 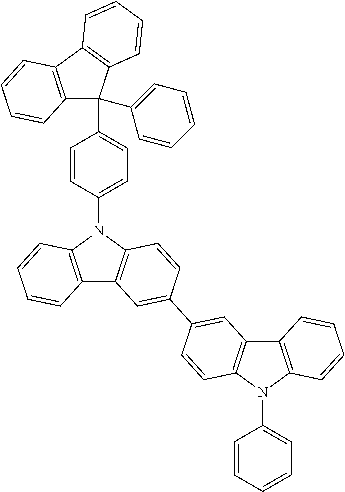 [SMILES: c1ccc(-n2c3ccccc3c3cc(-c4ccc5c(c4)c4ccccc4n5-c4ccc(C5(c6ccccc6)c6ccccc6-c6ccccc65)cc4)ccc32)cc1] | |
| 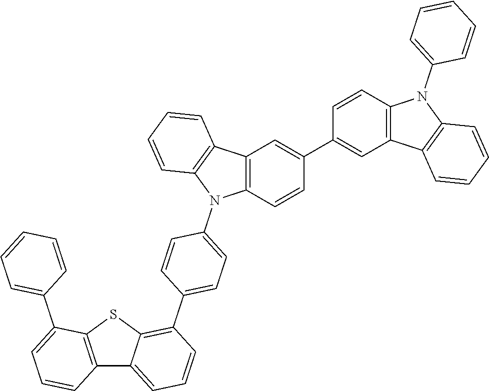 [SMILES: c1ccc(-c2cccc3c2sc2c(-c4ccc(-n5c6ccccc6c6cc(-c7ccc8c(c7)c7ccccc7n8-c7ccccc7)ccc65)cc4)cccc23)cc1] | |
| 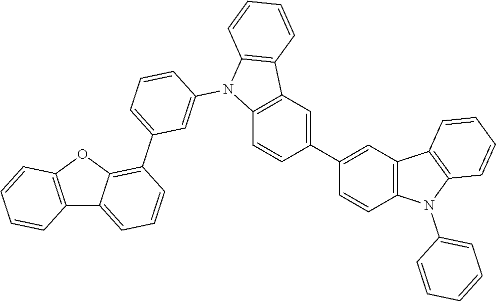 [SMILES: c1ccc(-n2c3ccccc3c3cc(-c4ccc5c(c4)c4ccccc4n5-c4cccc(-c5cccc6c5oc5ccccc56)c4)ccc32)cc1] | |
| 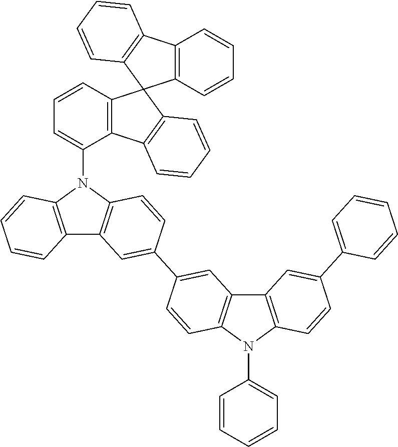 [SMILES: c1ccc(-c2ccc3c(c2)c2cc(-c4ccc5c(c4)c4ccccc4n5-c4cccc5c4-c4ccccc4C54c5ccccc5-c5ccccc54)ccc2n3-c2ccccc2)cc1] | |
| 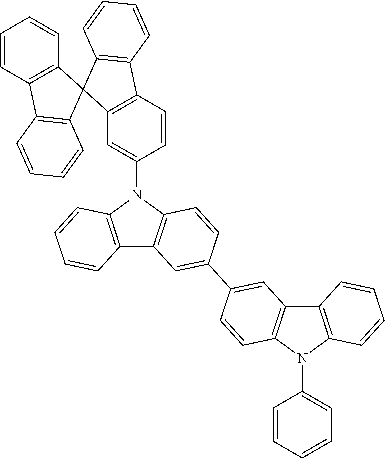 [SMILES: c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1] | |
| 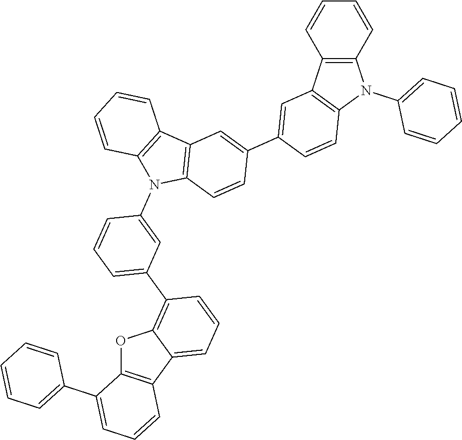 [SMILES: c1ccc(-c2cccc3c2oc2c(-c4cccc(-n5c6ccccc6c6cc(-c7ccc8c(c7)c7ccccc7n8-c7ccccc7)ccc65)c4)cccc23)cc1] | |
| 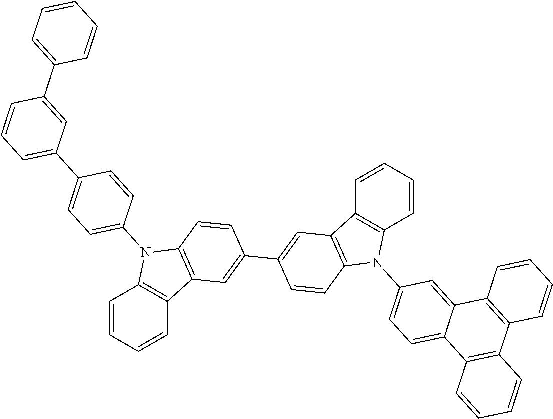 [SMILES: c1ccc(-c2cccc(-c3ccc(-n4c5ccccc5c5cc(-c6ccc7c(c6)c6ccccc6n7-c6ccc7c8ccccc8c8ccccc8c7c6)ccc54)cc3)c2)cc1] | |
| 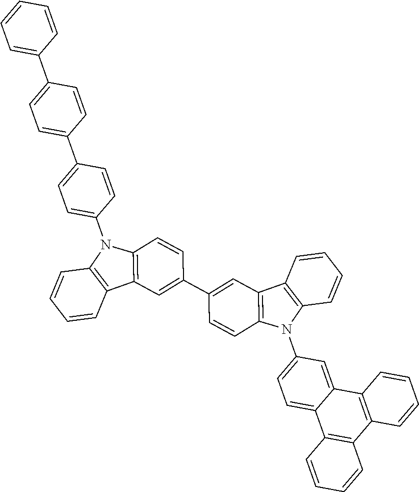 [SMILES: c1ccc(-c2ccc(-c3ccc(-n4c5ccccc5c5cc(-c6ccc7c(c6)c6ccccc6n7-c6ccc7c8ccccc8c8ccccc8c7c6)ccc54)cc3)cc2)cc1] | |
| 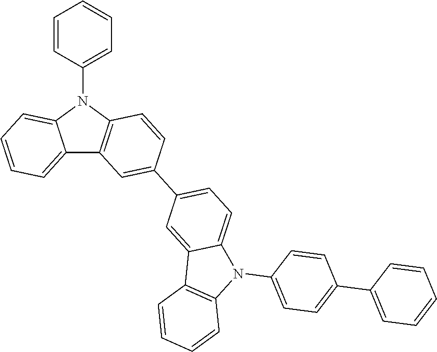 [SMILES: c1ccc(-c2ccc(-n3c4ccccc4c4cc(-c5ccc6c(c5)c5ccccc5n6-c5ccccc5)ccc43)cc2)cc1] | 12 |
| 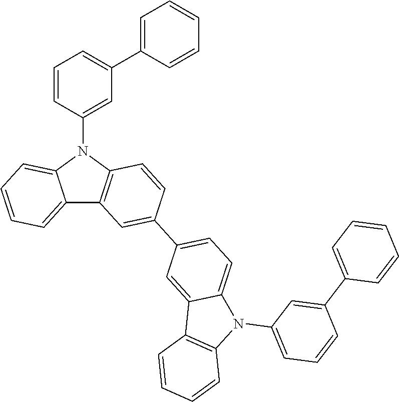 [SMILES: c1ccc(-c2cccc(-n3c4ccccc4c4cc(-c5ccc6c(c5)c5ccccc5n6-c5cccc(-c6ccccc6)c5)ccc43)c2)cc1] | 13 |
| 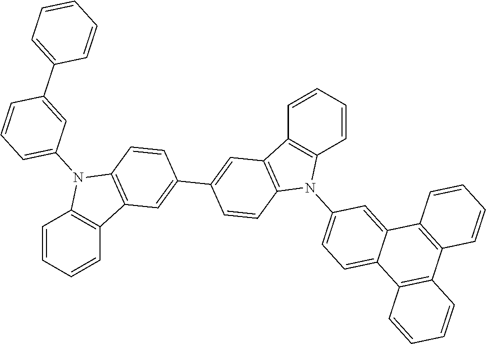 [SMILES: c1ccc(-c2cccc(-n3c4ccccc4c4cc(-c5ccc6c(c5)c5ccccc5n6-c5ccc6c7ccccc7c7ccccc7c6c5)ccc43)c2)cc1] | |
| 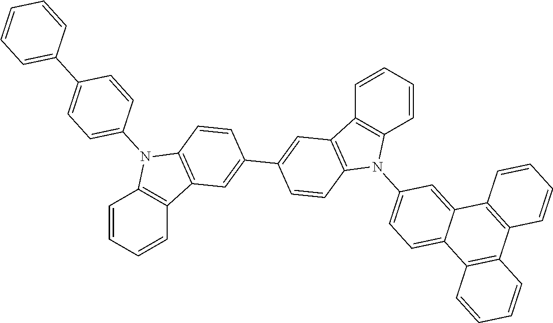 [SMILES: c1ccc(-c2ccc(-n3c4ccccc4c4cc(-c5ccc6c(c5)c5ccccc5n6-c5ccc6c7ccccc7c7ccccc7c6c5)ccc43)cc2)cc1] | |
| 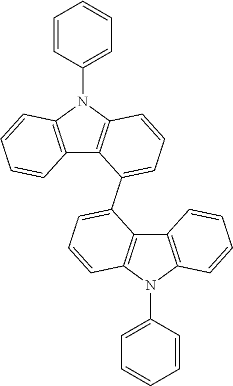 [SMILES: c1ccc(-n2c3ccccc3c3c(-c4cccc5c4c4ccccc4n5-c4ccccc4)cccc32)cc1] | |
| 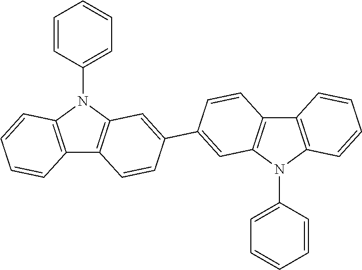 [SMILES: c1ccc(-n2c3ccccc3c3ccc(-c4ccc5c6ccccc6n(-c6ccccc6)c5c4)cc32)cc1] | |
| 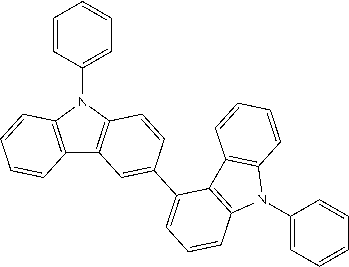 [SMILES: c1ccc(-n2c3ccccc3c3cc(-c4cccc5c4c4ccccc4n5-c4ccccc4)ccc32)cc1] | |
| 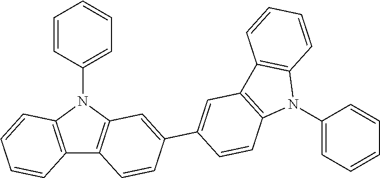 [SMILES: c1ccc(-n2c3ccccc3c3cc(-c4ccc5c6ccccc6n(-c6ccccc6)c5c4)ccc32)cc1] | |
| 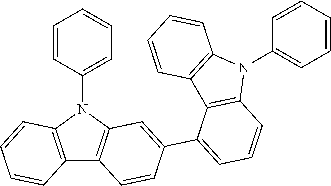 [SMILES: c1ccc(-n2c3ccccc3c3ccc(-c4cccc5c4c4ccccc4n5-c4ccccc4)cc32)cc1] | |
| 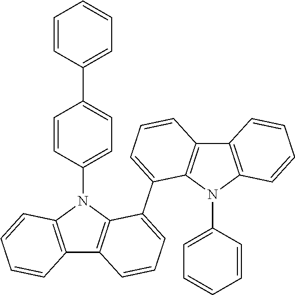 [SMILES: c1ccc(-c2ccc(-n3c4ccccc4c4cccc(-c5cccc6c7ccccc7n(-c7ccccc7)c56)c43)cc2)cc1] | |
| 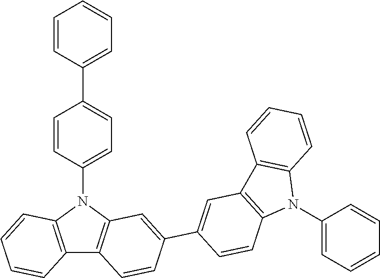 [SMILES: c1ccc(-c2ccc(-n3c4ccccc4c4ccc(-c5ccc6c(c5)c5ccccc5n6-c5ccccc5)cc43)cc2)cc1] | |
| 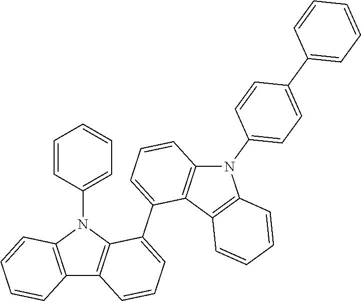 [SMILES: c1ccc(-c2ccc(-n3c4ccccc4c4c(-c5cccc6c7ccccc7n(-c7ccccc7)c56)cccc43)cc2)cc1] | |
| 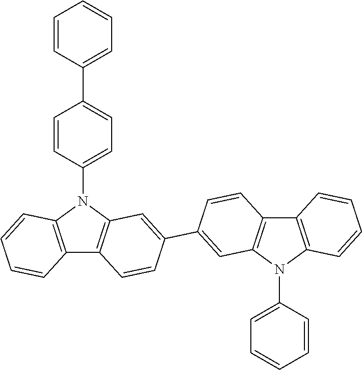 [SMILES: c1ccc(-c2ccc(-n3c4ccccc4c4ccc(-c5ccc6c7ccccc7n(-c7ccccc7)c6c5)cc43)cc2)cc1] | |
| 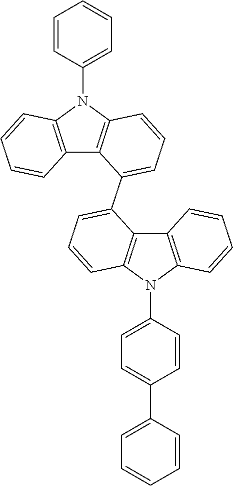 [SMILES: c1ccc(-c2ccc(-n3c4ccccc4c4c(-c5cccc6c5c5ccccc5n6-c5ccccc5)cccc43)cc2)cc1] | |
| 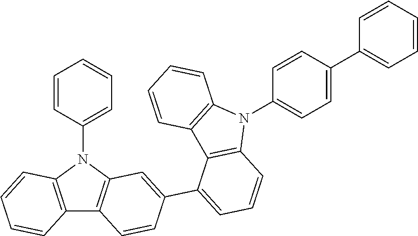 [SMILES: c1ccc(-c2ccc(-n3c4ccccc4c4c(-c5ccc6c7ccccc7n(-c7ccccc7)c6c5)cccc43)cc2)cc1] | |
| 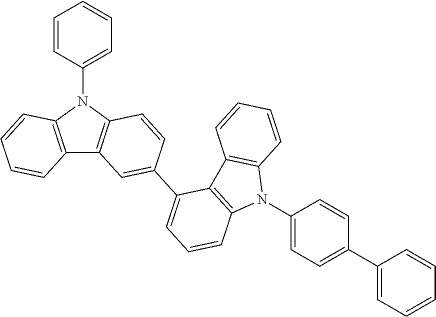 [SMILES: c1ccc(-c2ccc(-n3c4ccccc4c4c(-c5ccc6c(c5)c5ccccc5n6-c5ccccc5)cccc43)cc2)cc1] | |
| 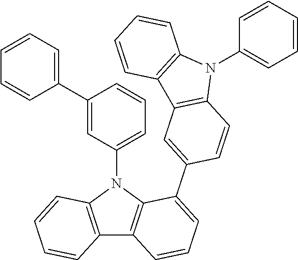 [SMILES: c1ccc(-c2cccc(-n3c4ccccc4c4cccc(-c5ccc6c(c5)c5ccccc5n6-c5ccccc5)c43)c2)cc1] | |
| 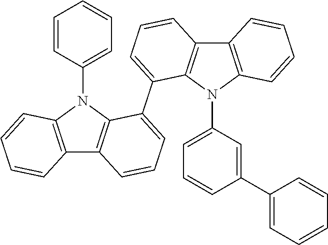 [SMILES: c1ccc(-c2cccc(-n3c4ccccc4c4cccc(-c5cccc6c7ccccc7n(-c7ccccc7)c56)c43)c2)cc1] | |
| 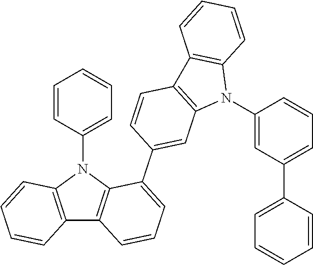 [SMILES: c1ccc(-c2cccc(-n3c4ccccc4c4ccc(-c5cccc6c7ccccc7n(-c7ccccc7)c56)cc43)c2)cc1] | |
| 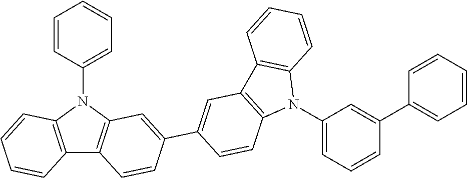 [SMILES: c1ccc(-c2cccc(-n3c4ccccc4c4cc(-c5ccc6c7ccccc7n(-c7ccccc7)c6c5)ccc43)c2)cc1] | |
| 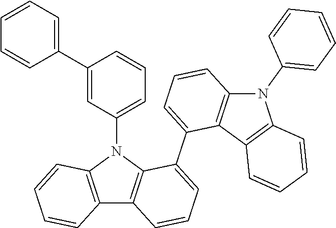 [SMILES: c1ccc(-c2cccc(-n3c4ccccc4c4cccc(-c5cccc6c5c5ccccc5n6-c5ccccc5)c43)c2)cc1] | |
| 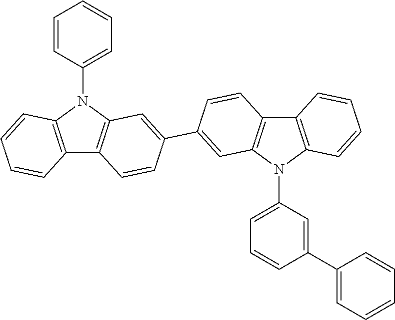 [SMILES: c1ccc(-c2cccc(-n3c4ccccc4c4ccc(-c5ccc6c7ccccc7n(-c7ccccc7)c6c5)cc43)c2)cc1] | |
| 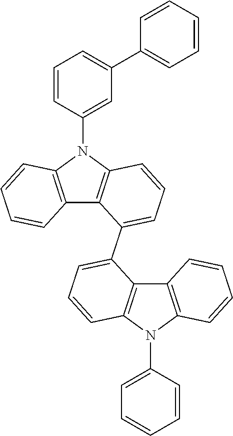 [SMILES: c1ccc(-c2cccc(-n3c4ccccc4c4c(-c5cccc6c5c5ccccc5n6-c5ccccc5)cccc43)c2)cc1] | |
| 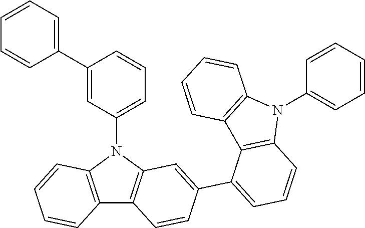 [SMILES: c1ccc(-c2cccc(-n3c4ccccc4c4ccc(-c5cccc6c5c5ccccc5n6-c5ccccc5)cc43)c2)cc1] | |
| 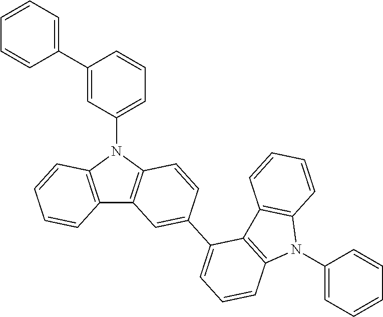 [SMILES: c1ccc(-c2cccc(-n3c4ccccc4c4cc(-c5cccc6c5c5ccccc5n6-c5ccccc5)ccc43)c2)cc1] | |
| 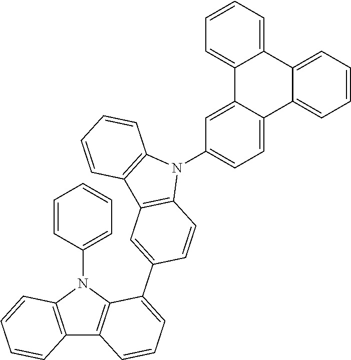 [SMILES: c1ccc(-n2c3ccccc3c3cccc(-c4ccc5c(c4)c4ccccc4n5-c4ccc5c6ccccc6c6ccccc6c5c4)c32)cc1] | |
| 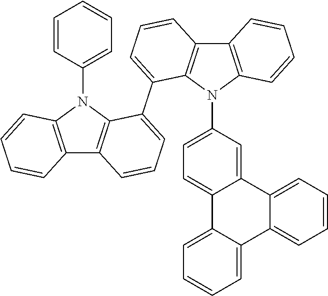 [SMILES: c1ccc(-n2c3ccccc3c3cccc(-c4cccc5c6ccccc6n(-c6ccc7c8ccccc8c8ccccc8c7c6)c45)c32)cc1] | |
| 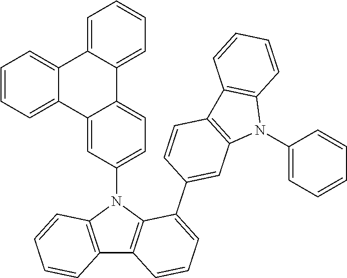 [SMILES: c1ccc(-n2c3ccccc3c3ccc(-c4cccc5c6ccccc6n(-c6ccc7c8ccccc8c8ccccc8c7c6)c45)cc32)cc1] | |
| 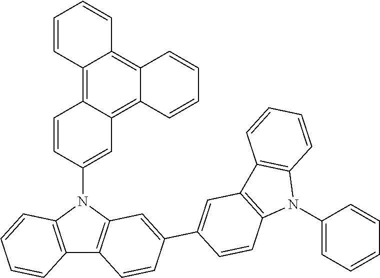 [SMILES: c1ccc(-n2c3ccccc3c3cc(-c4ccc5c6ccccc6n(-c6ccc7c8ccccc8c8ccccc8c7c6)c5c4)ccc32)cc1] | |
| 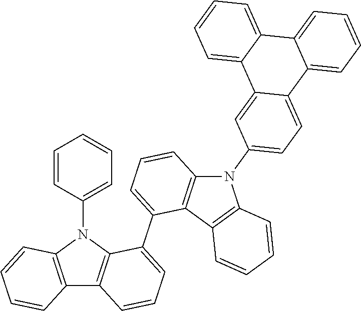 [SMILES: c1ccc(-n2c3ccccc3c3cccc(-c4cccc5c4c4ccccc4n5-c4ccc5c6ccccc6c6ccccc6c5c4)c32)cc1] | |
| 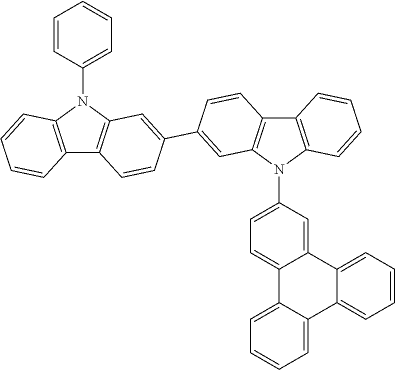 [SMILES: c1ccc(-n2c3ccccc3c3ccc(-c4ccc5c6ccccc6n(-c6ccc7c8ccccc8c8ccccc8c7c6)c5c4)cc32)cc1] | |
| 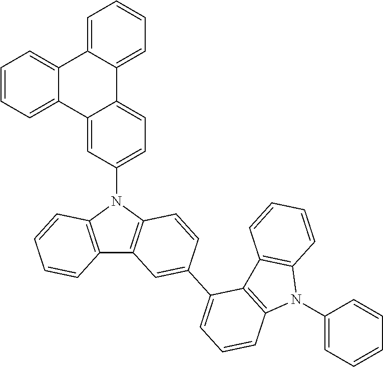 [SMILES: c1ccc(-n2c3ccccc3c3c(-c4ccc5c(c4)c4ccccc4n5-c4ccc5c6ccccc6c6ccccc6c5c4)cccc32)cc1] | |
| 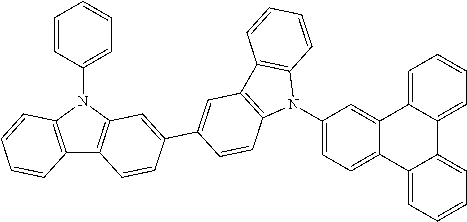 [SMILES: c1ccc(-n2c3ccccc3c3ccc(-c4ccc5c(c4)c4ccccc4n5-c4ccc5c6ccccc6c6ccccc6c5c4)cc32)cc1] | |
| 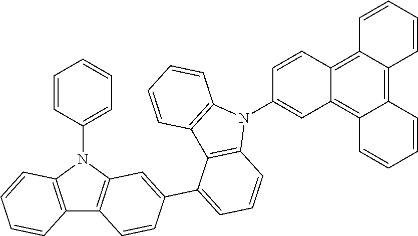 [SMILES: c1ccc(-n2c3ccccc3c3ccc(-c4cccc5c4c4ccccc4n5-c4ccc5c6ccccc6c6ccccc6c5c4)cc32)cc1] | |
| 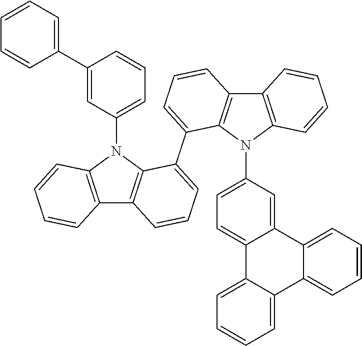 [SMILES: c1ccc(-c2cccc(-n3c4ccccc4c4cccc(-c5cccc6c7ccccc7n(-c7ccc8c9ccccc9c9ccccc9c8c7)c56)c43)c2)cc1] | |
| 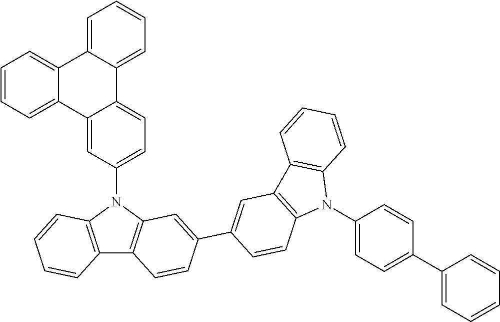 [SMILES: c1ccc(-c2ccc(-n3c4ccccc4c4cc(-c5ccc6c7ccccc7n(-c7ccc8c9ccccc9c9ccccc9c8c7)c6c5)ccc43)cc2)cc1] | |
| 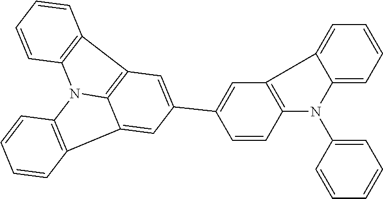 [SMILES: c1ccc(-n2c3ccccc3c3cc(-c4cc5c6ccccc6n6c7ccccc7c(c4)c56)ccc32)cc1] | |
| 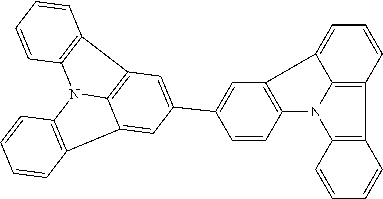 [SMILES: c1ccc2c(c1)c1cccc3c4cc(-c5cc6c7ccccc7n7c8ccccc8c(c5)c67)ccc4n2c13] | |
| 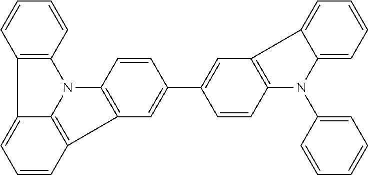 [SMILES: c1ccc(-n2c3ccccc3c3cc(-c4ccc5c(c4)c4cccc6c7ccccc7n5c64)ccc32)cc1] | |
| 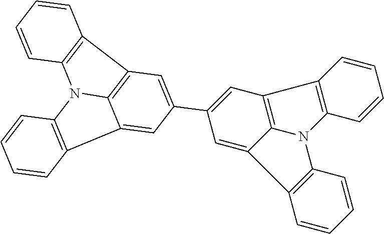 [SMILES: c1ccc2c(c1)c1cc(-c3cc4c5ccccc5n5c6ccccc6c(c3)c45)cc3c4ccccc4n2c13] | |
| 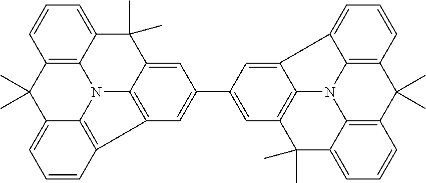 | |
| 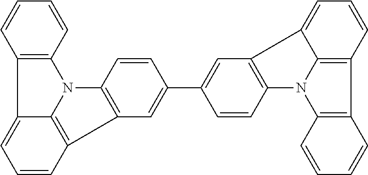 [SMILES: c1ccc2c(c1)c1cccc3c4cc(-c5ccc6c(c5)c5cccc7c8ccccc8n6c75)ccc4n2c13] | |
| 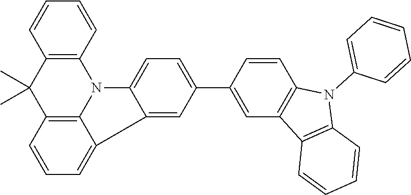 [SMILES: CC1(C)c2ccccc2-n2c3ccc(-c4ccc5c(c4)c4ccccc4n5-c4ccccc4)cc3c3cccc1c32] | |
| 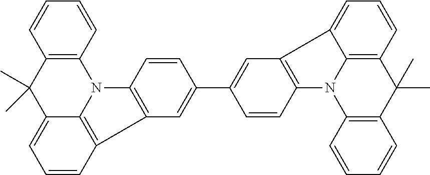 | |

Particularly suitable compounds of the formula (2) which are preferably used in combination with at least one compound of the formula (1) in the electroluminescent device according to the invention are compounds 12 to 27 and 45 to 52:

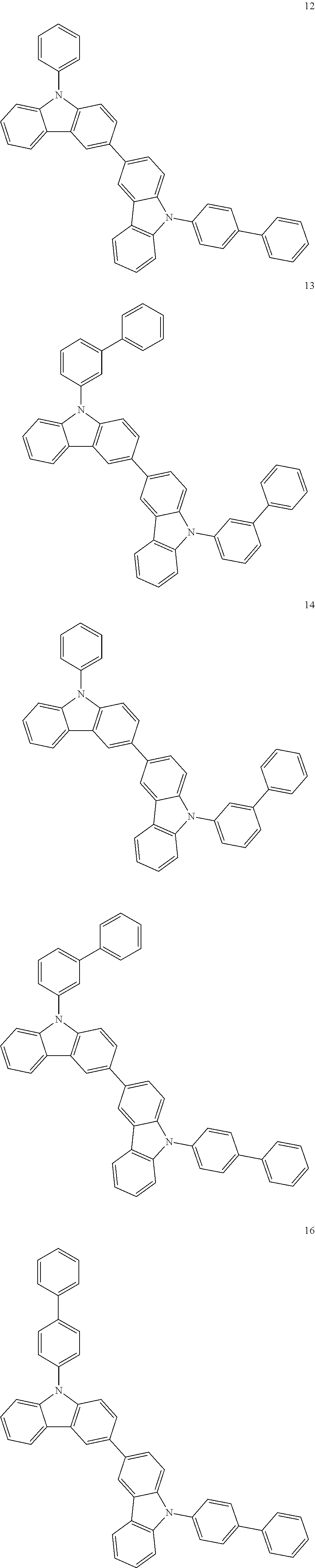

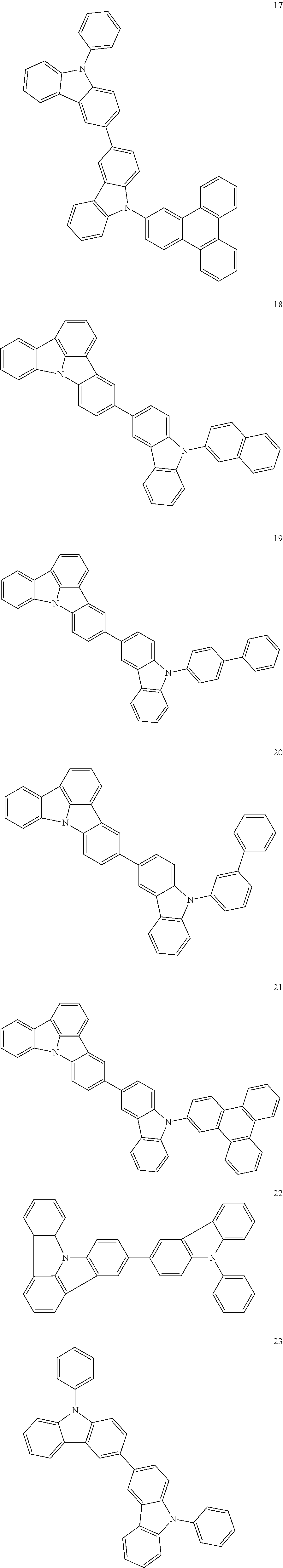

[chemical structure]

The preparation of the compounds of the formula (2) or the preferred compounds of the formulae (2), (2a), (2b), (2b-1), (2b-2), (2b-3), (2b-4, (2b-5) and (2c), and the compounds from Table 2 and 12 to 27 and 45 to 52 is known to the person skilled in the art. The compounds can be prepared by synthesis steps known to the person skilled in the art, such as, for example, halogenation, preferably bromination, and a subsequent organometallic coupling reaction, for example Suzuki coupling, Heck coupling or Hartwig-Buchwald coupling. Some of the compounds of the formula (2) are commercially available.

The host materials of the formula (1) mentioned above and their preferably described embodiments or the compounds from Table 1 and compounds 1 to 11 and 29 to 44 can be combined as desired in the device according to the invention with the said host materials of the formulae (2), (2a), (2b), (2), (2a), (2b), (2b-1), (2b-2), (2b-3), (2b-4, (2b-5), (2c), (2c-1), (2c-2), (2c-3), (2c-4), (2c-5), (2c-6), (2c-7) and (2c-8) and their preferably described embodiments or the compounds from Table 2 or compounds 12 to 27 and 45 to 52.

Above-mentioned specific combinations of host materials of the formula (1) with host materials of the formula (2) are preferred, as described above. Preferred combinations of host materials are likewise described below.

The invention likewise furthermore relates to mixtures comprising at least one compound of the formula (1) and at least one compound of the formula (2),

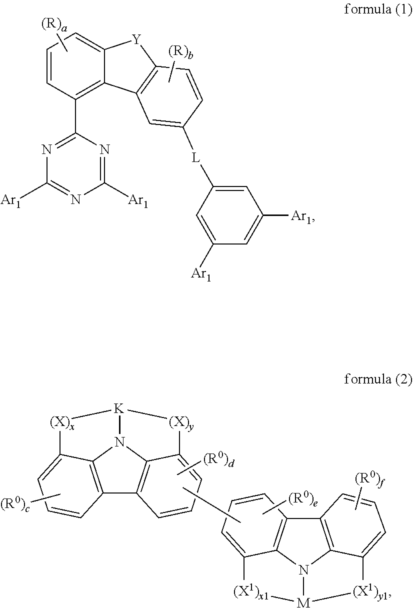

where the following applies to the symbols and indices used:
Y is selected from O, S, C(CH₃)₂, C(phenyl)₂ or

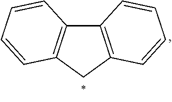 [SMILES: c1ccc2c(c1)Cc1ccccc1-2]

where * marks the C atom that is bonded to the remainder of the formula (1);
L is selected from one of the divalent linkers L-1 to L-26,

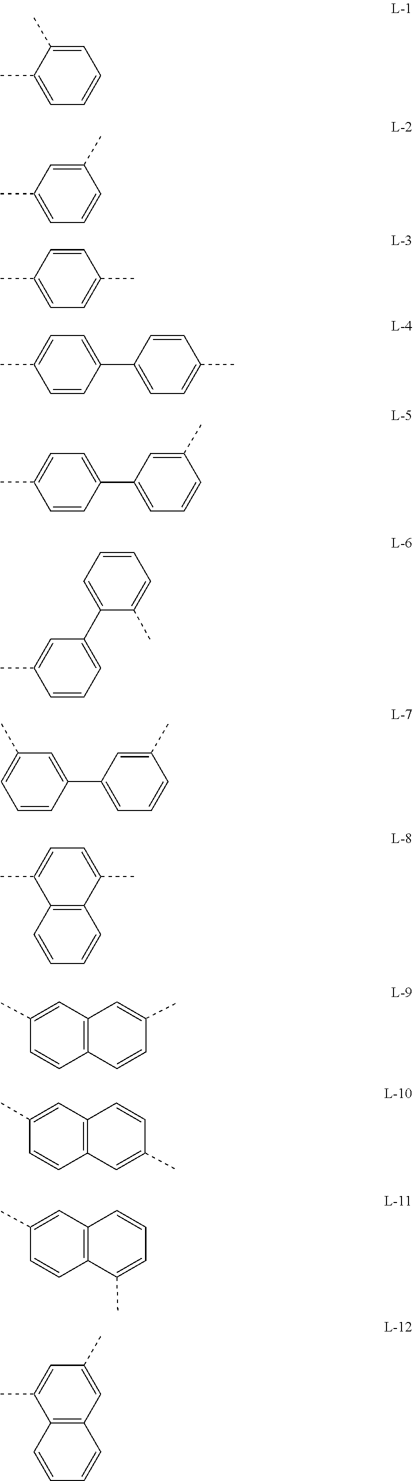

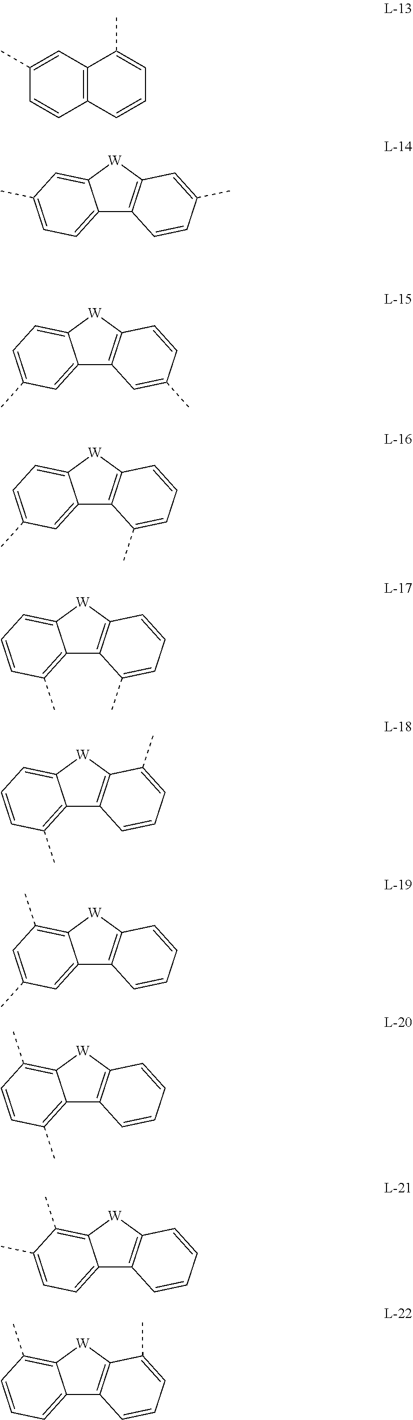

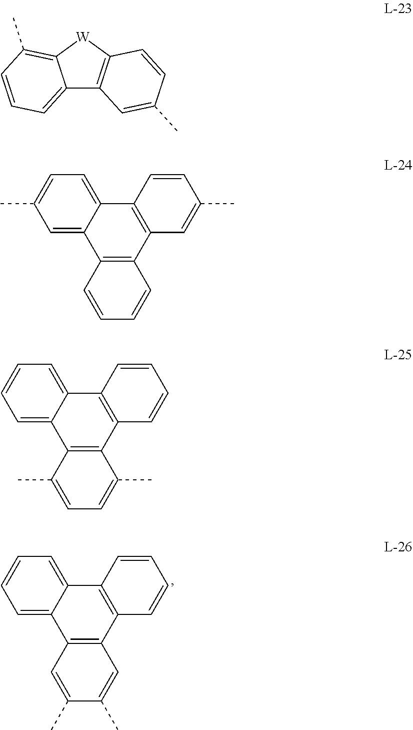

where the linkers L-1 to L-26 may also be substituted by one or more substituents R;
W is O, S or C(CH₃)₂; preferably O or S;
a is 0 or 1;
b is 0 or 1;
R is selected on each occurrence, identically or differently, from the group consisting of CN, a straight-chain alkyl, alkoxy or thioalkyl group having 1 to 20 C atoms or a branched or cyclic alkyl, alkoxy or thioalkyl group having 3 to 20 C atoms, an aromatic or heteroaromatic ring system having 5 to 40 aromatic ring atoms, an aryloxy or heteroaryloxy group having 5 to 40 aromatic ring atoms, or an aralkyl or heteroaralkyl group having 5 to 40 aromatic ring atoms;
Ar₁ is on each occurrence, in each case independently of one another, an aryl or heteroaryl group having 5 to 40 aromatic ring atoms, which may be substituted by one or more radicals R;
K, M are in each case, independently of one another, an aromatic ring system having 6 to 40 aromatic ring atoms which is unsubstituted or partially or fully deuterated or monosubstituted by R*, if x and y denote 0 and if x₁ and y₁ denote 0, or
K, M in each case, independently of one another, together with X or X¹, form a heteroaromatic ring system having 14 to 40 ring atoms as soon as the value of x, x1, y and/or y1 denotes 1;
x, x1 are in each case, independently on each occurrence, 0 or 1;
y, y1 are in each case, independently on each occurrence, 0 or 1;
X and X¹ are in each case, independently of one another on each occurrence, a bond or C(R#)₂;
R⁰ is on each occurrence, independently of one another, an unsubstituted or partially or fully deuterated aromatic ring system having 6 to 18 C atoms;
R* is dibenzofuranyl or dibenzothiophenyl;
R# is on each occurrence, independently of one another, a straight-chain or branched alkyl group having 1 to 4 C atoms; and
c, d, e and f are, independently of one another, 0 or 1.

The statements regarding the host materials of the formulae (1) and (2) and their preferred embodiments and their combination also apply correspondingly to the mixture according to the invention.

Particularly preferred mixtures of the host materials of the formula (1) with the host materials of the formula (2) for the device according to the invention are obtained by combination of compounds 1 to 11 and 29 to 44 with the compounds from Table 2.

Very particularly preferred mixtures of the host materials of the formula (1) with the host materials of the formula (2) for the device according to the invention are obtained by combination of compounds 1 to 11 and 29 to 44 with compounds 12 to 27 and 45 to 52 as shown below in Table 3.

TABLE 3

| | | | | | | | | |
|---|---|---|---|---|---|---|---|---|
| M1 | 1 | 12 | M2 | 2 | 12 | M3 | 3 | 12 |
| M4 | 4 | 12 | M5 | 5 | 12 | M6 | 6 | 12 |
| M7 | 7 | 12 | M8 | 8 | 12 | M9 | 9 | 12 |
| M10 | 10 | 12 | M11 | 11 | 12 | M12 | 29 | 12 |
| M13 | 30 | 12 | M14 | 31 | 12 | M15 | 32 | 12 |
| M16 | 33 | 12 | M17 | 34 | 12 | M18 | 35 | 12 |
| M19 | 36 | 12 | M20 | 37 | 12 | M21 | 38 | 12 |
| M22 | 39 | 12 | M23 | 40 | 12 | M24 | 41 | 12 |
| M25 | 42 | 12 | M26 | 43 | 12 | M27 | 44 | 12 |
| M28 | 1 | 13 | M29 | 2 | 13 | M30 | 3 | 13 |
| M31 | 4 | 13 | M32 | 5 | 13 | M33 | 6 | 13 |
| M34 | 7 | 13 | M35 | 8 | 13 | M36 | 9 | 13 |
| M37 | 10 | 13 | M38 | 11 | 13 | M39 | 29 | 13 |
| M40 | 30 | 13 | M41 | 31 | 13 | M42 | 32 | 13 |
| M43 | 33 | 13 | M44 | 34 | 13 | M45 | 35 | 13 |
| M46 | 36 | 13 | M47 | 37 | 13 | M48 | 38 | 13 |
| M49 | 39 | 13 | M50 | 40 | 13 | M51 | 41 | 13 |
| M52 | 42 | 13 | M53 | 43 | 13 | M54 | 44 | 13 |
| M55 | 1 | 14 | M56 | 2 | 14 | M57 | 3 | 14 |
| M58 | 4 | 14 | M59 | 5 | 14 | M60 | 6 | 14 |
| M61 | 7 | 14 | M62 | 8 | 14 | M63 | 9 | 14 |
| M64 | 10 | 14 | M65 | 11 | 14 | M66 | 29 | 14 |
| M67 | 30 | 14 | M68 | 31 | 14 | M69 | 32 | 14 |
| M70 | 33 | 14 | M71 | 34 | 14 | M72 | 35 | 14 |
| M73 | 36 | 14 | M74 | 37 | 14 | M75 | 38 | 14 |
| M76 | 39 | 14 | M77 | 40 | 14 | M78 | 41 | 14 |
| M79 | 42 | 14 | M80 | 43 | 14 | M81 | 44 | 14 |
| M82 | 1 | 15 | M83 | 2 | 15 | M84 | 3 | 15 |
| M85 | 4 | 15 | M86 | 5 | 15 | M87 | 6 | 15 |
| M88 | 7 | 15 | M89 | 8 | 15 | M90 | 9 | 15 |
| M91 | 10 | 15 | M92 | 11 | 15 | M93 | 29 | 15 |
| M94 | 30 | 15 | M95 | 31 | 15 | M96 | 32 | 15 |
| M97 | 33 | 15 | M98 | 34 | 15 | M99 | 35 | 15 |
| M100 | 36 | 15 | M101 | 37 | 15 | M102 | 38 | 15 |
| M103 | 39 | 15 | M104 | 40 | 15 | M105 | 41 | 15 |
| M106 | 42 | 15 | M107 | 43 | 15 | M108 | 44 | 15 |
| M109 | 1 | 16 | M110 | 2 | 16 | M111 | 3 | 16 |
| M112 | 4 | 16 | M113 | 5 | 16 | M114 | 6 | 16 |
| M115 | 7 | 16 | M116 | 8 | 16 | M117 | 9 | 16 |
| M118 | 10 | 16 | M119 | 11 | 16 | M120 | 29 | 16 |
| M121 | 30 | 16 | M122 | 31 | 16 | M123 | 32 | 16 |
| M124 | 33 | 16 | M125 | 34 | 16 | M126 | 35 | 16 |
| M127 | 36 | 16 | M128 | 37 | 16 | M129 | 38 | 16 |
| M130 | 39 | 16 | M131 | 40 | 16 | M132 | 41 | 16 |
| M133 | 42 | 16 | M134 | 43 | 16 | M135 | 44 | 16 |
| M136 | 1 | 17 | M137 | 2 | 17 | M138 | 3 | 17 |
| M139 | 4 | 17 | M140 | 5 | 17 | M141 | 6 | 17 |
| M142 | 7 | 17 | M143 | 8 | 17 | M144 | 9 | 17 |
| M145 | 10 | 17 | M146 | 11 | 17 | M147 | 29 | 17 |
| M148 | 30 | 17 | M149 | 31 | 17 | M150 | 32 | 17 |
| M151 | 33 | 17 | M152 | 34 | 17 | M153 | 35 | 17 |
| M154 | 36 | 17 | M155 | 37 | 17 | M156 | 38 | 17 |
| M157 | 39 | 17 | M158 | 40 | 17 | M159 | 41 | 17 |
| M160 | 42 | 17 | M161 | 43 | 17 | M162 | 44 | 17 |
| M163 | 1 | 18 | M164 | 2 | 18 | M165 | 3 | 18 |
| M166 | 4 | 18 | M167 | 5 | 18 | M168 | 6 | 18 |
| M169 | 7 | 18 | M170 | 8 | 18 | M171 | 9 | 18 |
| M172 | 10 | 18 | M173 | 11 | 18 | M174 | 29 | 18 |
| M175 | 30 | 18 | M176 | 31 | 18 | M177 | 32 | 18 |
| M178 | 33 | 18 | M179 | 34 | 18 | M180 | 35 | 18 |
| M181 | 36 | 18 | M182 | 37 | 18 | M183 | 38 | 18 |
| M184 | 39 | 18 | M185 | 40 | 18 | M186 | 41 | 18 |
| M187 | 42 | 18 | M188 | 43 | 18 | M189 | 44 | 18 |
| M190 | 1 | 19 | M191 | 2 | 19 | M192 | 3 | 19 |
| M193 | 4 | 19 | M194 | 5 | 19 | M195 | 6 | 19 |
| M196 | 7 | 19 | M197 | 8 | 19 | M198 | 9 | 19 |
| M199 | 10 | 19 | M200 | 11 | 19 | M201 | 29 | 19 |
| M202 | 30 | 19 | M203 | 31 | 19 | M204 | 32 | 19 |
| M205 | 33 | 19 | M206 | 34 | 19 | M207 | 35 | 19 |
| M208 | 36 | 19 | M209 | 37 | 19 | M210 | 38 | 19 |
| M211 | 39 | 19 | M212 | 40 | 19 | M213 | 41 | 19 |
| M214 | 42 | 19 | M215 | 43 | 19 | M216 | 44 | 19 |
| M217 | 1 | 20 | M218 | 2 | 20 | M219 | 3 | 20 |
| M220 | 4 | 20 | M221 | 5 | 20 | M222 | 6 | 20 |
| M223 | 7 | 20 | M224 | 8 | 20 | M225 | 9 | 20 |
| M226 | 10 | 20 | M227 | 11 | 20 | M228 | 29 | 20 |
| M229 | 30 | 20 | M230 | 31 | 20 | M231 | 32 | 20 |
| M232 | 33 | 20 | M233 | 34 | 20 | M234 | 35 | 20 |
| M235 | 36 | 20 | M236 | 37 | 20 | M237 | 38 | 20 |
| M238 | 39 | 20 | M239 | 40 | 20 | M240 | 41 | 20 |
| M241 | 42 | 20 | M242 | 43 | 20 | M243 | 44 | 20 |
| M244 | 1 | 21 | M245 | 2 | 21 | M246 | 3 | 21 |
| M247 | 4 | 21 | M248 | 5 | 21 | M249 | 6 | 21 |
| M250 | 7 | 21 | M251 | 8 | 21 | M252 | 9 | 21 |
| M253 | 10 | 21 | M254 | 11 | 21 | M255 | 29 | 21 |
| M256 | 30 | 21 | M257 | 31 | 21 | M258 | 32 | 21 |
| M259 | 33 | 21 | M260 | 34 | 21 | M261 | 35 | 21 |
| M262 | 36 | 21 | M263 | 37 | 21 | M264 | 38 | 21 |
| M265 | 39 | 21 | M266 | 40 | 21 | M267 | 41 | 21 |
| M268 | 42 | 21 | M269 | 43 | 21 | M270 | 44 | 21 |
| M271 | 1 | 22 | M272 | 2 | 22 | M273 | 3 | 22 |
| M274 | 4 | 22 | M275 | 5 | 22 | M276 | 6 | 22 |
| M277 | 7 | 22 | M278 | 8 | 22 | M279 | 9 | 22 |
| M280 | 10 | 22 | M281 | 11 | 22 | M282 | 29 | 22 |
| M283 | 30 | 22 | M284 | 31 | 22 | M285 | 32 | 22 |
| M286 | 33 | 22 | M287 | 34 | 22 | M288 | 35 | 22 |
| M289 | 36 | 22 | M290 | 37 | 22 | M291 | 38 | 22 |
| M292 | 39 | 22 | M293 | 40 | 22 | M294 | 41 | 22 |
| M295 | 42 | 22 | M296 | 43 | 22 | M297 | 44 | 22 |
| M298 | 1 | 23 | M299 | 2 | 23 | M300 | 3 | 23 |
| M301 | 4 | 23 | M302 | 5 | 23 | M303 | 6 | 23 |
| M304 | 7 | 23 | M305 | 8 | 23 | M306 | 9 | 23 |
| M307 | 10 | 23 | M308 | 11 | 23 | M309 | 29 | 23 |
| M310 | 30 | 23 | M311 | 31 | 23 | M312 | 32 | 23 |
| M313 | 33 | 23 | M314 | 34 | 23 | M315 | 35 | 23 |
| M316 | 36 | 23 | M317 | 37 | 23 | M318 | 38 | 23 |
| M319 | 39 | 23 | M320 | 40 | 23 | M321 | 41 | 23 |
| M322 | 42 | 23 | M323 | 43 | 23 | M324 | 44 | 23 |
| M325 | 1 | 24 | M326 | 2 | 24 | M327 | 3 | 24 |
| M328 | 4 | 24 | M329 | 5 | 24 | M330 | 6 | 24 |
| M331 | 7 | 24 | M332 | 8 | 24 | M333 | 9 | 24 |
| M334 | 10 | 24 | M335 | 11 | 24 | M336 | 29 | 24 |
| M337 | 30 | 24 | M338 | 31 | 24 | M339 | 32 | 24 |
| M340 | 33 | 24 | M341 | 34 | 24 | M342 | 35 | 24 |
| M343 | 36 | 24 | M344 | 37 | 24 | M345 | 38 | 24 |
| M346 | 39 | 24 | M347 | 40 | 24 | M348 | 41 | 24 |
| M349 | 42 | 24 | M350 | 43 | 24 | M351 | 44 | 24 |
| M352 | 1 | 25 | M353 | 2 | 25 | M354 | 3 | 25 |
| M355 | 4 | 25 | M356 | 5 | 25 | M357 | 6 | 25 |
| M358 | 7 | 25 | M359 | 8 | 25 | M360 | 9 | 25 |
| M361 | 10 | 25 | M362 | 11 | 25 | M363 | 29 | 25 |
| M364 | 30 | 25 | M365 | 31 | 25 | M366 | 32 | 25 |
| M367 | 33 | 25 | M368 | 34 | 25 | M369 | 35 | 25 |
| M370 | 36 | 25 | M371 | 37 | 25 | M372 | 38 | 25 |
| M373 | 39 | 25 | M374 | 40 | 25 | M375 | 41 | 25 |
| M376 | 42 | 25 | M377 | 43 | 25 | M378 | 44 | 25 |
| M379 | 1 | 26 | M380 | 2 | 26 | M381 | 3 | 26 |
| M382 | 4 | 26 | M383 | 5 | 26 | M384 | 6 | 26 |
| M385 | 7 | 26 | M386 | 8 | 26 | M387 | 9 | 26 |
| M388 | 10 | 26 | M389 | 11 | 26 | M390 | 29 | 26 |
| M391 | 30 | 26 | M392 | 31 | 26 | M393 | 32 | 26 |
| M394 | 33 | 26 | M395 | 34 | 26 | M396 | 35 | 26 |
| M397 | 36 | 26 | M398 | 37 | 26 | M399 | 38 | 26 |
| M400 | 39 | 26 | M401 | 40 | 26 | M402 | 41 | 26 |
| M403 | 42 | 26 | M404 | 43 | 26 | M405 | 44 | 26 |
| M406 | 1 | 27 | M407 | 2 | 27 | M408 | 3 | 27 |
| M409 | 4 | 27 | M410 | 5 | 27 | M411 | 6 | 27 |
| M412 | 7 | 27 | M413 | 8 | 27 | M414 | 9 | 27 |
| M415 | 10 | 27 | M416 | 11 | 27 | M417 | 29 | 27 |
| M418 | 30 | 27 | M419 | 31 | 27 | M420 | 32 | 27 |
| M421 | 33 | 27 | M422 | 34 | 27 | M423 | 35 | 27 |
| M424 | 36 | 27 | M425 | 37 | 27 | M426 | 38 | 27 |
| M427 | 39 | 27 | M428 | 40 | 27 | M429 | 41 | 27 |
| M430 | 42 | 27 | M431 | 43 | 27 | M432 | 44 | 27 |
| M433 | 1 | 45 | M434 | 2 | 45 | M435 | 3 | 45 |
| M436 | 4 | 45 | M437 | 5 | 45 | M438 | 6 | 45 |
| M439 | 7 | 45 | M440 | 8 | 45 | M441 | 9 | 45 |
| M442 | 10 | 45 | M443 | 11 | 45 | M444 | 29 | 45 |
| M445 | 30 | 45 | M446 | 31 | 45 | M447 | 32 | 45 |
| M448 | 33 | 45 | M449 | 34 | 45 | M450 | 35 | 45 |
| M451 | 36 | 45 | M452 | 37 | 45 | M453 | 38 | 45 |
| M454 | 39 | 45 | M455 | 40 | 45 | M456 | 41 | 45 |
| M457 | 42 | 45 | M458 | 43 | 45 | M459 | 44 | 45 |
| M460 | 1 | 46 | M461 | 2 | 46 | M462 | 3 | 46 |
| M463 | 4 | 46 | M464 | 5 | 46 | M465 | 6 | 46 |
| M466 | 7 | 46 | M467 | 8 | 46 | M468 | 9 | 46 |
| M469 | 10 | 46 | M470 | 11 | 46 | M471 | 29 | 46 |
| M472 | 30 | 46 | M473 | 31 | 46 | M474 | 32 | 46 |
| M475 | 33 | 46 | M476 | 34 | 46 | M477 | 35 | 46 |
| M478 | 36 | 46 | M479 | 37 | 46 | M480 | 38 | 46 |
| M481 | 39 | 46 | M482 | 40 | 46 | M483 | 41 | 46 |
| M484 | 42 | 46 | M485 | 43 | 46 | M486 | 44 | 46 |
| M487 | 1 | 47 | M488 | 2 | 47 | M489 | 3 | 47 |
| M490 | 4 | 47 | M491 | 5 | 47 | M492 | 6 | 47 |
| M493 | 7 | 47 | M494 | 8 | 47 | M495 | 9 | 47 |
| M496 | 10 | 47 | M497 | 11 | 47 | M498 | 29 | 47 |
| M499 | 30 | 47 | M500 | 31 | 47 | M501 | 32 | 47 |
| M502 | 33 | 47 | M503 | 34 | 47 | M504 | 35 | 47 |
| M505 | 36 | 47 | M506 | 37 | 47 | M507 | 38 | 47 |
| M508 | 39 | 47 | M509 | 40 | 47 | M510 | 41 | 47 |
| M511 | 42 | 47 | M512 | 43 | 47 | M513 | 44 | 47 |
| M514 | 1 | 48 | M515 | 2 | 48 | M516 | 3 | 48 |
| M517 | 4 | 48 | M518 | 5 | 48 | M519 | 6 | 48 |
| M520 | 7 | 48 | M521 | 8 | 48 | M522 | 9 | 48 |
| M523 | 10 | 48 | M524 | 11 | 48 | M525 | 29 | 48 |
| M526 | 30 | 48 | M527 | 31 | 48 | M528 | 32 | 48 |
| M529 | 33 | 48 | M530 | 34 | 48 | M531 | 35 | 48 |
| M532 | 36 | 48 | M533 | 37 | 48 | M534 | 38 | 48 |
| M535 | 39 | 48 | M536 | 40 | 48 | M537 | 41 | 48 |
| M538 | 42 | 48 | M539 | 43 | 48 | M540 | 44 | 48 |
| M541 | 1 | 49 | M542 | 2 | 49 | M543 | 3 | 49 |
| M544 | 4 | 49 | M545 | 5 | 49 | M546 | 6 | 49 |
| M547 | 7 | 49 | M548 | 8 | 49 | M549 | 9 | 49 |
| M550 | 10 | 49 | M551 | 11 | 49 | M552 | 29 | 49 |
| M553 | 30 | 49 | M554 | 31 | 49 | M555 | 32 | 49 |
| M556 | 33 | 49 | M557 | 34 | 49 | M558 | 35 | 49 |
| M559 | 36 | 49 | M560 | 37 | 49 | M561 | 38 | 49 |
| M562 | 39 | 49 | M563 | 40 | 49 | M564 | 41 | 49 |
| M565 | 42 | 49 | M566 | 43 | 49 | M567 | 44 | 49 |
| M568 | 1 | 50 | M569 | 2 | 50 | M570 | 3 | 50 |
| M571 | 4 | 50 | M572 | 5 | 50 | M573 | 6 | 50 |
| M574 | 7 | 50 | M575 | 8 | 50 | M576 | 9 | 50 |
| M577 | 10 | 50 | M578 | 11 | 50 | M579 | 29 | 50 |
| M580 | 30 | 50 | M581 | 31 | 50 | M582 | 32 | 50 |
| M583 | 33 | 50 | M584 | 34 | 50 | M585 | 35 | 50 |
| M586 | 36 | 50 | M587 | 37 | 50 | M588 | 38 | 50 |
| M589 | 39 | 50 | M590 | 40 | 50 | M591 | 41 | 50 |
| M592 | 42 | 50 | M593 | 43 | 50 | M594 | 44 | 50 |
| M595 | 1 | 51 | M596 | 2 | 51 | M597 | 3 | 51 |
| M598 | 4 | 51 | M599 | 5 | 51 | M600 | 6 | 51 |
| M601 | 7 | 51 | M602 | 8 | 51 | M603 | 9 | 51 |
| M604 | 10 | 51 | M605 | 11 | 51 | M606 | 29 | 51 |
| M607 | 30 | 51 | M608 | 31 | 51 | M609 | 32 | 51 |
| M610 | 33 | 51 | M611 | 34 | 51 | M612 | 35 | 51 |
| M613 | 36 | 51 | M614 | 37 | 51 | M615 | 38 | 51 |
| M616 | 39 | 51 | M617 | 40 | 51 | M618 | 41 | 51 |
| M619 | 42 | 51 | M620 | 43 | 51 | M621 | 44 | 51 |
| M622 | 1 | 52 | M623 | 2 | 52 | M624 | 3 | 52 |
| M625 | 4 | 52 | M626 | 5 | 52 | M627 | 6 | 52 |
| M628 | 7 | 52 | M629 | 8 | 52 | M630 | 9 | 52 |
| M631 | 10 | 52 | M632 | 11 | 52 | M633 | 29 | 52 |
| M634 | 30 | 52 | M635 | 31 | 52 | M636 | 32 | 52 |
| M637 | 33 | 52 | M638 | 34 | 52 | M639 | 35 | 52 |
| M640 | 36 | 52 | M641 | 37 | 52 | M642 | 38 | 52 |
| M643 | 39 | 52 | M644 | 40 | 52 | M645 | 41 | 52 |
| M646 | 42 | 52 | M647 | 43 | 52 | M648 | 44 | 52 |

The concentration of the electron-transporting host material of the formula (1), as described or preferably described above, in the mixture according to the invention or in the light-emitting layer of the device according to the invention is in the range from 5% by weight to 90% by weight, preferably in the range from 10% by weight to 85% by weight, more preferably in the range from 20% by weight to 85% by weight, still more preferably in the range from 30% by weight to 80% by weight, very particularly preferably in the range from 20% by weight to 60% by weight and most preferably in the range from 30% by weight to 50% by weight, based on the entire mixture or based on the entire composition of the light-emitting layer.

The concentration of the hole-transporting host material of the formula (2), as described above or as preferably described, in the mixture according to the invention or in the light-emitting layer of the device according to the invention is in the range from 10% by weight to 95% by weight, preferably in the range from 15% by weight to 90% by weight, more preferably in the range from 15% by weight to 80% by weight, still more preferably in the range from 20% by weight to 70% by weight, very particularly preferably in the range from 40% by weight to 80% by weight and most preferably in the range from 50% by weight to 70% by weight, based on the entire mixture or based on the entire composition of the light-emitting layer.

The present invention also relates to a mixture which, besides the above-mentioned host materials 1 and 2, as described or preferably described above, in particular mixtures M1 to M648, at least also comprises a phosphorescent emitter.

The present invention also relates to an organic electroluminescent device, as described or preferably described above, where the light-emitting layer, besides the above-mentioned host materials 1 and 2, as described or preferably described above, in particular material combinations M1 to M648, at least also comprises a phosphorescent emitter.

The term phosphorescent emitter typically encompasses compounds in which the light emission takes place through a spin-forbidden transition from an excited state having higher spin multiplicity, i.e. a spin state >1, for example through a transition from a triplet state or a state having an even higher spin quantum number, for example a quintet state. This is preferably taken to mean a transition from a triplet state.

Suitable phosphorescent emitters (=triplet emitters) are, in particular, compounds which emit light, preferably in the visible region, on suitable excitation and in addition contain at least one atom having an atomic number greater than 20, preferably greater than 38 and less than 84, particularly preferably greater than 56 and less than 80, in particular a metal having this atomic number. The phosphorescent emitters used are preferably compounds which contain copper, molybdenum, tungsten, rhenium, ruthenium, osmium, rhodium, iridium, palladium, platinum, silver, gold or europium, in particular compounds which contain iridium or platinum. For the purposes of the present invention, all luminescent compounds which contain the above-mentioned metals are regarded as phosphorescent emitters.

In general, all phosphorescent complexes as are used in accordance with the prior art for phosphorescent OLEDs and as are known to the person skilled in the art in the area of organic electroluminescent devices are suitable.

Examples of the emitters described above are revealed by the applications WO 2016/015815, WO 00/70655, WO 2001/41512, WO 2002/02714, WO2002/15645, EP 1191613, EP 1191612, EP 1191614, WO 05/033244, WO 05/019373, US 2005/0258742, WO 2009/146770, WO 2010/015307, WO 2010/031485, WO 2010/054731, WO 2010/054728, WO 2010/086089, WO 2010/099852, WO 2010/102709, WO 2011/032626, WO 2011/066898, WO 2011/157339, WO 2012/007086, WO 2014/008982, WO 2014/023377, WO 2014/094961, WO 2014/094960, WO 2015/036074, WO 2015/104045, WO 2015/117718, WO 2016/015815, WO 2016/124304, WO 2017/032439, WO 2015/036074, WO 2015/117718 and WO 2016/015815.

Preferred phosphorescent emitters in accordance with the present invention conform to the formula (3),

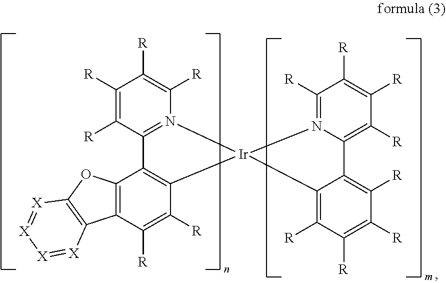

where the symbols and indices for this formula (3) have the meaning:
n+m is 3, n is 1 or 2, m is 2 or 1,

### X is N or CR,

R is H, D or a branched or linear alkyl group having 1 to 10 C atoms or a partially or fully deuterated branched or linear alkyl group having 1 to 10 C atoms or a cycloalkyl group having 4 to 7 C atoms, which may be partially or fully substituted by deuterium.

Accordingly, the invention furthermore relates to an organic electroluminescent device, as described or preferably described above, characterised in that the light-emitting layer, besides host materials 1 and 2, comprises at least one phosphorescent emitter which conforms to the formula (3), as described above.

In emitters of the formula (3), n is preferably 1 and m is preferably 2.

In emitters of the formula (3), preferably one X is selected from N and the other X denote CR.

In emitters of the formula (3), at least one R is preferably other than H. In emitters of the formula (3), preferably two R are other than H and have one of the meanings otherwise indicated above for the emitters of the formula (3).

Preferred examples of phosphorescent emitters are shown in Table 4 below.

TABLE 4

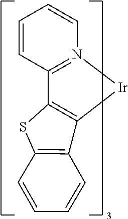

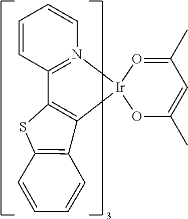

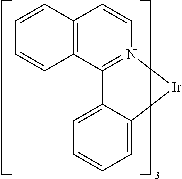

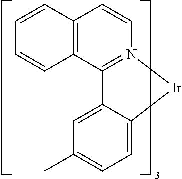

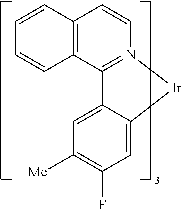

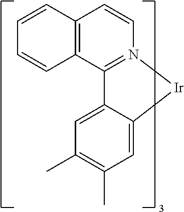

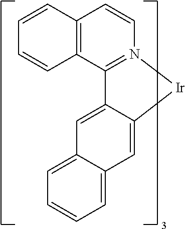

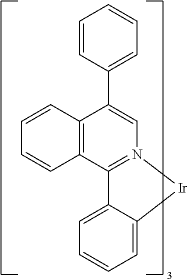

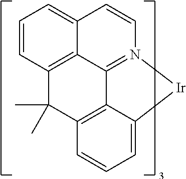

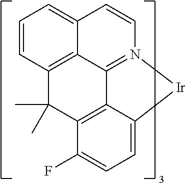

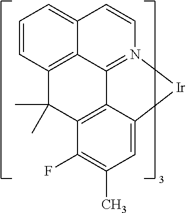

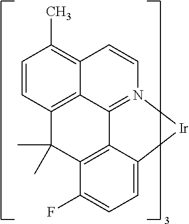

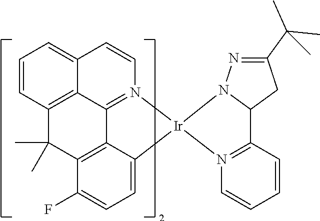

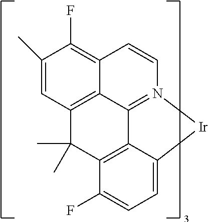

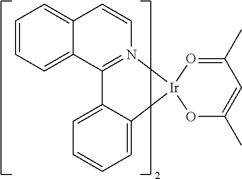

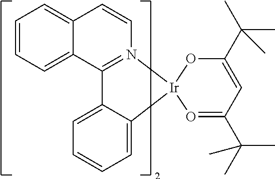

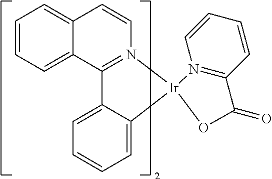

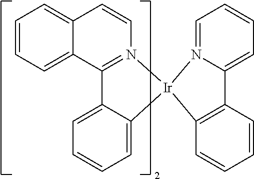

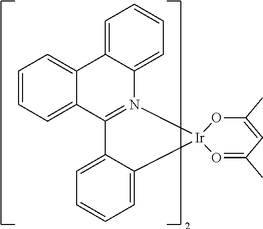

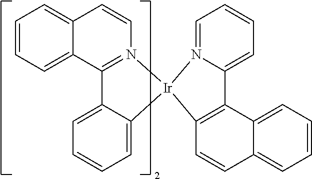

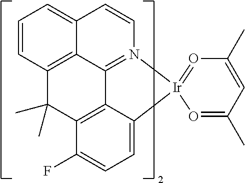

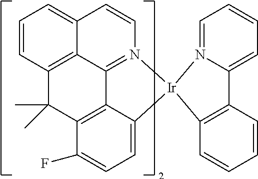

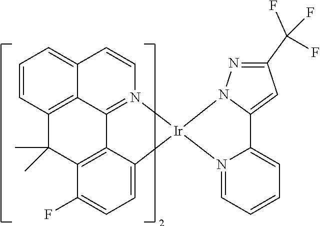

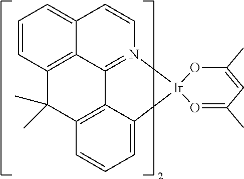

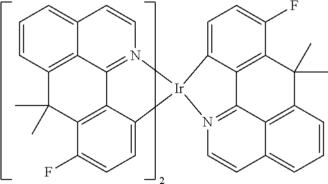

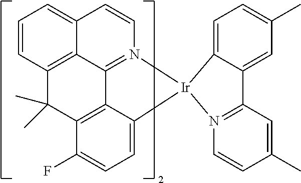

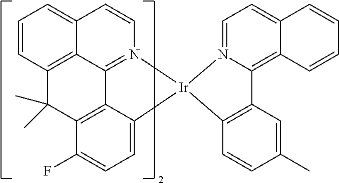

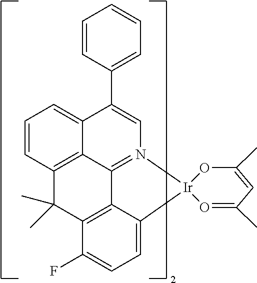

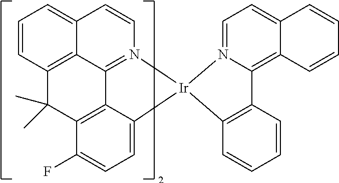

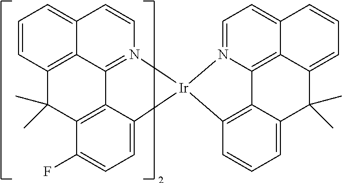

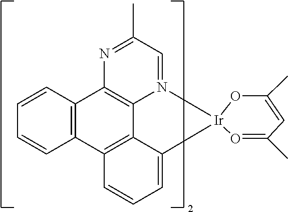

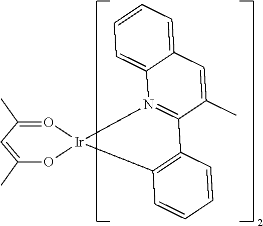

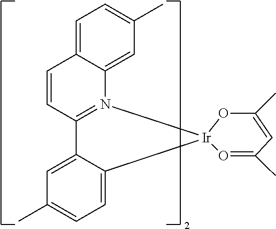

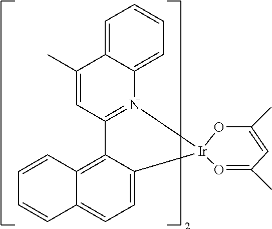

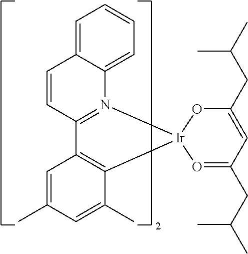

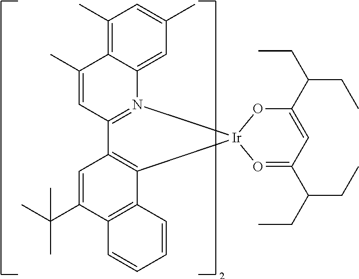

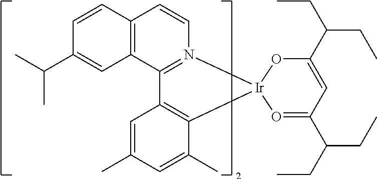

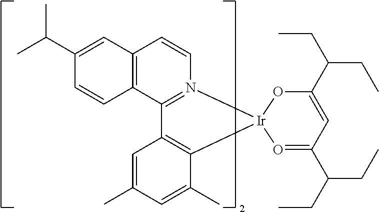

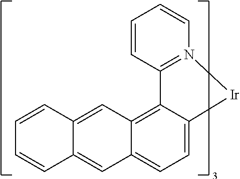

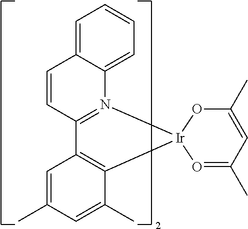

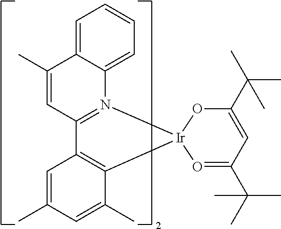

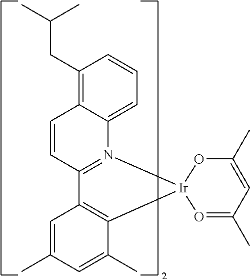

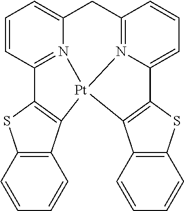

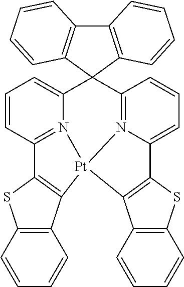

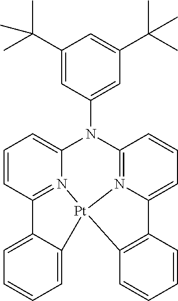

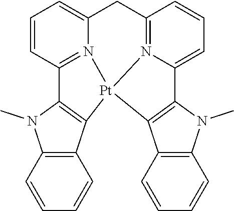

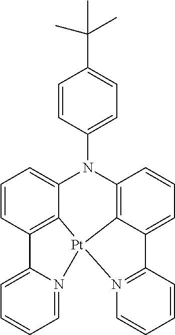

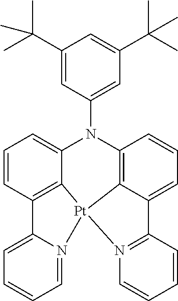

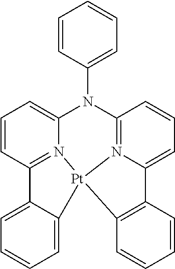

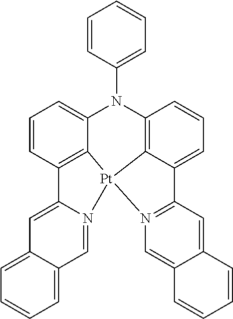

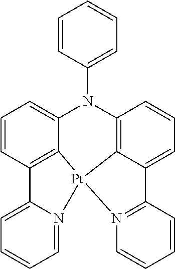

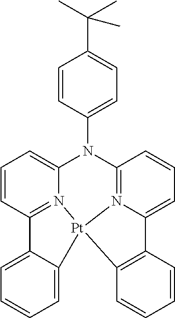

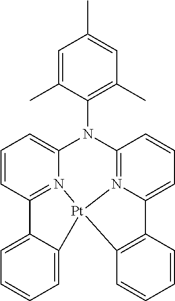

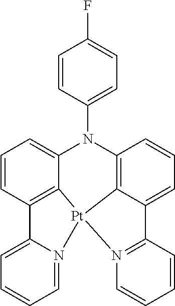

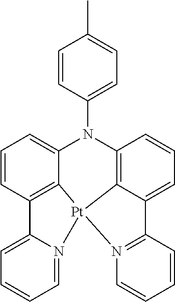

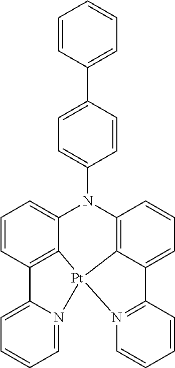

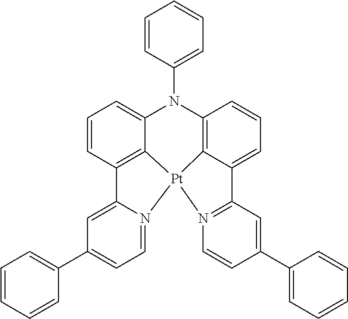

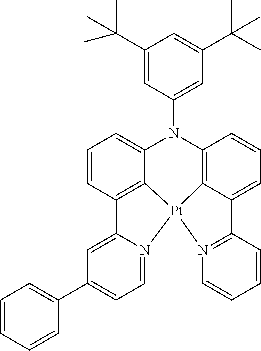

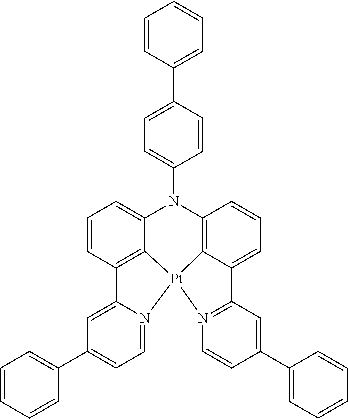

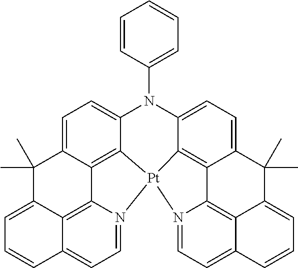

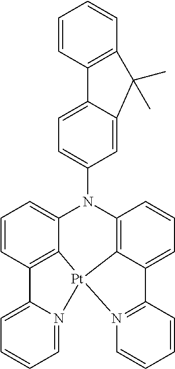

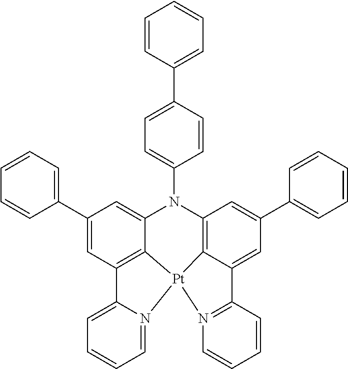

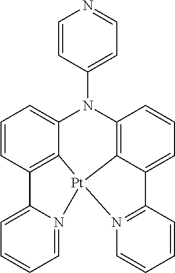

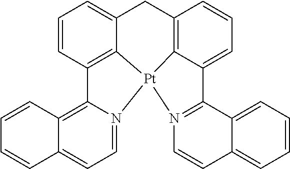

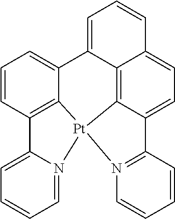

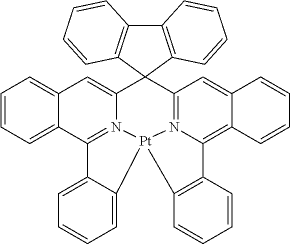

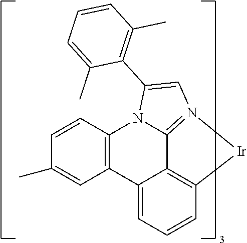

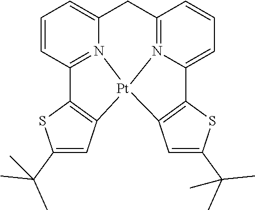

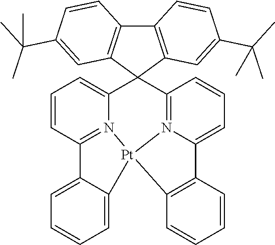

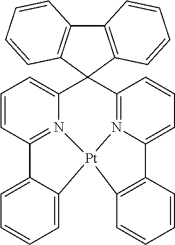

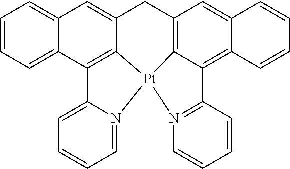

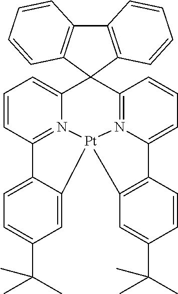

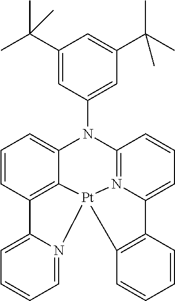

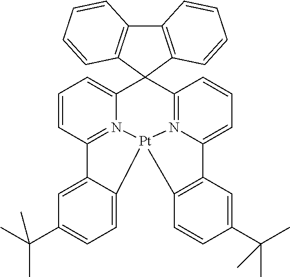

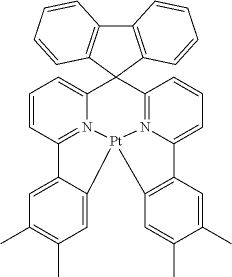

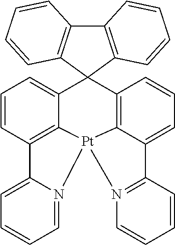

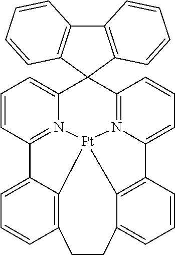

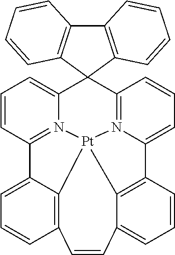

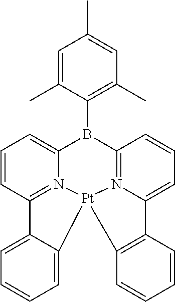

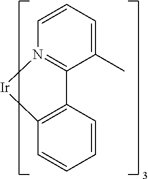

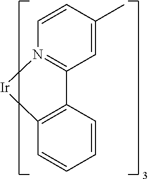

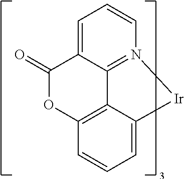

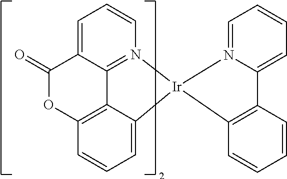

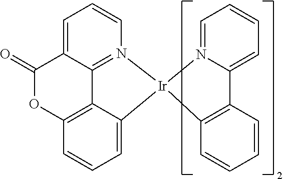

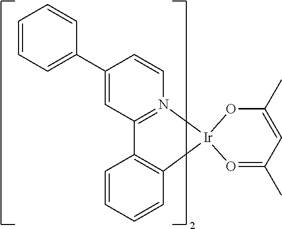

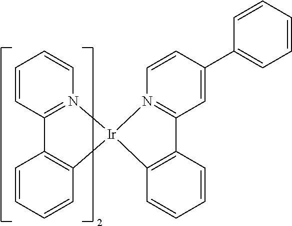

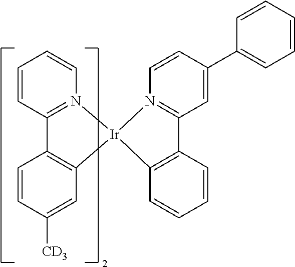

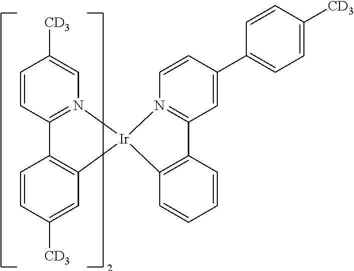

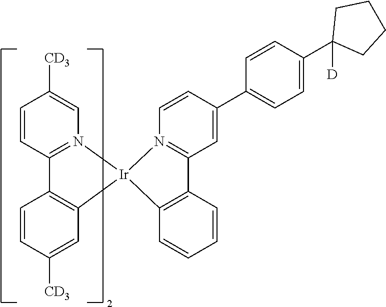

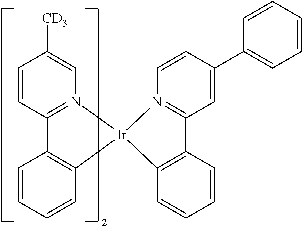

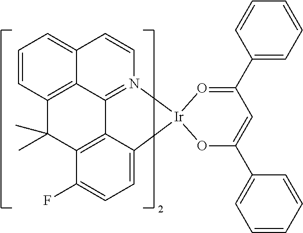

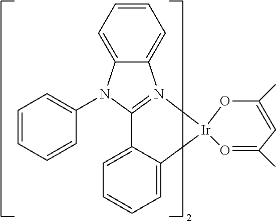

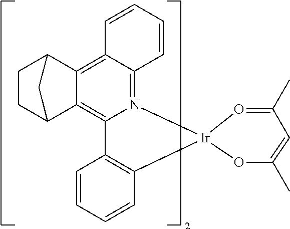

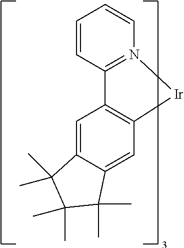

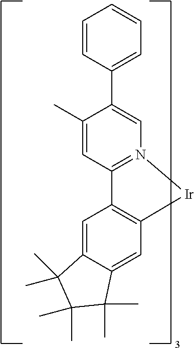

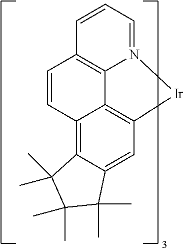

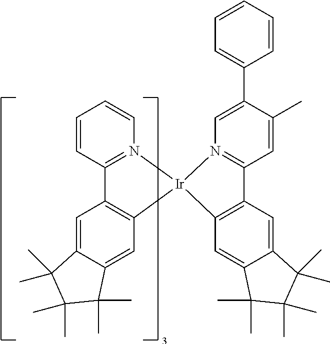

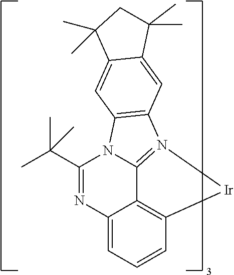

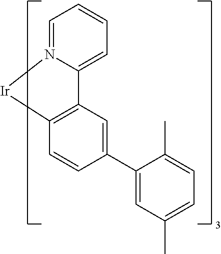

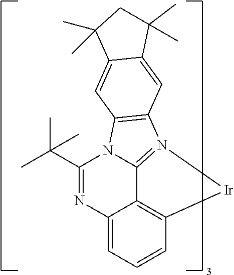

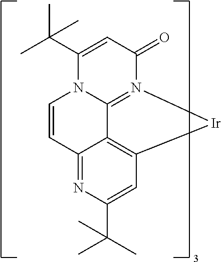

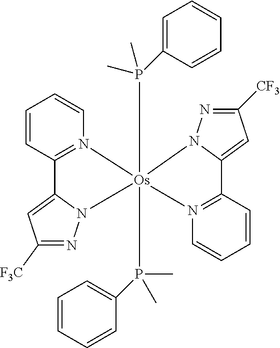

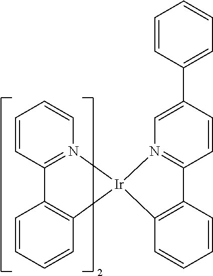

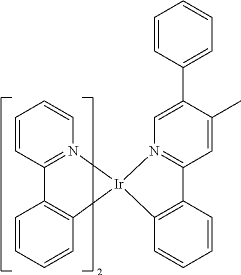

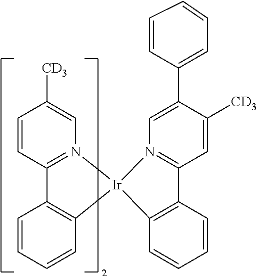

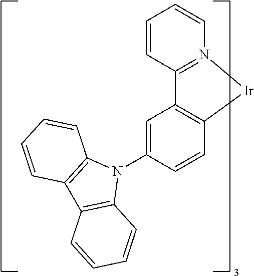

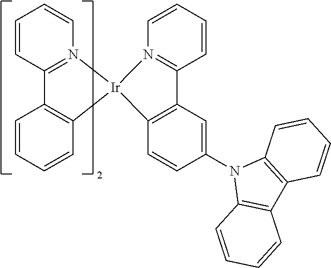

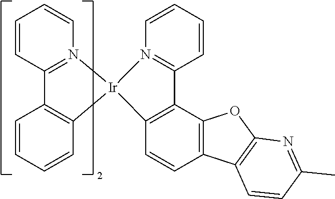

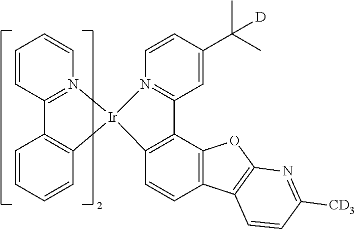

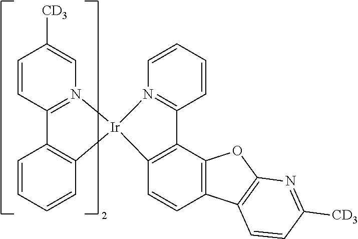

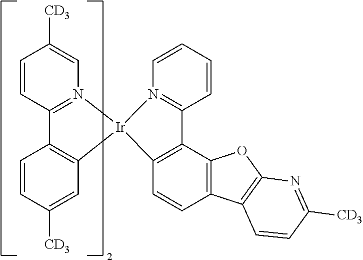

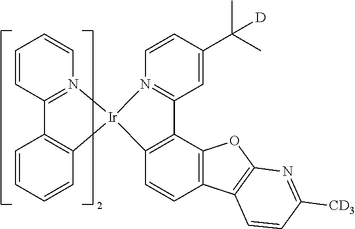

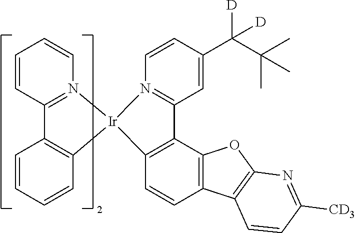

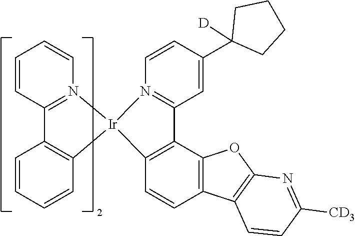

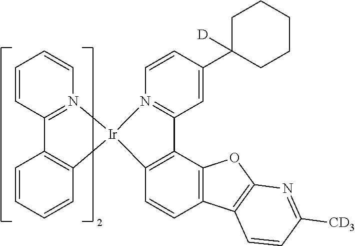

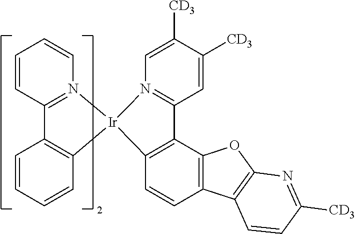

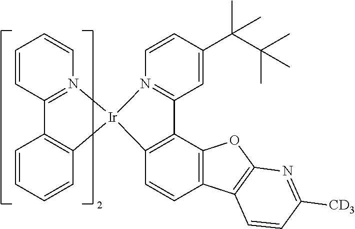

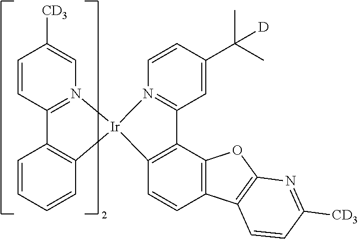

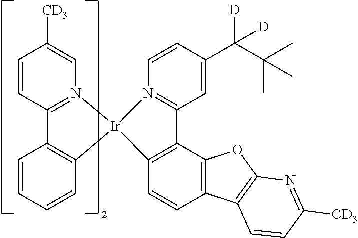

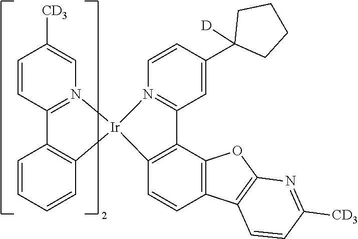

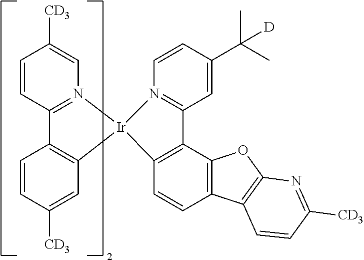

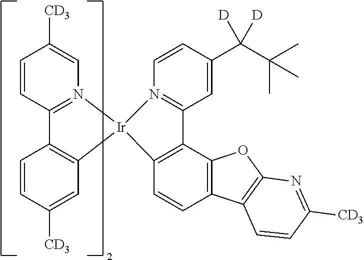

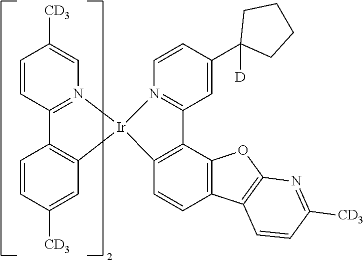

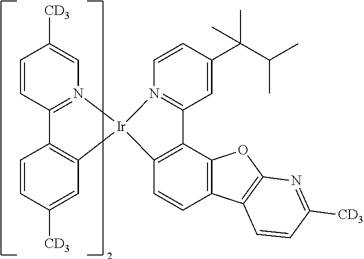

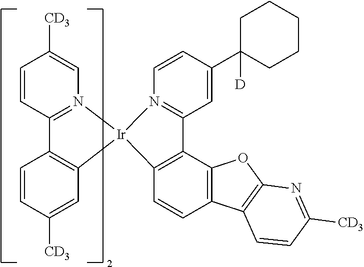

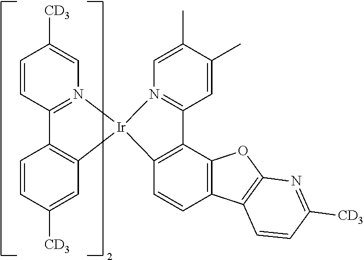

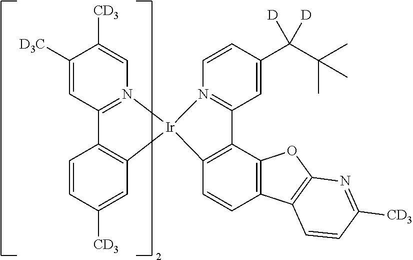

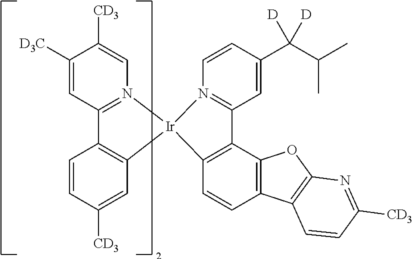

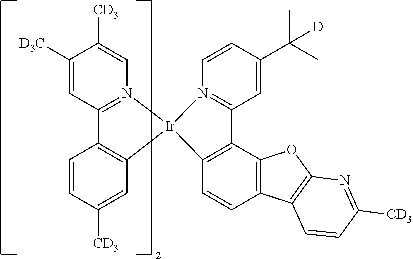

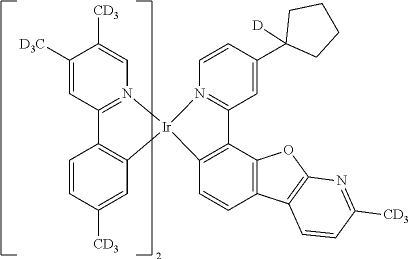

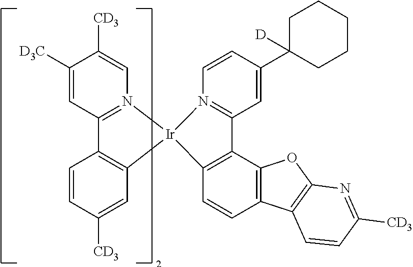

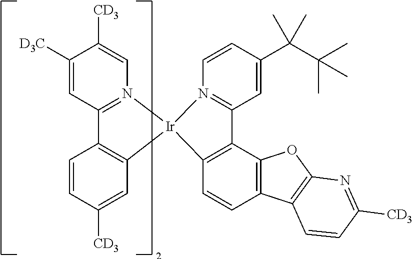

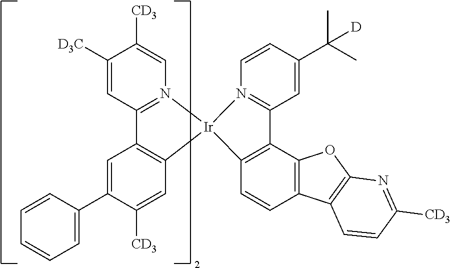

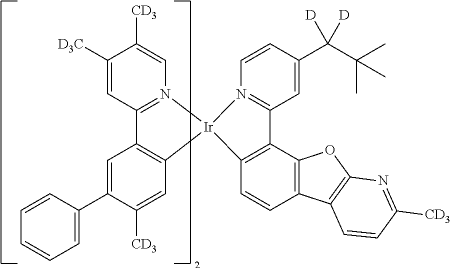

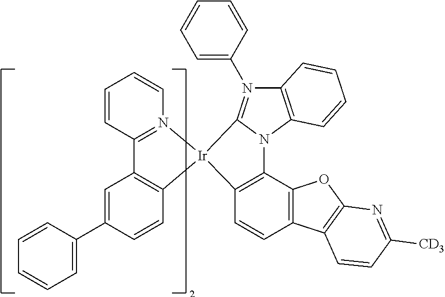

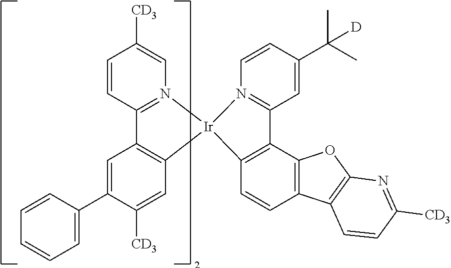

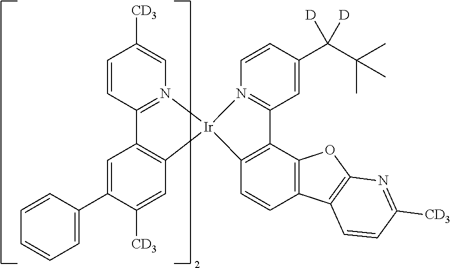

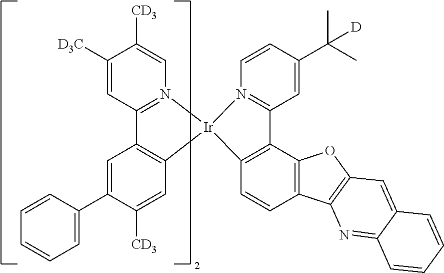

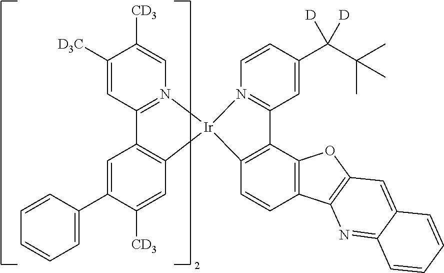

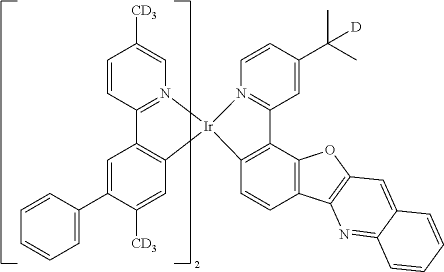

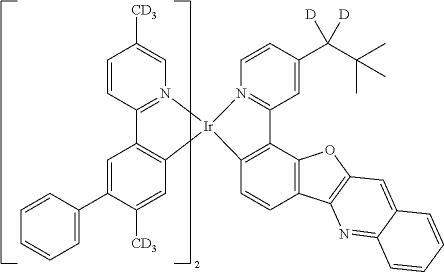

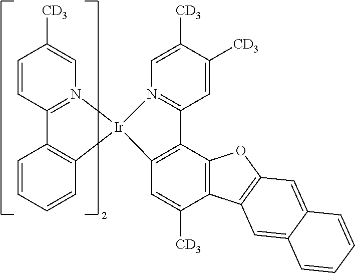

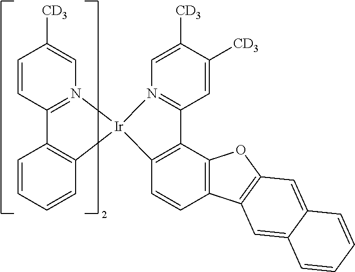

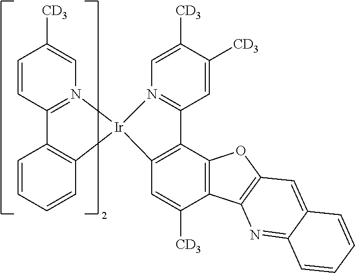

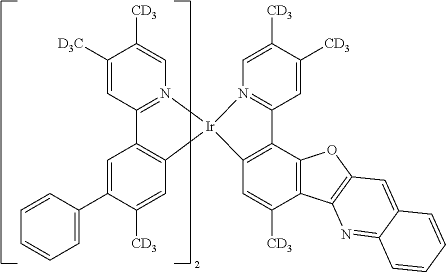

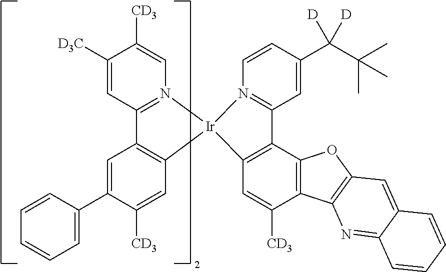

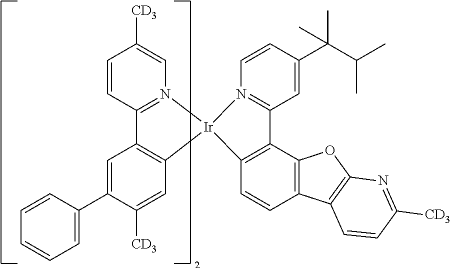

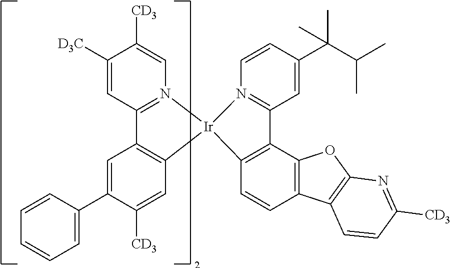

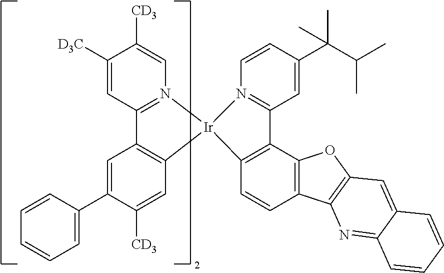

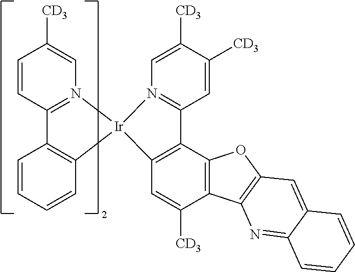

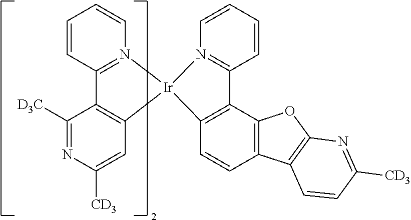

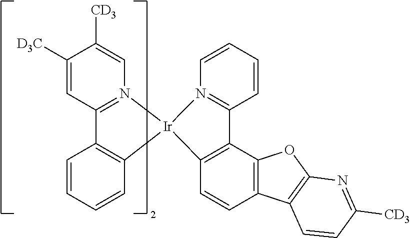

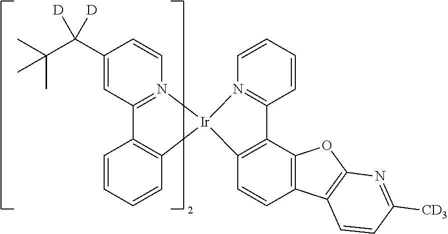

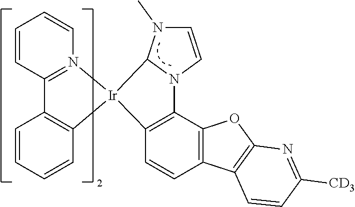

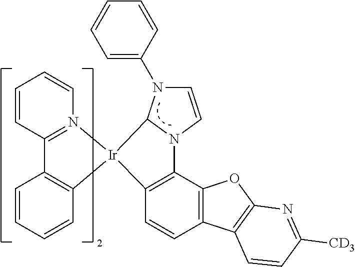

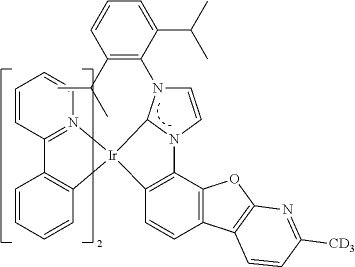

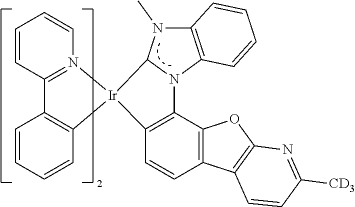

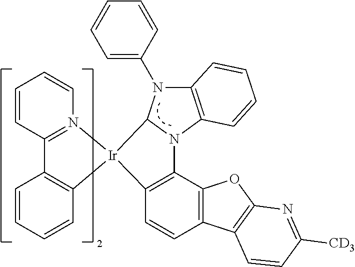

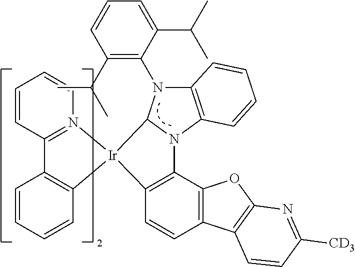

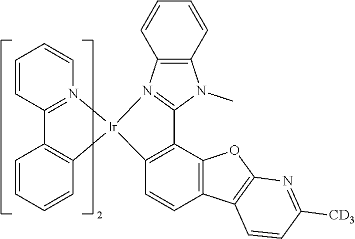

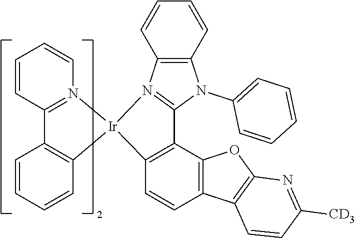

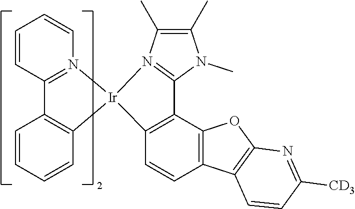

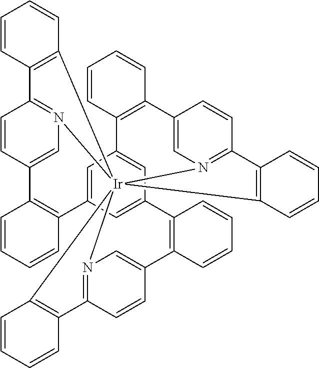

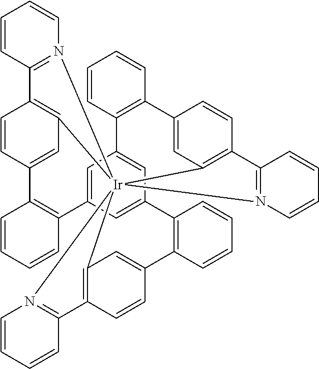

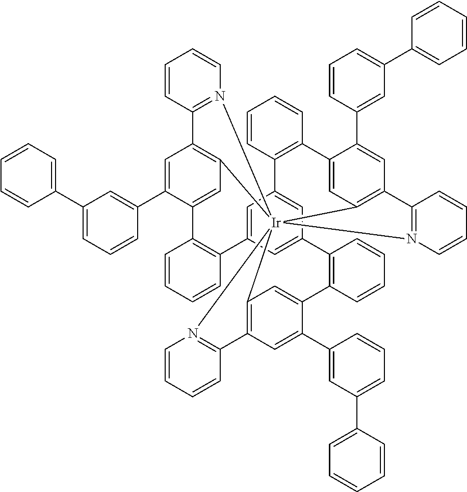

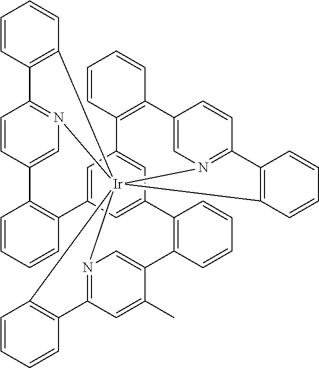

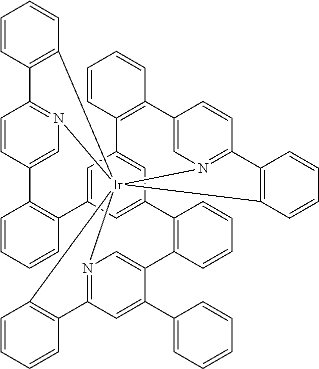

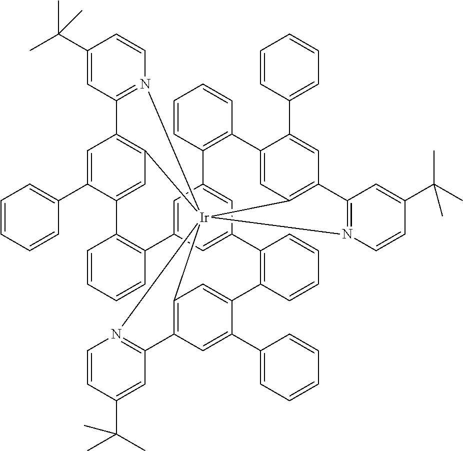

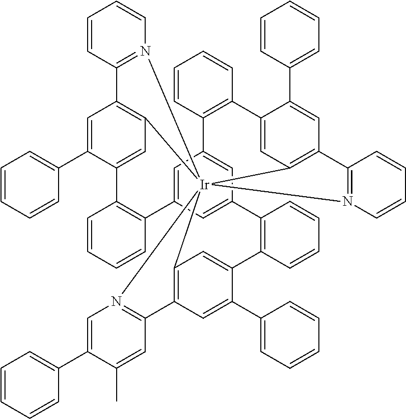

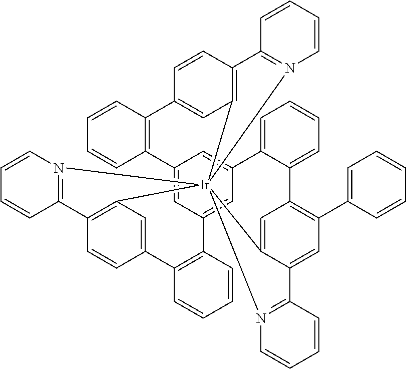

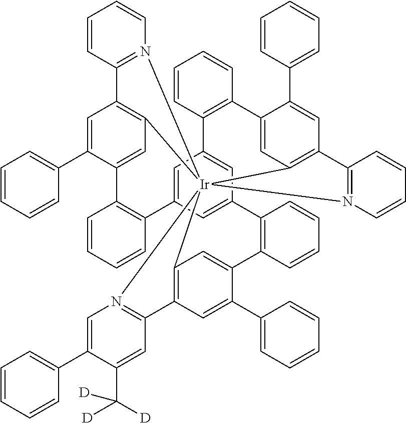

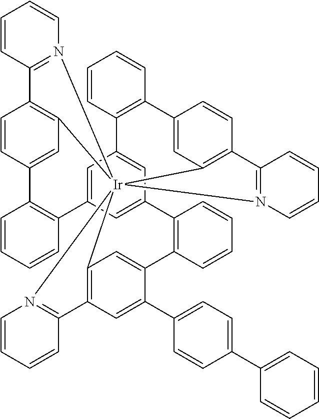

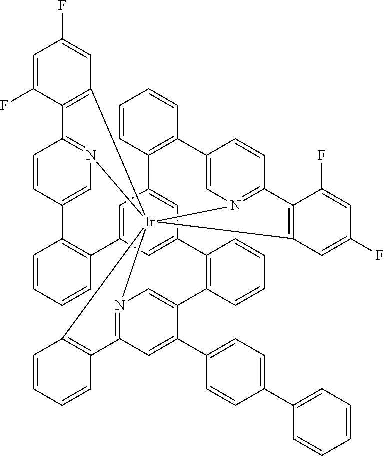

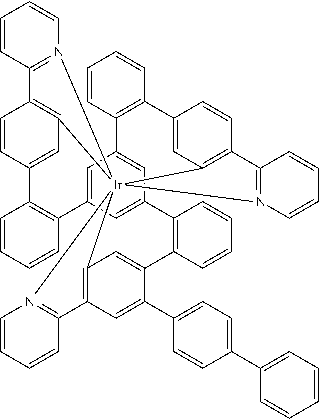

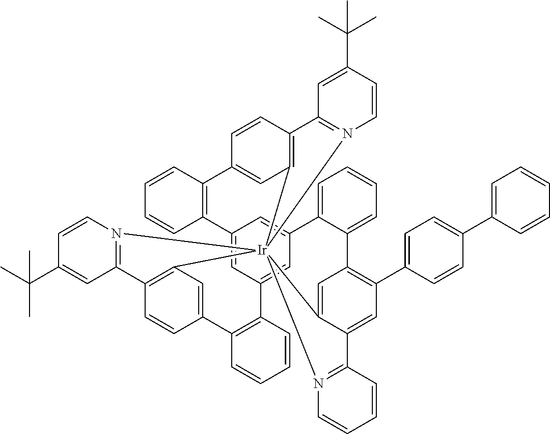

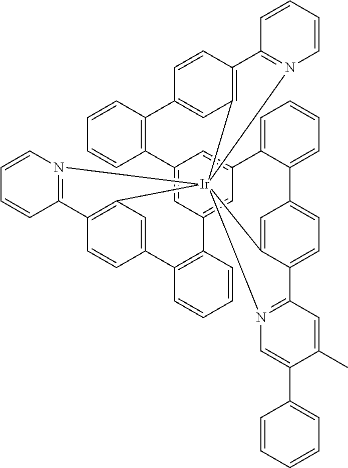

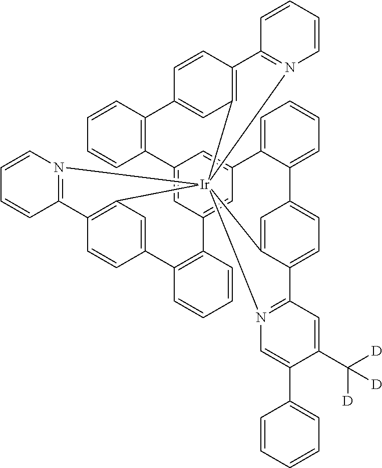

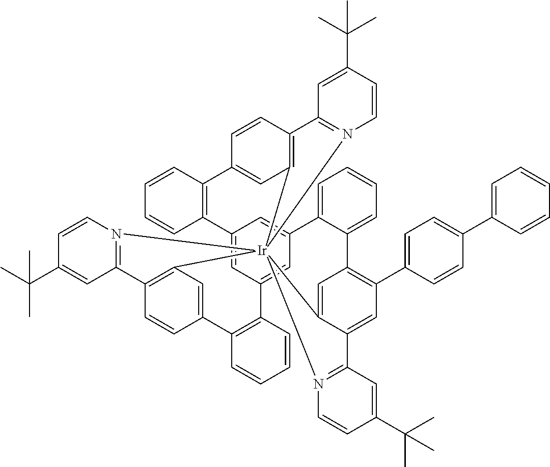

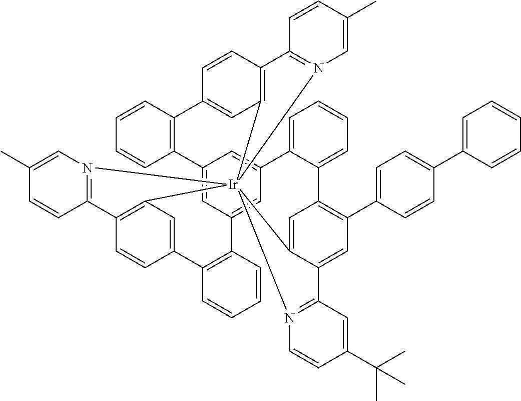

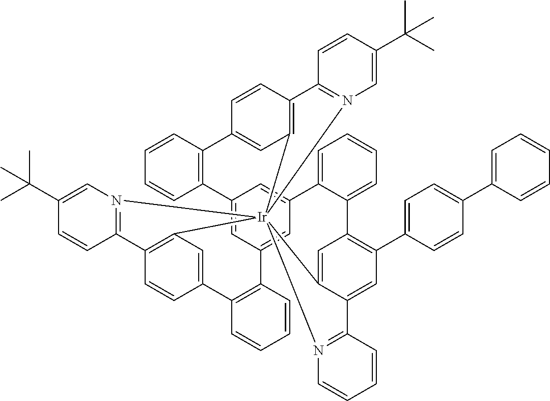

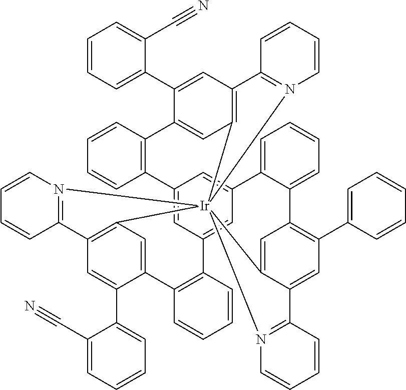

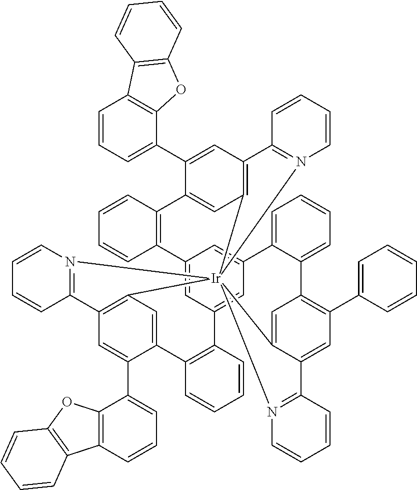

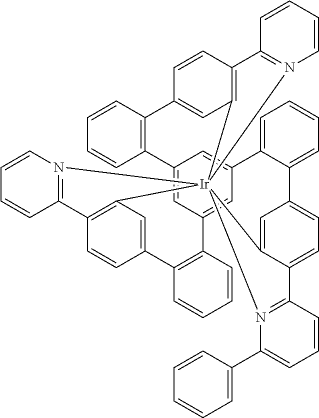

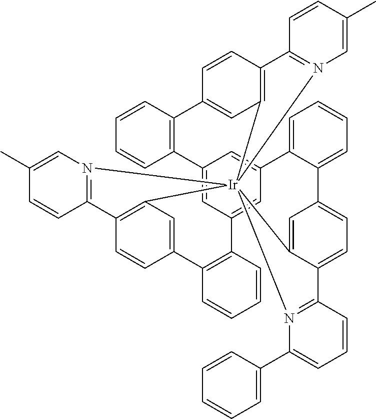

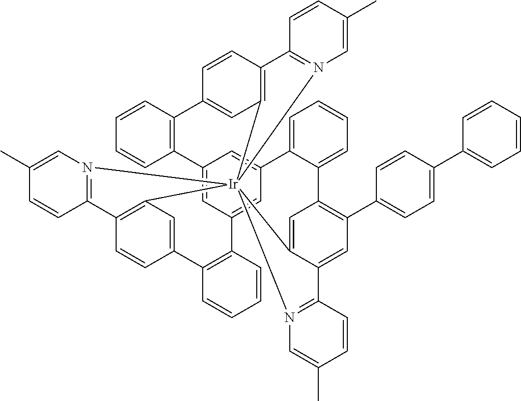

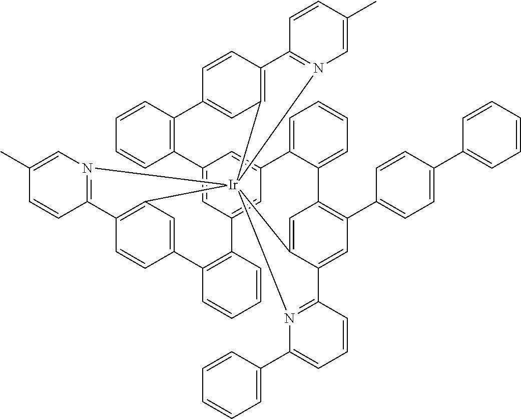

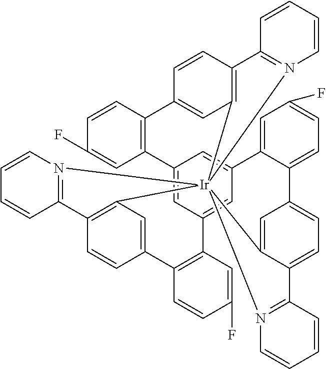

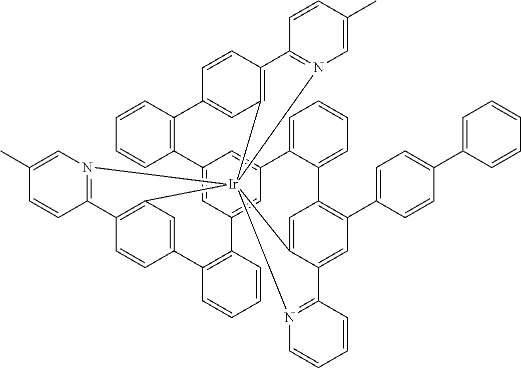

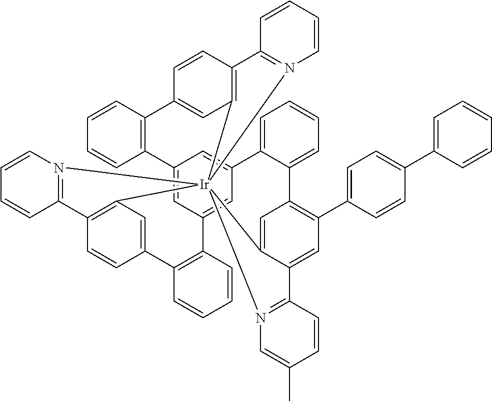

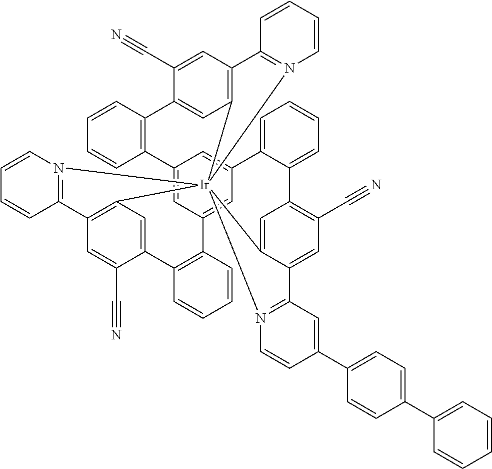

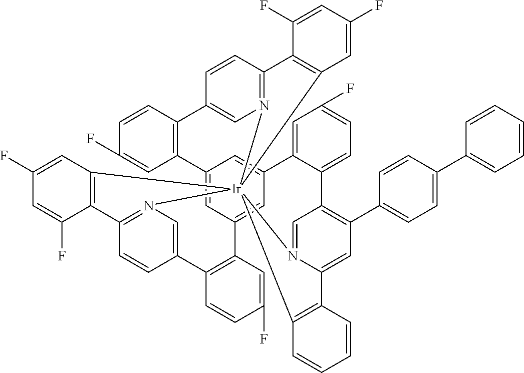

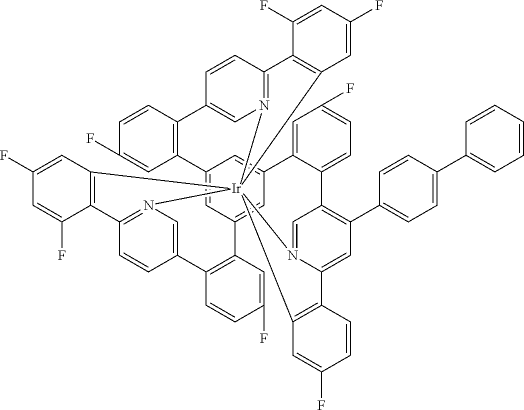

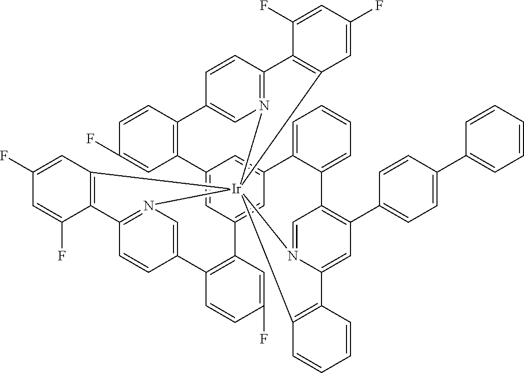

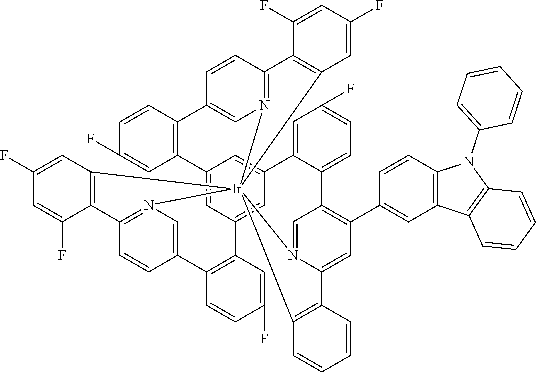

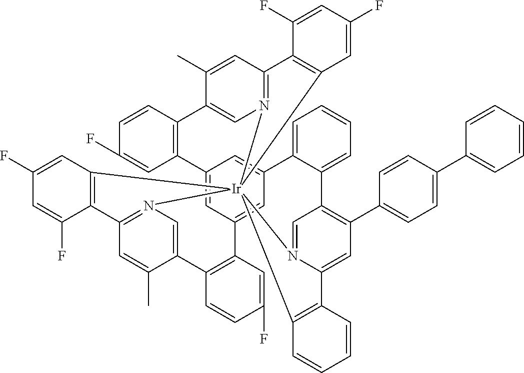

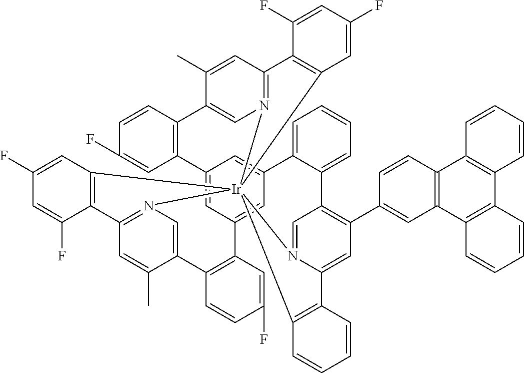

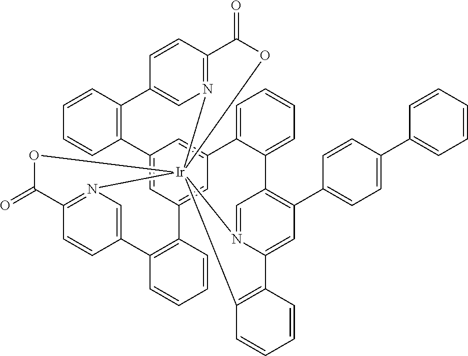

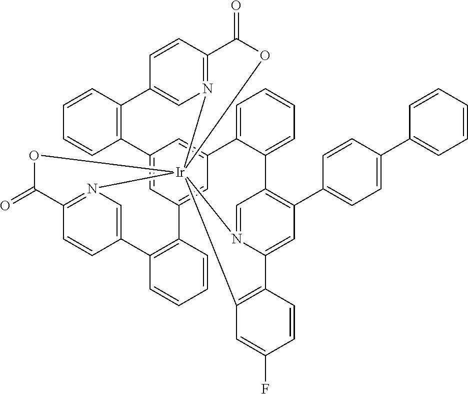

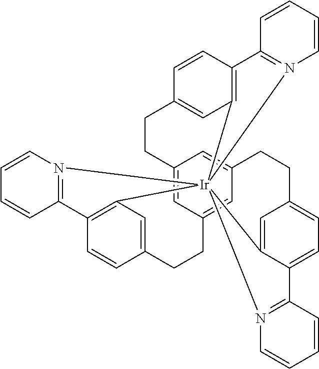

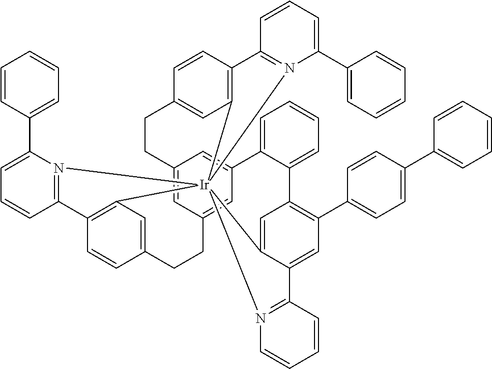

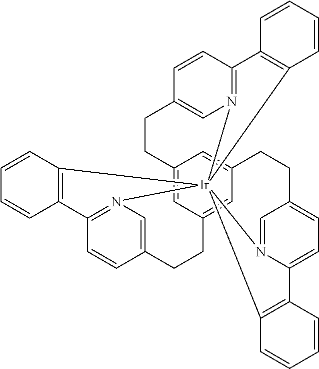

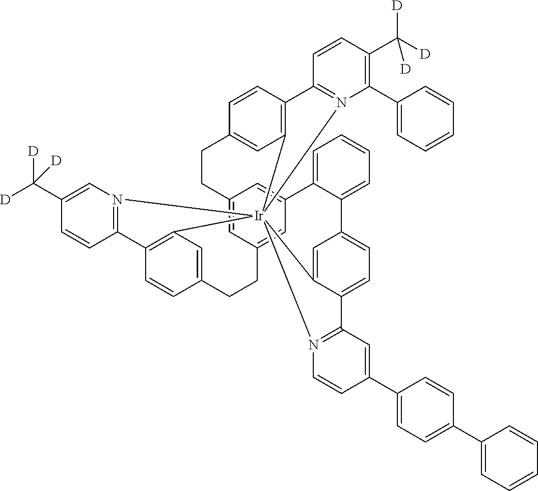

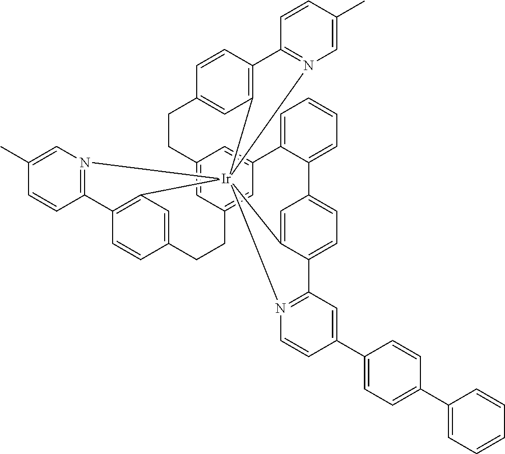

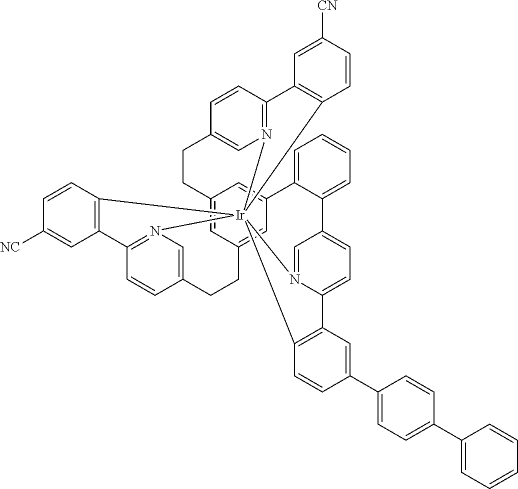

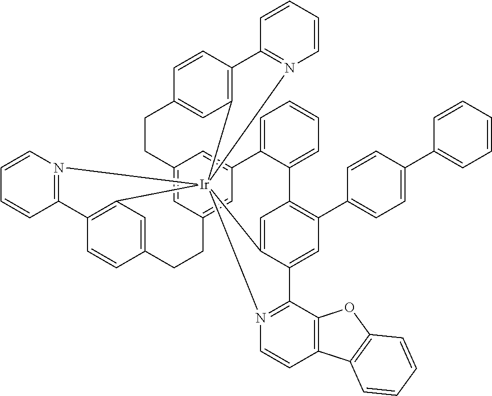

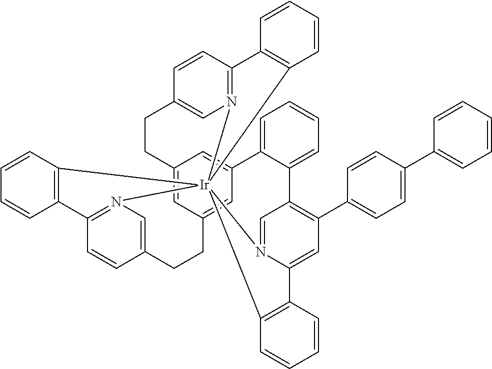

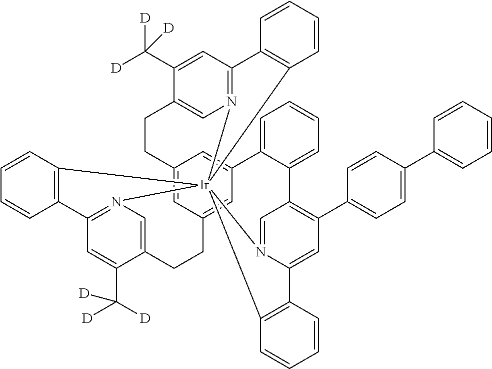

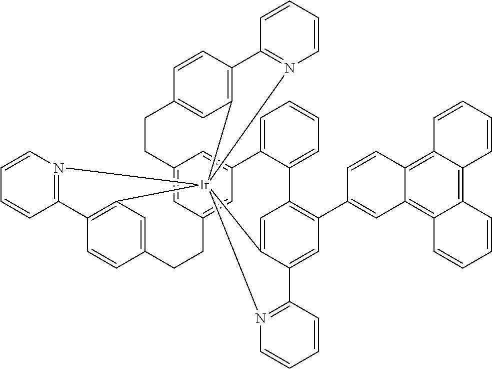

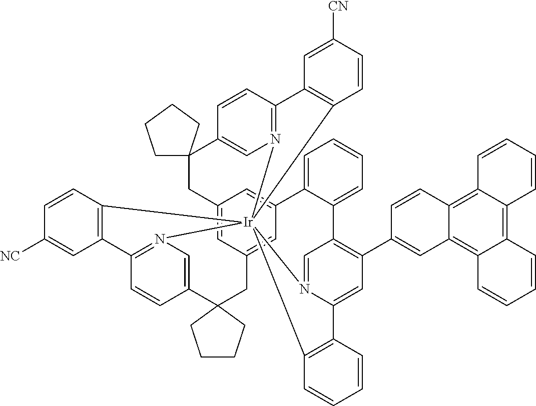

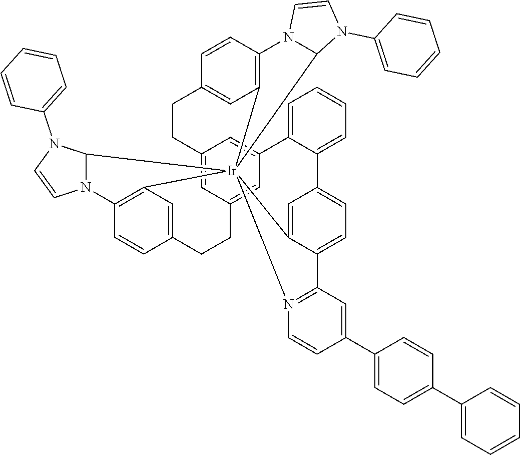

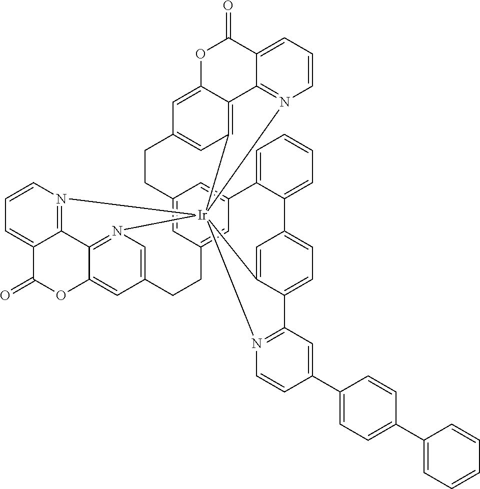

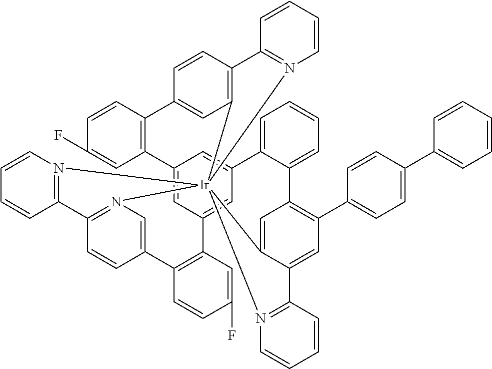

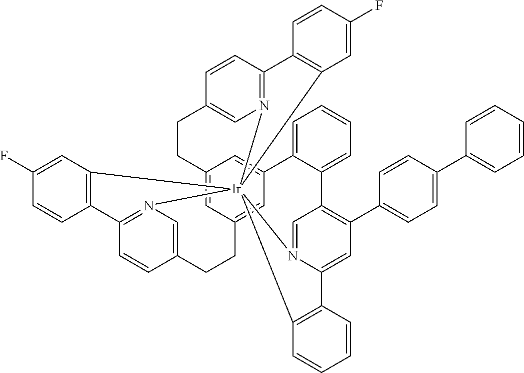

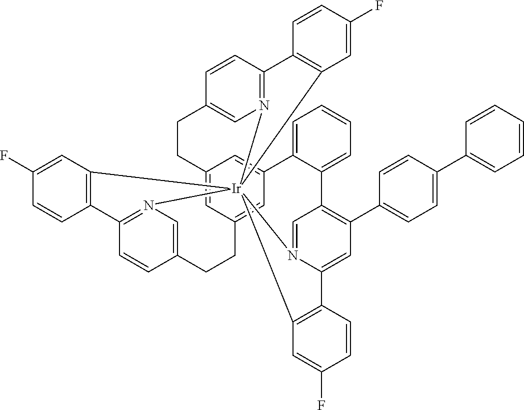

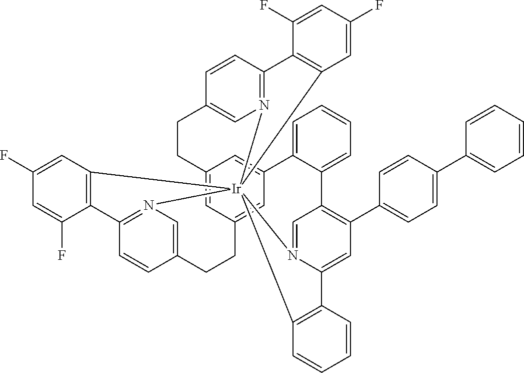

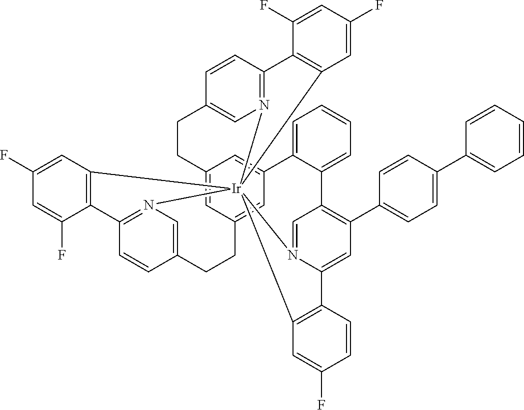

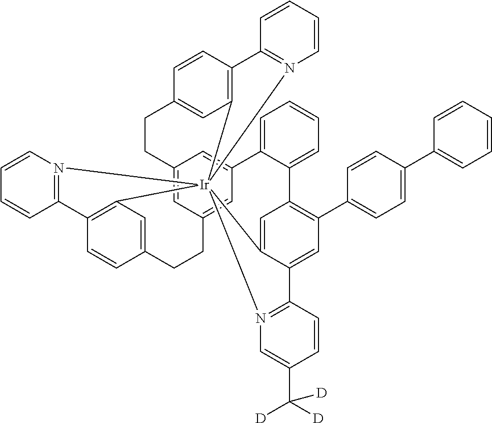

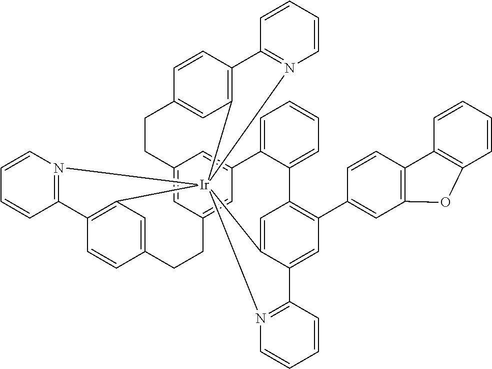

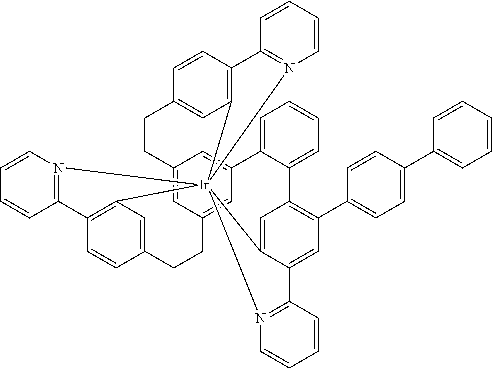

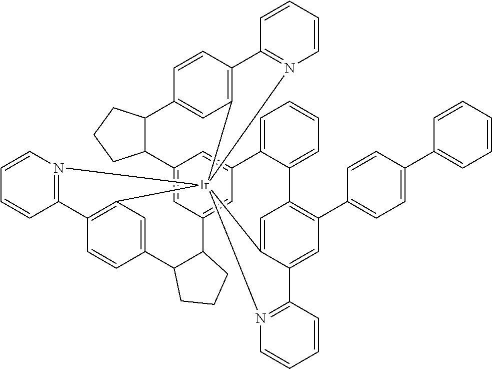

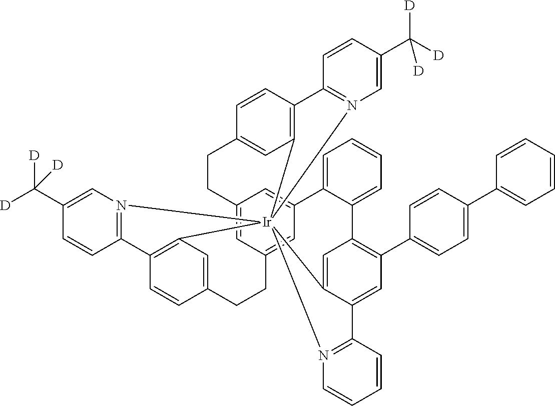

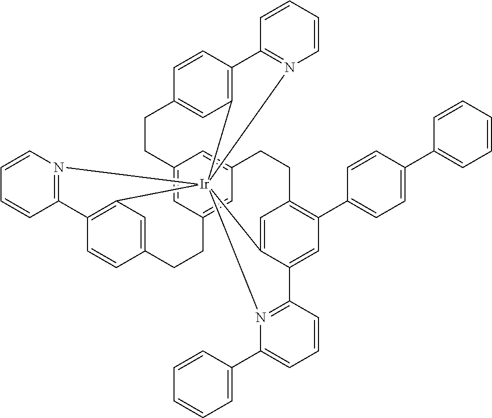

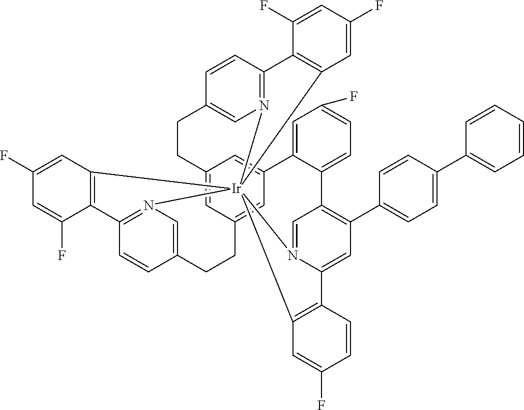

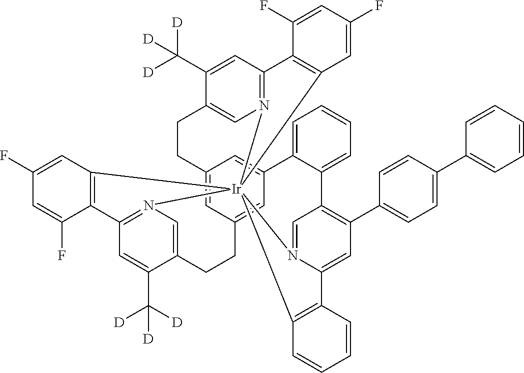

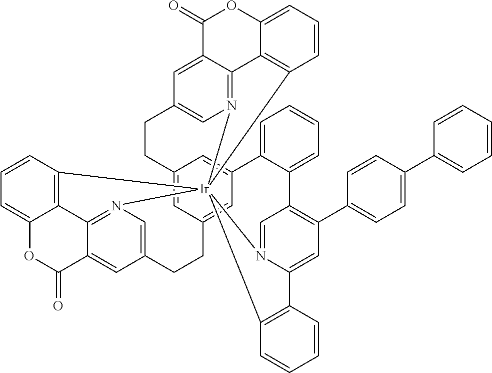

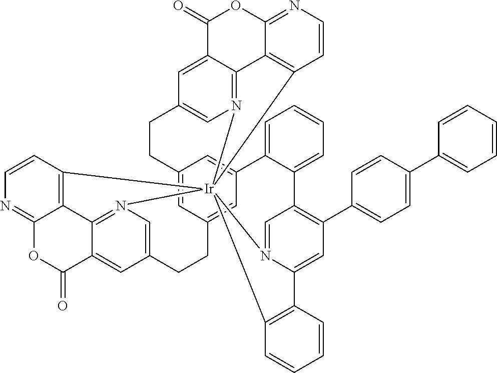

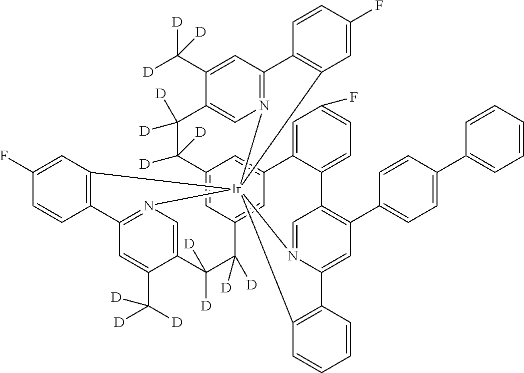

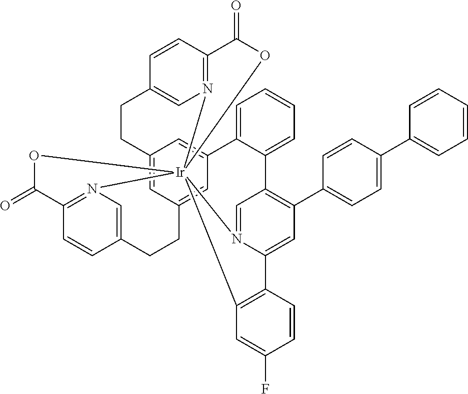

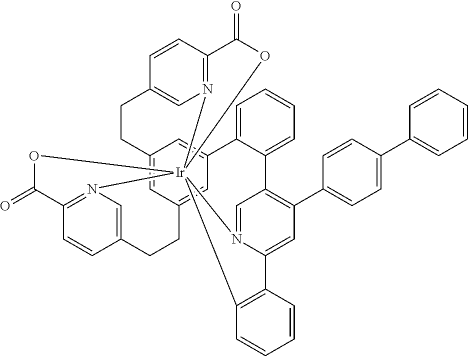

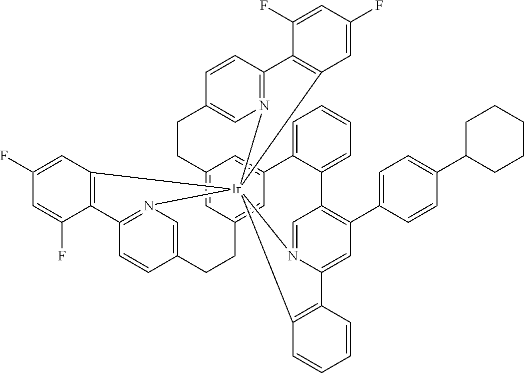

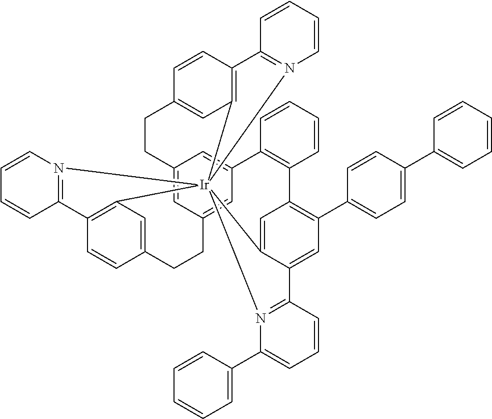

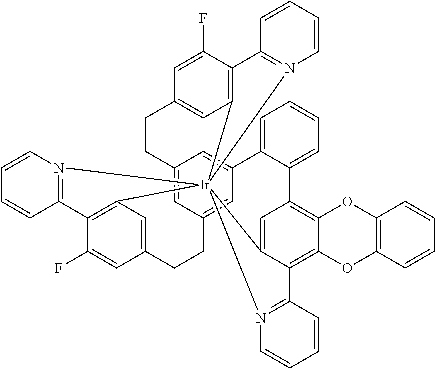

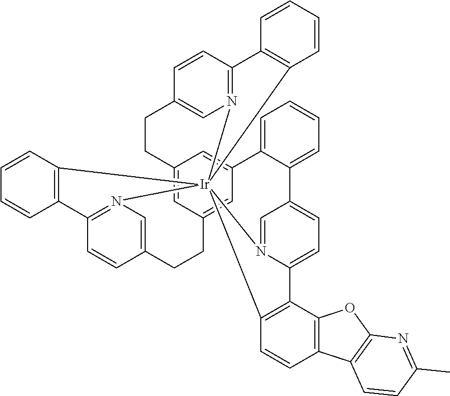

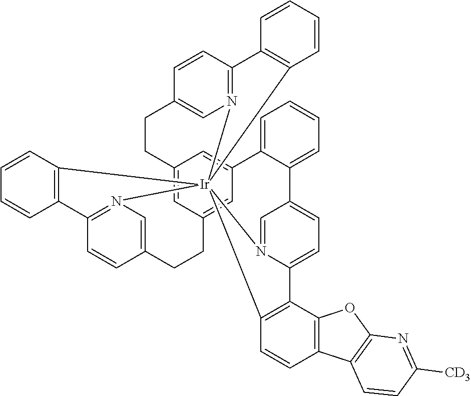

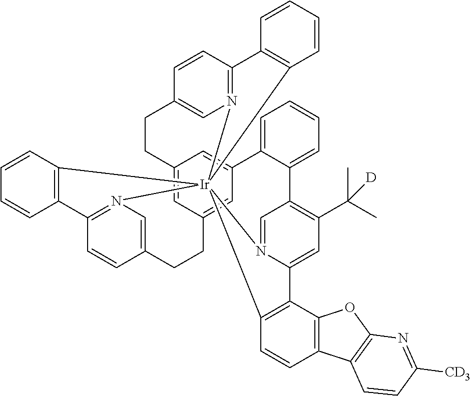

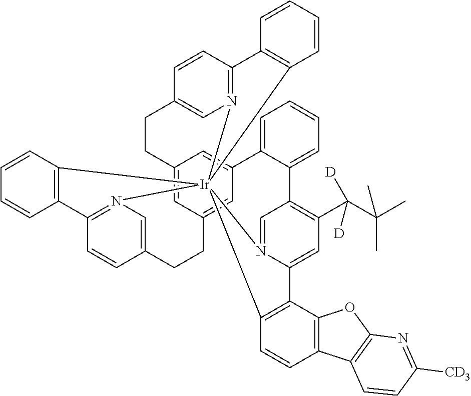

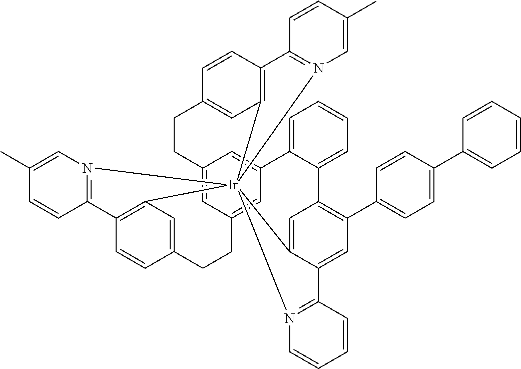

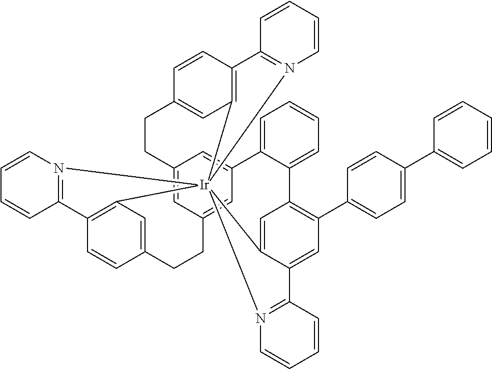

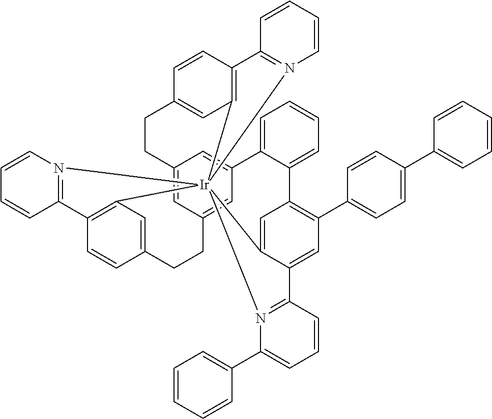

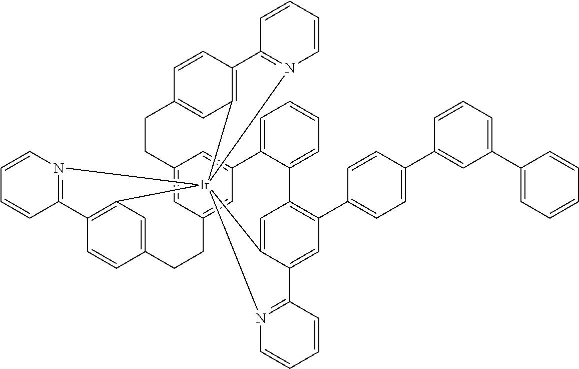

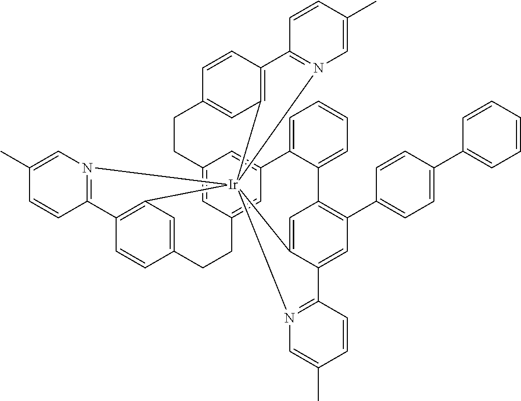

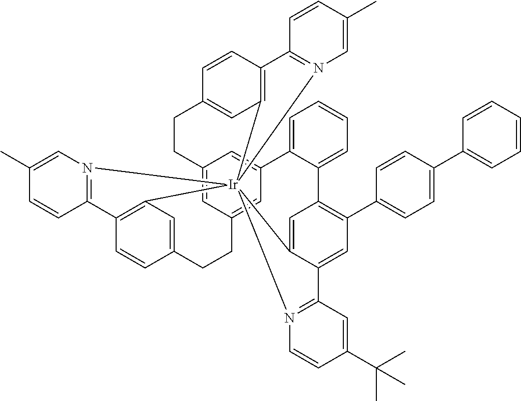

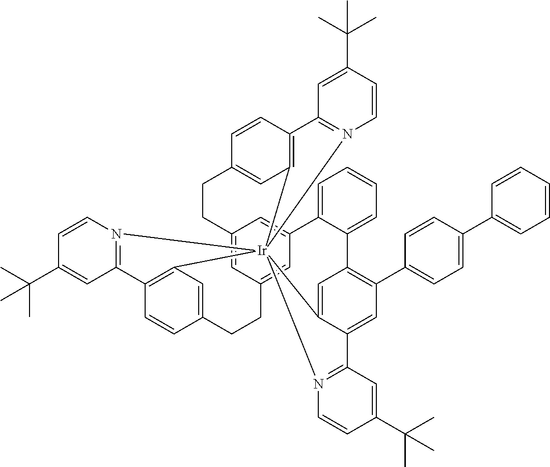

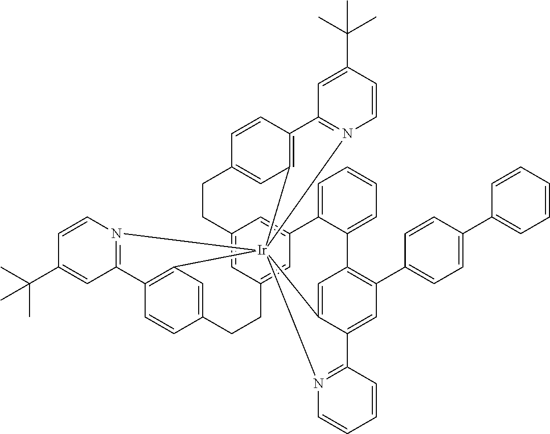

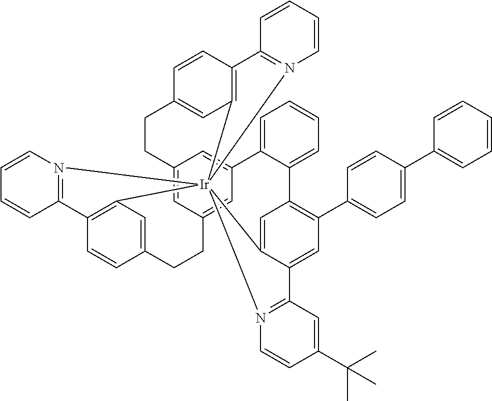

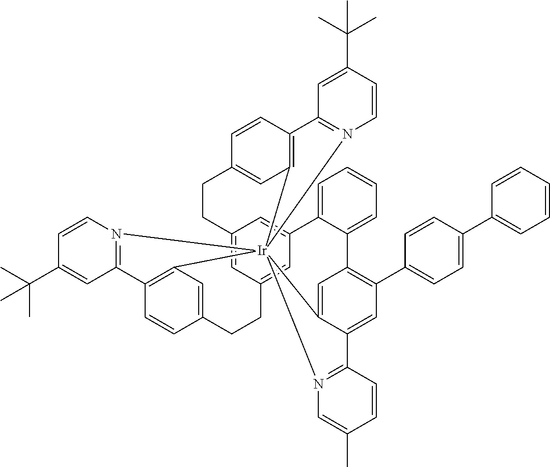

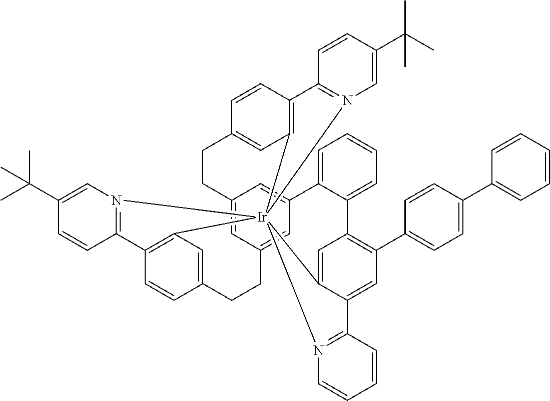

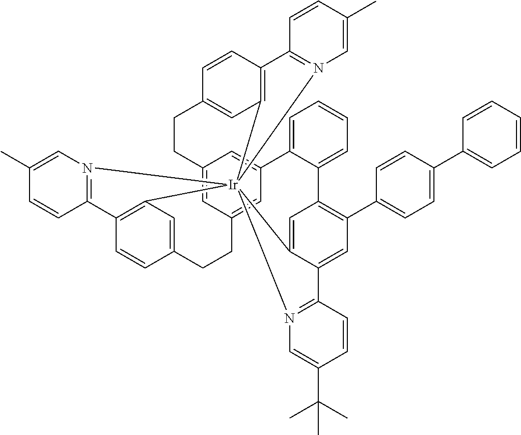

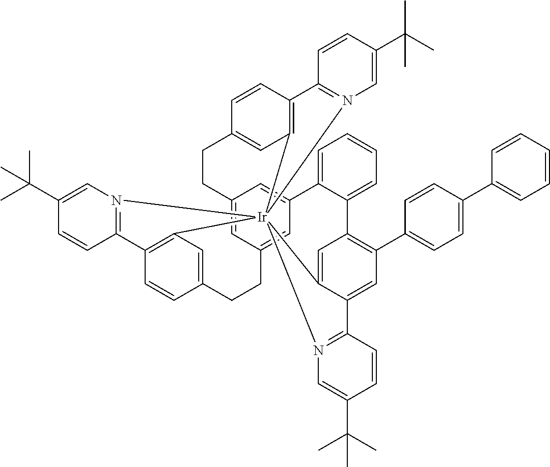

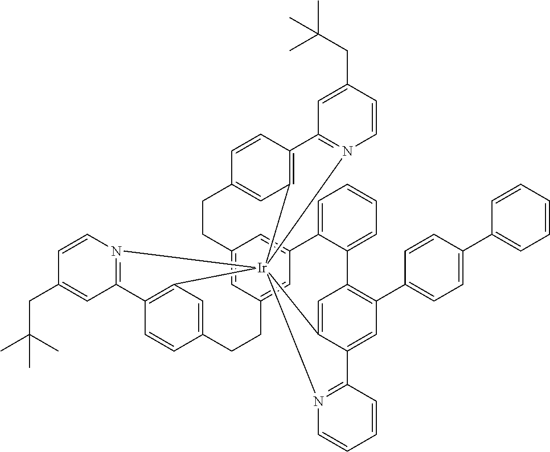

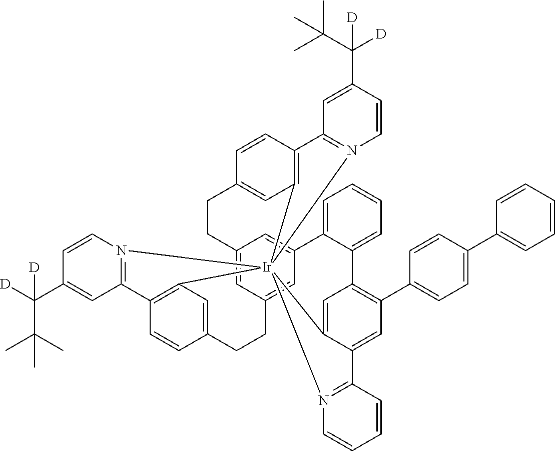

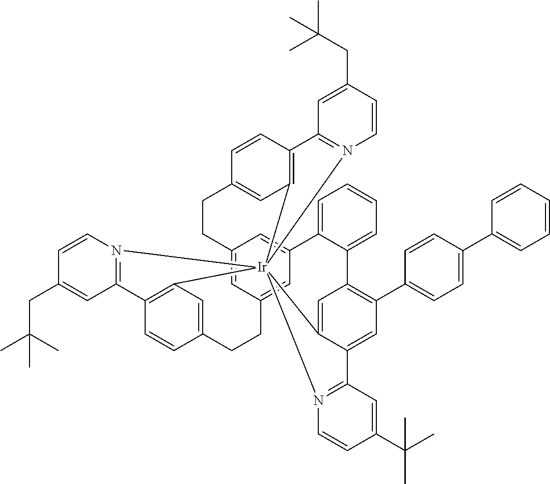

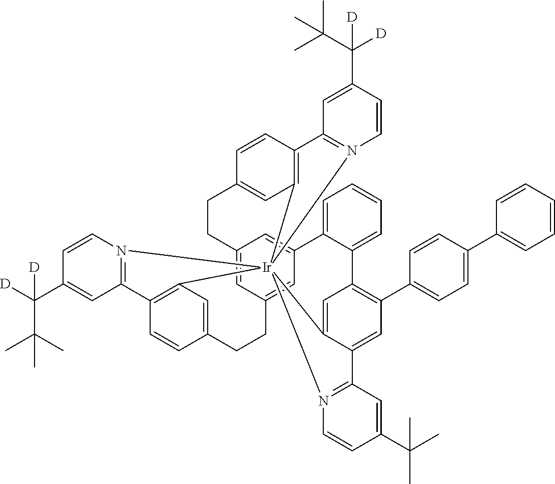

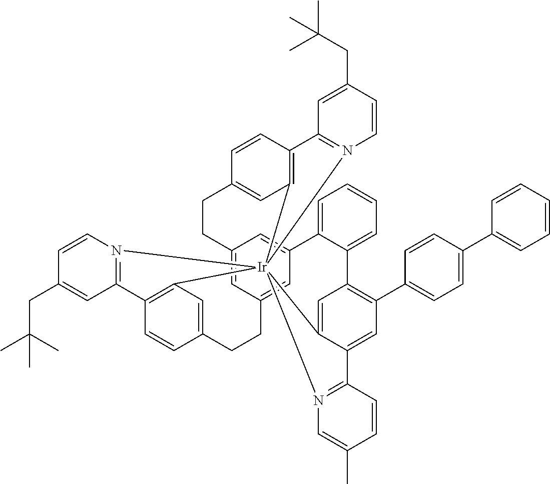

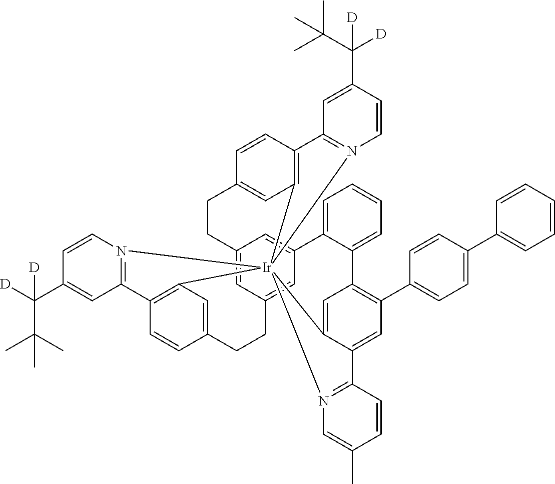

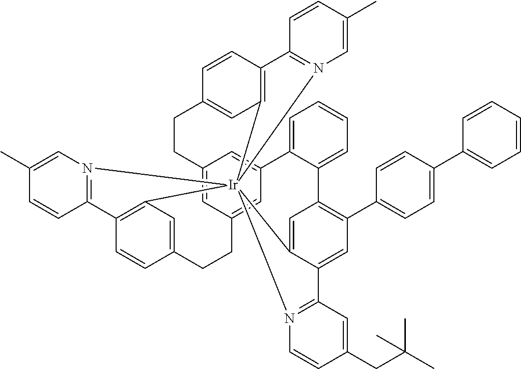

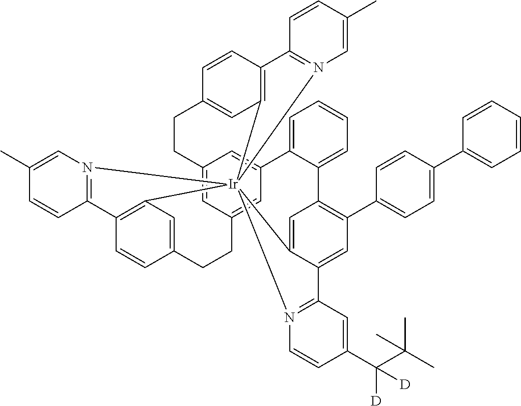

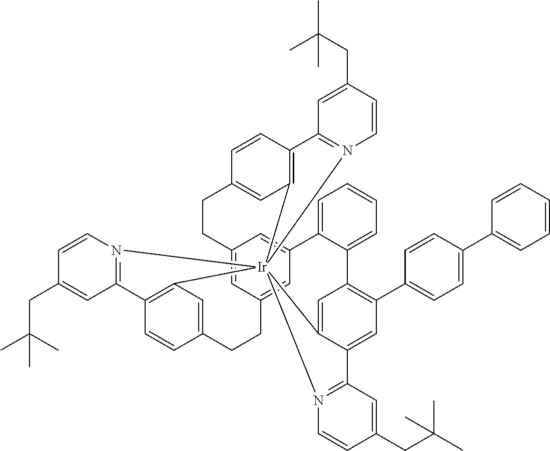

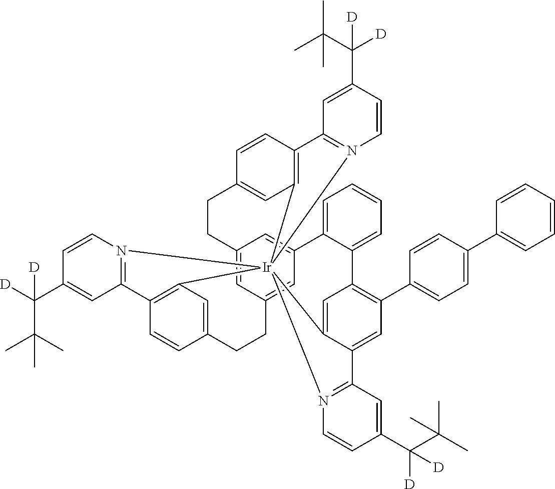

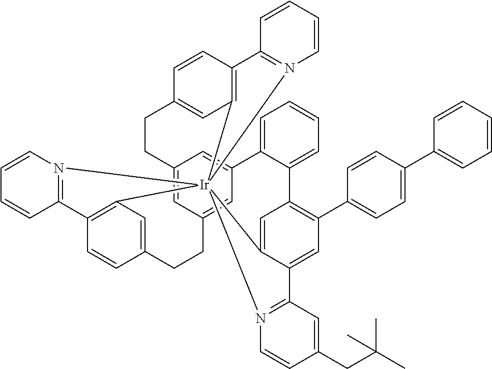

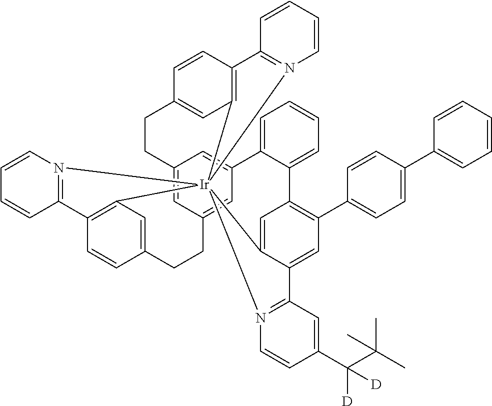

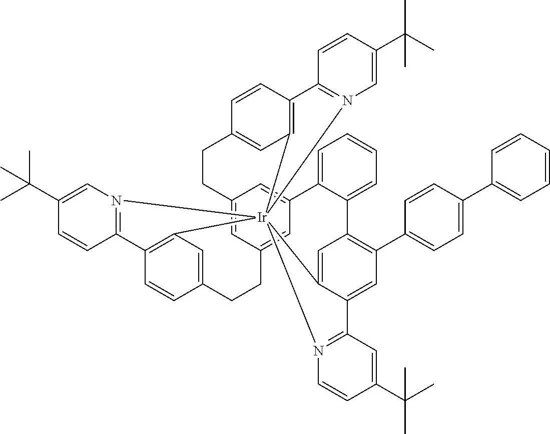

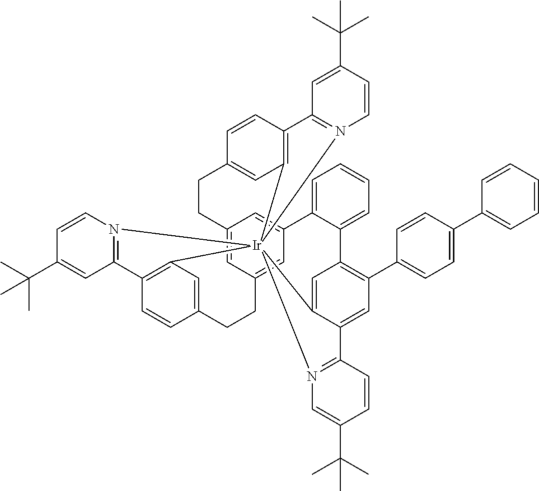

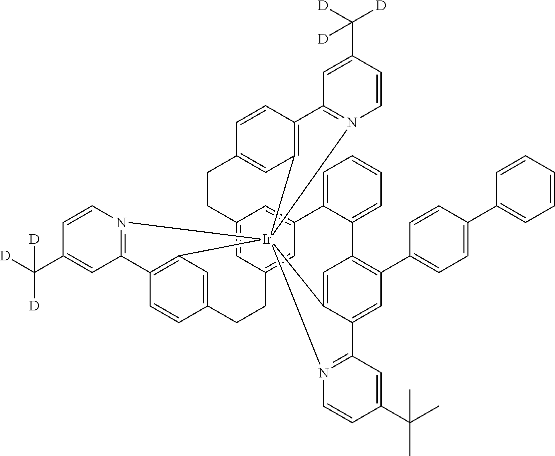

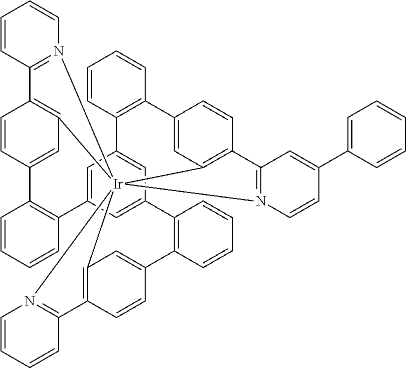

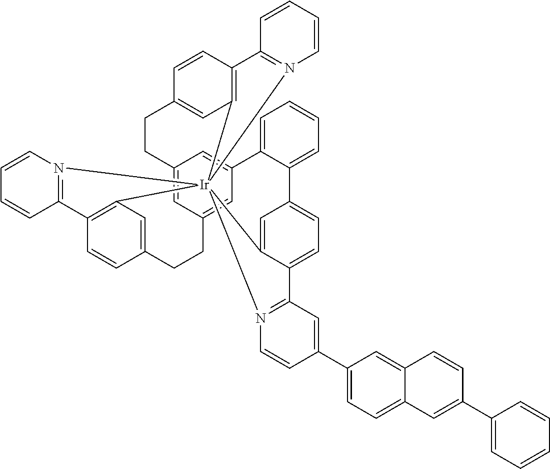

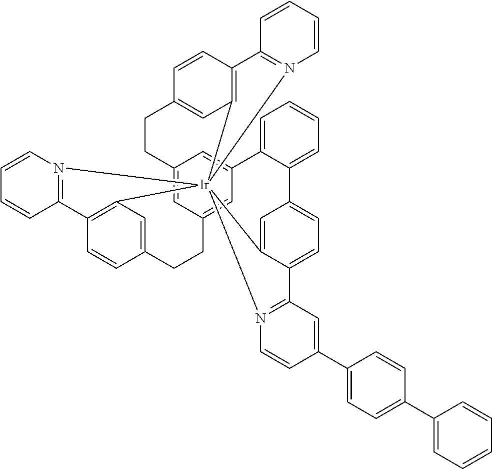

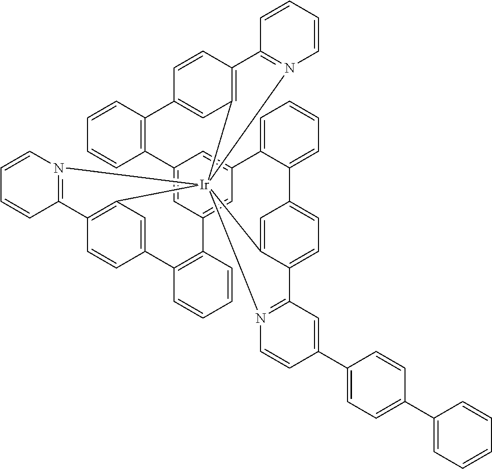

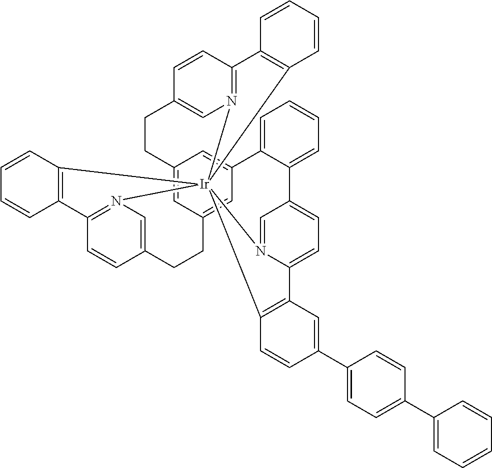

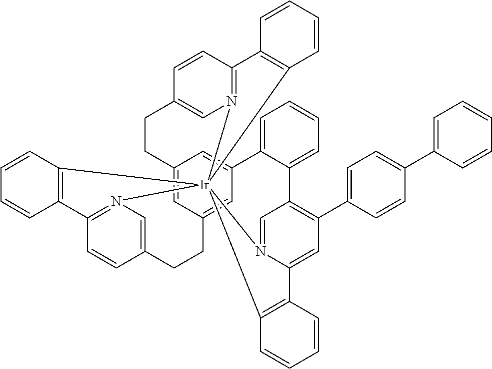

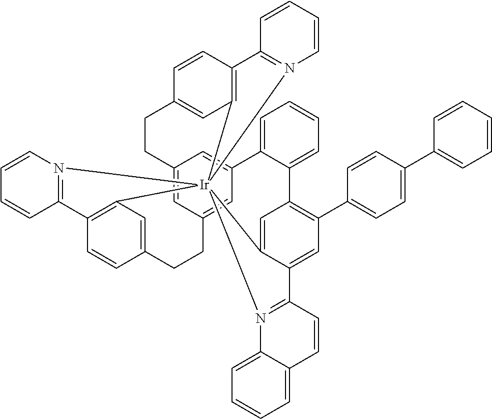

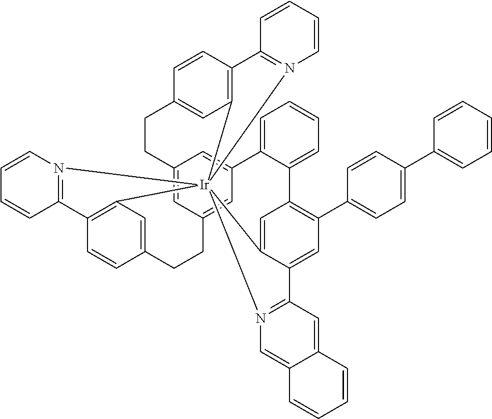

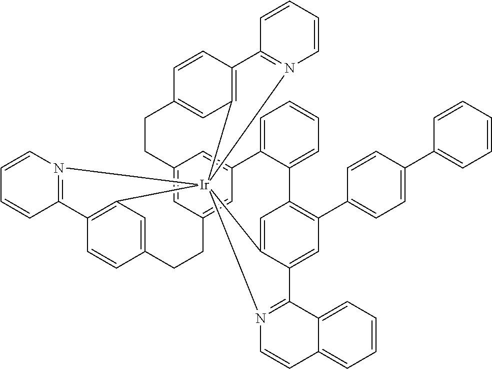

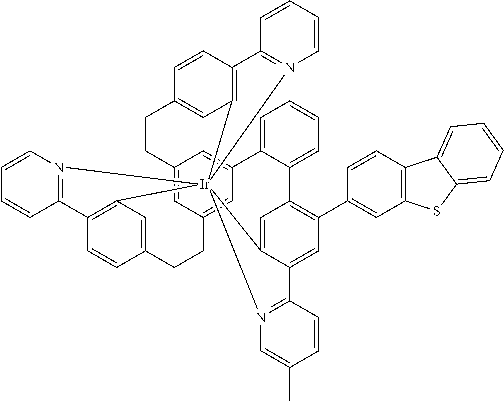

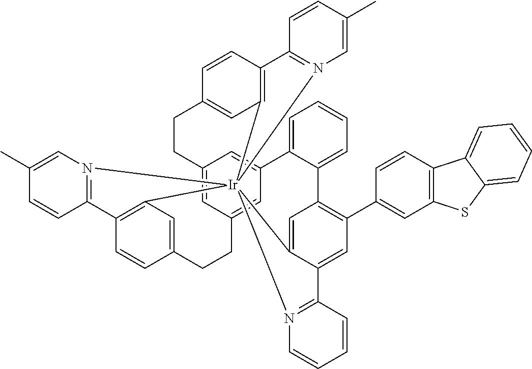

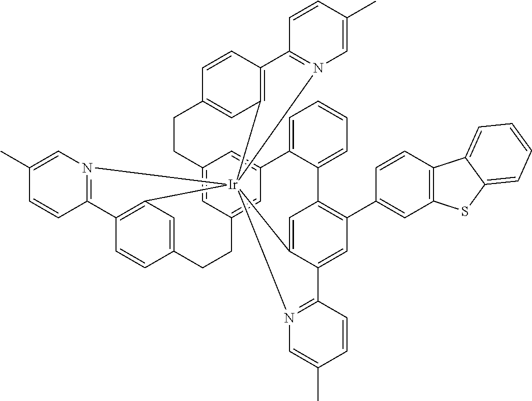

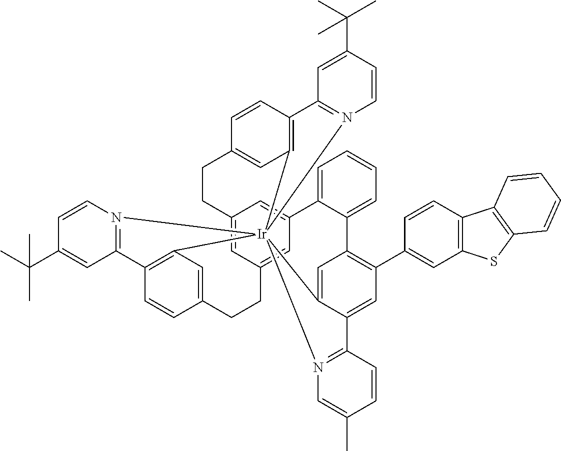

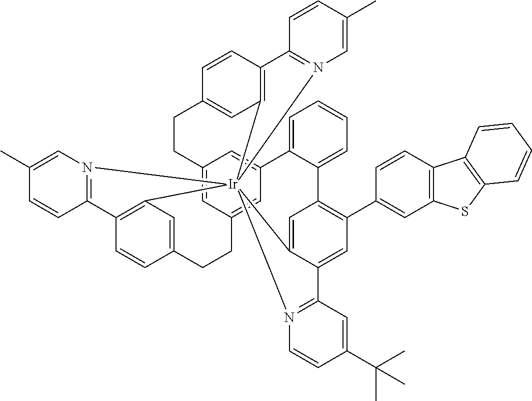

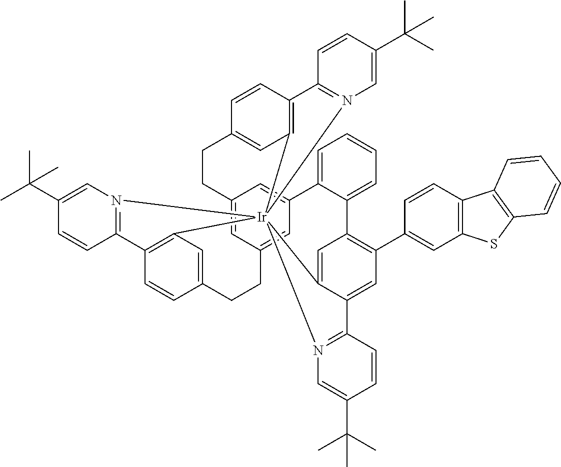

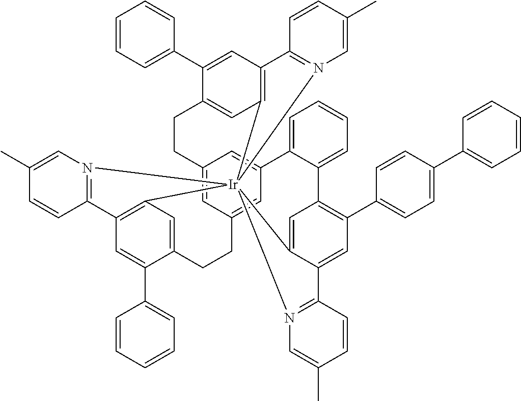

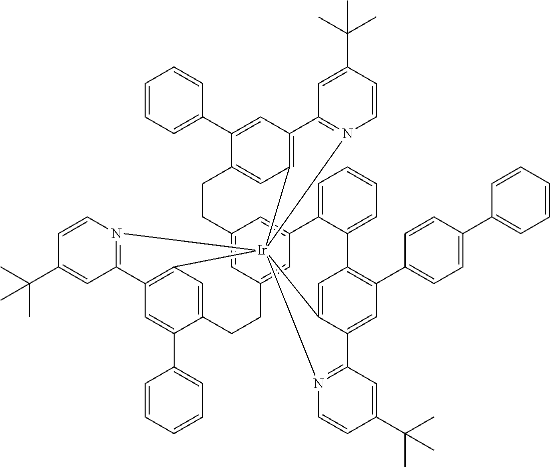

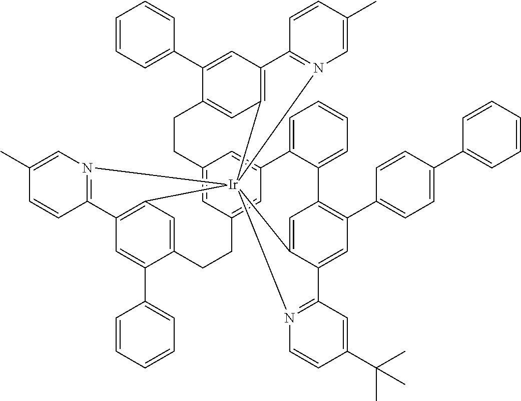

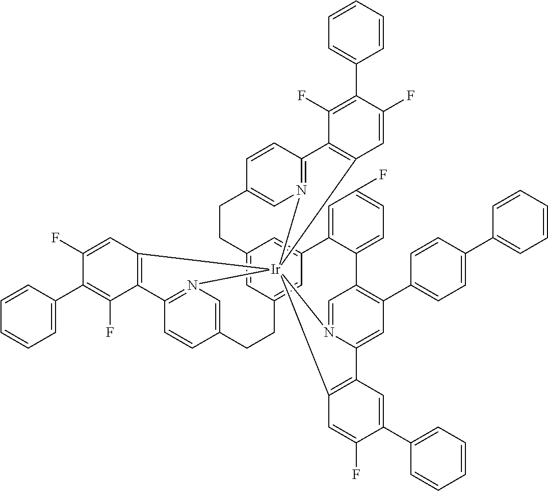

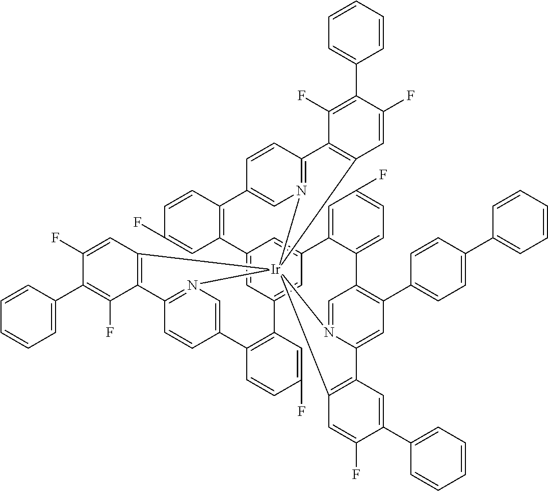

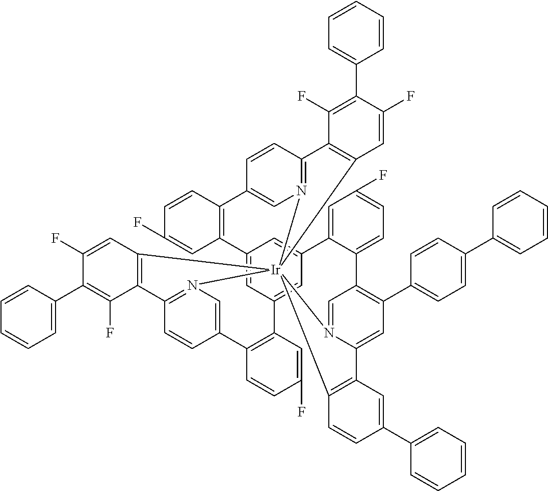

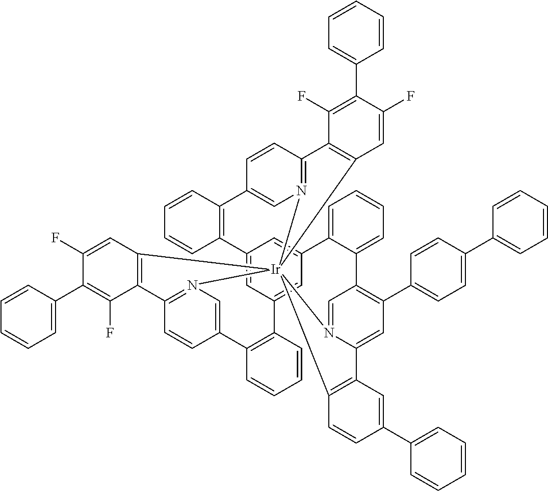

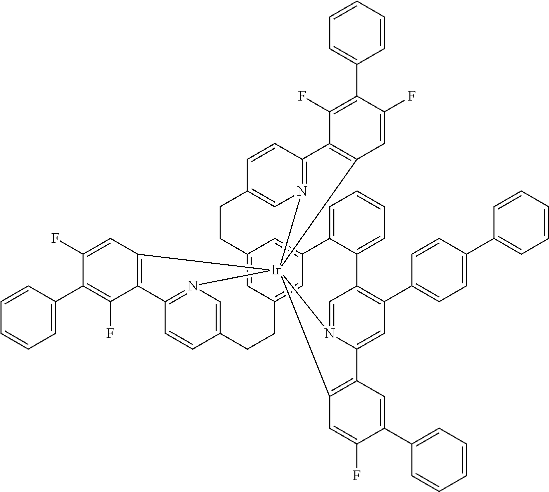

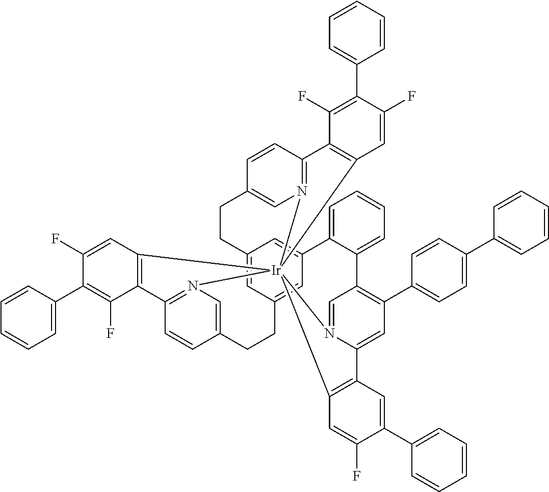

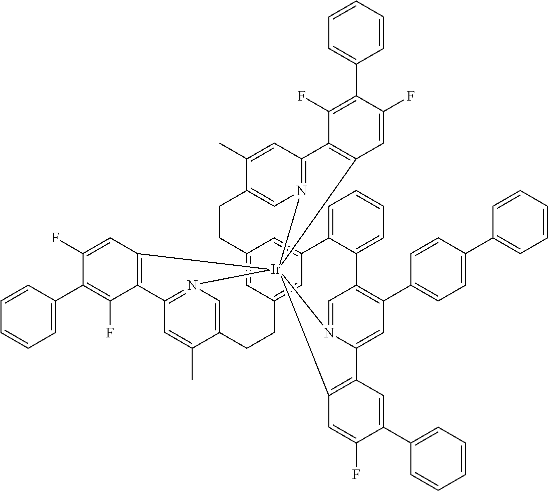

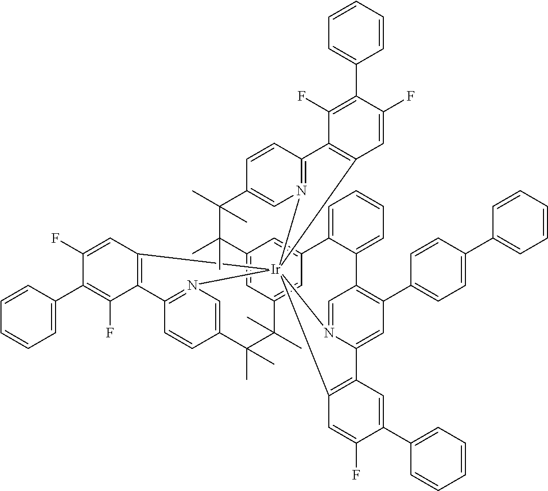

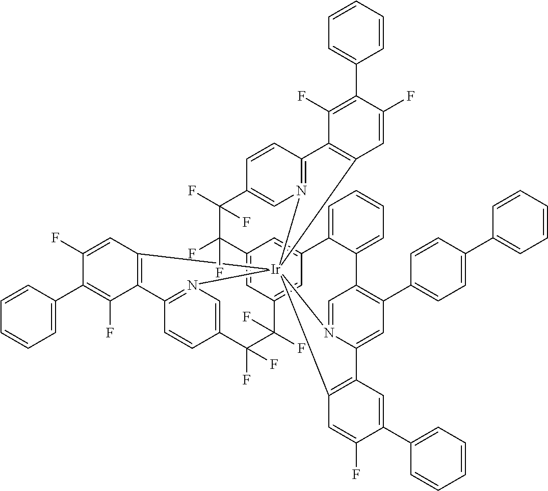

Preferred examples of phosphorescent polypodal emitters are shown in Table 5 below.

TABLE 5

| | | | |
|---|---|---|---|
| CAS-1269508-30-6 | CAS-1989601-68-4 | CAS-1989602-19-8 | CAS-1989602-70-1 |
| CAS-1215692-34-4 | CAS-1989601-69-5 | CAS-1989602-20-1 | CAS-1989602-71-2 |
| CAS-1370364-40-1 | CAS-1989601-70-8 | CAS-1989602-21-2 | CAS-1989602-72-3 |
| CAS-1370364-42-3 | CAS-1989601-71-9 | CAS-1989602-22-3 | CAS-1989602-73-4 |
| CAS-1989600-74-9 | CAS-1989601-72-0 | CAS-1989602-23-4 | CAS-1989602-74-5 |
| CAS-1989600-75-0 | CAS-1989601-73-1 | CAS-1989602-24-5 | CAS-1989602-75-6 |
| CAS-1989600-77-2 | CAS-1989601-74-2 | CAS-1989602-25-6 | CAS-1989602-76-7 |
| CAS-1989600-78-3 | CAS-1989601-75-3 | CAS-1989602-26-7 | CAS-1989602-77-8 |
| CAS-1989600-79-4 | CAS-1989601-76-4 | CAS-1989602-27-8 | CAS-1989602-78-9 |
| CAS-1989600-82-9 | CAS-1989601-77-5 | CAS-1989602-28-9 | CAS-1989602-79-0 |
| CAS-1989600-83-0 | CAS-1989601-78-6 | CAS-1989602-29-0 | CAS-1989602-80-3 |
| CAS-1989600-84-1 | CAS-1989601-79-7 | CAS-1989602-30-3 | CAS-1989602-82-5 |
| CAS-1989600-85-2 | CAS-1989601-80-0 | CAS-1989602-31-4 | CAS-1989602-84-7 |
| CAS-1989600-86-3 | CAS-1989601-81-1 | CAS-1989602-32-5 | CAS-1989602-85-8 |
| CAS-1989600-87-4 | CAS-1989601-82-2 | CAS-1989602-33-6 | CAS-1989602-86-9 |
| CAS-1989600-88-5 | CAS-1989601-83-3 | CAS-1989602-34-7 | CAS-1989602-87-0 |
| CAS-1989600-89-6 | CAS-1989601-84-4 | CAS-1989602-35-8 | CAS-1989602-88-1 |
| CAS-1989601-11-7 | CAS-1989601-85-5 | CAS-1989602-36-9 | CAS-1989604-00-3 |
| CAS-1989601-23-1 | CAS-1989601-86-6 | CAS-1989602-37-0 | CAS-1989604-01-4 |
| CAS-1989601-26-4 | CAS-1989601-87-7 | CAS-1989602-38-1 | CAS-1989604-02-5 |
| CAS-1989601-28-6 | CAS-1989601-88-8 | CAS-1989602-39-2 | CAS-1989604-03-6 |
| CAS-1989601-29-7 | CAS-1989601-89-9 | CAS-1989602-40-5 | CAS-1989604-04-7 |
| CAS-1989601-33-3 | CAS-1989601-90-2 | CAS-1989602-41-6 | CAS-1989604-05-8 |
| CAS-1989601-40-2 | CAS-1989601-91-3 | CAS-1989602-42-7 | CAS-1989604-06-9 |
| CAS-1989601-41-3 | CAS-1989601-92-4 | CAS-1989602-43-8 | CAS-1989604-07-0 |
| CAS-1989601-42-4 | CAS-1989601-93-5 | CAS-1989602-44-9 | CAS-1989604-08-1 |
| CAS-1989601-43-5 | CAS-1989601-94-6 | CAS-1989602-45-0 | CAS-1989604-09-2 |
| CAS-1989601-44-6 | CAS-1989601-95-7 | CAS-1989602-46-1 | CAS-1989604-10-5 |
| CAS-1989601-45-7 | CAS-1989601-96-8 | CAS-1989602-47-2 | CAS-1989604-11-6 |
| CAS-1989601-46-8 | CAS-1989601-97-9 | CAS-1989602-48-3 | CAS-1989604-13-8 |
| CAS-1989601-47-9 | CAS-1989601-98-0 | CAS-1989602-49-4 | CAS-1989604-14-9 |
| CAS-1989601-48-0 | CAS-1989601-99-1 | CAS-1989602-50-7 | CAS-1989604-15-0 |
| CAS-1989601-49-1 | CAS-1989602-00-7 | CAS-1989602-51-8 | CAS-1989604-16-1 |
| CAS-1989601-50-4 | CAS-1989602-01-8 | CAS-1989602-52-9 | CAS-1989604-17-2 |
| CAS-1989601-51-5 | CAS-1989602-02-9 | CAS-1989602-53-0 | CAS-1989604-18-3 |
| CAS-1989601-52-6 | CAS-1989602-03-0 | CAS-1989602-54-1 | CAS-1989604-19-4 |
| CAS-1989601-53-7 | CAS-1989602-04-1 | CAS-1989602-55-2 | CAS-1989604-20-7 |
| CAS-1989601-54-8 | CAS-1989602-05-2 | CAS-1989602-56-3 | CAS-1989604-21-8 |
| CAS-1989601-55-9 | CAS-1989602-06-3 | CAS-1989602-57-4 | CAS-1989604-22-9 |
| CAS-1989601-56-0 | CAS-1989602-07-4 | CAS-1989602-58-5 | CAS-1989604-23-0 |
| CAS-1989601-57-1 | CAS-1989602-08-5 | CAS-1989602-59-6 | CAS-1989604-24-1 |
| CAS-1989601-58-2 | CAS-1989602-09-6 | CAS-1989602-60-9 | CAS-1989604-25-2 |
| CAS-1989601-59-3 | CAS-1989602-10-9 | CAS-1989602-61-0 | CAS-1989604-26-3 |
| CAS-1989601-60-6 | CAS-1989602-11-0 | CAS-1989602-62-1 | CAS-1989604-27-4 |
| CAS-1989601-61-7 | CAS-1989602-12-1 | CAS-1989602-63-2 | CAS-1989604-28-5 |
| CAS-1989601-62-8 | CAS-1989602-13-2 | CAS-1989602-64-3 | CAS-1989604-29-6 |
| CAS-1989601-63-9 | CAS-1989602-14-3 | CAS-1989602-65-4 | CAS-1989604-30-9 |
| CAS-1989601-64-0 | CAS-1989602-15-4 | CAS-1989602-66-5 | CAS-1989604-31-0 |
| CAS-1989601-65-1 | CAS-1989602-16-5 | CAS-1989602-67-6 | CAS-1989604-32-1 |
| CAS-1989601-66-2 | CAS-1989602-17-6 | CAS-1989602-68-7 | CAS-1989604-33-2 |
| CAS-1989601-67-3 | CAS-1989602-18-7 | CAS-1989602-69-8 | CAS-1989604-34-3 |
| CAS-1989604-35-4 | CAS-1989604-88-7 | CAS-1989605-52-8 | CAS-1989606-07-6 |
| CAS-1989604-36-5 | CAS-1989604-89-8 | CAS-1989605-53-9 | CAS-1989606-08-7 |
| CAS-1989604-37-6 | CAS-1989604-90-1 | CAS-1989605-54-0 | CAS-1989606-09-8 |
| CAS-1989604-38-7 | CAS-1989604-92-3 | CAS-1989605-55-1 | CAS-1989606-10-1 |
| CAS-1989604-39-8 | CAS-1989604-93-4 | CAS-1989605-56-2 | CAS-1989606-11-2 |
| CAS-1989604-40-1 | CAS-1989604-94-5 | CAS-1989605-57-3 | CAS-1989606-12-3 |
| CAS-1989604-41-2 | CAS-1989604-95-6 | CAS-1989605-58-4 | CAS-1989606-13-4 |
| CAS-1989604-42-3 | CAS-1989604-96-7 | CAS-1989605-59-5 | CAS-1989606-14-5 |
| CAS-1989604-43-4 | CAS-1989604-97-8 | CAS-1989605-61-9 | CAS-1989606-15-6 |
| CAS-1989604-45-6 | CAS-1989605-09-5 | CAS-1989605-62-0 | CAS-1989606-16-7 |
| CAS-1989604-46-7 | CAS-1989605-10-8 | CAS-1989605-63-1 | CAS-1989606-17-8 |
| CAS-1989604-47-8 | CAS-1989605-11-9 | CAS-1989605-64-2 | CAS-1989606-18-9 |
| CAS-1989604-48-9 | CAS-1989605-13-1 | CAS-1989605-65-3 | CAS-1989606-19-0 |
| CAS-1989604-49-0 | CAS-1989605-14-2 | CAS-1989605-66-4 | CAS-1989606-20-3 |
| CAS-1989604-50-3 | CAS-1989605-15-3 | CAS-1989605-67-5 | CAS-1989606-21-4 |
| CAS-1989604-52-5 | CAS-1989605-16-4 | CAS-1989605-68-6 | CAS-1989606-22-5 |
| CAS-1989604-53-6 | CAS-1989605-17-5 | CAS-1989605-69-7 | CAS-1989606-23-6 |
| CAS-1989604-54-7 | CAS-1989605-18-6 | CAS-1989605-70-0 | CAS-1989606-24-7 |
| CAS-1989604-55-8 | CAS-1989605-19-7 | CAS-1989605-71-1 | CAS-1989606-26-9 |
| CAS-1989604-56-9 | CAS-1989605-20-0 | CAS-1989605-72-2 | CAS-1989606-27-0 |
| CAS-1989604-57-0 | CAS-1989605-21-1 | CAS-1989605-73-3 | CAS-1989606-28-1 |
| CAS-1989604-58-1 | CAS-1989605-22-2 | CAS-1989605-74-4 | CAS-1989606-29-2 |
| CAS-1989604-59-2 | CAS-1989605-23-3 | CAS-1989605-75-5 | CAS-1989606-30-5 |
| CAS-1989604-60-5 | CAS-1989605-24-4 | CAS-1989605-76-6 | CAS-1989606-31-6 |
| CAS-1989604-61-6 | CAS-1989605-25-5 | CAS-1989605-77-7 | CAS-1989606-32-7 |
| CAS-1989604-62-7 | CAS-1989605-26-6 | CAS-1989605-78-8 | CAS-1989606-33-8 |
| CAS-1989604-63-8 | CAS-1989605-27-7 | CAS-1989605-79-9 | CAS-1989606-34-9 |
| CAS-1989604-64-9 | CAS-1989605-28-8 | CAS-1989605-81-3 | CAS-1989606-35-0 |
| CAS-1989604-65-0 | CAS-1989605-29-9 | CAS-1989605-82-4 | CAS-1989606-36-1 |
| CAS-1989604-66-1 | CAS-1989605-30-2 | CAS-1989605-83-5 | CAS-1989606-37-2 |
| CAS-1989604-67-2 | CAS-1989605-31-3 | CAS-1989605-84-6 | CAS-1989606-38-3 |
| CAS-1989604-68-3 | CAS-1989605-32-4 | CAS-1989605-85-7 | CAS-1989606-39-4 |
| CAS-1989604-69-4 | CAS-1989605-33-5 | CAS-1989605-86-8 | CAS-1989606-40-7 |
| CAS-1989604-70-7 | CAS-1989605-34-6 | CAS-1989605-87-9 | CAS-1989606-41-8 |
| CAS-1989604-71-8 | CAS-1989605-35-7 | CAS-1989605-88-0 | CAS-1989606-42-9 |
| CAS-1989604-72-9 | CAS-1989605-36-8 | CAS-1989605-89-1 | CAS-1989606-43-0 |
| CAS-1989604-73-0 | CAS-1989605-37-9 | CAS-1989605-90-4 | CAS-1989606-44-1 |
| CAS-1989604-74-1 | CAS-1989605-38-0 | CAS-1989605-91-5 | CAS-1989606-45-2 |
| CAS-1989604-75-2 | CAS-1989605-39-1 | CAS-1989605-92-6 | CAS-1989606-46-3 |
| CAS-1989604-76-3 | CAS-1989605-40-4 | CAS-1989605-93-7 | CAS-1989606-48-5 |
| CAS-1989604-77-4 | CAS-1989605-41-5 | CAS-1989605-94-8 | CAS-1989606-49-6 |
| CAS-1989604-78-5 | CAS-1989605-42-6 | CAS-1989605-95-9 | CAS-1989606-53-2 |
| CAS-1989604-79-6 | CAS-1989605-43-7 | CAS-1989605-96-0 | CAS-1989606-55-4 |
| CAS-1989604-80-9 | CAS-1989605-44-8 | CAS-1989605-97-1 | CAS-1989606-56-5 |
| CAS-1989604-81-0 | CAS-1989605-45-9 | CAS-1989605-98-2 | CAS-1989606-61-2 |
| CAS-1989604-82-1 | CAS-1989605-46-0 | CAS-1989605-99-3 | CAS-1989606-62-3 |
| CAS-1989604-83-2 | CAS-1989605-47-1 | CAS-1989606-00-9 | CAS-1989606-63-4 |
| CAS-1989604-84-3 | CAS-1989605-48-2 | CAS-1989606-01-0 | CAS-1989606-67-8 |
| CAS-1989604-85-4 | CAS-1989605-49-3 | CAS-1989606-04-3 | CAS-1989606-69-0 |
| CAS-1989604-86-5 | CAS-1989605-50-6 | CAS-1989606-05-4 | CAS-1989606-70-3 |
| CAS-1989604-87-6 | CAS-1989605-51-7 | CAS-1989606-06-5 | CAS-1989606-74-7 |
| CAS-1989658-39-0 | CAS-2088184-56-7 | CAS-2088185-07-1 | CAS-2088185-66-2 |
| CAS-1989658-41-4 | CAS-2088184-57-8 | CAS-2088185-08-2 | CAS-2088185-67-3 |
| CAS-1989658-43-6 | CAS-2088184-58-9 | CAS-2088185-09-3 | CAS-2088185-68-4 |
| CAS-1989658-47-0 | CAS-2088184-59-0 | CAS-2088185-10-6 | CAS-2088185-69-5 |
| CAS-1989658-49-2 | CAS-2088184-60-3 | CAS-2088185-11-7 | CAS-2088185-70-8 |
| CAS-2088184-07-8 | CAS-2088184-61-4 | CAS-2088185-12-8 | CAS-2088185-71-9 |
| CAS-2088184-08-9 | CAS-2088184-62-5 | CAS-2088185-13-9 | CAS-2088185-72-0 |
| CAS-2088184-09-0 | CAS-2088184-63-6 | CAS-2088185-14-0 | CAS-2088185-73-1 |
| CAS-2088184-10-3 | CAS-2088184-64-7 | CAS-2088185-15-1 | CAS-2088185-74-2 |
| CAS-2088184-11-4 | CAS-2088184-65-8 | CAS-2088185-16-2 | CAS-2088185-75-3 |
| CAS-2088184-13-6 | CAS-2088184-66-9 | CAS-2088185-17-3 | CAS-2088185-76-4 |
| CAS-2088184-14-7 | CAS-2088184-67-0 | CAS-2088185-18-4 | CAS-2088185-77-5 |
| CAS-2088184-15-8 | CAS-2088184-68-1 | CAS-2088185-19-5 | CAS-2088185-78-6 |
| CAS-2088184-16-9 | CAS-2088184-69-2 | CAS-2088185-20-8 | CAS-2088185-79-7 |
| CAS-2088184-17-0 | CAS-2088184-70-5 | CAS-2088185-21-9 | CAS-2088185-80-0 |
| CAS-2088184-18-1 | CAS-2088184-71-6 | CAS-2088185-22-0 | CAS-2088185-81-1 |
| CAS-2088184-19-2 | CAS-2088184-72-7 | CAS-2088185-23-1 | CAS-2088185-82-2 |
| CAS-2088184-20-5 | CAS-2088184-73-8 | CAS-2088185-32-2 | CAS-2088185-83-3 |
| CAS-2088184-21-6 | CAS-2088184-74-9 | CAS-2088185-33-3 | CAS-2088185-84-4 |
| CAS-2088184-22-7 | CAS-2088184-75-0 | CAS-2088185-34-4 | CAS-2088185-85-5 |
| CAS-2088184-23-8 | CAS-2088184-76-1 | CAS-2088185-35-5 | CAS-2088185-86-6 |
| CAS-2088184-24-9 | CAS-2088184-77-2 | CAS-2088185-36-6 | CAS-2088185-87-7 |
| CAS-2088184-25-0 | CAS-2088184-78-3 | CAS-2088185-37-7 | CAS-2088185-88-8 |
| CAS-2088184-26-1 | CAS-2088184-79-4 | CAS-2088185-38-8 | CAS-2088185-89-9 |
| CAS-2088184-27-2 | CAS-2088184-80-7 | CAS-2088185-39-9 | CAS-2088185-90-2 |
| CAS-2088184-28-3 | CAS-2088184-81-8 | CAS-2088185-40-2 | CAS-2088185-91-3 |
| CAS-2088184-29-4 | CAS-2088184-82-9 | CAS-2088185-41-3 | CAS-2088185-92-4 |
| CAS-2088184-30-7 | CAS-2088184-83-0 | CAS-2088185-42-4 | CAS-2088185-93-5 |
| CAS-2088184-32-9 | CAS-2088184-84-1 | CAS-2088185-43-5 | CAS-2088185-94-6 |
| CAS-2088184-34-1 | CAS-2088184-85-2 | CAS-2088185-44-6 | CAS-2088185-95-7 |
| CAS-2088184-35-2 | CAS-2088184-86-3 | CAS-2088185-45-7 | CAS-2088185-96-8 |
| CAS-2088184-36-3 | CAS-2088184-87-4 | CAS-2088185-46-8 | CAS-2088185-97-9 |
| CAS-2088184-37-4 | CAS-2088184-88-5 | CAS-2088185-47-9 | CAS-2088185-98-0 |
| CAS-2088184-38-5 | CAS-2088184-89-6 | CAS-2088185-48-0 | CAS-2088185-99-1 |
| CAS-2088184-39-6 | CAS-2088184-90-9 | CAS-2088185-49-1 | CAS-2088186-00-7 |
| CAS-2088184-40-9 | CAS-2088184-91-0 | CAS-2088185-50-4 | CAS-2088186-01-8 |
| CAS-2088184-41-0 | CAS-2088184-92-1 | CAS-2088185-51-5 | CAS-2088186-02-9 |
| CAS-2088184-42-1 | CAS-2088184-93-2 | CAS-2088185-52-6 | CAS-2088195-88-2 |
| CAS-2088184-43-2 | CAS-2088184-94-3 | CAS-2088185-53-7 | CAS-2088195-89-3 |
| CAS-2088184-44-3 | CAS-2088184-95-4 | CAS-2088185-54-8 | CAS-2088195-90-6 |
| CAS-2088184-45-4 | CAS-2088184-96-5 | CAS-2088185-55-9 | CAS-2088195-91-7 |
| CAS-2088184-46-5 | CAS-2088184-97-6 | CAS-2088185-56-0 | CAS-861806-70-4 |
| CAS-2088184-47-6 | CAS-2088184-98-7 | CAS-2088185-57-1 | CAS-1269508-30-6 |
| CAS-2088184-48-7 | CAS-2088184-99-8 | CAS-2088185-58-2 | |
| CAS-2088184-49-8 | CAS-2088185-00-4 | CAS-2088185-59-3 | |
| CAS-2088184-50-1 | CAS-2088185-01-5 | CAS-2088185-60-6 | |
| CAS-2088184-51-2 | CAS-2088185-02-6 | CAS-2088185-61-7 | |
| CAS-2088184-52-3 | CAS-2088185-03-7 | CAS-2088185-62-8 | |
| CAS-2088184-53-4 | CAS-2088185-04-8 | CAS-2088185-63-9 | |
| CAS-2088184-54-5 | CAS-2088185-05-9 | CAS-2088185-64-0 | |
| CAS-2088184-55-6 | CAS-2088185-06-0 | CAS-2088185-65-1 | |

In the mixtures according to the invention or in the light-emitting layer of the device according to invention, each mixture M1, M2, M3, M4, M5, M6, M7, M8, M9, M10, M11, M12, M13, M14, M15, M16, M17, M18, M19, M20, M21, M22, M23, M24, M25, M26, M27, M28, M29, M30, M31, M32, M33, M34, M35, M36, M37, M38, M39, M40, M41, M42, M43, M44, M45, M46, M47, M48, M49, M50, M51, M52, M53, M54, M55, M56, M57, M58, M59, M60, M61, M62, M63, M64, M65, M66, M67, M68, M69, M70, M71, M72, M73, M74, M75, M76, M77, M78, M79, M80, M81, M82, M83, M84, M85, M86, M87, M88, M89, M90, M91, M92, M93, M94, M95, M96, M97, M98, M99, M100, M101, M102, M103, M104, M105, M106, M107, M108, M109, M110, M111, M112, M113, M114, M115, M116, M117, M118, M119, M120, M121, M122, M123, M124, M125, M126, M127, M128, M129, M130, M131, M132, M133, M134, M135, M136, M137, M138, M139, M140, M141, M142, M143, M144, M145, M146, M147, M148, M149, M150, M151, M152, M153, M154, M155, M156, M157, M158, M159, M160, M161, M162, M163, M164, M165, M166, M167, M168, M169, M170, M171, M172, M173, M174, M175, M176, M177, M178, M179, M180, M181, M182, M183, M184, M185, M186, M187, M188, M189, M190, M191, M192, M193, M194, M195, M196, M197, M198, M199, M200, M201, M202, M203, M204, M205, M206, M207, M208, M209, M210, M211, M212, M213, M214, M215, M216, M217, M218, M219, M220, M221, M222, M223, M224, M225, M226, M227, M228, M229, M230, M231, M232, M233, M234, M235, M236, M237, M238, M239, M240, M241, M242, M243, M244, M245, M246, M247, M248, M249, M250, M251, M252, M253, M254, M255, M256, M257, M258, M259, M260, M261, M262, M263, M264, M265, M266, M267, M268, M269, M270, M271, M272, M273, M274, M275, M276, M277, M278, M279, M280, M281, M282, M283, M284, M285, M286, M287, M288, M289, M290, M291, M292, M293, M294, M295, M296, M297, M298, M299, M300, M301, M302, M303, M304, M305, M306, M307, M308, M309, M310, M311, M312, M313, M314, M315, M316, M317, M318, M319, M320, M321, M322, M323, M324, M325, M326, M327, M328, M329, M330, M331, M332, M333, M334, M335, M336, M337, M338, M339, M340, M341, M342, M343, M344, M345, M346, M347, M348, M349, M350, M351, M352, M353, M354, M355, M356, M357, M358, M359, M360, M361, M362, M363, M364, M365, M366, M367, M368, M369, M370, M371, M372, M373, M374, M375, M376, M377, M378, M379, M380, M381, M382, M383, M384, M385, M386, M387, M388, M389, M390, M391, M392, M393, M394, M395, M396, M397, M398, M399, M400, M401, M402, M403, M404, M405, M406, M407, M408, M409, M410, M411, M412, M413, M414, M415, M416, M417, M418, M419, M420, M421, M422, M423, M424, M425, M426, M427, M428, M429, M430, M431, M432, M433, M434, M435, M436, M437, M438, M439, M440, M441, M442, M443, M444, M445, M446, M447, M448, M449, M450, M451, M452, M453, M454, M455, M456, M457, M458, M459, M460, M461, M462, M463, M464, M465, M466, M467, M468, M469, M470, M471, M472, M473, M474, M475, M476, M477, M478, M479, M480, M481, M482, M483, M484, M485, M486, M487, M488, M489, M490, M491, M492, M493, M494, M495, M496, M497, M498, M499, M500, M501, M502, M503, M504, M505, M506, M507, M508, M509, M510, M511, M512, M513, M514, M515, M516, M517, M518, M519, M520, M521, M522, M523, M524, M525, M526, M527, M528, M529, M530, M531, M532, M533, M534, M535, M536, M537, M538, M539, M540, M541, M542, M543, M544, M545, M546, M547, M548, M549, M550, M551, M552, M553, M554, M555, M556, M557, M558, M559, M560, M561, M562, M563, M564, M565, M566, M567, M568, M569, M570, M571, M572, M573, M574, M575, M576, M577, M578, M579, M580, M581, M582, M583, M584, M585, M586, M587, M588, M589, M590, M591, M592, M593, M594, M595, M596, M597, M598, M599, M600, M601, M602, M603, M604, M605, M606, M607, M608, M609, M610, M611, M612, M613, M614, M615, M616, M617, M618, M619, M620, M621, M622, M623, M624, M625, M626, M627, M628, M629, M630, M631, M632, M633, M634, M635, M636, M637, M638, M639, M640, M641, M642, M643, M644, M645, M646, M647, M648 is preferably combined with a compound of the formula (3) or a compound from Table 4 or 5.

The light-emitting layer in the organic electroluminescent device according to the invention comprising at least one phosphorescent emitter is preferably an infrared-, yellow-, orange-, red-, green-, blue- or ultraviolet-emitting layer, particularly preferably a yellow- or green-emitting layer and very particularly preferably a green-emitting layer.

A yellow-emitting layer here is taken to mean a layer whose photoluminescence maximum is in the range from 540 to 570 nm. An orange-emitting layer is taken to mean a layer whose photoluminescence maximum is in the range from 570 to 600 nm. A red-emitting layer is taken to mean a layer whose photoluminescence maximum is in the range from 600 to 750 nm. A green-emitting layer is taken to mean a layer whose photoluminescence maximum is in the range from 490 to 540 nm. A blue-emitting layer is taken to mean a layer whose photoluminescence maximum is in the range from 440 to 490 nm. The photoluminescence of the layer is determined here by measurement of the photoluminescence spectrum of the layer having a layer thickness of 50 nm at room temperature, where the layer comprises the combination according to the invention of the host materials of the formulae (1) and (2) and the corresponding emitter.

The photoluminescence spectrum of the layer is recorded, for example, using a commercially available photoluminescence spectrometer.

The photoluminescence spectrum of the selected emitter is generally measured in oxygen-free solution, 10-5 molar, where the measurement is carried out at room temperature and any solvent in which the selected emitter dissolves in the said concentration is suitable. Particularly suitable solvents are usually toluene or 2-methyl-THF, but also dichloromethane. The measurement is carried out using a commercially available photoluminescence spectrometer. The triplet energy T₁ in eV is determined from the photoluminescence spectra of the emitters. Firstly the peak maximum PImax. (in nm) of the photoluminescence spectrum is determined. The peak maximum PImax. (in nm) is then converted into in eV in accordance with: E(T1 in eV)=1240/E(T1 in nm)=1240/PImax. (in nm).

Preferred phosphorescent emitters are accordingly infrared emitters, whose triplet energy T₁ is preferably ˜1.9 eV to ˜1.0 eV.

Preferred phosphorescent emitters are accordingly red emitters, preferably of the formula (3) or from Table 4 or 5, whose triplet energy T₁ is preferably ˜2.1 eV to ˜1.9 eV.

Preferred phosphorescent emitters are accordingly yellow emitters, preferably of the formula (3) or from Table 4 or 5, whose triplet energy T₁ is preferably ˜2.3 eV to ˜2.1 eV.

Preferred phosphorescent emitters are accordingly green emitters, preferably of the formula (3) or from Table 4 or 5, whose triplet energy T₁ is preferably ˜2.5 eV to ˜2.3 eV.

Preferred phosphorescent emitters are accordingly blue emitters, preferably of the formula (3) or from Table 4 or 5, whose triplet energy T₁ is preferably ˜3.1 eV to ˜2.5 eV.

Preferred phosphorescent emitters are accordingly ultraviolet emitters, preferably of the formula (3) or from Table 4 or 5, whose triplet energy T₁ is preferably ˜4.0 eV to ˜3.1 eV.

Particularly preferred phosphorescent emitters are accordingly green or yellow emitters, preferably of the formula (3) or from Table 4 or 5, as described above.

Very particularly preferred phosphorescent emitters are accordingly green emitters, preferably of the formula (3) or from Table 4 or 5, whose triplet energy T₁ is preferably ˜2.5 eV to ˜2.3 eV.

Green emitters, preferably of the formula (3) or from Table 4 or 5, as described above, are very particularly preferably selected for the composition according to the invention or the emitting layer according to the invention.

The light-emitting layer of the device according to the invention may also comprise fluorescent emitters.

Preferred fluorescent emitters are selected from the class of the arylamines. An arylamine or aromatic amine in the sense of this invention is taken to mean a compound which contains three substituted or unsubstituted aromatic or heteroaromatic ring systems bonded directly to the nitrogen.

At least one of these aromatic or heteroaromatic ring systems is preferably a condensed ring system, particularly preferably having at least 14 aromatic ring atoms. Preferred examples thereof are aromatic anthracenamines, aromatic anthracenediamines, aromatic pyrenamines, aromatic pyrenediamines, aromatic chrysenamines or aromatic chrysenediamines. An aromatic anthracenamine is taken to mean a compound in which one diarylamino group is bonded directly to an anthracene group, preferably in the 9 position. An aromatic anthracenediamine is taken to mean a compound in which two diarylamino groups are bonded directly to an anthracene group, preferably in the 9,10 position. Aromatic pyrenamines, pyrenediamines, chrysenamines and chrysenediamines are defined analogously thereto, where the diarylamino groups are preferably bonded to the pyrene in the 1 position or in the 1,6 position. Further preferred fluorescent emitters are indenofluorenamines or indenofluorenediamines, for example in accordance with WO 2006/108497 or WO 2006/122630, benzoindenofluorenamines or benzoindenofluorenediamines, for example in accordance with WO 2008/006449, and dibenzoindenofluorenamines or dibenzoindenofluorenediamines, for example in accordance with WO 2007/140847, and the indenofluorene derivatives containing condensed aryl groups that are disclosed in WO 2010/012328.

In a further preferred embodiment of the invention, the at least one light-emitting layer of the organic electroluminescent device may, besides host materials 1 and 2, as described above or as preferably described, comprise further host materials or matrix materials, so-called mixed-matrix systems. The mixed-matrix systems preferably comprise three or four different matrix materials, particularly preferably three different matrix materials (i.e. a further matrix component in addition to host materials 1 and 2, as described above). Particularly suitable matrix materials which can be used in combination as matrix component of a mixed-matrix system are selected from wide bandgap materials, bipolar host materials, electron-transport materials (ETMs) and hole-transport materials (HTMs).

A wide bandgap material herein is taken to mean a material in the sense of the disclosure of U.S. Pat. No. 7,294,849, which is characterised by a band gap of at least 3.5 eV, where band gap is taken to mean the separation between the HOMO and LOMO energies of a material.

More precise details on mixed-matrix systems are given, inter alia, in the application WO 2010/108579. Particularly suitable matrix materials which can be employed in combination with host materials 1 and 2, as described or preferably described above, as matrix components of a mixed-matrix system in phosphorescent or fluorescent organic electroluminescent devices are selected from the preferred matrix materials indicated below for phosphorescent emitters or the preferred matrix materials for fluorescent emitters, depending on what type of emitter is employed. The mixed-matrix system is preferably optimised for an emitter of the formula (3) or from Table 4 or 5.

Suitable further host materials, preferably for fluorescent emitters, besides host materials 1 and 2, in the device according to the invention, as described above, particularly preferably comprising the combination of host materials selected from M1 to M648, are various classes of substance. Preferred further host materials are selected from the classes of the oligoarylenes (for example 2,2′,7,7′-tetraphenylspirobifluorene in accordance with EP 676461 or dinaphthylanthracene), in particular the oligoarylenes containing condensed aromatic groups, the oligoarylenevinylenes (for example DPVBi or spiro-DPVBi in accordance with EP 676461), the polypodal metal complexes (for example in accordance with WO 2004/081017), the hole-conducting compounds (for example in accordance with WO 2004/058911), the electron-conducting compounds, in particular ketones, phosphine oxides, sulfoxides, etc. (for example in accordance with WO 2005/084081 and WO 2005/084082), the atropisomers (for example in accordance with WO 2006/048268), the boronic acid derivatives (for example in accordance with WO 2006/117052) or the benzanthracenes (for example in accordance with WO 2008/145239). Particularly preferred matrix materials are selected from the classes of the oligoarylenes, containing naphthalene, anthracene, benzanthracene and/or pyrene or atropisomers of these compounds, the oligoarylenevinylenes, the ketones, the phosphine oxides and the sulfoxides. Very particularly preferred matrix materials are selected from the classes of the oligoarylenes, containing anthracene, benzanthracene, benzophenanthrene and/or pyrene or atropisomers of these compounds. An oligoarylene in the sense of this invention is intended to be taken to mean a compound in which at least three aryl or arylene groups are bonded to one another.

Suitable further matrix materials, preferably for phosphorescent emitters, besides host materials 1 and 2, in the device according to the invention, as described above, particularly preferably comprising the combination of host materials selected from M1 to M648, as described above, are the following classes of compound: aromatic amines, in particular triarylamines, for example in accordance with US 2005/0069729, carbazole derivatives (for example CBP, N,N-biscarbazolylbiphenyl) or compounds in accordance with WO 2005/039246, US 2005/0069729, JP 2004/288381, EP 1205527 or WO 2008/086851, bridged carbazole derivatives, for example in accordance with WO 2011/088877 and WO 2011/128017, indenocarbazole derivatives, for example in accordance with WO 2010/136109 and WO 2011/000455, azacarbazole derivatives, for example in accordance with EP 1617710, EP 1617711, EP 1731584, JP 2005/347160, indolocarbazole derivatives, for example in accordance with WO 2007/063754 or WO 2008/056746, ketones, for example in accordance with WO 2004/093207 or WO 2010/006680, phosphine oxides, sulfoxides and sulfones, for example in accordance with WO 2005/003253, oligophenylenes, bipolar matrix materials, for example in accordance with WO 2007/137725, silanes, for example in accordance with WO 2005/111172, azaboroles or boronic esters, for example in accordance with WO 2006/117052, triazine derivatives, for example in accordance with WO 2010/015306, WO 2007/063754 or WO 2008/056746, zinc complexes, for example in accordance with EP 652273 or WO 2009/062578, aluminium complexes, for example BAlq, diazasilole and tetraazasilole derivatives, for example in accordance with WO 2010/054729, diazaphosphole derivatives, for example in accordance with WO 2010/054730, and aluminium complexes, for example BAlQ.

According to an embodiment of the present invention, the mixture comprises no further constituents, i.e. functional materials, besides the constituents electron-transporting host material of the formula (1) and hole-transporting host material of the formula (2). These are material mixtures which are used as such for the production of the light-emitting layer. These mixtures are also called premix systems, which are used as the sole material source during vapour deposition of the host materials for the light-emitting layer and have a constant mixing ratio during vapour deposition. This enables the vapour deposition of a layer with uniform distribution of the components to be achieved in a simple and rapid manner without precise control of a multiplicity of material sources being necessary.

According to an alternative embodiment of the present invention, the mixture also comprises the phosphorescent emitter, as described above, besides the constituents electron-transporting host material of the formula (1) and hole-transporting host material of the formula (2). Given a suitable mixing ratio during vapour deposition, this mixture can also be used as the sole material source, as described above.

The components or constituents of the light-emitting layer of the device according to the invention can thus be processed by vapour deposition or from solution. To this end, the material combination of host materials 1 and 2, as described or preferably described above, optionally with the phosphorescent emitter, as described or preferably described above, are provided in a formulation which comprises at least one solvent. These formulations can be, for example, solutions, dispersions or emulsions. It may be preferred to use mixtures of two or more solvents for this purpose.

The present invention therefore furthermore relates to a formulation comprising a mixture according to the invention of host materials 1 and 2, as described above, optionally in combination with a phosphorescent emitter, as described or preferably described above, and at least one solvent.

Suitable and preferred solvents are, for example, toluene, anisole, o-, m- or p-xylene, methyl benzoate, mesitylene, tetralin, veratrol, THF, methyl-THF, THP, chlorobenzene, dioxane, phenoxytoluene, in particular 3-phenoxytoluene, (−)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclohexanol, cyclohexanone, cyclohexylbenzene, decalin, dodecylbenzene, ethyl benzoate, indane, methyl benzoate, NMP, p-cymene, phenetol, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)ethane, hexamethylindane or mixtures of these solvents.

The formulation here may also comprise at least one further organic or inorganic compound, which is likewise employed in the light-emitting layer of the device according to the invention, in particular a further emitting compound and/or a further matrix material. Suitable emitting compounds and further matrix materials have already been indicated above.

The light-emitting layer in the device according to the invention in accordance with the preferred embodiments and the emitting compound preferably comprises between 99.9 and 1% by vol., further preferably between 99 and 10% by vol., particularly preferably between 98 and 60% by vol., very particularly preferably between 97 and 80% by vol., of matrix material comprising at least one compound of the formula (1) and at least one compound of the formula (2) in accordance with the preferred embodiments, based on the entire composition comprising emitter and matrix material. Correspondingly, the light-emitting layer in the device according to the invention preferably comprises between 0.1 and 99% by vol., further preferably between 1 and 90% by vol., particularly preferably between 2 and 40% by vol., very particularly preferably between 3 and 20% by vol., of the emitter, based on the entire composition of the light-emitting layer consisting of emitter and matrix material. If the compounds are processed from solution, the corresponding amounts in % by weight are preferably used instead of the above-mentioned amounts in % by vol.

The light-emitting layer in the device according to the invention in accordance with the preferred embodiments and the emitting compound preferably comprises the matrix material of the formula (1) and the matrix material of the formula (2) in a volume percent ratio between 3:1 and 1:3, preferably between 1:2.5 and 1:1, particularly preferably between 1:2 and 1:1. If the compounds are processed from solution, the corresponding ratio in % by weight is preferably used instead of the above-mentioned ratio in % by vol.

The sequence of the layers in the organic electroluminescent device according to the invention is preferably the following: anode/hole-injection layer/hole-transport layer/emitting layer/electron-transport layer/electron-injection layer/cathode.

This sequence of the layers is a preferred sequence.

It should again be pointed out here that not all of the said layers have to be present, and/or that further layers may additionally be present.

The organic electroluminescent device according to the invention may comprise a plurality of emitting layers. At least one of the emitting layers is the light-emitting layer according to the invention comprising at least one compound of the formula (1) as host material 1 and at least one compound of the formula (2) as host material 2, as described above. These emission layers in this case particularly preferably have in total a plurality of emission maxima between 380 nm and 750 nm, resulting overall in white emission, i.e. various emitting compounds which are able to fluoresce or phosphoresce and which emit blue or yellow or orange or red light are used in the emitting layers. Particular preference is given to three-layer systems, i.e. systems having three emitting layers, where the three layers exhibit blue, green and orange or red emission (for the basic structure see, for example, WO 2005/011013). It should be noted that, for the generation of white light, one emitter compound used individually which emits in a broad wavelength range may also be suitable instead of a plurality of emitter compounds emitting in colour.

Suitable charge-transport materials, as can be used in the hole-injection or hole-transport layer or electron-blocking layer or in the electron-transport layer of the organic electroluminescent device according to the invention, are, for example, the compounds disclosed in Y. Shirota et al., Chem. Rev. 2007, 107(4), 953-1010 or other materials as are employed in accordance with the prior art in these layers.

Materials which can be used for the electron-transport layer are all materials as are used in accordance with the prior art as electron-transport materials in the electron-transport layer. Particularly suitable are aluminium complexes, for example Alq₃, zirconium complexes, for example Zrq₄, benzimidazole derivatives, triazine derivatives, pyrimidine derivatives, pyridine derivatives, pyrazine derivatives, quinoxaline derivatives, quinoline derivatives, oxadiazole derivatives, aromatic ketones, lactams, boranes, diazaphosphole derivatives and phosphine oxide derivatives. Furthermore suitable materials are derivatives of the above-mentioned compounds, as disclosed in JP 2000/053957, WO 2003/060956, WO 2004/028217, WO 2004/080975 and WO 2010/072300.

Preferred hole-transport materials are, in particular, materials which can be used in a hole-transport, hole-injection or electron-blocking layer, such as indenofluorenamine derivatives (for example in accordance with WO 06/122630 or WO 06/100896), the amine derivatives disclosed in EP 1661888, hexaazatriphenylene derivatives (for example in accordance with WO 01/049806), amine derivatives containing condensed aromatic rings (for example in accordance with U.S. Pat. No. 5,061,569), the amine derivatives disclosed in WO 95/09147, monobenzoindenofluorenamines (for example in accordance with WO 08/006449), dibenzoindenofluorenamines (for example in accordance with WO 07/140847), spirobifluorenamines (for example in accordance with WO 2012/034627 or the as yet unpublished EP 12000929.5), fluorenamines (for example in accordance with WO 2014/015937, WO 2014/015938 and WO 2014/015935), spirodibenzopyranamines (for example in accordance with WO 2013/083216) and dihydroacridine derivatives (for example in accordance with WO 2012/150001).

Suitable as cathode of the device according to the invention are metals having a low work function, metal alloys or multilayered structures comprising various metals, such as, for example, alkaline-earth metals, alkali metals, main-group metals or lanthanoids (for example Ca, Ba, Mg, Al, In, Mg, Yb, Sm, etc.). Also suitable are alloys comprising an alkali metal or alkaline-earth metal and silver, for example an alloy comprising magnesium and silver. In the case of multilayered structures, further metals which have a relatively high work function, such as, for example, Ag or Al, can also be used in addition to the said metals, in which case combinations of the metals, such as, for example, Ca/Ag, Mg/Ag or Ba/Ag, are generally used. It may also be preferred to introduce a thin interlayer of a material having a high dielectric constant between a metallic cathode and the organic semiconductor. Suitable for this purpose are, for example, alkali metal fluorides or alkaline-earth metal fluorides, but also the corresponding oxides or carbonates (for example LiF, Li₂O, BaF₂, MgO, NaF, CsF, Cs₂CO₃, etc.). Furthermore, lithium quinolinate (LiQ) can be used for this purpose. The layer thickness of this layer is preferably between 0.5 and 5 nm.

The anode preferably comprises materials having a high work function. The anode preferably has a work function of greater than 4.5 eV vs. vacuum. Suitable for this purpose are on the one hand metals having a high redox potential, such as, for example, Ag, Pt or Au. On the other hand, metal/metal oxide electrodes (for example Al/Ni/NiOₓ, Al/PtOₓ) may also be preferred. For some applications, at least one of the electrodes must be transparent or partially transparent in order to facilitate either irradiation of the organic material (organic solar cells) or the coupling-out of light (OLEDs, O-lasers). Preferred anode materials here are conductive mixed metal oxides. Particular preference is given to indium tin oxide (ITO) or indium zinc oxide (IZO). Preference is furthermore given to conductive, doped organic materials, in particular conductive doped polymers. Furthermore, the anode may also consist of a plurality of layers, for example of an inner layer of ITO and an outer layer of a metal oxide, preferably tungsten oxide, molybdenum oxide or vanadium oxide.

During production, the organic electroluminescent device according to the invention is appropriately (depending on the application) structured, provided with contacts and finally sealed, since the lifetime of the devices according to the invention is shortened in the presence of water and/or air.

The production of the device according to the invention is not restricted here. It is possible for one or more organic layers, including the light-emitting layer, to be applied by means of a sublimation process, in which the materials are applied by vapour deposition in vacuum sublimation units at an initial pressure of less than 10⁻⁵ mbar, preferably less than 10⁻⁶ mbar. However, it is also possible here for the initial pressure to be even lower, for example less than 10⁻⁷ mbar.

The organic electroluminescent device according to the invention is preferably characterised in that one or more layers are applied by means of the OVPD (organic vapour phase deposition) process or with the aid of carrier-gas sublimation, in which the materials are applied at a pressure of between 10˜5 mbar and 1 bar. A special case of this process is the OVJP (organic vapour jet printing) process, in which the materials are applied directly through a nozzle and are thus structured (for example M. S. Arnold et al., Appl. Phys. Lett. 2008, 92, 053301).

The organic electroluminescent device according to the invention is furthermore preferably characterised in that one or more organic layers comprising the composition according to the invention are produced from solution, such as, for example, by spin coating, or by means of any desired printing process, such as, for example, screen printing, flexographic printing, nozzle printing or offset printing, but particularly preferably LITI (light induced thermal imaging, thermal transfer printing) or ink-jet printing. Soluble host materials 1 and 2 and phosphorescent emitters are necessary for this purpose. Processing from solution has the advantage that, for example, the light-emitting layer can be applied very simply and inexpensively. This technique is suitable, in particular, for the mass production of organic electroluminescent devices.

Also possible are hybrid processes, in which, for example, one or more layers are applied from solution and one or more further layers are applied by vapour deposition.

These processes are generally known to the person skilled in the art and can be applied to organic electroluminescent devices.

The invention therefore furthermore relates to a process for the production of the organic electroluminescent device according to the invention, as described or preferably described above, characterised in that the light-emitting layer is applied by gas-phase deposition, in particular by means of a sublimation process and/or by means of an OVPD (organic vapour phase deposition) process and/or with the aid of carrier-gas sublimation, or from solution, in particular by spin coating or by means of a printing process.

In the case of production by means of gas-phase deposition, there are basically two possibilities for how the light-emitting layer according to the invention can be applied or vapour-deposited onto any desired substrate or the prior layer. On the one hand, the materials used may each be present in one material source and finally evaporated out of the various material sources (“co-evaporation”). On the other hand, the various materials can be premixed (premix systems) and the mixture presented in a single material source, from which it is finally evaporated (“premix evaporation”). This enables the vapour-deposition of the light-emitting layer with uniform distribution of the components to be achieved in a simple and rapid manner without precise control of a multiplicity of material sources being necessary.

Accordingly, the invention furthermore relates to a process for the production of the device according to the invention, characterised in that the at least one compound of the formula (1), as described above or as preferably described, and the at least one compound of the formula (2), as described above or as preferably described, are deposited from the gas phase successively or simultaneously from at least two material sources, optionally with the at least one phosphorescent emitter, as described or preferably described above, and form the light-emitting layer.

In a preferred embodiment of the present invention, the light-emitting layer is applied by means of gas-phase deposition, where the constituents of the composition are premixed and evaporated from a single material source.

Accordingly, the invention furthermore relates to a process for the production of the device according to the invention, characterised in that the at least one compound of the formula (1) and the at least one compound of formula (2) are deposited from the gas phase as a mixture, successively or simultaneously with the at least one phosphorescent emitter, and form the light-emitting layer.

The invention furthermore relates to a process for the production of the device according to the invention, as described or preferably described above, characterised in that the at least one compound of the formula (1) and the at least one compound of the formula (2), as described or preferably described above, are applied from solution together with the at least one phosphorescent emitter in order to form the light-emitting layer.

The devices according to the invention are distinguished by the following surprising advantages over the prior art:

The use of the material combination described of host materials 1 and 2, as described above, leads, in particular, to an increase in the lifetime of the devices.

As can be seen in the example given below, it can be observed by comparison of the data for OLEDs with combinations from the prior art that the combinations according to the invention of matrix materials in the EML lead to devices whose lifetimes are increased by about 30 to 70%, irrespective of the emitter concentration.

It should be pointed out that variations of the embodiments described in the present invention fall within the scope of this invention. Each feature disclosed in the present invention can, unless this is explicitly excluded, be replaced by alternative features which serve the same, an equivalent or a similar purpose. Thus, each feature disclosed in the present invention is, unless stated otherwise, to be regarded as an example of a generic series or as an equivalent or similar feature.

All features of the present invention can be combined with one another in any way, unless certain features and/or steps are mutually exclusive. This applies, in particular, to preferred features of the present invention. Equally, features of non-essential combinations can be used separately (and not in combination).

The teaching regarding technical action disclosed with the present invention can be abstracted and combined with other examples.

The invention is explained in greater detail by the following examples without wishing to restrict it thereby.

General Methods:

In all quantum-chemical calculations, the Gaussian16 (Rev. B.01) software package is used. The neutral singlet ground state is optimised to the B3LYP/6-31G(d) level. HOMO und LUMO values are determined at the B3LYP/6-31G(d) level for the ground state energy optimised with B3LYP/6-31G(d). TD-DFT singlet and triplet excitations (vertical excitations) are then calculated using the same method (B3LYP/6-31G(d)) and the optimised ground state geometry is calculated. The standard settings for SCF and gradient convergence are used.

The energy calculation gives the HOMO as the last orbital occupied by two electrons (Alpha occ. eigenvalues) and LUMO as the first unoccupied orbital (alpha virt. eigenvalues) in hartree units, where HEh and LEh stand for the HOMO energy in hartree units and the LUMO energy in hartree units respectively. The HOMO and LUMO values in electron volts calibrated with reference to cyclic voltammetry measurements are determined thereform as follows:

HOMOcorr=0.90603*HOMO−0.84836

LUMOcorr=0.99687*LUMO−0.72445

The triplet level T1 of a material is defined as the relative excitation energy (in eV) of the triplet state having the lowest energy which arises from the quantum-chemical energy calculation.

The singlet level S1 is defined as the relative excitation energy (in eV) of the singlet state having the second lowest energy which arises from the quantum-chemical energy calculation.

The singlet state of lowest energy is called S0.

The method described herein is independent of the software package used and always gives the same results. Examples of frequently used programs for this purpose are “Gaussian09” (Gaussian Inc.) and Q-Chem 4.1 (Q-Chem, Inc.). In the present application, the “Gaussian16, Rev. B.01” software package is used for the calculation of the energies.

### EXAMPLE 1: PRODUCTION OF THE OLEDS

The use of the material combinations according to the invention in OLEDs compared with material combinations from the prior art is presented in Examples V1 to Ex28 below (see Tables 6 and 7).

Pretreatment for Examples V1 to Ex28: Glass plates coated with structured ITO (indium tin oxide) in a thickness of 50 nm are, before coating, treated firstly with an oxygen plasma, followed by an argon plasma. These plasma-treated glass plates form the substrates to which the OLEDs are applied.

The OLEDs have basically the following layer structure: substrate/hole-injection layer (HIL)/hole-transport layer (HTL)/electron-blocking layer (EBL)/emission layer (EML)/optional hole-blocking layer (HBL)/electron-transport layer (ETL)/optional electron-injection layer (EIL) and finally a cathode. The cathode is formed by an aluminium layer with a thickness of 100 nm. The precise structure of the OLEDs is shown in Table 6. The materials required for the production of the OLEDs are shown in Table 8. The device data of the OLEDs are listed in Table 7.

Examples V1, V2 und V3 are comparative examples with a hole-transporting host in accordance with the prior art WO2017/178311. Examples Ex1, Ex2 and Ex3 use corresponding material combinations according to the invention in the EML.

Examples V4 and V5 are comparative examples for the OLED according to the invention of Example Ex4 and Examples V6 and V7 are comparative examples for the OLED according to the invention of Example Ex5 with symmetrically substituted electron-transporting host materials in accordance with the prior art. Compound VG1 is derived, for example, from US2016329502. Compound VG2 is described, for example, in US20140299192.

Examples Ex6 to Ex28 likewise show data of OLEDs according to the invention.

All materials are applied by thermal vapour deposition in a vacuum chamber. The emission layer here always consists of at least one matrix material (also host material), in the sense of the invention at least two matrix materials, and an emitting dopant (emitter), which is admixed with the matrix material or matrix materials in a certain proportion by volume by co-evaporation. An expression such as E1:IC3:TEG1 (33%:60%:7%) here means that material E1 is present in the layer in a proportion by volume of 33% as host material 1, compound IC3 as host material 2 is present in a proportion of 60% and TEG1 is present in a proportion of 7% in a layer with a thickness of 30 nm. Analogously, the electron-transport layer may also consist of a mixture of two materials.

The OLEDs are characterised by standard methods. For this purpose, the electroluminescence spectra and current/voltage/luminous density characteristic lines (IUL characteristic lines) are measured. EQE and the current efficiency CE (in cd/A) are calculated therefrom. The calculation of the CE is carried out assuming Lambert emission characteristics.

The lifetime LT is defined as the time after which the luminous density on operation with constant current density j0 in mA/cm² drops from an initial luminous density L0 (in cd/m²) to a certain proportion L1 (in cd/m²). An expression L1/L0=80% in Table 7 means that the lifetime indicated in column LT corresponds to the time (in h) after which the luminous density drops to 80% of its initial value (L0).

### Use of Mixtures According to the Invention in OLEDs

The material combinations according to the invention can be employed in the emission layer in phosphorescent green OLEDs. The combinations according to the invention of compounds E1 to E16 compounds BC1 to BC17 are employed in Examples Ex1 and Ex28 as matrix material in the emission layer, as described in Table 6.

On comparison of the examples according to the invention with the corresponding comparative examples (see above), it is clearly evident that the examples according to the invention in each case exhibit a clear advantage in the device lifetime.

TABLE 6
Structure of the OLEDs

| | HTL | IL | EBL | | HBL | | EIL |
|---|---|---|---|---|---|---|---|
| | Thick- | Thick- | Thick- | EML | Thick- | ETL | Thick- |
| Ex. | ness | ness | ness | Thickness | ness | Thickness | ness |
| V1 | HTCN | SpMA1 | SpMA2 | E1:IC3:TEG1 | ST2 | ST2:LiQ | LiQ |
| | 5 nm | 230 nm | 20 nm | (33%:60%:7%) 30 nm | 10 nm | (50%:50%) 30 nm | 1 nm |
| Ex1 | HTCN | SpMA1 | SpMA2 | E1:BC1:TEG1 | ST2 | ST2:LiQ | LiQ |
| | 5 nm | 230 nm | 20 nm | (33%:60%:7%) 30 nm | 10 nm | (50%:50%) 30 nm | 1 nm |
| V2 | HTCN | SpMA1 | SpMA2 | E1:IC3:TEG2 | ST2 | ST2:LiQ | LiQ |
| | 5 nm | 230 nm | 20 nm | (28%:60%:12%) 40 nm | 5 nm | (50%:50%) 30 nm | 1 nm |
| Ex2 | HTCN | SpMA1 | SpMA2 | E1:BC1:TEG2 | ST2 | ST2:LiQ | LiQ |
| | 5 nm | 230 nm | 20 nm | (28%:60%:12%) 40 nm | 5 nm | (50%:50%) 30 nm | 1 nm |
| V3 | HTCN | SpMA1 | SpMA2 | E1:IC3:TEG3 | ST2 | ST2:LiQ | LiQ |
| | 5 nm | 230 nm | 20 nm | (33%:60%:7%) 40 nm | 5 nm | (50%:50%) 30 nm | 1 nm |
| Ex3 | HTCN | SpMA1 | SpMA2 | E1:BC1:TEG3 | ST2 | ST2:LiQ | LiQ |
| | 5 nm | 230 nm | 20 nm | (33%:60%:7%) 40 nm | 5 nm | (50%:50%) 30 nm | 1 nm |
| V4 | HTCN | SpMA1 | SpMA2 | VG1:BC2:TEG3 | ST2 | ST2:LiQ | LiQ |
| | 5 nm | 230 nm | 20 nm | (38%:50%:12%) 40 nm | 5 nm | (50%:50%) 30 nm | 1 nm |
| V5 | HTCN | SpMA1 | SpMA2 | VG2:BC2:TEG3 | ST2 | ST2:LiQ | LiQ |
| | 5 nm | 230 nm | 20 nm | (38%:50%:12%) 40 nm | 5 nm | (50%:50%) 30 nm | 1 nm |
| Ex4 | HTCN | SpMA1 | SpMA2 | E1:BC2:TEG3 | ST2 | ST2:LiQ | LiQ |
| | 5 nm | 230 nm | 20 nm | (38%:50%:12%) 40 nm | 5 nm | (50%:50%) 30 nm | 1 nm |
| V6 | HTCN | SpMA1 | SpMA2 | VG1:BC3:TEG3 | ST2 | ST2:LiQ | LiQ |
| | 5 nm | 230 nm | 20 nm | (38%:50%:12%) 40 nm | 5 nm | (50%:50%) 30 nm | 1 nm |
| V7 | HTCN | SpMA1 | SpMA2 | VG2:BC3:TEG3 | ST2 | ST2:LiQ | LiQ |
| | 5 nm | 230 nm | 20 nm | (38%:50%:12%) 40 nm | 5 nm | (50%:50%) 30 nm | 1 nm |
| Ex5 | HTCN | SpMA1 | SpMA2 | E1:BC3:TEG3 | ST2 | ST2:LiQ | LiQ |
| | 5 nm | 230 nm | 20 nm | (38%:50%:12%) 40 nm | 5 nm | (50%:50%) 30 nm | 1 nm |
| Ex6 | HTCN | SpMA1 | SpMA2 | E1:BC4:TEG3 | ST2 | ST2:LiQ | LiQ |
| | 5 nm | 230 nm | 20 nm | (33%:60%:7%) 40 nm | 5 nm | (50%:50%) 30 nm | 1 nm |
| Ex7 | HTCN | SpMA1 | SpMA2 | E2:BC3:TEG3 | ST2 | ST2:LiQ | LiQ |
| | 5 nm | 230 nm | 20 nm | (33%:60%:7%) 40 nm | 5 nm | (50%:50%) 30 nm | 1 nm |
| Ex8 | HTCN | SpMA1 | SpMA2 | E2:BC4:TEG3 | ST2 | ST2:LiQ | LiQ |
| | 5 nm | 230 nm | 20 nm | (33%:60%:7%) 40 nm | 5 nm | (50%:50%) 30 nm | 1 nm |
| Ex9 | HTCN | SpMA1 | SpMA2 | E3:BC5:TEG3 | ST2 | ST2:LiQ | LiQ |
| | 5 nm | 230 nm | 20 nm | (33%:60%:7%) 40 nm | 5 nm | (50%:50%) 30 nm | 1 nm |
| Ex10 | HTCN | SpMA1 | SpMA2 | E3:BC7:TEG3 | ST2 | ST2:LiQ | LiQ |
| | 5 nm | 230 nm | 20 nm | (33%:60%:7%) 40 nm | 5 nm | (50%:50%) 30 nm | 1 nm |
| Ex11 | HTCN | SpMA1 | SpMA2 | E4:BC6:TEG3 | ST2 | ST2:LiQ | LiQ |
| | 5 nm | 230 nm | 20 nm | (33%:60%:7%) 40 nm | 5 nm | (50%:50%) 30 nm | 1 nm |
| Ex12 | HTCN | SpMA1 | SpMA2 | E4:BC8:TEG3 | ST2 | ST2:LiQ | LiQ |
| | 5 nm | 230 nm | 20 nm | (33%:60%:7%) 40 nm | 5 nm | (50%:50%) 30 nm | 1 nm |
| Ex13 | HTCN | SpMA1 | SpMA2 | E5:BC1:TEG3 | ST2 | ST2:LiQ | LiQ |
| | 5 nm | 230 nm | 20 nm | (33%:60%:7%) 40 nm | 5 nm | (50%:50%) 30 nm | 1 nm |
| Ex14 | HTCN | SpMA1 | SpMA2 | E5:BC9:TEG3 | ST2 | ST2:LiQ | LiQ |
| | 5 nm | 230 nm | 20 nm | (33%:60%:7%) 40 nm | 5 nm | (50%:50%) 30 nm | 1 nm |
| Ex15 | HTCN | SpMA1 | SpMA2 | E6:BC3:TEG3 | ST2 | ST2:LiQ | LiQ |
| | 5 nm | 230 nm | 20 nm | (33%:60%:7%) 40 nm | 5 nm | (50%:50%) 30 nm | 1 nm |
| Ex16 | HTCN | SpMA1 | SpMA2 | E6:BC10:TEG3 | ST2 | ST2:LiQ | LiQ |
| | 5 nm | 230 nm | 20 nm | (33%:60%:7%) 40 nm | 5 nm | (50%:50%) 30 nm | 1 nm |
| Ex17 | HTCN | SpMA1 | SpMA2 | E7:BC10:TEG3 | ST2 | ST2:LiQ | LiQ |
| | 5 nm | 230 nm | 20 nm | (33%:60%:7%) 40 nm | 5 nm | (50%:50%) 30 nm | 1 nm |
| Ex18 | HTCN | SpMA1 | SpMA2 | E8:BC13:TEG2 | ST2 | ST2:LiQ | LiQ |
| | 5 nm | 230 nm | 20 nm | (28%:60%:12%) 40 nm | 5 nm | (50%:50%) 30 nm | 1 nm |
| Ex19 | HTCN | SpMA1 | SpMA2 | E9:BC5:TEG3 | ST2 | ST2:LiQ | LiQ |
| | 5 nm | 230 nm | 20 nm | (33%:60%:7%) 40 nm | 5 nm | (50%:50%) 30 nm | 1 nm |
| Ex20 | HTCN | SpMA1 | SpMA2 | E10:BC5:TEG3 | ST2 | ST2:LiQ | LiQ |
| | 5 nm | 230 nm | 20 nm | (33%:60%:7%) 40 nm | 5 nm | (50%:50%) 30 nm | 1 nm |
| Ex21 | HTCN | SpMA1 | SpMA2 | E11:BC6:TEG3 | ST2 | ST2:LiQ | LiQ |
| | 5 nm | 230 nm | 20 nm | (38%:50%:12%) 40 nm | 5 nm | (50%:50%) 30 nm | 1 nm |
| Ex22 | HTCN | SpMA1 | SpMA2 | E12:BC12:TEG3 | ST2 | ST2:LiQ | LiQ |
| | 5 nm | 230 nm | 20 nm | (38%:50%:12%) 40 nm | 5 nm | (50%:50%) 30 nm | 1 nm |
| Ex23 | HTCN | SpMA1 | SpMA2 | E13:BC5:TEG3 | ST2 | ST2:LiQ | LiQ |
| | 5 nm | 230 nm | 20 nm | (38%:50%:12%) 40 nm | 5 nm | (50%:50%) 30 nm | 1 nm |
| Ex24 | HTCN | SpMA1 | SpMA2 | E14:BC11:TEG3 | ST2 | ST2:LiQ | LiQ |
| | 5 nm | 230 nm | 20 nm | (33%:60%:7%) 40 nm | 5 nm | (50%:50%) 30 nm | 1 nm |
| Ex25 | HTCN | SpMA1 | SpMA2 | E15:BC14:TEG2 | ST2 | ST2:LiQ | LiQ |
| | 5 nm | 230 nm | 20 nm | (28%:60%:12%) 40 nm | 5 nm | (50%:50%) 30 nm | 1 nm |
| Ex26 | HTCN | SpMA1 | SpMA2 | E16:BC15:TEG3 | ST2 | ST2:LiQ | LiQ |
| | 5 nm | 230 nm | 20 nm | (33%:60%:7%) 40 nm | 5 nm | (50%:50%) 30 nm | 1 nm |
| Ex27 | HTCN | SpMA1 | SpMA2 | E9:BC16:TEG3 | ST2 | ST2:LiQ | LiQ |
| | 5 nm | 230 nm | 20 nm | (33%:60%:7%) 40 nm | 5 nm | (50%:50%) 30 nm | 1 nm |
| E2x8 | HTCN | SpMA1 | SpMA2 | E2:BC17:TEG2 | ST2 | ST2:LiQ | LiQ |
| | 5 nm | 230 nm | 20 nm | (28%:60%:12%) 40 nm | 5 nm | (50%:50%) 30 nm | 1 nm |

TABLE 7
Data of the OLEDs

| | j0 | L1/L0 | LT |
|---|---|---|---|
| Ex. | (mA/cm²) | (%) | (h) |
| V1 | 40 | 80 | 270 |
| Ex1 | 40 | 80 | 350 |
| V2 | 40 | 80 | 980 |
| Ex2 | 40 | 80 | 1250 |
| V3 | 40 | 80 | 460 |
| Ex3 | 40 | 80 | 620 |
| V4 | 40 | 80 | 480 |
| V5 | 40 | 80 | 560 |
| Ex4 | 40 | 80 | 820 |
| V6 | 40 | 80 | 530 |
| V7 | 40 | 80 | 610 |
| Ex5 | 40 | 80 | 910 |
| Ex6 | 40 | 80 | 690 |
| Ex7 | 40 | 80 | 580 |
| Ex8 | 40 | 80 | 650 |
| Ex9 | 40 | 80 | 600 |
| Ex10 | 40 | 80 | 620 |
| Ex11 | 40 | 80 | 580 |
| Ex12 | 40 | 80 | 640 |
| Ex13 | 40 | 80 | 590 |
| Ex14 | 40 | 80 | 640 |
| Ex15 | 40 | 80 | 550 |
| Ex16 | 40 | 80 | 610 |
| Ex17 | 40 | 80 | 705 |
| Ex18 | 40 | 80 | 1100 |
| Ex19 | 40 | 80 | 730 |
| Ex20 | 40 | 80 | 690 |
| Ex21 | 40 | 80 | 940 |
| Ex22 | 40 | 80 | 1055 |
| Ex23 | 40 | 80 | 990 |
| Ex24 | 40 | 80 | 770 |
| Ex25 | 40 | 80 | 790 |
| Ex26 | 40 | 80 | 735 |
| Ex27 | 40 | 80 | 645 |
| Ex28 | 40 | 80 | 970 |

TABLE 8
Materials used

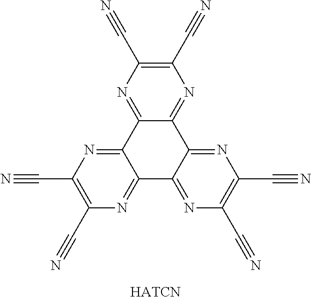

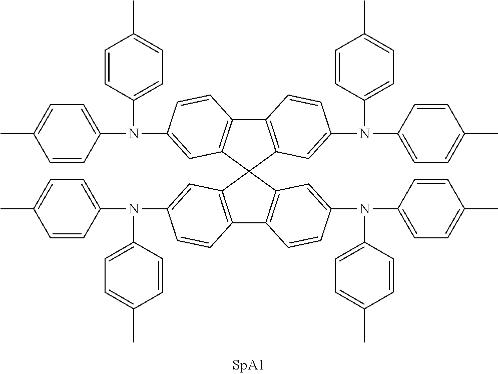

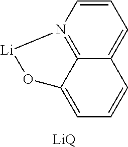

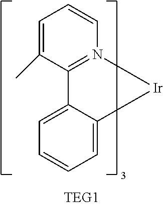

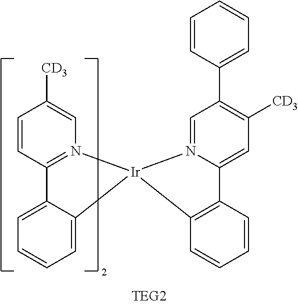

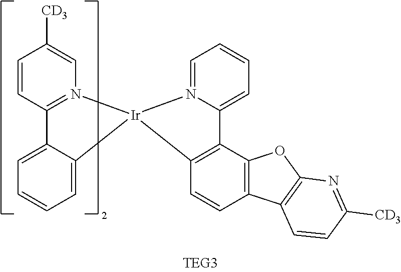

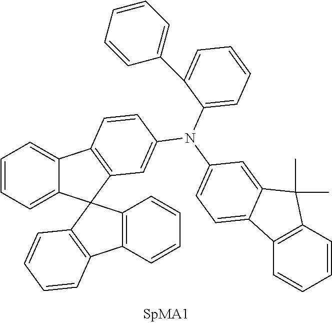 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

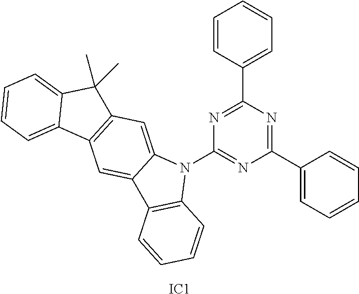

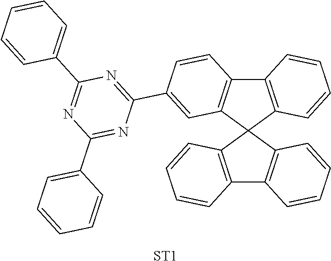 [SMILES: c1ccc(-c2nc(-c3ccccc3)nc(-c3ccc4c(c3)C3(c5ccccc5-c5ccccc53)c3ccccc3-4)n2)cc1 ; "ST1"]

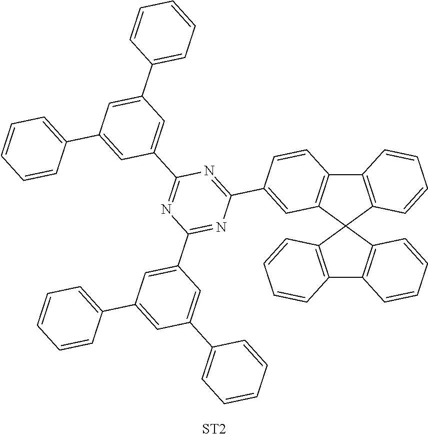 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1 ; "ST2"]

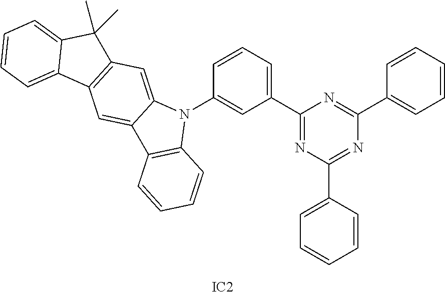 [SMILES: CC1(C)c2ccccc2-c2cc3c4ccccc4n(-c4cccc(-c5nc(-c6ccccc6)nc(-c6ccccc6)n5)c4)c3cc21 ; "IC2"]

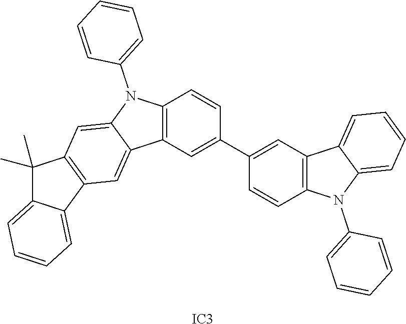 [SMILES: CC1(C)c2ccccc2-c2cc3c4cc(-c5ccc6c(c5)c5ccccc5n6-c5ccccc5)ccc4n(-c4ccccc4)c3cc21 ; "IC3"]

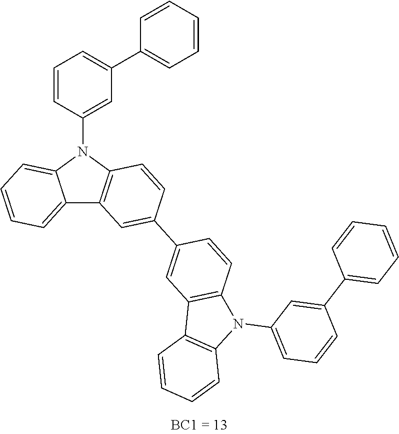 [SMILES: c1ccc(-c2cccc(-n3c4ccccc4c4cc(-c5ccc6c(c5)c5ccccc5n6-c5cccc(-c6ccccc6)c5)ccc43)c2)cc1]

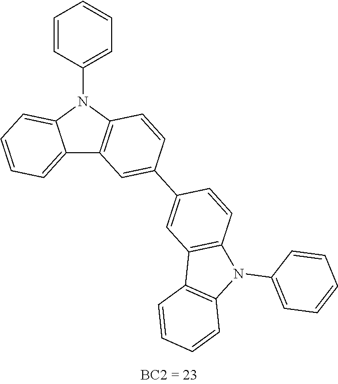 [SMILES: c1ccc(-n2c3ccccc3c3cc(-c4ccc5c(c4)c4ccccc4n5-c4ccccc4)ccc32)cc1]

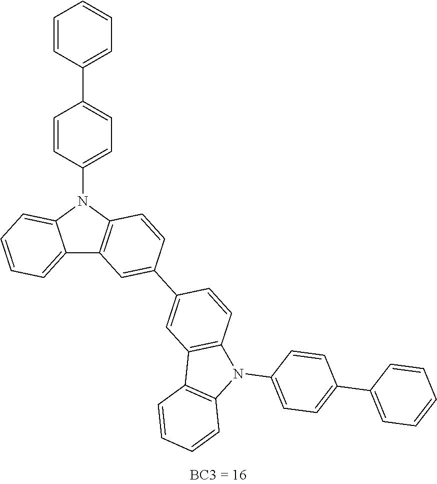 [SMILES: c1ccc(-c2ccc(-n3c4ccccc4c4cc(-c5ccc6c(c5)c5ccccc5n6-c5ccc(-c6ccccc6)cc5)ccc43)cc2)cc1]

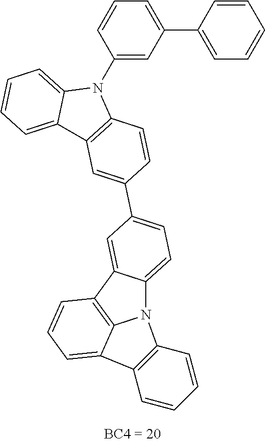 [SMILES: c1ccc(-c2cccc(-n3c4ccccc4c4cc(-c5ccc6c(c5)c5cccc7c8ccccc8n6c75)ccc43)c2)cc1]

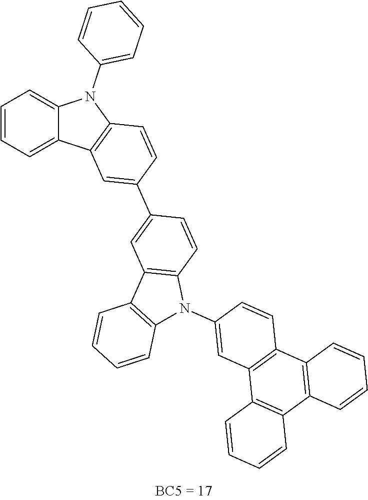 [SMILES: c1ccc(-n2c3ccccc3c3cc(-c4ccc5c(c4)c4ccccc4n5-c4ccc5c6ccccc6c6ccccc6c5c4)ccc32)cc1]

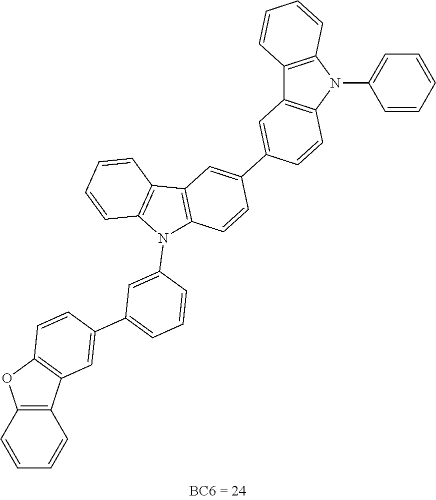 [SMILES: c1ccc(-n2c3ccccc3c3cc(-c4ccc5c(c4)c4ccccc4n5-c4cccc(-c5ccc6oc7ccccc7c6c5)c4)ccc32)cc1]

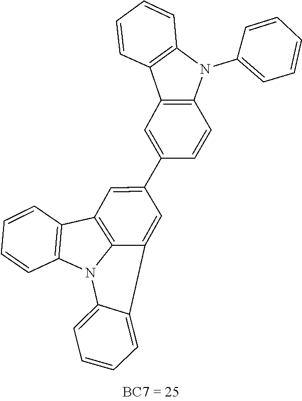 [SMILES: c1ccc(-n2c3ccccc3c3cc(-c4cc5c6ccccc6n6c7ccccc7c(c4)c56)ccc32)cc1]

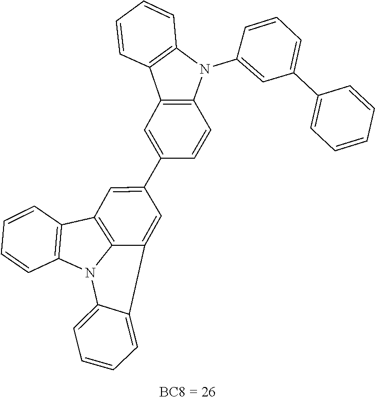 [SMILES: c1ccc(-c2cccc(-n3c4ccccc4c4cc(-c5cc6c7ccccc7n7c8ccccc8c(c5)c67)ccc43)c2)cc1]

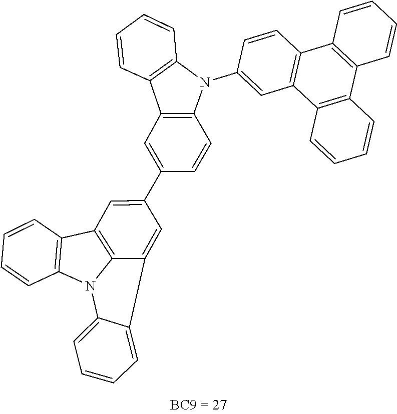 [SMILES: c1ccc2c(c1)c1ccccc1c1cc(-n3c4ccccc4c4cc(-c5cc6c7ccccc7n7c8ccccc8c(c5)c67)ccc43)ccc21]

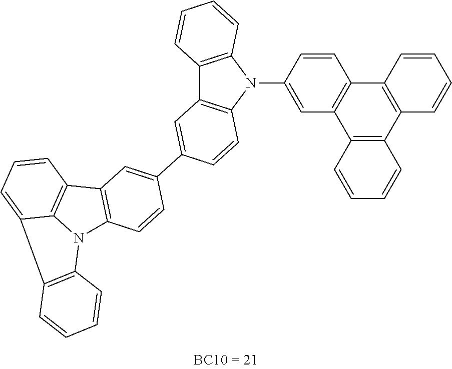 [SMILES: c1ccc2c(c1)c1ccccc1c1cc(-n3c4ccccc4c4cc(-c5ccc6c(c5)c5cccc7c8ccccc8n6c75)ccc43)ccc21]

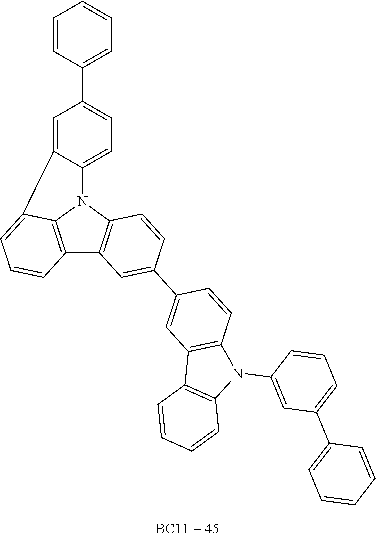 [SMILES: c1ccc(-c2cccc(-n3c4ccccc4c4cc(-c5ccc6c(c5)c5cccc7c8cc(-c9ccccc9)ccc8n6c75)ccc43)c2)cc1]

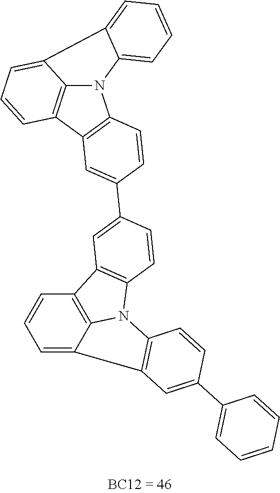 [SMILES: c1ccc(-c2ccc3c(c2)c2cccc4c5cc(-c6ccc7c(c6)c6cccc8c9ccccc9n7c86)ccc5n3c24)cc1]

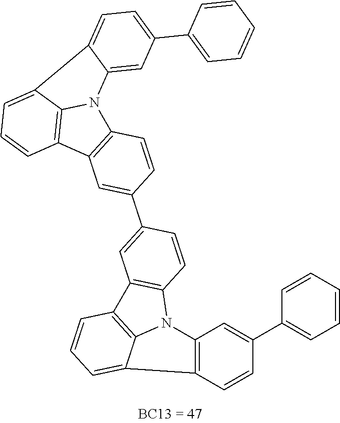 [SMILES: c1ccc(-c2ccc3c4cccc5c6cc(-c7ccc8c(c7)c7cccc9c%10ccc(-c%11ccccc%11)cc%10n8c79)ccc6n(c3c2)c54)cc1]

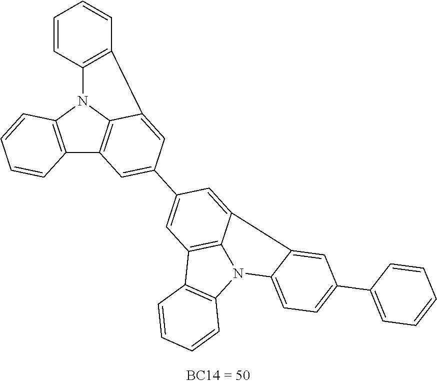 [SMILES: c1ccc(-c2ccc3c(c2)c2cc(-c4cc5c6ccccc6n6c7ccccc7c(c4)c56)cc4c5ccccc5n3c42)cc1]

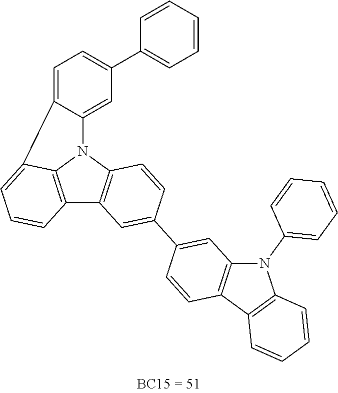 [SMILES: c1ccc(-c2ccc3c4cccc5c6cc(-c7ccc8c9ccccc9n(-c9ccccc9)c8c7)ccc6n(c3c2)c54)cc1]

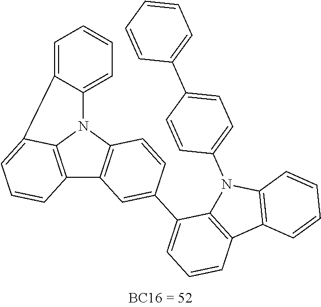 [SMILES: c1ccc(-c2ccc(-n3c4ccccc4c4cccc(-c5ccc6c(c5)c5cccc7c8ccccc8n6c75)c43)cc2)cc1]

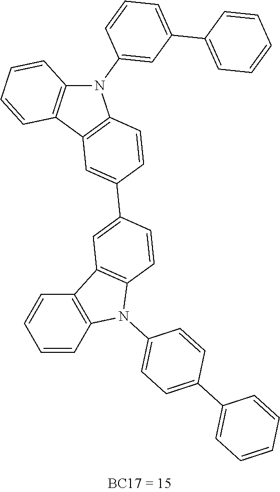 [SMILES: c1ccc(-c2ccc(-n3c4ccccc4c4cc(-c5ccc6c(c5)c5ccccc5n6-c5cccc(-c6ccccc6)c5)ccc43)cc2)cc1]

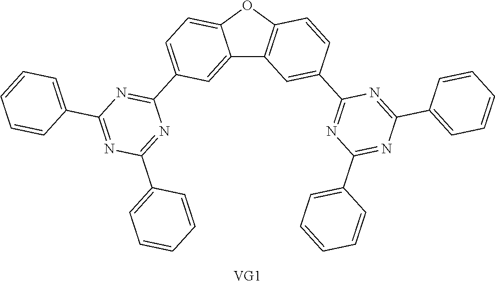 [SMILES: c1ccc(-c2nc(-c3ccccc3)nc(-c3ccc4oc5ccc(-c6nc(-c7ccccc7)nc(-c7ccccc7)n6)cc5c4c3)n2)cc1]

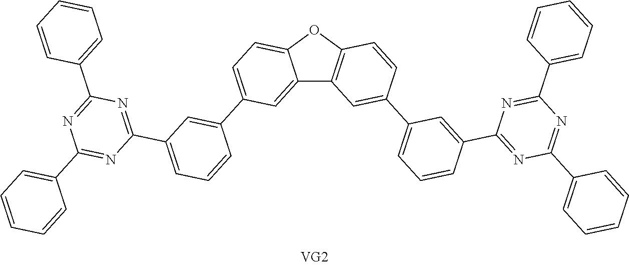 [SMILES: c1ccc(-c2nc(-c3ccccc3)nc(-c3cccc(-c4ccc5oc6ccc(-c7cccc(-c8nc(-c9ccccc9)nc(-c9ccccc9)n8)c7)cc6c5c4)c3)n2)cc1]

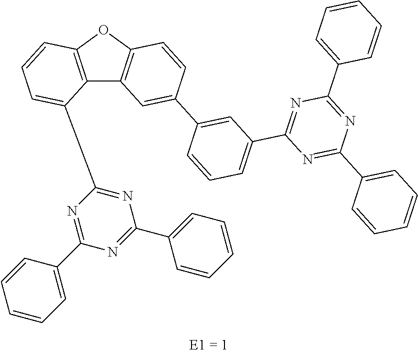 [SMILES: c1ccc(-c2nc(-c3ccccc3)nc(-c3cccc(-c4ccc5oc6cccc(-c7nc(-c8ccccc8)nc(-c8ccccc8)n7)c6c5c4)c3)n2)cc1]

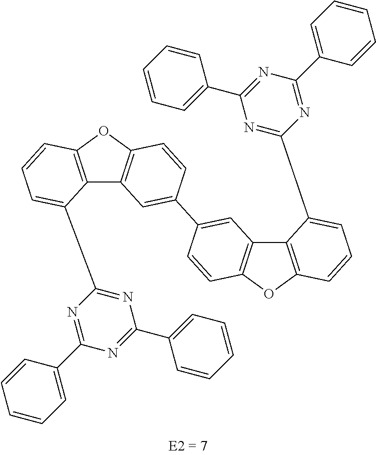 [SMILES: c1ccc(-c2nc(-c3ccccc3)nc(-c3cccc4oc5ccc(-c6ccc7oc8cccc(-c9nc(-c%10ccccc%10)nc(-c%10ccccc%10)n9)c8c7c6)cc5c34)n2)cc1]

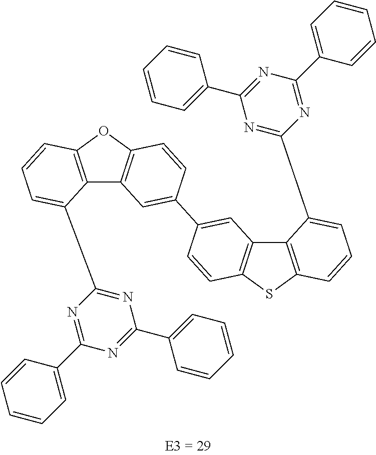 [SMILES: c1ccc(-c2nc(-c3ccccc3)nc(-c3cccc4oc5ccc(-c6ccc7sc8cccc(-c9nc(-c%10ccccc%10)nc(-c%10ccccc%10)n9)c8c7c6)cc5c34)n2)cc1]

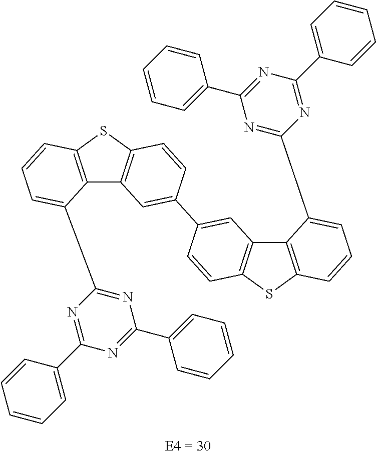 [SMILES: c1ccc(-c2nc(-c3ccccc3)nc(-c3cccc4sc5ccc(-c6ccc7sc8cccc(-c9nc(-c%10ccccc%10)nc(-c%10ccccc%10)n9)c8c7c6)cc5c34)n2)cc1]

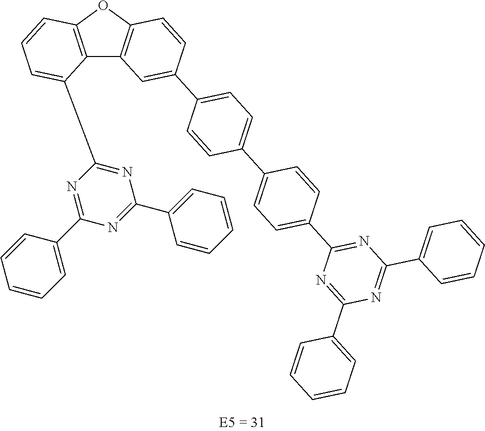 [SMILES: c1ccc(-c2nc(-c3ccccc3)nc(-c3ccc(-c4ccc(-c5ccc6oc7cccc(-c8nc(-c9ccccc9)nc(-c9ccccc9)n8)c7c6c5)cc4)cc3)n2)cc1]

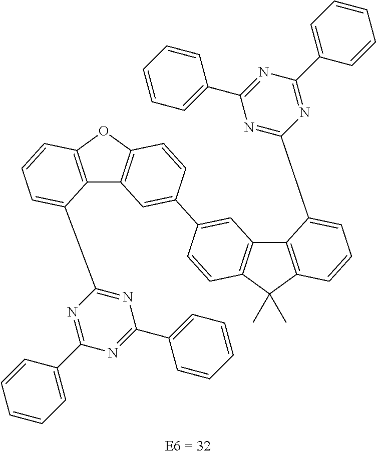 [SMILES: CC1(C)c2ccc(-c3ccc4oc5cccc(-c6nc(-c7ccccc7)nc(-c7ccccc7)n6)c5c4c3)cc2-c2c(-c3nc(-c4ccccc4)nc(-c4ccccc4)n3)cccc21]

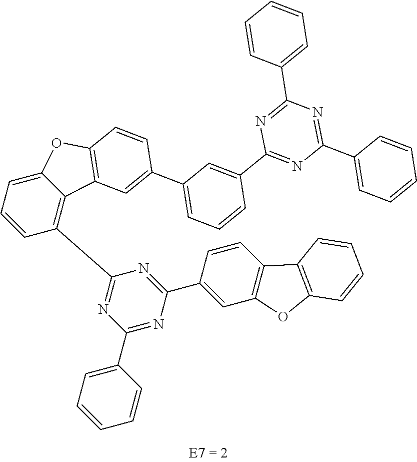 [SMILES: c1ccc(-c2nc(-c3ccccc3)nc(-c3cccc(-c4ccc5oc6cccc(-c7nc(-c8ccccc8)nc(-c8ccc9c(c8)oc8ccccc89)n7)c6c5c4)c3)n2)cc1]

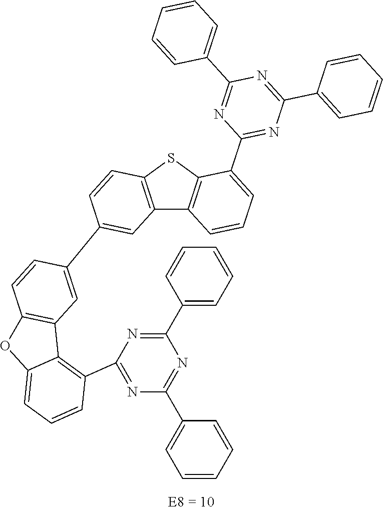 [SMILES: c1ccc(-c2nc(-c3ccccc3)nc(-c3cccc4c3sc3ccc(-c5ccc6oc7cccc(-c8nc(-c9ccccc9)nc(-c9ccccc9)n8)c7c6c5)cc34)n2)cc1]

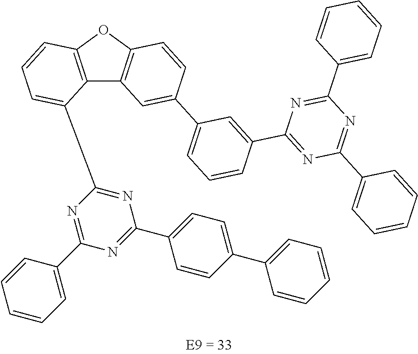 [SMILES: c1ccc(-c2ccc(-c3nc(-c4ccccc4)nc(-c4cccc5oc6ccc(-c7cccc(-c8nc(-c9ccccc9)nc(-c9ccccc9)n8)c7)cc6c45)n3)cc2)cc1]

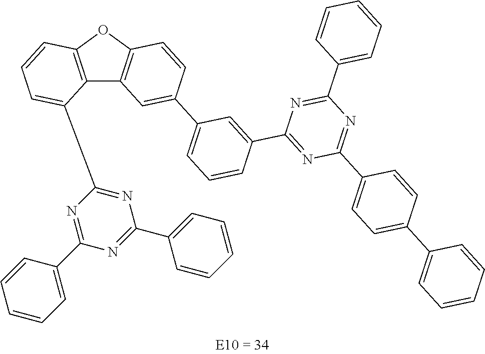 [SMILES: c1ccc(-c2ccc(-c3nc(-c4ccccc4)nc(-c4cccc(-c5ccc6oc7cccc(-c8nc(-c9ccccc9)nc(-c9ccccc9)n8)c7c6c5)c4)n3)cc2)cc1]

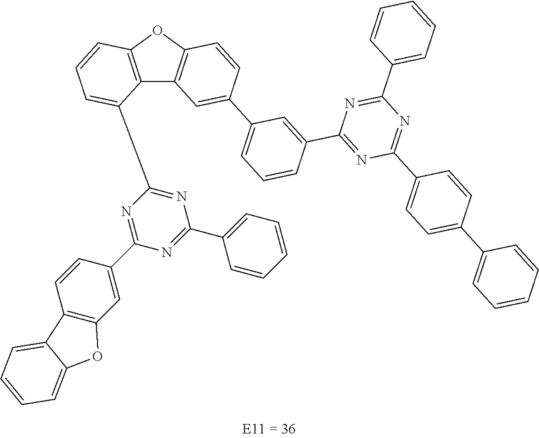 [SMILES: c1ccc(-c2ccc(-c3nc(-c4ccccc4)nc(-c4cccc(-c5ccc6oc7cccc(-c8nc(-c9ccccc9)nc(-c9ccc%10c(c9)oc9ccccc9%10)n8)c7c6c5)c4)n3)cc2)cc1]

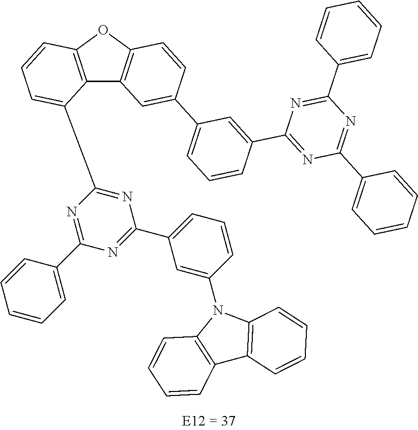 [SMILES: c1ccc(-c2nc(-c3ccccc3)nc(-c3cccc(-c4ccc5oc6cccc(-c7nc(-c8ccccc8)nc(-c8cccc(-n9c%10ccccc%10c%10ccccc%109)c8)n7)c6c5c4)c3)n2)cc1]

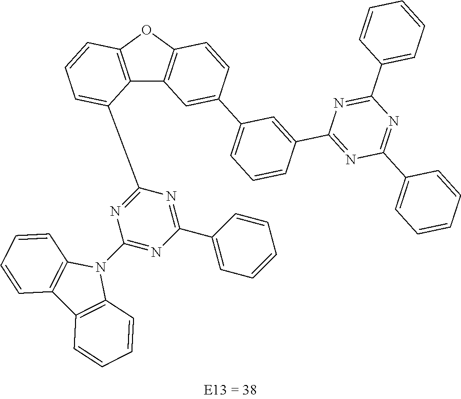 [SMILES: c1ccc(-c2nc(-c3ccccc3)nc(-c3cccc(-c4ccc5oc6cccc(-c7nc(-c8ccccc8)nc(-n8c9ccccc9c9ccccc98)n7)c6c5c4)c3)n2)cc1]

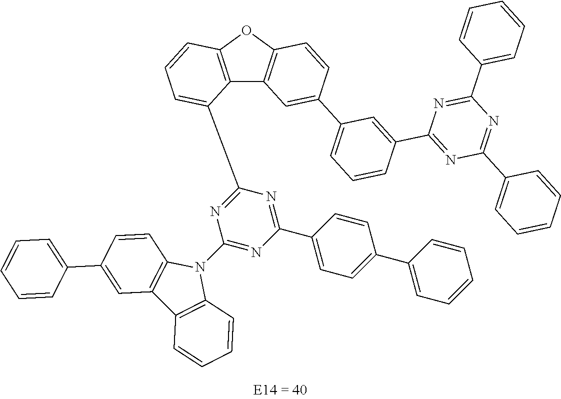 [SMILES: c1ccc(-c2ccc(-c3nc(-c4cccc5oc6ccc(-c7cccc(-c8nc(-c9ccccc9)nc(-c9ccccc9)n8)c7)cc6c45)nc(-n4c5ccccc5c5cc(-c6ccccc6)ccc54)n3)cc2)cc1]

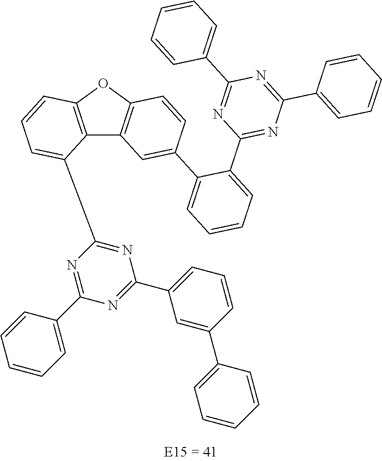 [SMILES: c1ccc(-c2cccc(-c3nc(-c4ccccc4)nc(-c4cccc5oc6ccc(-c7ccccc7-c7nc(-c8ccccc8)nc(-c8ccccc8)n7)cc6c45)n3)c2)cc1]

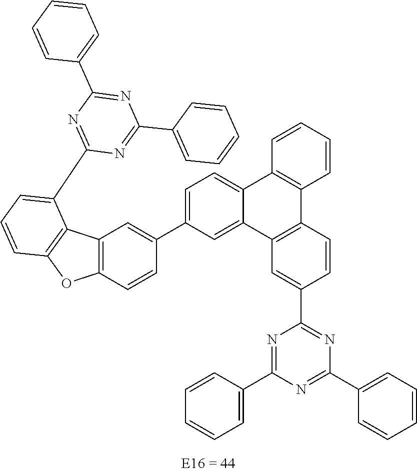 [SMILES: c1ccc(-c2nc(-c3ccccc3)nc(-c3ccc4c5ccccc5c5ccc(-c6ccc7oc8cccc(-c9nc(-c%10ccccc%10)nc(-c%10ccccc%10)n9)c8c7c6)cc5c4c3)n2)cc1]

### EXAMPLE 2: SYNTHESIS OF HOST MATERIALS AND PRECURSORS THEREOF

### a) 2-Dibenzofuran-1-yl-4,6-diphenyl-1,3,5-triazine

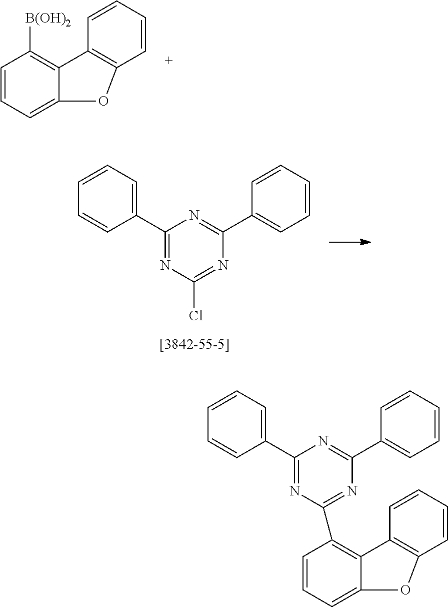 [SMILES: OB(O)c1cccc2oc3ccccc3c12 ; Clc1nc(-c2ccccc2)nc(-c2ccccc2)n1 ; c1ccc(-c2nc(-c3ccccc3)nc(-c3cccc4oc5ccccc5c34)n2)cc1]

23 g (110.0 mmol) of dibenzofuran-1-boronic acid, 29.5 g (110.0 mmol) of 2-chloro-4,6-diphenyl-1,3,5-triazine and 21 g (210.0 mmol) of sodium carbonate are suspended in 500 ml of ethylene glycol diamine ether and 500 ml of water. 913 mg (3.0 mmol) of tri-o-tolylphosphine and then 112 mg (0.5 mmol) of palladium(II) acetate are added to this suspension, and the reaction mixture is heated under reflux for 16 h. After cooling, the organic phase is separated off, filtered through silica gel, washed three times with 200 ml of water and subsequently evaporated to dryness. The residue is recrystallised from toluene and from dichloromethane/heptane. The yield is 37 g (94 mmol), corresponding to 87% of theory.

The following compounds can be obtained analogously:

| | Starting material 1 | Starting material 2 | Product | Yield |
|---|---|---|---|---|
| 1a | 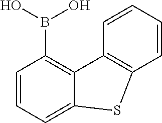 [SMILES: OB(O)c1cccc2sc3ccccc3c12] | 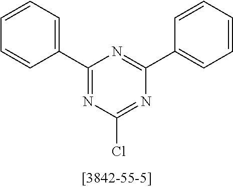 [SMILES: Clc1nc(-c2ccccc2)nc(-c2ccccc2)n1] | 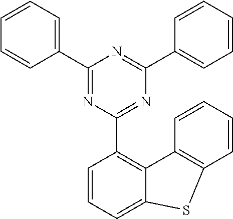 [SMILES: c1ccc(-c2nc(-c3ccccc3)nc(-c3cccc4sc5ccccc5c34)n2)cc1] | 63% |
| 2a | 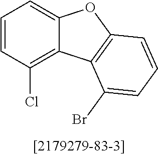 [SMILES: Clc1cccc2oc3cccc(Br)c3c12] | 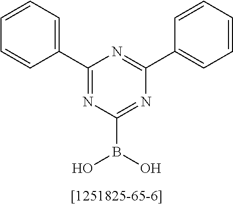 [SMILES: OB(O)c1nc(-c2ccccc2)nc(-c2ccccc2)n1] | 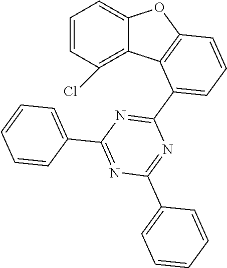 [SMILES: Clc1cccc2oc3cccc(-c4nc(-c5ccccc5)nc(-c5ccccc5)n4)c3c12] | 61% |
| 3a | 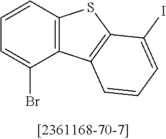 [SMILES: Brc1cccc2sc3c(I)cccc3c12] | 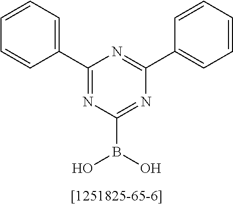 [SMILES: OB(O)c1nc(-c2ccccc2)nc(-c2ccccc2)n1] | 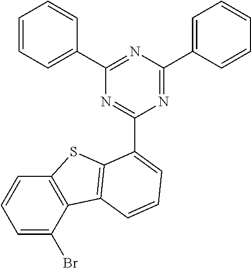 [SMILES: Brc1cccc2sc3c(-c4nc(-c5ccccc5)nc(-c5ccccc5)n4)cccc3c12] | 60% |
| 4a | 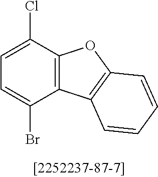 [SMILES: Clc1ccc(Br)c2c1oc1ccccc12] | 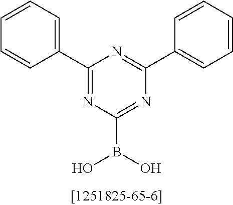 [SMILES: OB(O)c1nc(-c2ccccc2)nc(-c2ccccc2)n1] | 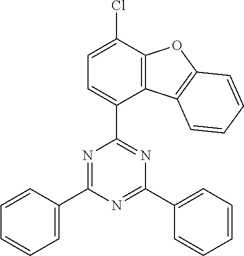 [SMILES: Clc1ccc(-c2nc(-c3ccccc3)nc(-c3ccccc3)n2)c2c1oc1ccccc12] | 64% |
| 5a | 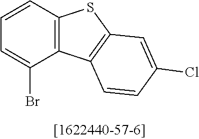 [SMILES: Clc1ccc2c(c1)sc1cccc(Br)c12] | 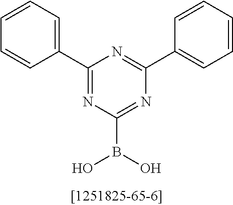 [SMILES: OB(O)c1nc(-c2ccccc2)nc(-c2ccccc2)n1] | 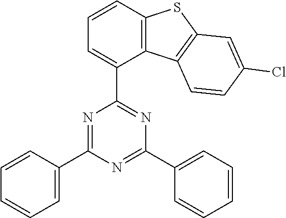 [SMILES: Clc1ccc2c(c1)sc1cccc(-c3nc(-c4ccccc4)nc(-c4ccccc4)n3)c12] | 58% |
| 6a | 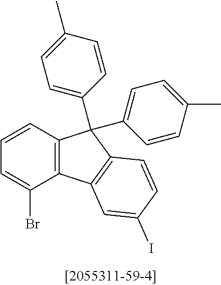 [SMILES: Cc1ccc(C2(c3ccc(C)cc3)c3ccc(I)cc3-c3c(Br)cccc32)cc1] | 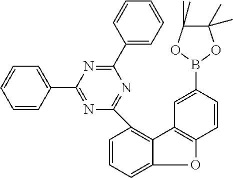 [SMILES: CC1(C)OB(c2ccc3oc4cccc(-c5nc(-c6ccccc6)nc(-c6ccccc6)n5)c4c3c2)OC1(C)C] | 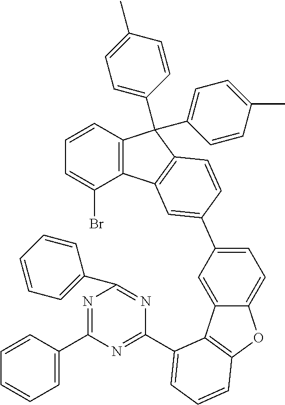 [SMILES: Cc1ccc(C2(c3ccc(C)cc3)c3ccc(-c4ccc5oc6cccc(-c7nc(-c8ccccc8)nc(-c8ccccc8)n7)c6c5c4)cc3-c3c(Br)cccc32)cc1] | 64% |
| 7a | 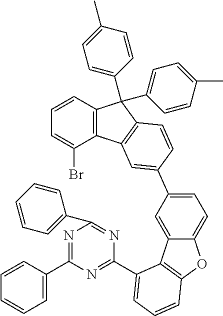 [SMILES: Cc1ccc(C2(c3ccc(C)cc3)c3ccc(-c4ccc5oc6cccc(-c7nc(-c8ccccc8)nc(-c8ccccc8)n7)c6c5c4)cc3-c3c(Br)cccc32)cc1] | 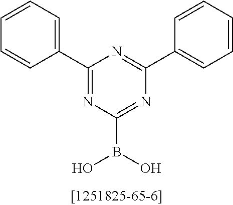 [SMILES: OB(O)c1nc(-c2ccccc2)nc(-c2ccccc2)n1] | 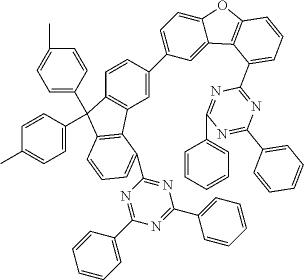 [SMILES: Cc1ccc(C2(c3ccc(C)cc3)c3ccc(-c4ccc5oc6cccc(-c7nc(-c8ccccc8)nc(-c8ccccc8)n7)c6c5c4)cc3-c3c(-c4nc(-c5ccccc5)nc(-c5ccccc5)n4)cccc32)cc1] | 75% |
| 8a | 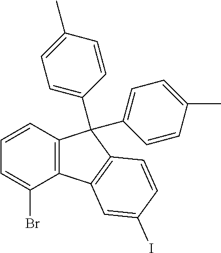 [SMILES: Cc1ccc(C2(c3ccc(C)cc3)c3ccc(I)cc3-c3c(Br)cccc32)cc1] | 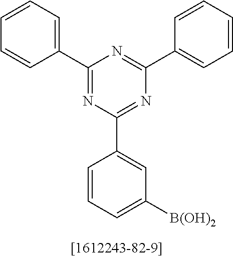 [SMILES: OB(O)c1cccc(-c2nc(-c3ccccc3)nc(-c3ccccc3)n2)c1] | 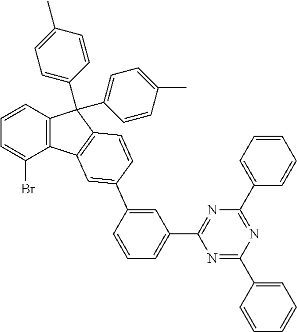 [SMILES: Cc1ccc(C2(c3ccc(C)cc3)c3ccc(-c4cccc(-c5nc(-c6ccccc6)nc(-c6ccccc6)n5)c4)cc3-c3c(Br)cccc32)cc1] | 65% |
| 9a | 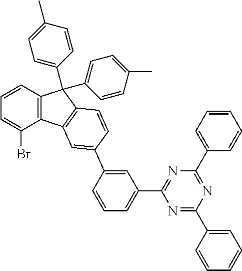 [SMILES: Cc1ccc(C2(c3ccc(C)cc3)c3ccc(-c4cccc(-c5nc(-c6ccccc6)nc(-c6ccccc6)n5)c4)cc3-c3c(Br)cccc32)cc1] | 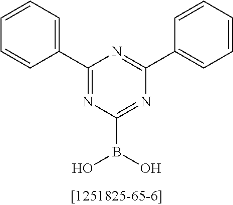 [SMILES: OB(O)c1nc(-c2ccccc2)nc(-c2ccccc2)n1] | 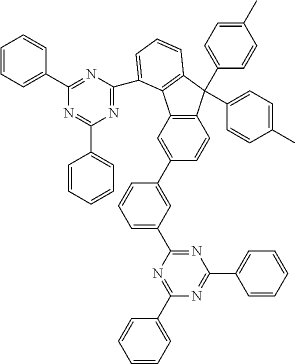 [SMILES: Cc1ccc(C2(c3ccc(C)cc3)c3ccc(-c4cccc(-c5nc(-c6ccccc6)nc(-c6ccccc6)n5)c4)cc3-c3c(-c4nc(-c5ccccc5)nc(-c5ccccc5)n4)cccc32)cc1] | 68% |
| 10a | 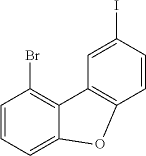 [SMILES: Brc1cccc2oc3ccc(I)cc3c12] | 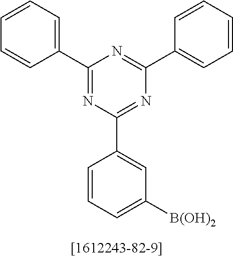 [SMILES: OB(O)c1cccc(-c2nc(-c3ccccc3)nc(-c3ccccc3)n2)c1] | 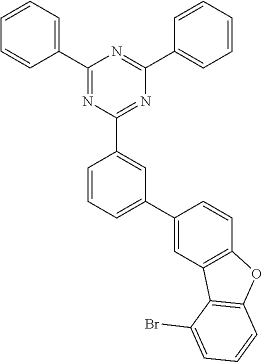 [SMILES: Brc1cccc2oc3ccc(-c4cccc(-c5nc(-c6ccccc6)nc(-c6ccccc6)n5)c4)cc3c12] | 62% |
| 11a | 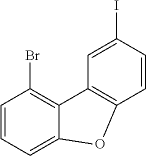 [SMILES: Brc1cccc2oc3ccc(I)cc3c12] | 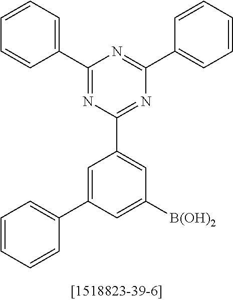 [SMILES: OB(O)c1cc(-c2ccccc2)cc(-c2nc(-c3ccccc3)nc(-c3ccccc3)n2)c1] | 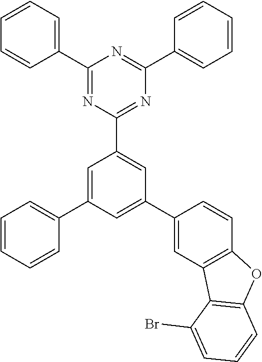 [SMILES: Brc1cccc2oc3ccc(-c4cc(-c5ccccc5)cc(-c5nc(-c6ccccc6)nc(-c6ccccc6)n5)c4)cc3c12] | 57% |
| 12a | 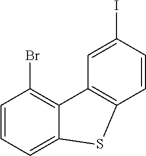 [SMILES: Brc1cccc2sc3ccc(I)cc3c12] | 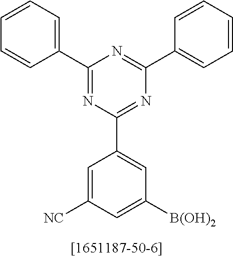 [SMILES: N#Cc1cc(B(O)O)cc(-c2nc(-c3ccccc3)nc(-c3ccccc3)n2)c1] | 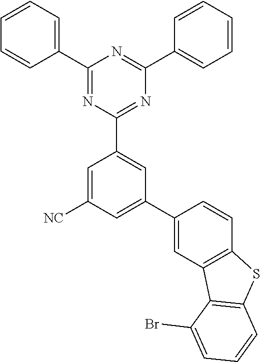 [SMILES: N#Cc1cc(-c2ccc3sc4cccc(Br)c4c3c2)cc(-c2nc(-c3ccccc3)nc(-c3ccccc3)n2)c1] | 64% |
| 13a | 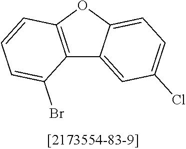 [SMILES: Clc1ccc2oc3cccc(Br)c3c2c1] | 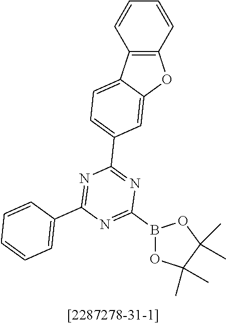 [SMILES: CC1(C)OB(c2nc(-c3ccccc3)nc(-c3ccc4c(c3)oc3ccccc34)n2)OC1(C)C] | 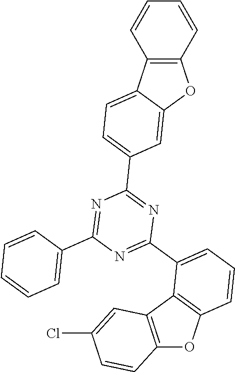 [SMILES: Clc1ccc2oc3cccc(-c4nc(-c5ccccc5)nc(-c5ccc6c(c5)oc5ccccc56)n4)c3c2c1] | 61% |

### b) 2-(8-Bromodibenzofuran-1-yl)˜4,6-diphenyl-1,3,5-triazine

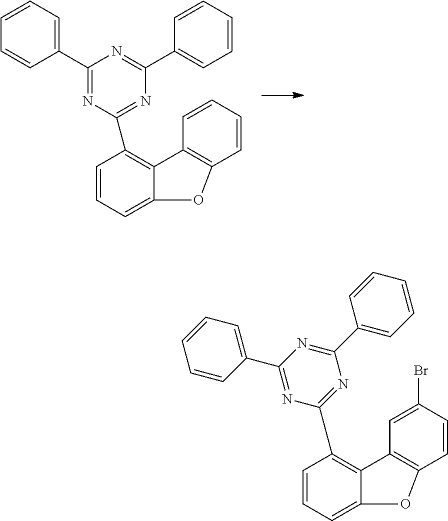 [SMILES: c1ccc(-c2nc(-c3ccccc3)nc(-c3cccc4oc5ccccc5c34)n2)cc1 ; Brc1ccc2oc3cccc(-c4nc(-c5ccccc5)nc(-c5ccccc5)n4)c3c2c1]

70 g (190.0 mmol) of 2-dibenzofuran-1-yl-4,6-diphenyl-1,3,5-triazine are suspended in 2000 ml of acetic acid (100%) and 2000 ml of sulfuric acid (95˜98%). 34 g (190 mmol) of NBS are added in portions to this suspension, and the mixture is stirred in the dark for 2 hours. Water/ice is then added, and the solid is separated off and rinsed with ethanol. The residue is recrystallised from toluene. The yield is 80 g (167 mmol), corresponding to 87% of theory.

The following compounds are prepared analogously:

| | Starting material 1 | Product | Yield |
|---|---|---|---|
| 1b | 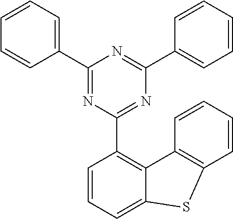 [SMILES: c1ccc(-c2nc(-c3ccccc3)nc(-c3cccc4sc5ccccc5c34)n2)cc1] | 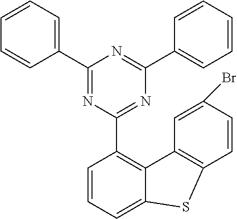 [SMILES: Brc1ccc2sc3cccc(-c4nc(-c5ccccc5)nc(-c5ccccc5)n4)c3c2c1] | 83% |

In the case of thiophene derivatives, nitrobenzene is employed instead of sulfuric acid and elemental bromine is employed instead of NBS.

### c) 2,4-Diphenyl-6-[8-(4,4,5,5-tetramethyl-1,3,2-dioxaborolan-2-yl)dibenzofuran-1-yl]-1,3,5-triazine

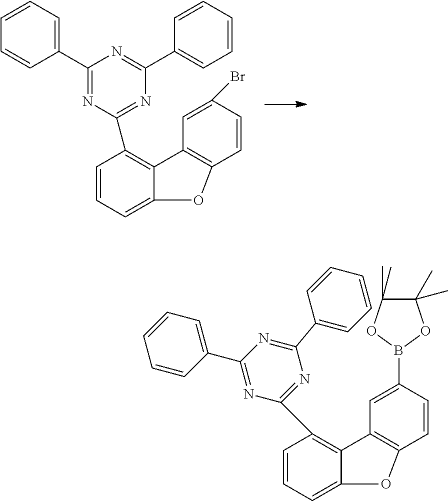 [SMILES: Brc1ccc2oc3cccc(-c4nc(-c5ccccc5)nc(-c5ccccc5)n4)c3c2c1 ; CC1(C)OB(c2ccc3oc4cccc(-c5nc(-c6ccccc6)nc(-c6ccccc6)n5)c4c3c2)OC1(C)C]

60 g (125 mmol) of the 2-(8-bromodibenzofuran-1-yl)˜4,6-diphenyl-1,3,5-triazine together with 39 g (1051 mmol) of bis(pinacolato)diborane (CAS 73183˜34˜3) are dissolved in 900 ml of dry DMF in a 500 ml flask under protective gas and degassed for 30 minutes. 37 g (376 mmol) of potassium acetate and 1.9 g (8.7 mmol) of palladium acetate are subsequently added, and the batch is heated at 80° C. overnight. When the reaction is complete, the mixture is diluted with 300 ml of toluene and extracted with water. The solvent is removed on a rotary evaporator, and the product is recrystallised from heptane. Yield: 61 g (117 mmol), 94% of theory.

The following compounds are prepared analogously:

| | Starting material 1 | Product | Yield |
|---|---|---|---|
| 1c | 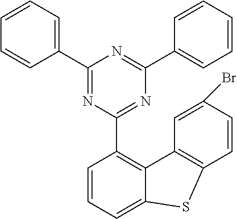 [SMILES: Brc1ccc2sc3cccc(-c4nc(-c5ccccc5)nc(-c5ccccc5)n4)c3c2c1] | 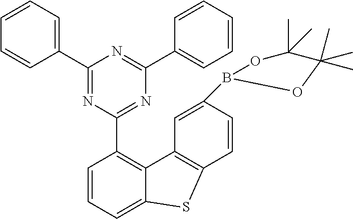 | 98% |

### d) 2-[4-[9-(4,6-Diphenyl-1,3,5-triazin-2-yl)dibenzofuran-2-yl]phenyl]˜4,6-diphenyl-1,3,5-triazine

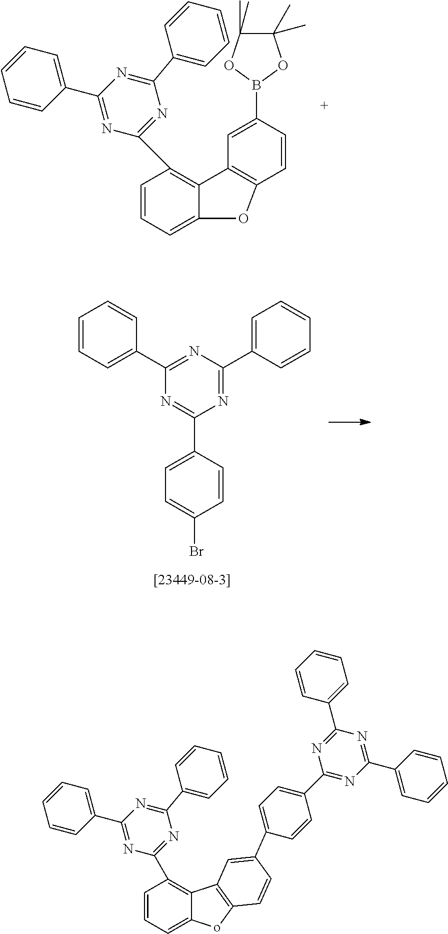

68.7 g (110.0 mmol) of 2,4-diphenyl-6-[8-(4,4,5,5-tetramethyl-1,3,2-dioxaborolan-2-yl)dibenzofuran-1-yl]-1,3,5-triazine, 42 g (110.0 mmol) of 2-(4-bromophenyl)˜4,6-diphenyl-1,3,5-triazine and 21 g (210.0 mmol) of sodium carbonate are suspended in 500 ml of ethylene glycol diamine ether and 500 ml of water. 913 mg (3.0 mmol) of tri-o-tolylphosphine and then 112 mg (0.5 mmol) of palladium(II) acetate are added to this suspension, and the reaction mixture is heated under reflux for 16 h. After cooling, the organic phase is separated off, filtered through silica gel, washed three times with 200 ml of water and subsequently evaporated to dryness. The product is purified by column chromatography on silica gel with toluene/CHCl₃ (1:1) and finally sublimed in a high vacuum (p=5×10⁻⁷ mbar) (purity 99.9%). The yield is 64 g (81 mmol), corresponding to 70% of theory.

The following compounds can be prepared analogously:

| | Starting material 1 | Starting material 2 | Product | Yield |
|---|---|---|---|---|
| 1d | 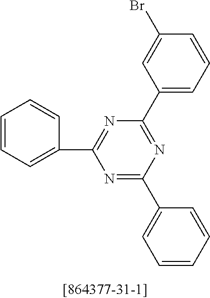 [SMILES: Brc1cccc(-c2nc(-c3ccccc3)nc(-c3ccccc3)n2)c1] | 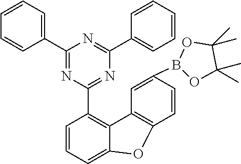 [SMILES: CC1(C)OB(c2ccc3oc4cccc(-c5nc(-c6ccccc6)nc(-c6ccccc6)n5)c4c3c2)OC1(C)C] | 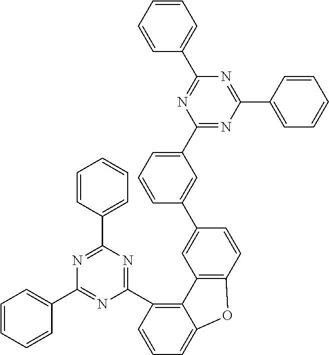 [SMILES: c1ccc(-c2nc(-c3ccccc3)nc(-c3cccc(-c4ccc5oc6cccc(-c7nc(-c8ccccc8)nc(-c8ccccc8)n7)c6c5c4)c3)n2)cc1] | 61% |
| 2d | 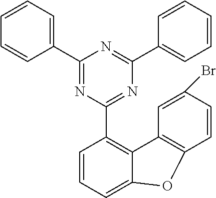 [SMILES: Brc1ccc2oc3cccc(-c4nc(-c5ccccc5)nc(-c5ccccc5)n4)c3c2c1] | 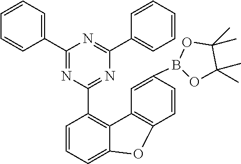 [SMILES: CC1(C)OB(c2ccc3oc4cccc(-c5nc(-c6ccccc6)nc(-c6ccccc6)n5)c4c3c2)OC1(C)C] | 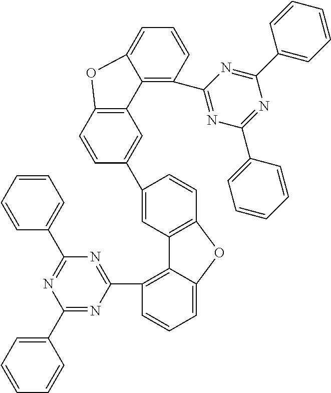 [SMILES: c1ccc(-c2nc(-c3ccccc3)nc(-c3cccc4oc5ccc(-c6ccc7oc8cccc(-c9nc(-c%10ccccc%10)nc(-c%10ccccc%10)n9)c8c7c6)cc5c34)n2)cc1] | 65% |
| 3d | 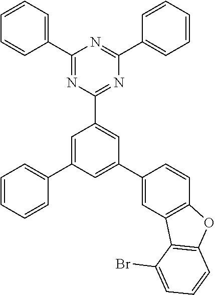 [SMILES: Brc1cccc2oc3ccc(-c4cc(-c5ccccc5)cc(-c5nc(-c6ccccc6)nc(-c6ccccc6)n5)c4)cc3c12] | 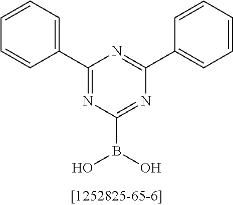 [SMILES: OB(O)c1nc(-c2ccccc2)nc(-c2ccccc2)n1] | 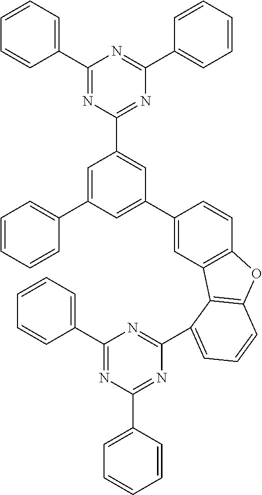 [SMILES: c1ccc(-c2cc(-c3ccc4oc5cccc(-c6nc(-c7ccccc7)nc(-c7ccccc7)n6)c5c4c3)cc(-c3nc(-c4ccccc4)nc(-c4ccccc4)n3)c2)cc1] | 67% |
| 4d | 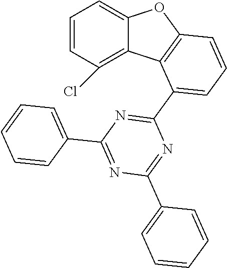 [SMILES: Clc1cccc2oc3cccc(-c4nc(-c5ccccc5)nc(-c5ccccc5)n4)c3c12] | 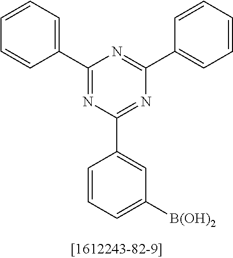 [SMILES: OB(O)c1cccc(-c2nc(-c3ccccc3)nc(-c3ccccc3)n2)c1] | 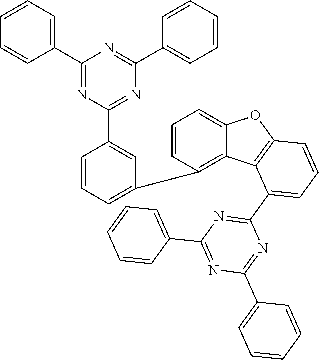 [SMILES: c1ccc(-c2nc(-c3ccccc3)nc(-c3cccc(-c4cccc5oc6cccc(-c7nc(-c8ccccc8)nc(-c8ccccc8)n7)c6c45)c3)n2)cc1] | 69% |
| 5d | 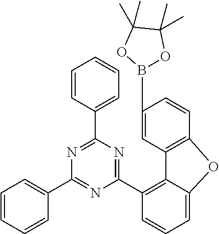 [SMILES: CC1(C)OB(c2ccc3oc4cccc(-c5nc(-c6ccccc6)nc(-c6ccccc6)n5)c4c3c2)OC1(C)C] | 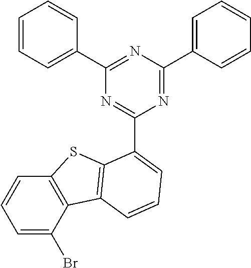 [SMILES: Brc1cccc2sc3c(-c4nc(-c5ccccc5)nc(-c5ccccc5)n4)cccc3c12] | 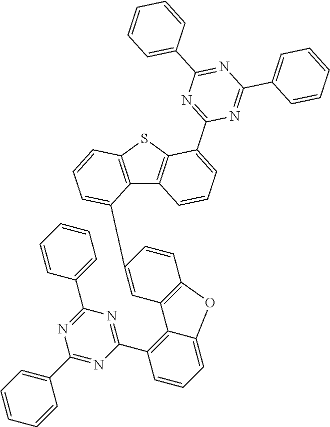 [SMILES: c1ccc(-c2nc(-c3ccccc3)nc(-c3cccc4c3sc3cccc(-c5ccc6oc7cccc(-c8nc(-c9ccccc9)nc(-c9ccccc9)n8)c7c6c5)c34)n2)cc1] | 65% |
| 6d | 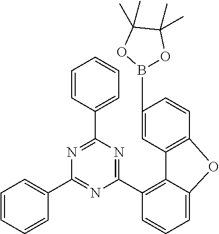 [SMILES: CC1(C)OB(c2ccc3oc4cccc(-c5nc(-c6ccccc6)nc(-c6ccccc6)n5)c4c3c2)OC1(C)C] | 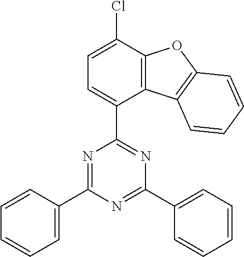 [SMILES: Clc1ccc(-c2nc(-c3ccccc3)nc(-c3ccccc3)n2)c2c1oc1ccccc12] | 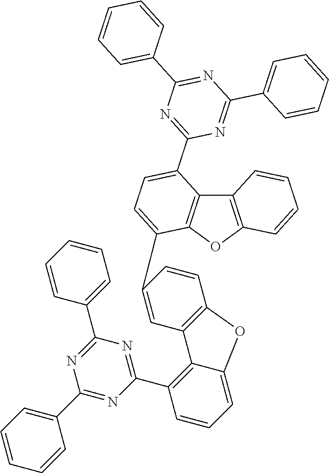 [SMILES: c1ccc(-c2nc(-c3ccccc3)nc(-c3cccc4oc5ccc(-c6ccc(-c7nc(-c8ccccc8)nc(-c8ccccc8)n7)c7c6oc6ccccc67)cc5c34)n2)cc1] | 66% |
| 7d | 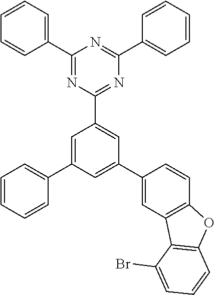 [SMILES: Brc1cccc2oc3ccc(-c4cc(-c5ccccc5)cc(-c5nc(-c6ccccc6)nc(-c6ccccc6)n5)c4)cc3c12] | 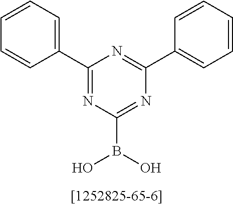 [SMILES: OB(O)c1nc(-c2ccccc2)nc(-c2ccccc2)n1] | 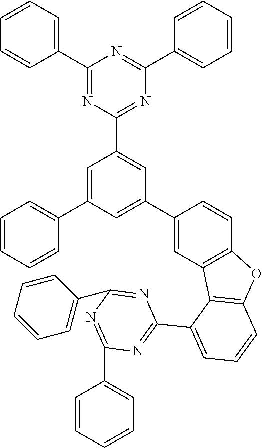 [SMILES: c1ccc(-c2cc(-c3ccc4oc5cccc(-c6nc(-c7ccccc7)nc(-c7ccccc7)n6)c5c4c3)cc(-c3nc(-c4ccccc4)nc(-c4ccccc4)n3)c2)cc1] | 62% |
| 8d | 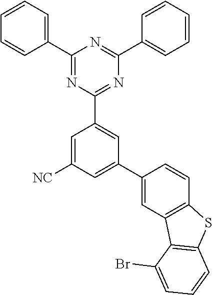 [SMILES: N#Cc1cc(-c2ccc3sc4cccc(Br)c4c3c2)cc(-c2nc(-c3ccccc3)nc(-c3ccccc3)n2)c1] | 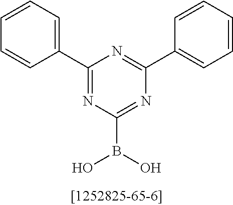 [SMILES: OB(O)c1nc(-c2ccccc2)nc(-c2ccccc2)n1] | 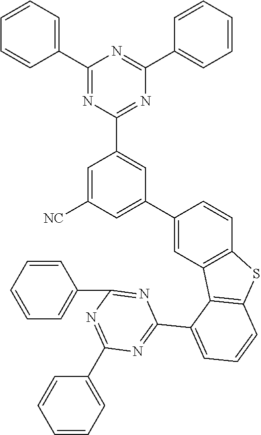 [SMILES: N#Cc1cc(-c2ccc3sc4cccc(-c5nc(-c6ccccc6)nc(-c6ccccc6)n5)c4c3c2)cc(-c2nc(-c3ccccc3)nc(-c3ccccc3)n2)c1] | 64% |
| 9d | 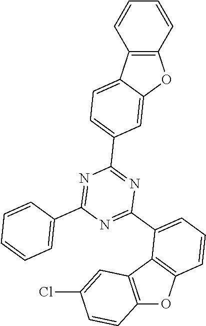 [SMILES: Clc1ccc2oc3cccc(-c4nc(-c5ccccc5)nc(-c5ccc6c(c5)oc5ccccc56)n4)c3c2c1] | 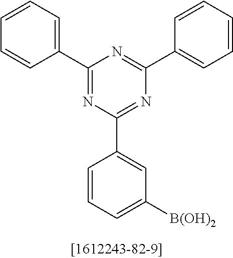 [SMILES: OB(O)c1cccc(-c2nc(-c3ccccc3)nc(-c3ccccc3)n2)c1] | 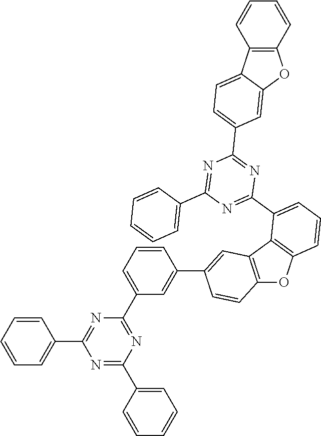 [SMILES: c1ccc(-c2nc(-c3ccccc3)nc(-c3cccc(-c4ccc5oc6cccc(-c7nc(-c8ccccc8)nc(-c8ccc9c(c8)oc8ccccc89)n7)c6c5c4)c3)n2)cc1] | 76% |

1.-15. (canceled)

16. An organic electroluminescent device comprising an anode, a cathode and at least one organic layer, comprising at least one light-emitting layer, where the at least one light-emitting layer comprises at least one compound of the formula (1) as host material 1 and at least one compound of the formula (2) as host material 2, 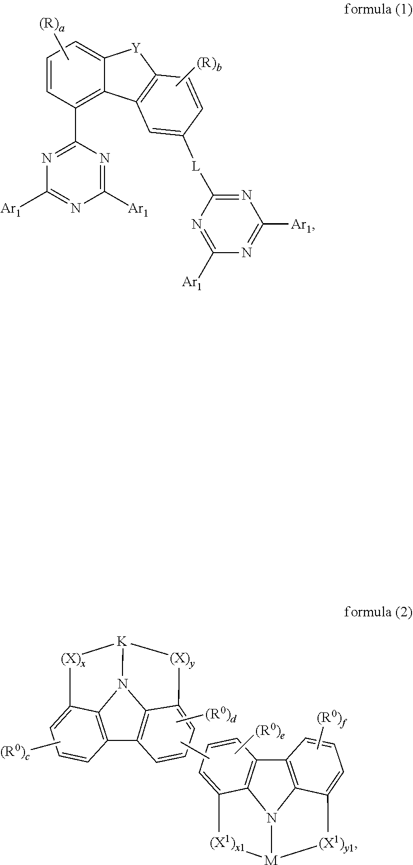
where the following applies to the symbols and indices used:
Y is selected from O, S, C(CH₃)₂, C(phenyl)₂ or 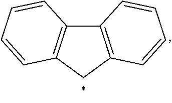 [SMILES: c1ccc2c(c1)Cc1ccccc1-2]
where * marks the C atom that is bonded to the remainder of the formula (1);
L is selected from one of the divalent linkers L-1 to L-26, 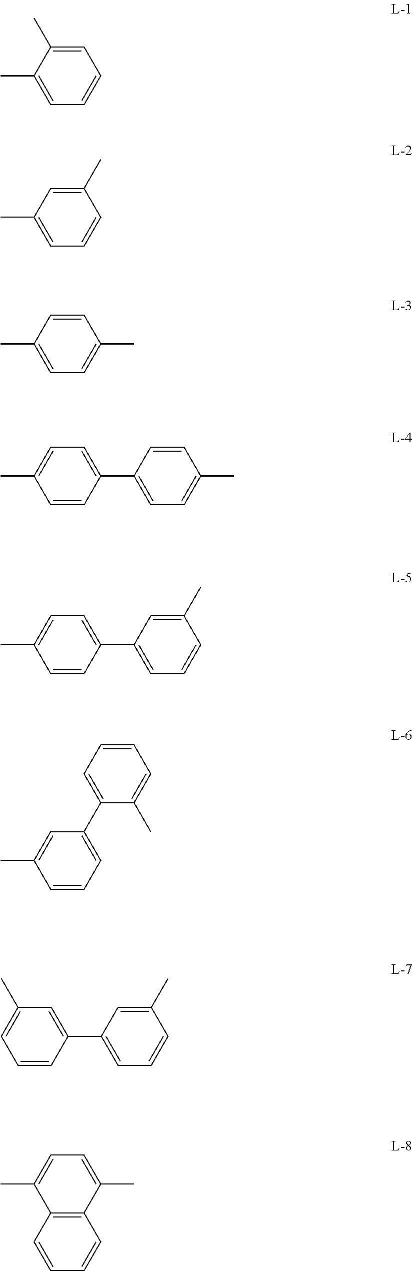 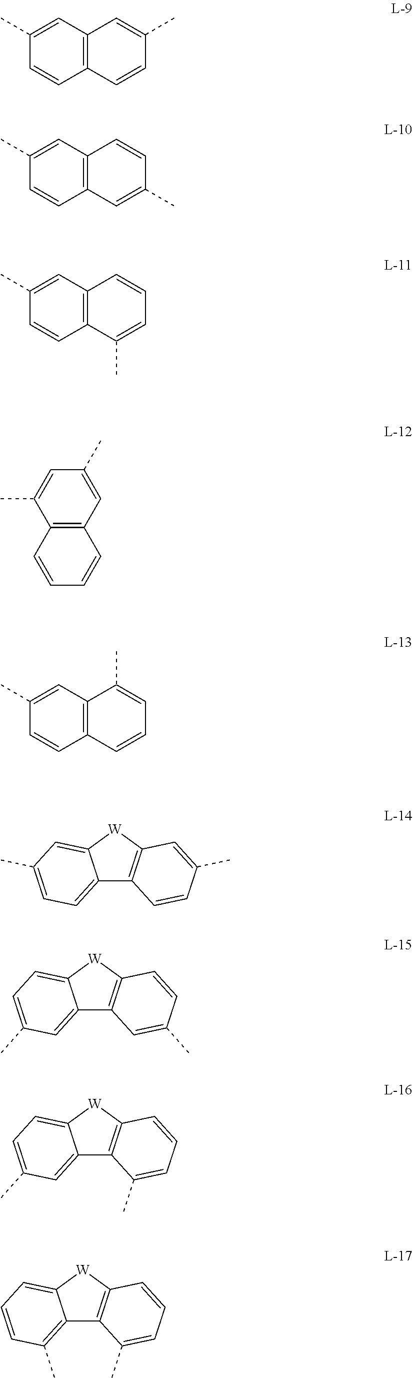 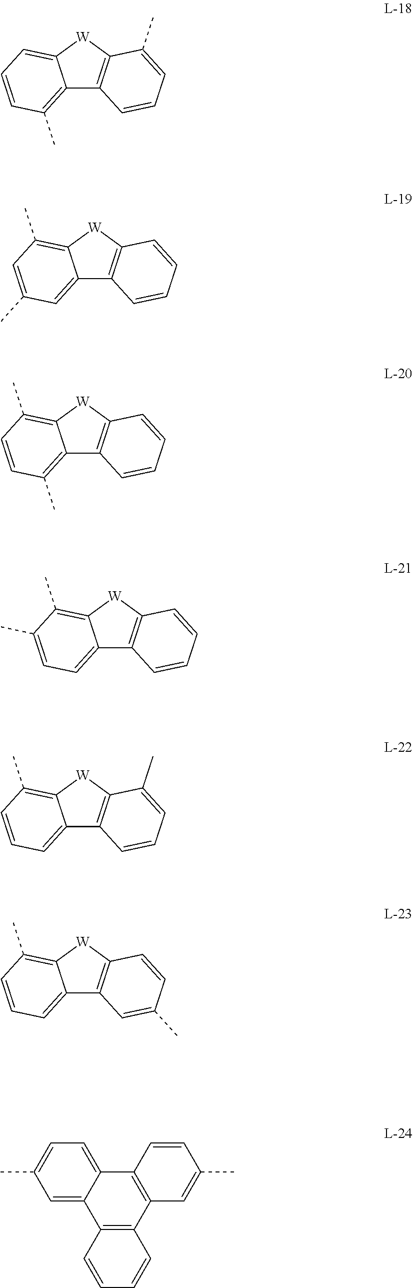 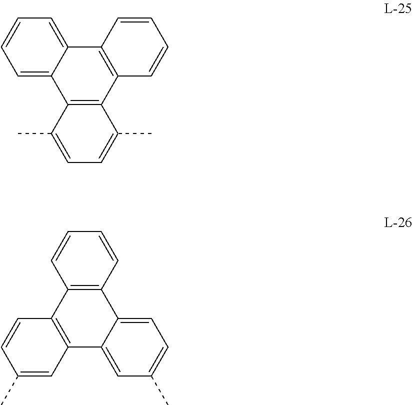
where the linkers L-1 to L-26 may also be substituted by one or more substituents R;
W is O, S or C(CH₃)₂;
a is 0 or 1;
b is 0 or 1;
R is selected on each occurrence, identically or differently, from the group consisting of CN, a straight-chain alkyl, alkoxy or thioalkyl group having 1 to 20 C atoms or a branched or cyclic alkyl, alkoxy or thioalkyl group having 3 to 20 C atoms, an aromatic or heteroaromatic ring system having 5 to 40 aromatic ring atoms, an aryloxy or heteroaryloxy group having 5 to 40 aromatic ring atoms, or an aralkyl or heteroaralkyl group having 5 to 40 aromatic ring atoms;
Ar1 is on each occurrence, in each case independently of one another, an aryl or heteroaryl group having 5 to 40 aromatic ring atoms, which may be substituted by one or more radicals R;
K, M are in each case, independently of one another, an aromatic ring system having 6 to 40 aromatic ring atoms which is unsubstituted or partially or fully deuterated or monosubstituted by R*, if x and y denote 0 and if x₁ and y₁ denote 0, or
K, M in each case, independently of one another, together with X or X¹, form a heteroaromatic ring system having 14 to 40 ring atoms as soon as the value of x, x1, y and/or y1 denotes 1;
x, x1 are in each case, independently on each occurrence, 0 or 1;
y, y1 are in each case, independently on each occurrence, 0 or 1;
X and X¹ are in each case, independently of one another on each occurrence, a bond or C(R#)₂;
R⁰ is on each occurrence, independently of one another, an unsubstituted or partially or fully deuterated aromatic ring system having 6 to 18 C atoms;
R* is dibenzofuranyl or dibenzothiophenyl;
R# is on each occurrence, independently of one another, a straight-chain or branched alkyl group having 1 to 4 C atoms and
c, d, e and f are, independently of one another, 0 or 1.

17. The organic electroluminescent device according to claim 16, wherein Y in host material 1 denotes O.

18. The organic electroluminescent device according to claim 16, wherein host material 2 conforms to one of the formulae (2a), (2b) or (2c), 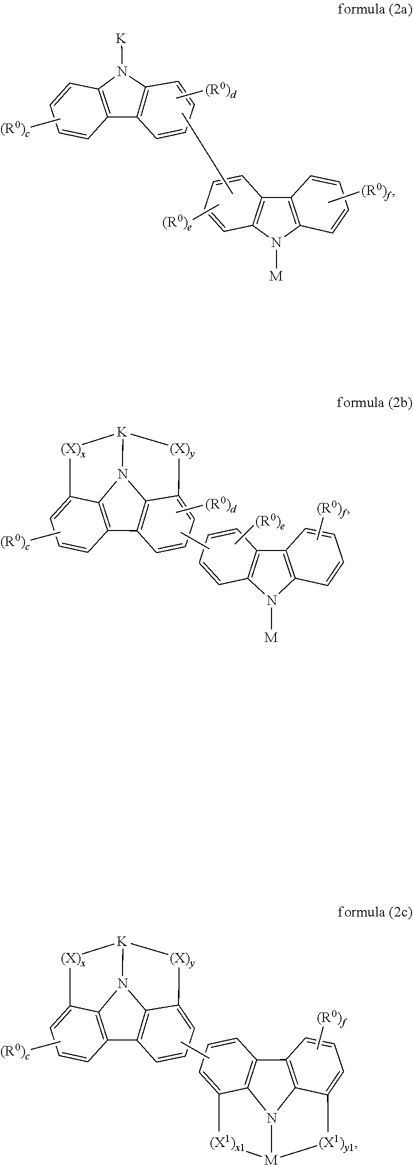
where the symbols and indices X, X¹, R⁰, c, d, e and f used have a meaning as in claim 16 and
K and M in compounds of the formula (2a) in each case, independently of one another, denote an aromatic ring system having 6 to 40 aromatic ring atoms which is unsubstituted or partially or fully deuterated or monosubstituted by R*;
M in compounds of the formula (2b) denotes an aromatic ring system having 6 to 40 aromatic ring atoms which is unsubstituted or partially or fully deuterated or monosubstituted by R*;
K in compounds of the formula (2b), together with X, forms a heteroaromatic ring system having 14 to 40 ring atoms and x and y in compounds of the formula (2b) in each case, independently of one another, denote 0 or 1 and the sum of x and y denotes at least 1; and
K and M in compounds of the formula (2c) in each case, independently of one another, together with X or X¹, form a heteroaromatic ring system having 14 to 40 ring atoms and
x, x1, y and y1 in compounds of the formula (2c) in each case, independently of one another, denote 0 or 1 and the sum of x and y denotes at least 1 and the sum of x1 and yl denotes at least 1.

19. The organic electroluminescent device according to claim 16, wherein L in host material 1 is selected from the divalent linkers L-1 to L-13 and L-24 to L-26.

20. The organic electroluminescent device according to claim 16, wherein the device is an electroluminescent device selected from organic light-emitting transistors (OLETs), organic field-quench devices (OFQDs), organic light-emitting electrochemical cells (OLECs, LECs, LEECs), organic laser diodes (O-lasers) and organic light-emitting diodes (OLEDs).

21. The organic electroluminescent device according to claim 16, wherein, besides the light-emitting layer (EML), the device comprises a hole-injection layer (HIL), a hole-transport layer (HTL), an electron-transport layer (ETL), an electron-injection layer (EIL) and/or a hole-blocking layer (HBL).

22. The organic electroluminescent device according to claim 16, wherein the light-emitting layer, besides the at least one host material 1 and the at least one host material 2, comprises at least one phosphorescent emitter.

23. The organic electroluminescent device according to claim 22, wherein the phosphorescent emitter conforms to the formula (3), 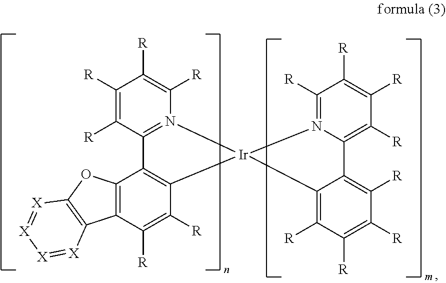
where the symbols and indices for this formula (3) have the meaning:
n+m is 3, n is 1 or 2, m is 2 or 1,
X is N or CR,
R is H, D or a branched or linear alkyl group having 1 to 10 C atoms or a partially or fully deuterated branched or linear alkyl group having 1 to 10 C atoms or a cycloalkyl group having 4 to 7 C atoms, which may be partially or fully substituted by deuterium.

24. A process for the production of a device according to claim 16, wherein the light-emitting layer is applied by gas-phase deposition or from solution.

25. The process according to claim 24, wherein the at least one compound of the formula (1) and the at least one compound of the formula (2) are deposited from the gas phase, successively or simultaneously from at least two material sources, optionally with the at least one phosphorescent emitter, and form the light-emitting layer.

26. The process according to claim 24, wherein the at least one compound of the formula (1) and the at least one compound of the formula (2) are deposited from the gas phase as a mixture, successively or simultaneously with the at least one phosphorescent emitter, and form the light-emitting layer.

27. The process according to claim 24, wherein the at least one compound of the formula (1) and the at least one compound of the formula (2) are applied from a solution together with the at least one phosphorescent emitter in order to form the light-emitting layer.

28. A mixture comprising at least one compound of the formula (1) and at least one compound of the formula (2), 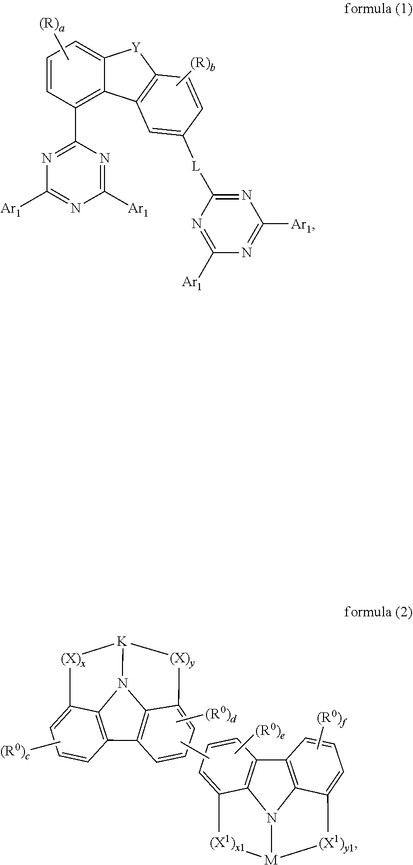
where the following applies to the symbols and indices used:
Y is selected from O, S, C(CH₃)₂, C(phenyl)₂ or 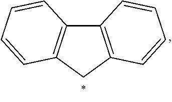 [SMILES: c1ccc2c(c1)Cc1ccccc1-2]
where * marks the C atom that is bonded to the remainder of the formula (1);
L is selected from one of the divalent linkers L-1 to L-26, 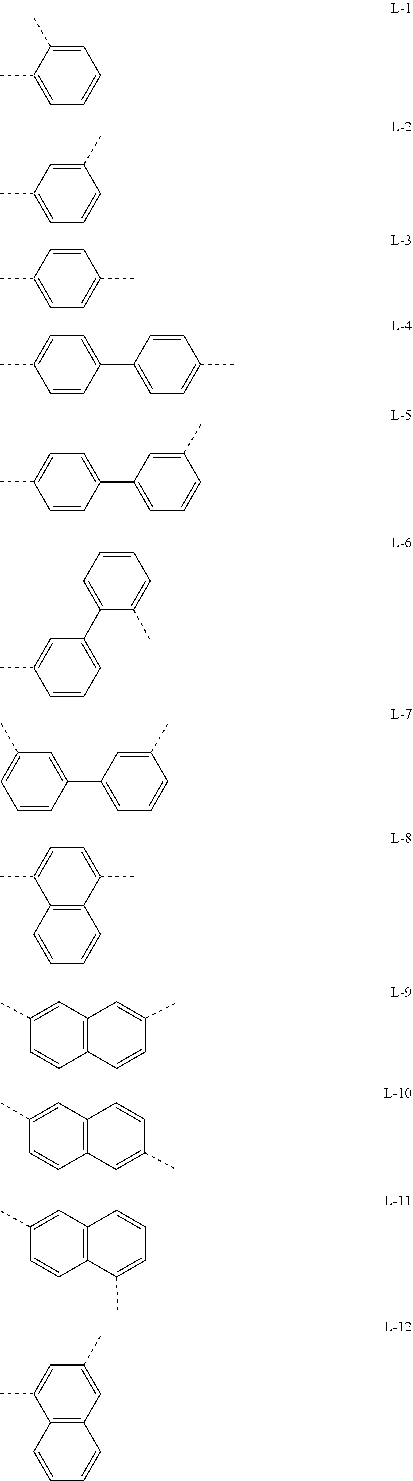 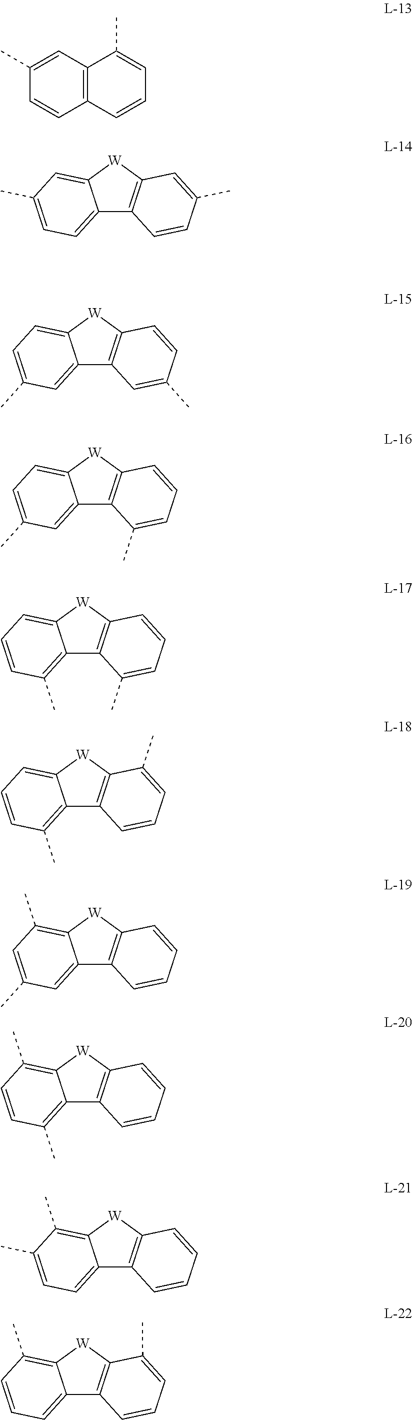 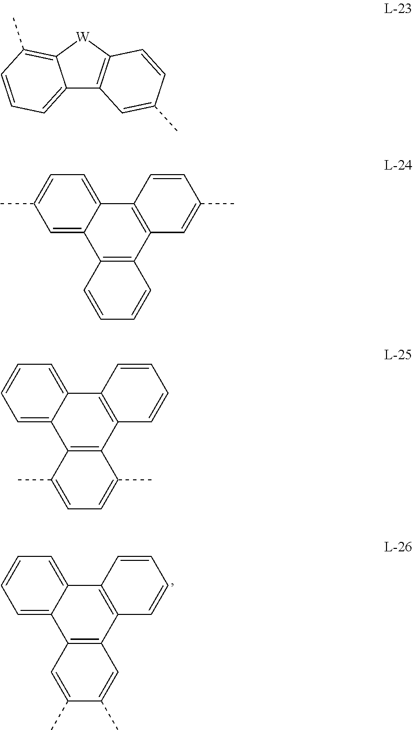
where the linkers L-1 to L-26 may also be substituted by one or more substituents R;
W is O, S or C(CH₃)₂;
a is 0 or 1;
b is 0 or 1;
R is selected on each occurrence, identically or differently, from the group consisting of CN, a straight-chain alkyl, alkoxy or thioalkyl group having 1 to 20 C atoms or a branched or cyclic alkyl, alkoxy or thioalkyl group having 3 to 20 C atoms, an aromatic or heteroaromatic ring system having 5 to 40 aromatic ring atoms, an aryloxy or heteroaryloxy group having 5 to 40 aromatic ring atoms, or an aralkyl or heteroaralkyl group having 5 to 40 aromatic ring atoms;
Ar₁ is on each occurrence, in each case independently of one another, an aryl or heteroaryl group having 5 to 40 aromatic ring atoms, which may be substituted by one or more radicals R;
K, M are in each case, independently of one another, an aromatic ring system having 6 to 40 aromatic ring atoms which is unsubstituted or partially or fully deuterated or monosubstituted by R*, if x and y denote 0 and if x₁ and y1 denote 0, or
K, M in each case, independently of one another, together with X or X¹, form a heteroaromatic ring system having 14 to 40 ring atoms as soon as the value of x, x1, y and/or y1 denotes 1;
x, x1 are in each case, independently on each occurrence, 0 or 1;
y, y1 are in each case, independently on each occurrence, 0 or 1;
X and X¹ are in each case, independently of one another on each occurrence, a bond or C(R#)₂;
R⁰ is on each occurrence, independently of one another, an unsubstituted or partially or fully deuterated aromatic ring system having 6 to 18 C atoms;
R* is dibenzofuranyl or dibenzothiophenyl;
R# is on each occurrence, independently of one another, a straight-chain or branched alkyl group having 1 to 4 C atoms; and
c, d, e and f are, independently of one another, 0 or 1.

29. The mixture according to claim 28, wherein the mixture consists of at least one compound of the formula (1), at least one compound of the formula (2) and a phosphorescent emitter.

30. A formulation comprising the mixture according to claim 28 and at least one solvent.
